(19) United States
(12) Patent Application Publication
(10) Pub. No.: US 2016/0209747 A1
(43) Pub. Date: Jul. 21, 2016

(54) ACTIVE LIGHT SENSITIVE OR RADIATION SENSITIVE COMPOSITION, AND RESIST FILM, PATTERN FORMING METHOD, RESIST-COATED MASK BLANK, METHOD FOR PRODUCING PHOTOMASK, PHOTOMASK, METHOD FOR MANUFACTURING ELECTRONIC DEVICE, AND ELECTRONIC DEVICE, EACH OF WHICH USES SAID ACTIVE LIGHT SENSITIVE OR RADIATION SENSITIVE COMPOSITION

(71) Applicant: FUJIFILM Corporation, Tokyo (JP)

(72) Inventor: Shuhei YAMAGUCHI, Haibara-gun (JP)

(73) Assignee: FUJIFILM Corporation, Tokyo (JP)

(21) Appl. No.: 15/081,089

(22) Filed: Mar. 25, 2016

Related U.S. Application Data
(63) Continuation of application No. PCT/JP2014/073959, filed on Sep. 10, 2014.

(30) Foreign Application Priority Data
Sep. 26, 2013 (JP) 2013-200599

(51) Int. Cl. G03F 7/039; G03F 1/78; G03F 7/32; G03F 1/50; G03F 7/038; G03F 7/20

(52) U.S. Cl. CPC G03F 7/039; G03F 7/038; G03F 7/20; G03F 7/32; G03F 1/50; G03F 1/78

(57) ABSTRACT

There is provided an active light sensitive or radiation sensitive composition which contains (A) a compound that generates an acid by irradiation with active light or radiation, (P) a compound of which the solubility in alkali developers is increased due to the action of an acid, and (N) at least one specific compound, and which can satisfy high resolving power, an excellent pattern shape, and low line width roughness (LWR) at the same time to a high level in formation of a very fine pattern (for example, a line width of 50 nm or less), and a resist film, a pattern forming method, a resist-coated mask blank, a method for producing a photomask, a photomask, a method for manufacturing an electronic device, and an electronic device, each of which uses this active light sensitive or radiation sensitive composition.

### CROSS REFERENCE TO RELATED APPLICATION

This is a continuation of International Application No. PCT/JP2014/073959 filed on Sep. 10, 2014, and claims priority from Japanese Patent Application No. 2013-200599 filed on Sep. 26, 2013, the entire disclosures of which are incorporated herein by reference.

### BACKGROUND OF THE INVENTION

1. Field of the Invention

The present invention relates to an active light sensitive or radiation sensitive composition, and a resist film, a pattern forming method, a resist-coated mask blank, a method for producing a photomask, a photomask, a method for manufacturing an electronic device, and an electronic device, each of which uses the active light sensitive or radiation sensitive composition. Particularly, the present invention relates to an active light sensitive or radiation sensitive composition that is suitably used for a production process of ultra LSIs and high-capacity microchips, a fabrication process of molds for nanoimprint, an ultramicrolithography process applicable for a production process of high-density information recording media, and other photofabrication processes, and a resist film, a pattern forming method, a resist-coated mask blank, a method for producing a photomask, a photomask, a method for manufacturing an electronic device, and an electronic device, each of which uses the active light sensitive or radiation sensitive composition. In more detail, the present invention relates to an active light sensitive or radiation sensitive composition which is suitable used in fine processing of a semiconductor element using an electron beam or EUV light, and a resist film, a pattern forming method, a resist-coated mask blank, a method for producing a photomask, a photomask, a method for manufacturing an electronic device, and an electronic device, each of which uses the active light sensitive or radiation sensitive composition.

2. Description of the Related Art

In the related art, fine processing by lithography using a photoresist composition has been performed in the manufacturing process of semiconductor devices such as IC and LSI. In recent years, with higher integration of integrated circuits, ultra fine patterns have been required to be formed in a sub-micron region or a quarter-micron region. Accordingly, exposure wavelengths tend to be shortened, for example, from g-line to i-line, and to a KrF excimer laser light. Furthermore, at present, lithography using an electron beam or EUV light, in addition to the excimer laser light, is also being developed.

Lithography using an electron beam or EUV light is positioned as a next generation or the generation after next pattern forming technology, and a resist composition having high sensitivity and high-resolution is desired.

In particular, for shortening the wafer processing time, sensitivity improvement is a very important issue, but when trying to improve sensitivity, the pattern shape or the resolving power represented by the limit resolution line width decreases, and therefore, development of a resist composition which satisfies these properties at the same time has been strongly desired.

High sensitivity, and high resolution and a favorable pattern shape are in a trade-off relationship, and how to satisfy these at the same time is very important.

As the active light sensitive or radiation sensitive composition suitable for a lithography process using an electron beam or EUV light, from the viewpoint of high sensitivity, a chemical amplification positive resist composition using mainly an acid catalytic reaction has been considered.

On the other hand, in the manufacture of a semiconductor element or the like, formation of patterns having various shapes such as a line, a trench, and a hole is required. To meet the requirement for formation of patterns having various shapes, development of not only a positive type active light sensitive or radiation sensitive resin composition but also a negative type active light sensitive or radiation sensitive resin composition has also been performed (for example, refer to JP2002-148806A and JP2008-268935A).

Fine processing using a resist composition is not only directly used for producing integrated circuits but also has been applied for fabricating a so-called mold structure for imprint in recent years (for example, refer to JP2002-6500A).

### SUMMARY OF THE INVENTION

Therefore, it has become an important issue to form a very fine pattern (for example, a line width of 50 nm or less) in a state in which various performances (in particular, resolution, pattern shape, and roughness performance) are satisfied at the same time, in electron beam or EUV light lithography, in order to sufficiently respond to these applications.

However, from the viewpoint of total performance as a resist, it is extremely difficult to find a suitable combination of a resin, a photoacid generator, a basic compound, an additive, and a solvent, used, and, in particular, in view of recent demand for forming a very fine pattern (for example, a line width of 50 nm or less) with high performance, the current situation cannot yet be said to be sufficient.

Moreover, for example, JP3723671B discloses a negative photoresist composition containing polyhydroxystyrene in which 10% to 30% of a hydroxy group is protected or a mixture of this with polyhydroxystyrene, and a cross-linking agent, and JP1995-261392A (JP-H07-261392A) discloses a chemically amplified resist containing a chemically amplified resist base resin having a hydrophobic atomic group which is cleaved by an acid on the side chain of the base resin and a cross-linking agent, but both documents show no intention for formation of a very fine pattern (for example, a line width of 50 nm or less) and performance improvement thereof.

An object of the present invention is to provide an active light sensitive or radiation sensitive composition which can satisfy high resolving power, an excellent pattern shape, and low line width roughness (LWR) at the same time to a high level in formation of a very fine pattern (for example, a line width of 50 nm or less).

Another object of the present invention is to provide a resist film, a pattern forming method, a resist-coated mask blank, a method for producing a photomask, a photomask, a method for manufacturing an electronic device, and an electronic device, each of which uses the active light sensitive or radiation sensitive composition.

The present invention has the following configuration, whereby the above-described objects of the present invention are achieved.

[1]

An active light sensitive or radiation sensitive composition containing (A) a compound that generates an acid by irradiation with active light or radiation, (P) a compound of which the solubility in alkali developers is increased due to the action of an acid, and (N) at least one compound selected from the group consisting of the following [N-A], [N-B], and [N-C], in which [N-A] is a resin of which the solubility in alkali developers is decreased due to the action of an acid, active light or radiation, or an activated species, [N-B] is a compound that generates an acid by irradiation with active light or radiation, and of which the solubility in alkali developers is decreased due to the action of an acid, active light or radiation, or an activated species, and [N-C] is a low molecular weight compound of which the solubility in alkali developers is decreased due to the action of an acid, active light or radiation, or an activated species.

[2]

The active light sensitive or radiation sensitive composition according to [1], which is an active light sensitive or radiation sensitive composition for alkali developing type electron beam exposure or for EUV exposure.

[3]

The active light sensitive or radiation sensitive composition according to [1] or [2], which is a negative type active light sensitive or radiation sensitive composition, in which the content of the compound (N) is 10% by mass or greater with respect to the total solid content of the active light sensitive or radiation sensitive composition.

[4]

The active light sensitive or radiation sensitive composition according to [3], in which the compound (P) is a resin of which the solubility in alkali developers is increased due to the action of an acid.

[5]

The active light sensitive or radiation sensitive composition according to [4], in which the compound (P) is a resin having a repeating unit represented by the following General Formula (1).

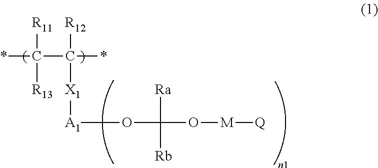

In General Formula (1), X₁ represents a single bond or a divalent connecting group.

A₁ represents a keto group or an (n1+1) valent aromatic ring group, and each of R₁₁, R₁₂, and R₁₃ independently represents a hydrogen atom, an alkyl group, a cycloalkyl group, a halogen atom, a cyano group, or an alkoxycarbonyl group.

R₁₃ may be bonded to A₁ to form a ring, and R₁₃ in this case represents an alkylene group.

Ra represents a hydrogen atom, an alkyl group, a cycloalkyl group, an aryl group, an aralkyl group, or a heterocyclic group, and Rb represents a hydrogen atom, an alkyl group, a cycloalkyl group, an aryl group, an aralkyl group, or a heterocyclic group.

M represents a single bond or a divalent connecting group. Q represents an alkyl group, a cycloalkyl group, an aryl group, an aralkyl group, or a heterocyclic group. Ra and Rb may be bonded to each other to form a ring. At least two of Ra, M, and Q may be bonded to each other to form a ring.

When A₁ is a keto group, n1 represents 1, and when A₁ is an (n+1) valent aromatic group, n1 represents an integer of 1 to 4. When n1 is 2 or greater, a plurality of Ra's, a plurality of Rb's, a plurality of M's, and a plurality of Q's may be the same as or different from each other, respectively.

[6]

The active light sensitive or radiation sensitive composition according to any one of [3] to [5], further containing a compound having a molecular weight of 500 or greater as the compound (N).

[7]

The active light sensitive or radiation sensitive composition according to any one of [3] to [6], still further containing a compound (N-1) of which the solubility in alkali developers is decreased due to the action of an acid as the compound (N).

[8]

The active light sensitive or radiation sensitive composition according to any one of [3] to [7], in which the compound (A) is a resin containing a repeating unit having a portion that generates an acid by irradiation with active light or radiation.

[9]

The active light sensitive or radiation sensitive composition according to any one of [3] to [8], still further containing (C) a basic compound or an ammonium salt compound, of which the basicity is decreased by irradiation with active light or radiation.

[10]

The active light sensitive or radiation sensitive composition according to [9], in which the compound (C) is a sulfonium salt having a nitrogen atom on the cation thereof.

[11]

The active light sensitive or radiation sensitive composition according to [1] or [2], which is a positive type active light sensitive or radiation sensitive composition, in which the content of the compound (N) is 1% by mass or greater with respect to the total solid content of the active light sensitive or radiation sensitive composition.

[12]

The active light sensitive or radiation sensitive composition according to [11], in which the compound (P) is a resin of which the solubility in alkali developers is increased due to the action of an acid.

[13]

The active light sensitive or radiation sensitive composition according to [12], in which the compound (P) is a resin having a repeating unit represented by the following General Formula (1).

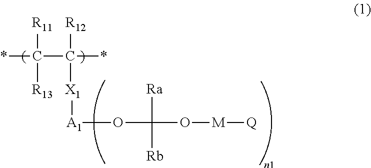

In General Formula (1), X₁ represents a single bond or a divalent connecting group.

A₁ represents a keto group or an (n1+1) valent aromatic ring group, and each of R₁₁, R₁₂, and R₁₃ independently represents a hydrogen atom, an alkyl group, a cycloalkyl group, a halogen atom, a cyano group, or an alkoxycarbonyl group.

R₁₃ may be bonded to A₁ to form a ring, and R₁₃ in this case represents an alkylene group.

Ra represents a hydrogen atom, an alkyl group, a cycloalkyl group, an aryl group, an aralkyl group, or a heterocyclic group, and Rb represents a hydrogen atom, an alkyl group, a cycloalkyl group, an aryl group, an aralkyl group, or a heterocyclic group.

M represents a single bond or a divalent connecting group. Q represents an alkyl group, a cycloalkyl group, an aryl group, an aralkyl group, or a heterocyclic group. Ra and Rb may be bonded to each other to form a ring. At least two of Ra, M, and Q may be bonded to each other to form a ring.

When A₁ is a keto group, n1 represents 1, and when A₁ is an (n+1) valent aromatic group, n1 represents an integer of 1 to 4. When n1 is 2 or greater, a plurality of Ra's, a plurality of Rb's, a plurality of M's, and a plurality of Q's may be the same as or different from each other, respectively.

[14]

The active light sensitive or radiation sensitive composition according to any one of [11] to [13], still further containing a compound having a molecular weight of 500 or greater as the compound (N).

[15]

The active light sensitive or radiation sensitive composition according to any one of [11] to [14], still further containing a compound (N-1) of which the solubility in alkali developers is decreased due to the action of an acid as the compound (N).

[16]

The active light sensitive or radiation sensitive composition according to any one of [11] to [15], in which the compound (A) is a resin containing a repeating unit having a portion that generates an acid by irradiation with active light or radiation.

[17]

The active light sensitive or radiation sensitive composition according to any one of [11] to [16], still further containing (C) a basic compound or an ammonium salt compound, of which the basicity is decreased by irradiation with active light or radiation.

[18]

The active light sensitive or radiation sensitive composition according to [17], in which the compound (C) is a sulfonium salt having a nitrogen atom on the cation thereof.

[19]

A resist film which is formed of the active light sensitive or radiation sensitive composition according to any one of [1] to [18].

[20]

A pattern forming method, including (a) forming a film using an active light sensitive or radiation sensitive composition according to any one of [1] to [18], (b) exposing the film, and (c) developing the exposed film using an alkali developer.

[21]

A resist-coated mask blank coated with the active light sensitive or radiation sensitive composition according to any one of [1] to [18].

[22]

A method for producing a photomask, including exposing the resist-coated mask blank according to [21] to an electron beam or EUV light and developing the exposed mask blank using an alkali developer.

[23]

A photomask obtained by the method for producing a photomask according to [22].

[24]

A method for manufacturing an electronic device, including the pattern forming method according to [20].

[25]

An electronic device manufactured by the method for manufacturing an electronic device according to [24].

According to the present invention, it is possible to provide an active light sensitive or radiation sensitive composition which can satisfy high resolving power, an excellent pattern shape, and low line width roughness (LWR) at the same time to a high level in formation of a very fine pattern (for example, a line width of 50 nm or less).

In addition, according to the present invention, it is possible to provide a resist film, a pattern forming method, a resist-coated mask blank, a method for producing a photomask, a photomask, a method for manufacturing an electronic device, and an electronic device, each of which uses the active light sensitive or radiation sensitive composition.

### DESCRIPTION OF THE PREFERRED EMBODIMENTS

Hereinafter, embodiments of the present invention will be described in detail.

Regarding the description of a group (atomic group) in the present specification, when the description does not indicate whether a group is substituted or unsubstituted, the description includes both the group having a substituent and the group not having a substituent. For example, “alkyl group” includes not only an alkyl group (an unsubstituted alkyl group) which does not have a substituent, but also an alkyl group (a substituted alkyl group) which has a substituent.

In the present invention, the term “active light” or “radiation” refers to, for example, a bright line spectrum of a mercury lamp, far-ultraviolet rays represented by an excimer laser, extreme ultraviolet rays (EUV light), X-rays, particle beams such as an electron beam, an ion beam, or the like. In addition, the “light” in the present invention refers to the active light or the radiation.

In addition, the term “exposure” in the present specification includes not only the exposure performed using a mercury lamp, far-ultraviolet rays represented by an excimer laser, X-rays, or extreme ultraviolet rays (EUV light), but also drawing performed using a particle beam such as an electron beam, an ion beam, or the like, unless otherwise specified.

The active light sensitive or radiation sensitive composition of the present invention is an active light sensitive or radiation sensitive composition containing (A) a compound that generates an acid by irradiation with active light or radiation, (P) a compound of which the solubility in alkali developers is increased due to the action of an acid, and (N) at least one type of compound selected from the group consisting of the following [N-A], [N-B], and [N-C] (hereinafter, collectively referred to as “compound (N)”), in which [N-A] is a resin of which the solubility in alkali developers is decreased due to the action of an acid, active light or radiation, or an activated species, [N-B] is a compound that generates an acid by irradiation with active light or radiation, and of which the solubility in alkali developers is decreased due to the action of an acid, active light or radiation, or an activated species, and [N-C] is a low molecular weight compound of which the solubility in alkali developers is decreased due to the action of an acid, active light or radiation, or an activated species.

The active light sensitive or radiation sensitive composition of the present invention is preferably an active light sensitive or radiation sensitive composition for alkali developing type electron beam exposure or for EUV exposure. That is, the composition of the present invention is preferably used in a pattern forming method in which a film formed of the composition is exposed to an electron beam or EUV light, and is developed with alkali developer.

The reason why an active light sensitive or radiation sensitive composition which can satisfy high resolving power, an excellent pattern shape, and low line width roughness (LWR) at the same time to a high level in formation of a very fine pattern (for example, a line width of 50 nm or less) can be provided by the present invention is not clear, but it is thought to be as follows.

As described above, the active light sensitive or radiation sensitive composition of the present invention contains a compound of which the solubility in alkali developers is increased due to the action of an acid and a compound of which the solubility in alkali aqueous solutions is decreased by the action of an acid, active light or radiation, or an activated species. That is, the active light sensitive or radiation sensitive composition of the present invention contains a compound configuring an image truly opposite to the target image, that is, a positive image in a case where the target image is a negative image, and a negative image in a case where the target image is a positive image. It is thought that action of forming such a reverse form of an image cancels the unwanted image formation at the unexposed portion by, in particular, forward scattering and backward scattering in the electron beam exposure, and flare light and out-of-band light in the EUV exposure (leakage light generated at the ultraviolet light range of a wavelength of 100 nm to 400 nm), and as a result, the above-described effects are obtained.

The active light sensitive or radiation sensitive composition according to the present invention is representatively a positive composition or a negative composition. In addition, the active light sensitive or radiation sensitive composition according to the present invention is typically a chemical amplification resist composition. The constitution of this composition will be described below.

[1] (P) Compound of which Solubility in Alkali Developers is Increased Due to Action of Acid

The active light sensitive or radiation sensitive composition of the present invention contains a compound (P) of which the solubility in alkali developers is increased due to the action of an acid.

The compound of which the solubility in alkali developers is increased due to the action of an acid, of the present invention, is not particularly limited, and examples thereof include a resin [P-A] of which the solubility in alkali developers is increased due to the action of an acid, a compound [P-B] that generates an acid by irradiation with active light or radiation, and of which the solubility in alkali developers is increased due to the action of an acid, and a low molecular weight compound [P-C] of which the solubility in alkali developers is increased due to the action of an acid.

[P-A] Resin of which Solubility in Alkali Developers is Increased Due to Action of Acid

Although the resin [P-A] of which the solubility in alkali developers is increased due to the action of an acid is not particularly limited, the resin [P-A] is preferably a resin having a group (hereinafter, also referred to as “acid-decomposable group”) that generates an alkali-soluble group by being decomposed due to the action of an acid.

The acid-decomposable group preferably has a structure in which an alkali-soluble group is decomposed due to the action of an acid, which is protected with a group leaving.

Examples of the alkali-soluble group include a phenolic hydroxyl group, a carboxyl group, a fluorinated alcohol group, a sulfonic acid group, a sulfonamide group, a sulfonyl imide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

Preferable examples of the alkali-soluble group include a phenolic hydroxyl group, a carboxyl group, a fluorinated alcohol group (preferably, a hexafluoroisopropanol group), and a sulfonic acid group.

A preferable group as the acid-decomposable group is a group in which a hydrogen atom of the alkali-soluble group has been substituted with a group leaving due to an acid.

Examples of the group leaving due to an acid include —C(R₃₆)(R₃₇)(R₃₈), —C(R₃₆)(R₃₇)(OR₃₉), and —C(R₀₁)(R₀₂)(OR₃₉).

In the formula, each of R₃₆ to R₃₉ independently represents an alkyl group, a cycloalkyl group, an aryl group, an aralkyl group, or an alkenyl group. R₃₆ and R₃₇ may be bonded to each other to form a ring.

Each of R₀₁ and R₀₂ independently represents a hydrogen atom, an alkyl group, a cycloalkyl group, an aryl group, an aralkyl group, or an alkenyl group.

The acid-decomposable group is preferably a cumyl ester group, an enol ester group, an acetal ester group, and a tertiary alkyl ester group, and more preferably a tertiary alkyl ester group.

In a case where the resin [P-A] is a resin having an acid-decomposable group, the resin [P-A] is preferably a resin having a repeating unit having an acid-decomposable group, more preferably a resin having a repeating unit represented by the following General Formula (1) or (V), and still more preferably a resin having a repeating unit represented by the following General Formula (1).

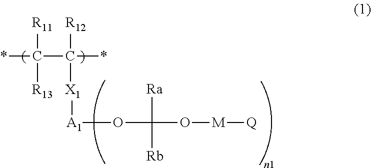

In General Formula (1), X₁ represents a single bond or a divalent connecting group.

A₁ represents a keto group or an (n1+1) valent aromatic ring group.

Each of R₁₁, R₁₂, and R₁₃ independently represents a hydrogen atom, an alkyl group, a cycloalkyl group, a halogen atom, a cyano group, or an alkoxycarbonyl group.

R₁₃ may be bonded to A₁ to form a ring, and R₁₃ in this case represents an alkylene group.

Ra represents a hydrogen atom, an alkyl group, a cycloalkyl group, an aryl group, an aralkyl group, or a heterocyclic group, and is preferably a group having 2 or more carbon atoms, and Rb represents a hydrogen atom, an alkyl group, a cycloalkyl group, an aryl group, an aralkyl group, or a heterocyclic group.

M represents a single bond or a divalent connecting group. Q represents an alkyl group, a cycloalkyl group, an aryl group, an aralkyl group, or a heterocyclic group. Ra and Rb may be bonded to each other to form a ring. At least two of Ra, M, and Q may be bonded to each other to form a ring.

When A₁ is a keto group, n1 represents 1, and when A₁ is an (n+1) valent aromatic group, n1 represents an integer of 1 to 4. When n1 is 2 or greater, a plurality of Ra's, a plurality of Rb's, a plurality of M's, and a plurality of Q's may be the same as or different from each other, respectively.

As the alkyl group represented by each of R₁₁ to R₁₃ in General Formula (1), alkyl groups having 20 or less carbon atoms such as a methyl group, an ethyl group, a propyl group, an isopropyl group, an n-butyl group, a sec-butyl group, a hexyl group, a 2-ethylhexyl group, an octyl group, and a dodecyl group, which may have a substituent, are preferalby, and alkyl groups having 8 or less carbon atoms are more preferable.

The alkyl group included in an alkoxycarbonyl group is preferably the same alkyl group as that represented by each of R₁₁ to R₁₃ described above.

The cycloalkyl group may be monocyclic or may be polycyclic, and preferable examples thereof include a monocyclic cycloalkyl group having 3 to 10 carbon atoms, such as a cyclopropyl group, a cyclopentyl group, or a cyclohexyl group, which may have a substituent.

Examples of the halogen atom include a fluorine atom, a chlorine atom, a bromine atom, and an iodine atom, and a fluorine atom is more preferable.

Examples of the preferable substituent in each group described above include an alkyl group, a cycloalkyl group, an aryl group, an amino group, an amide group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group, and the substituent preferably has 8 or less carbon atoms.

In a case where R₁₃ represents an alkylene group and forms a ring together with A₁, preferable examples of the alkylene group include an alkylene group having 1 to 8 carbon atoms such as a methylene group, an ethylene group, a propylene group, a butylene group, a hexylene group, or an octylene group. The alkylene group more preferably has 1 to 4 carbon atoms, and particularly preferably has 1 or 2 carbon atoms. A ring formed by bonding of R₁₃ and A₁ is particularly preferably a 5- or 6-membered ring.

As R₁₁ and R₁₂ in Formula (1), a hydrogen atom, an alkyl group, or a halogen atom is more preferable, and a hydrogen atom, a methyl group, an ethyl group, a trifluoromethyl group (—CF₃), a hydroxymethyl group (—CH₂—OH), a chloromethyl group (—CH₂—Cl), or a fluorine atom (—F) is particularly preferable. As R₁₃, a hydrogen atom, an alkyl group, a halogen atom, or an alkylene group (which forms a ring together with L₅) is more preferable, and a hydrogen atom, a methyl group, an ethyl group, a trifluoromethyl group (—CF₃), a hydroxymethyl group (—CH₂—OH), a chloromethyl group (—CH₂—Cl), a fluorine atom (—F), a methylene group (which forms a ring together with A₁), or an ethylene group (which forms a ring together with A₁) is particularly preferable.

Examples of the divalent connecting group represented by X₁ include —COO—, —CONR₁₄— (R₁₄ represents a hydrogen atom or an alkyl group), an alkylene group, and a group formed by combining two or more thereof. Here, examples of the alkyl group represented by R₁₄ include the same alkyl group as that represented by each of R₁₁ to R₁₃.

X₁ is preferably a single bond, —COO—, or —CONH—, more preferably a single bond or —COO—, and still more preferably a single bond.

A₁ represents a keto group or an (n1+1) valent aromatic ring group, and preferably an (n1+1) valent aromatic ring group.

The divalent aromatic ring group in a case where n1 is 1 may have a substituent, and preferable examples thereof include an arylene group having 6 to 18 carbon atoms such as a phenylene group, a tolylene group, and a naphthylene group, and divalent aromatic ring groups including a hetero ring, such as thiophene, furan, pyrrole, benzothiophene, benzofuran, benzopyrrole, triazine, imidazole, benzimidazole, triazole, thiadiazole, or thiazole.

Suitable specific examples of the (n1+1) valent aromatic ring group in a case where n1 is an integer of 2 or greater include a group obtained by excluding arbitrary (n1-1) hydrogen atoms from a specific example described above of the divalent aromatic ring group.

The (n1+1) valent aromatic ring group may further have a substituent.

Specific examples of the substituent which the (n1+1) valent aromatic ring group described above can have include the same as the specific examples of the substituent which each group represented by R₁₁ to R₁₃ can have.

When A₁ is an (n1+1) valent aromatic ring group, n1 is preferably 1 or 2, and more preferably 1.

The alkyl group represented by Ra is, for example, an alkyl group having 2 to 8 carbon atoms, and specifically, preferable examples thereof include a methyl group, an ethyl group, a propyl group, an n-butyl group, a sec-butyl group, a t-butyl group, a hexyl group, and an octyl group.

The alkyl group represented by Rb is, for example, an alkyl group having 1 to 8 carbon atoms, and specifically, preferable examples thereof include a methyl group, an ethyl group, a propyl group, an n-butyl group, a sec-butyl group, a t-butyl group, a hexyl group, and an octyl group.

The cycloalkyl group represented by Ra or Rb is, for example, a cycloalkyl group having 3 to 15 carbon atoms, and specifically, preferable examples thereof include a cyclopentyl group, a cyclohexyl group, a norbornyl group, and an adamantyl group.

The aryl group represented by Ra or Rb is, for example, an aryl group having 6 to 15 carbon atoms, and specifically, preferable examples thereof include a phenyl group, a tolyl group, a naphthyl group, and an anthryl group.

The aralkyl group represented by Ra or Rb is preferably an aralkyl group having 6 to 20 carbon atoms, and more preferably an aralkyl group having 7 to 12 carbon atoms. Specific examples of the aralkyl group represented by Ra or Rb include a benzyl group, a phenethyl group, a naphthylmethyl group, and a naphthylethyl group.

The heterocyclic group represented by Ra or Rb is preferably a heterocyclic group having 6 to 20 carbon atoms, and more preferably a heterocyclic group having 6 to 12 carbon atoms. Specific examples of the heterocyclic group represented by Ra or Rb include a pyridyl group, a pyrazyl group, a tetrahydrofuranyl group, a tetrahydropyranyl group, a tetrahydrothiophene group, a piperidyl group, a piperazyl group, a furanyl group, a pyranyl group, and a chromanyl group.

In General Formula (1), Ra is preferably an alkyl group having 2 or more carbon atoms, and more preferably a group represented by the following General Formula (4), from the viewpoint of moderate stability and moderate acid decomposition reactivity of an acid-decomposable group. In addition, Rb is preferably a hydrogen atom.

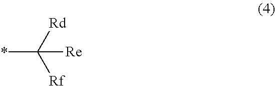

In General Formula (4), Rd represents an alkyl group, a cycloalkyl group, or an aryl group, and each of Re and Rf independently represents a hydrogen atom, an alkyl group, a cycloalkyl group, or an aryl group. Rd may be bonded to any one of Re and Rf, or to both Re and Rf to form a ring structure.

Examples of the alkyl group represented by each of Rd, Re, and Rf include the same as the alkyl groups described as the alkyl group represented by Rb.

Examples of the cycloalkyl group or the aryl group represented by each of Rd, Re, and Rf include the same as the cycloalkyl groups or the aryl groups described as the cycloalkyl group or the aryl group represented by Ra or Rb.

Examples of the divalent connecting group represented by M include an alkylene group (for example, a methylene group, an ethylene group, a propylene group, a butylene group, a hexylene group, or an octylene group), a cycloalkylene group (for example, a cyclopentylene group, a cyclohexylene group, or adamantylene group), an alkenylene group (for example, an ethenylene group, a propenylene group, or a butenylene group), a divalent aromatic ring group (for example, a phenylene group, a tolylene group, or a naphthylene group), —S—, —O—, —CO—, —SO₂—, —N(R₀)—, and a divalent connecting group obtained by combining a plurality of these. R₀ is a hydrogen atom or an alkyl group (which is, for example, an alkyl group having 1 to 8 carbon atoms, and specifically, a methyl group, an ethyl group, a propyl group, an n-butyl group, a sec-butyl group, a hexyl group, or an octyl group).

Specific examples and preferable examples of the alkyl group represented by Q include the same as those described for the alkyl group represented by Rb described above.

The cycloalkyl group represented by Q may be monocyclic or polycyclic. The cycloalkyl group preferably has 3 to 10 carbon atoms. Examples of the cycloalkyl group include a cyclopropyl group, a cyclobutyl group, a cyclopentyl group, a cyclohexyl group, a cycloheptyl group, a cyclooctyl group, a 1-adamantyl group, a 2-adamantyl group, a 1-norbornyl group, a 2-norbornyl group, a bornyl group, an isobornyl group, a 4-tetracyclo[6.2.1.1^{3,6}.0^{2,7}]dodecyl group, an 8-tricyclo[5.2.1.0^{2,6}]decyl group, and a 2-bicyclo[2.2.1]heptyl group. Among these, a cyclopentyl group, a cyclohexyl group, a 2-adamantyl group, an 8-tricyclo[5.2.1.0^{2,6}]decyl group, or a 2-bicyclo[2.2.1]heptyl group is preferable.

Specific examples and preferable examples of the aryl group represented by Q include the same as those described for the aryl group represented by Ra described above.

Specific examples and preferable examples of the heterocyclic group represented by Q include the same as those described for the heterocyclic group represented by Ra described above.

Each of the alkyl group, the cycloalkyl group, the aryl group, and the heterocyclic group represented by Q may have a substituent, and examples thereof include the same as the specific examples of the substituent which each group represented by R₁₁ to R₁₃ can have.

At least two of Q, M, and Ra may be bonded to each other to form a ring (preferably, a 5- or 6-membered ring).

As a ring which may be formed by bonding of at least two of Q, M, and Ra, a case where at least two of Q, M, and Ra are bonded to each other to form, for example, a propylene group or a butylene group, and as a result, a 5- or 6-membered ring containing an oxygen atom is formed is exemplified.

Each group represented by Ra, Rb, M, and Q in General Formula (1) may have a substituent, and examples thereof include the same as the specific examples of the substituent which each group represented by R₁₁ to R₁₃ can have, and the substituent preferably has 8 or less carbon atoms.

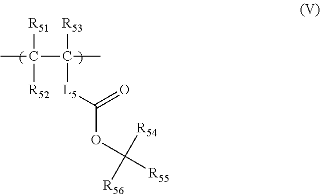

In General Formula (V), each of R₅₁, R₅₂, and R₅₃ independently represents a hydrogen atom, an alkyl group, a cycloalkyl group, a halogen atom, a cyano group, or an alkoxycarbonyl group. R₅₂ may be bonded to L₅ to form a ring, and R₅₂ in this case represents an alkylene group.

L₅ represents a single bond or a divalent connecting group, and in the case of forming a ring with R₅₂, represents a trivalent connecting group.

R₅₄ represents an alkyl group, and each of R₅₅ and R₅₆ independently represents a hydrogen atom, an alkyl group, a cycloalkyl group, an aryl group, or an aralkyl group. R₅₅ and R₅₆ may be bonded to each other to form a ring. However, R₅₅ and R₅₆ do not represent a hydrogen atom at the same time in any case.

General Formula (V) will be described in more detail.

Specific examples and preferable examples of the alkyl group, the alkoxycarbonyl group, the cycloalkyl group, or the halogen atom, represented by each of R₅₁ to R₅₃ in General Formula (V) include the same as the specific examples and preferable examples of the alkyl group, the alkoxycarbonyl group, the cycloalkyl group, or the halogen atom, represented by each of R₁₁ to R₁₃ in General Formula (1).

Examples of the divalent connecting group represented by L₅ include an alkylene group, a divalent aromatic ring group, —COO-L₁-, —O-L₁-, and a group formed by combining two or more thereof. Here, L₁ represents an alkylene group, a cycloalkylene group, a divalent aromatic ring group, and a group obtained by combining an alkylene group and a divalent aromatic ring group.

L₅ is preferably a single bond, a group represented by —COO-L₁-, or a divalent aromatic ring group. L₁ is preferably an alkylene group having 1 to 5 carbon atoms, and more preferably a methylene group or a propylene group. As the divalent aromatic ring group, a 1,4-phenylene group, a 1,3-phenylene group, a 1,2-phenylene group, or a 1,4-naphthylene group is preferable, and a 1,4-phenylene group is more preferable.

In a case where L₅ forms a ring by bonding to R₅₂, suitable examples of the trivalent connecting group represented by L₅ include a group obtained by excluding one arbitrary hydrogen atom from a specific example described above of the divalent connecting group represented by L₅.

The alkyl group represented by each of R₅₄ to R₅₆ is preferably an alkyl group having 1 to 20 carbon atoms, more preferably an alkyl group having 1 to 10 carbon atoms, and particularly preferably an alkyl group having 1 to 4 carbon atoms such as a methyl group, an ethyl group, an n-propyl group, an isopropyl group, an n-butyl group, an isobutyl group, or a t-butyl group.

The cycloalkyl group represented by R₅₅ or R₅₆ is preferably a cycloalkyl group having 3 to 20 carbon atoms, may be a cycloalkyl group which is monocyclic, such as a cyclopentyl group or a cyclohexyl group, and may be a cycloalkyl group which is polycyclic, such as a norbornyl group, an adamantyl group, a tetratricyclodecanyl group, or a tetracyclododecanyl group.

A ring formed by bonding of R₅₅ and R₅₆ to each other is preferably a ring having 3 to 20 carbon atoms, may be a monocyclic ring such as a cyclopentyl group or a cyclohexyl group, and may be a polycyclic ring such as a norbornyl group, an adamantyl group, a tetratricyclodecanyl group, or a tetracyclododecanyl group. In a case where R₅₅ and R₅₆ are bonded to each other to form a ring, R₅₄ is preferably an alkyl group having 1 to 3 carbon atoms, and a methyl group or an ethyl group is more preferable.

The aryl group represented by R₅₅ or R₅₆ preferably has 6 to 20 carbon atoms, and may be monocyclic or polycyclic, or may have a substituent. Examples thereof include a phenyl group, a 1-naphthyl group, a 2-naphthyl group, a 4-methylphenyl group, and a 4-methoxyphenyl group. In a case where any one of R₅₅ and R₅₆ is a hydrogen atom, the other is preferably an aryl group.

The aralkyl group represented by R₅₅ or R₅₆ may be monocyclic or polycyclic, or may have a substituent. The aralkyl group preferably has 7 to 21 carbon atoms, and examples thereof include a benzyl group and a 1-naphthylmethyl group.

As the synthetic method of a monomer corresponding to a repeating unit represented by General Formula (V), a general synthetic method of a polymerizable group-containing ester can be applied, but the method is not be particularly limited.

In a case where the resin [P-A] is a resin having an acid-decomposable group, the resin [P-A] is preferably a resin having a repeating unit represented by the following General Formula (AI).

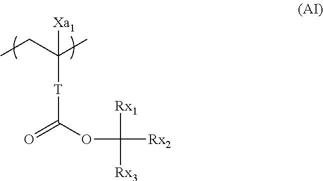

In General Formula (AI), Xa₁ represents a hydrogen atom, a methyl group which may have a substituent, or a group represented by —CH₂—R₉. R₉ represents a hydroxyl group or a monovalent organic group. Examples of the monovalent organic group include an alkyl group and an acyl group, having 5 or less carbon atoms, and an alkyl group having 3 or less carbon atoms is preferable, and a methyl group is more preferable. Xa₁ preferably represents a hydrogen atom, a methyl group, a trifluoromethyl group, or a hydroxymethyl group.

T represents a single bond or a divalent connecting group.

Each of Rx₁ to Rx₃ independently represents an alkyl group (linear or branched) or a cycloalkyl group (monocyclic or polycyclic).

Two of Rx₁ to Rx₃ may be bonded to each other to form a cycloalkyl group (monocyclic or polycyclic).

Examples of the divalent connecting group represented by T include an alkylene group, a —COO-Rt- group, and an —O-Rt- group. In the formula, Rt represents an alkylene group or a cycloalkylene group.

T is preferably a single bond. Rt is preferably an alkylene group having 1 to 5 carbon atoms, and more preferably a —CH₂— group.

The alkyl group represented by each of Rx₁ to Rx₃ is preferably a linear or branched alkyl group having 1 to 5 carbon atoms.

The cycloalkyl group represented by each of Rx₁ to Rx₃ is preferably a monocyclic cycloalkyl group having 3 to 8 carbon atoms, or a polycyclic cycloalkyl group having 7 to 20 carbon atoms. The cycloalkyl group represented by each of Rx₁ to Rx₃ may be a spiro ring.

The cycloalkyl group formed by bonding of two of Rx₁ to Rx₃ to each other is preferably a monocyclic cycloalkyl group having 3 to 8 carbon atoms, or a polycyclic cycloalkyl group having 7 to 20 carbon atoms. A monocyclic cycloalkyl group having 5 or 6 carbon atoms is particularly preferable. The cycloalkyl group formed by bonding of two of Rx₁ to Rx₃ to each other may be a spiro ring.

An aspect in which Rx₁ is a methyl group, an ethyl group, or an isopropyl group, and Rx₂ and Rx₃ are bonded to each other to form the cycloalkyl group described above is preferable.

Specific examples of the repeating unit having an acid-decomposable group are shown below, but the present invention is not limited thereto.

In the specific examples, each of Rx and Xa₁ represents a hydrogen atom, CH₃, CF₃, or CH₂OH. Each of Rxa and Rxb independently represents an alkyl group having 1 to 4 carbon atoms, an aryl group having 6 to 18 carbon atoms, or an aralkyl group having 7 to 19 carbon atoms. Z represents a substituent. p represents 0 or a positive integer, and p is preferably 0 to 2, and more preferably 0 or 1. When a plurality of Z's are present, Z's may be the same as or different from each other. As Z, a group consisting of only hydrogen atoms and carbon atoms is suitably exemplified, and, for example, a linear or branched alkyl group or a cycloalkyl group is preferable.

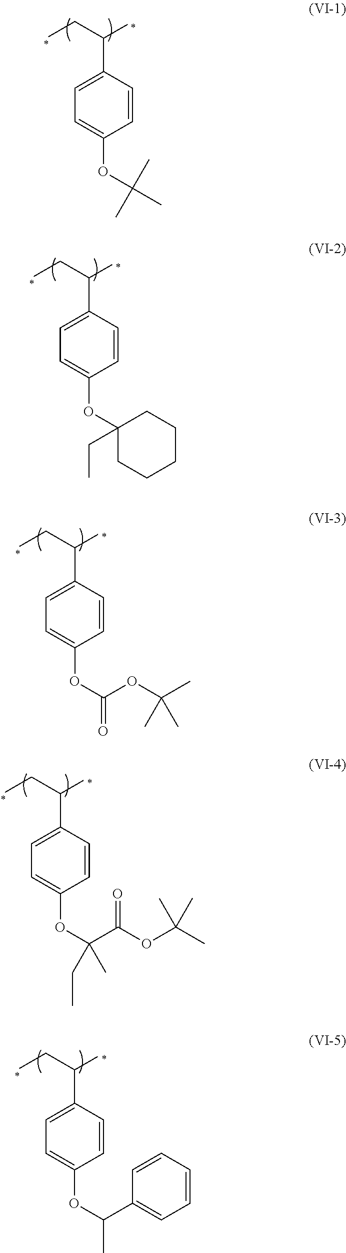

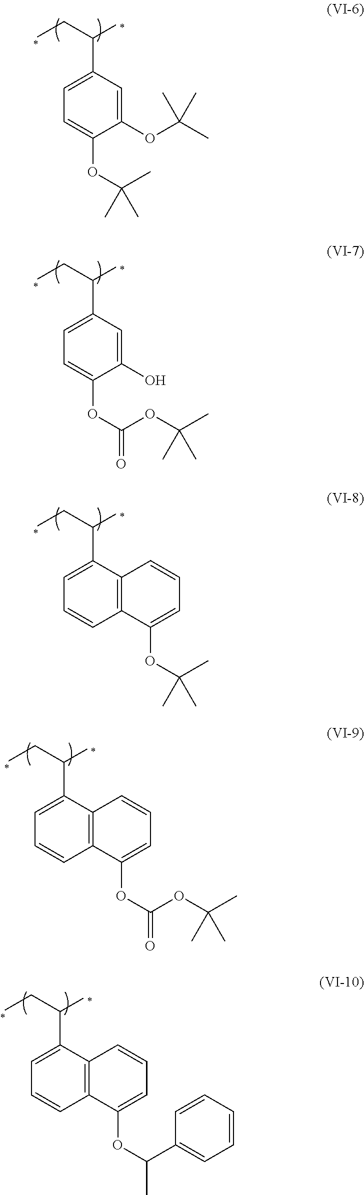

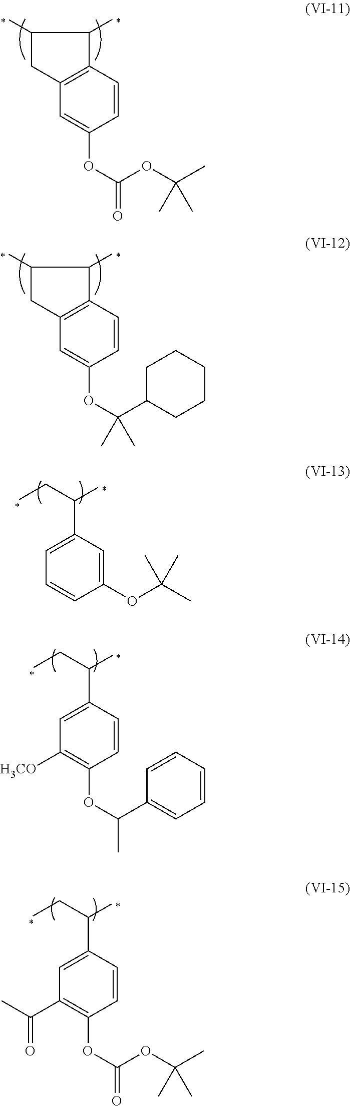

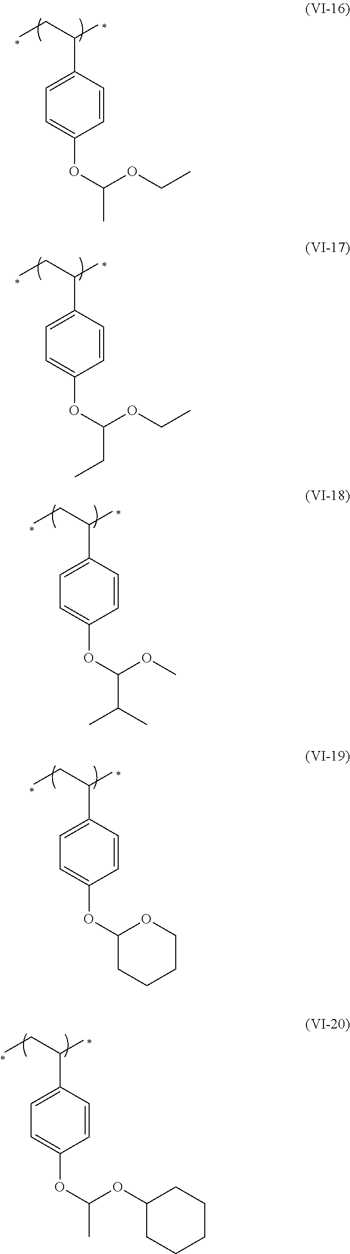

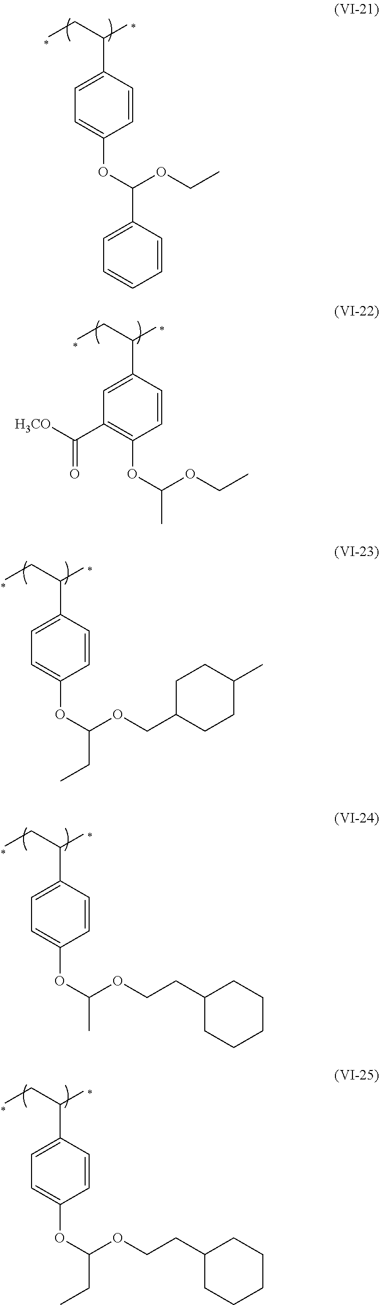

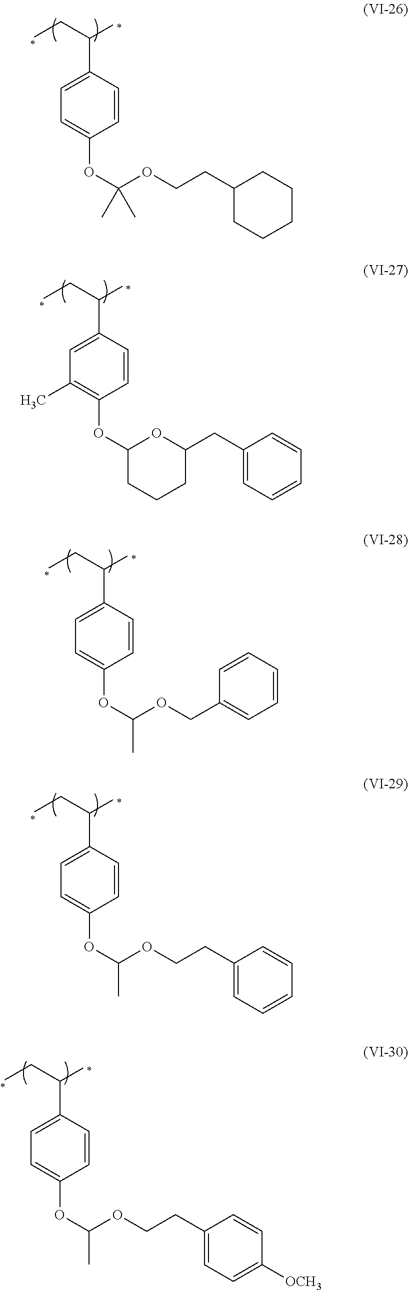

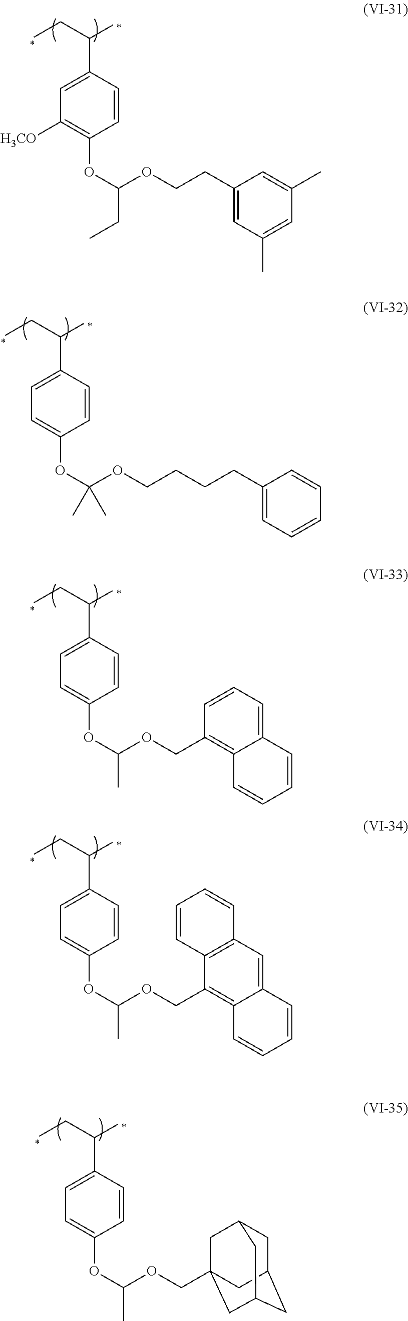

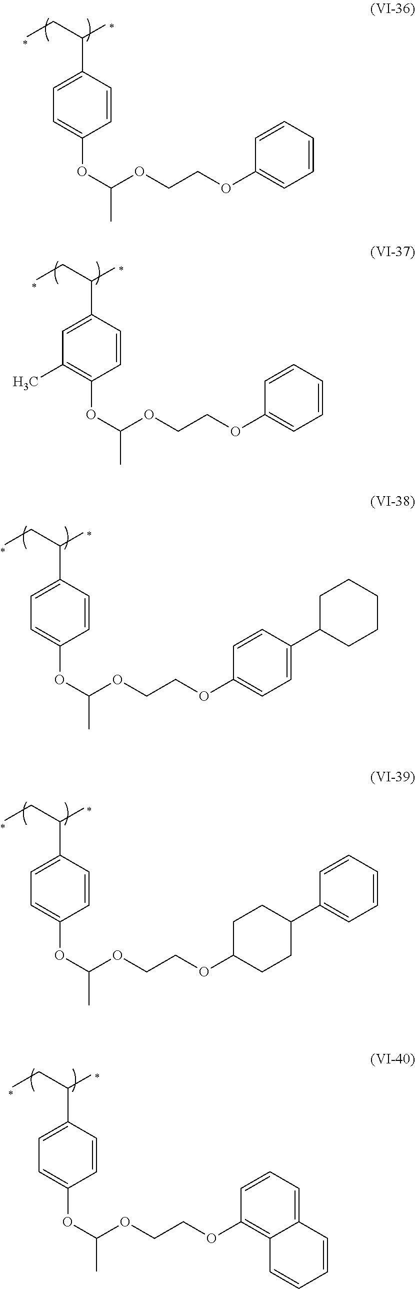

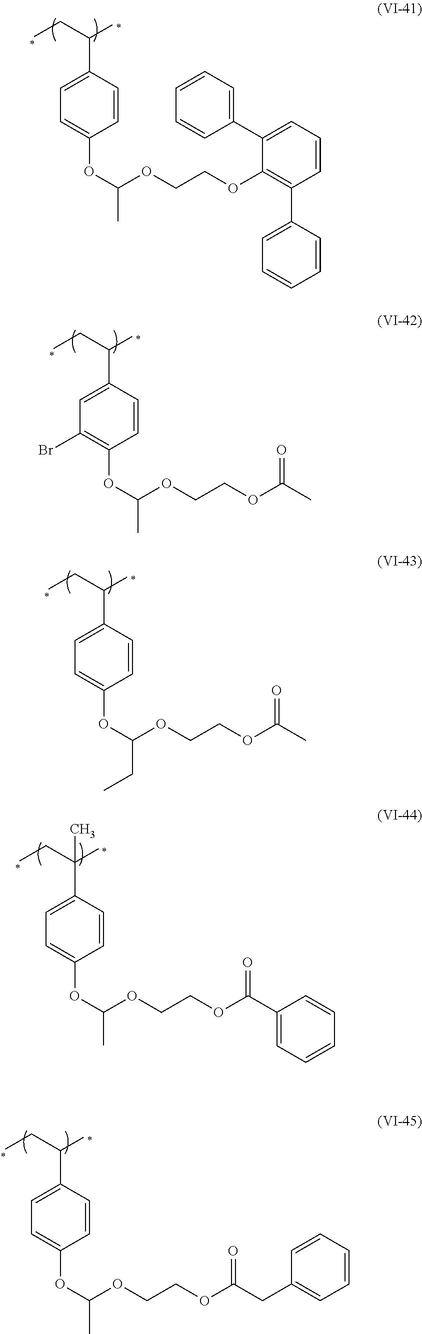

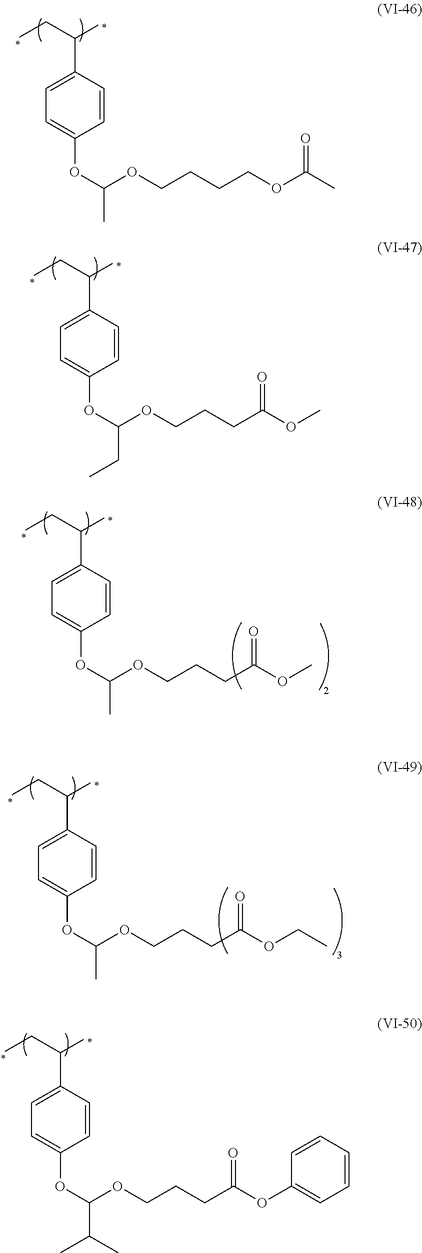

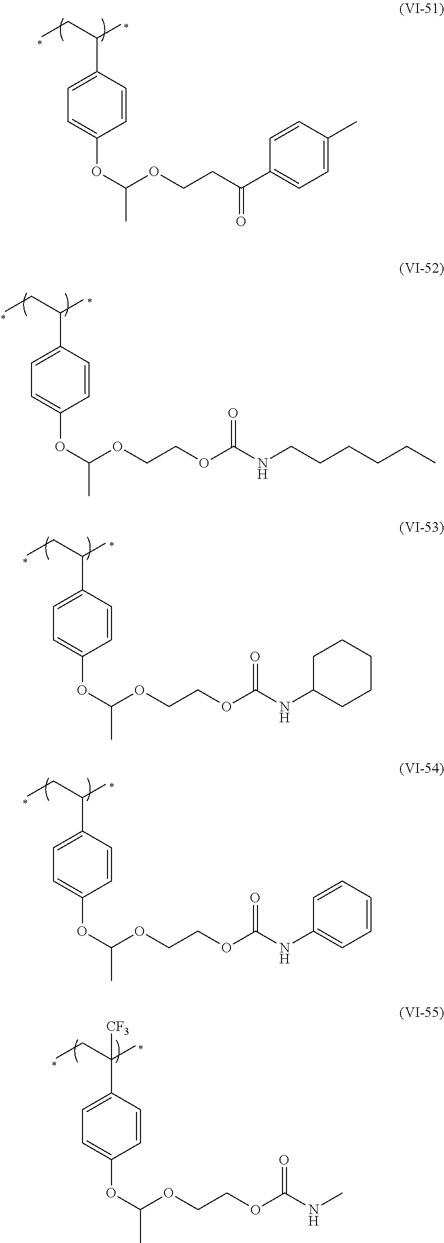

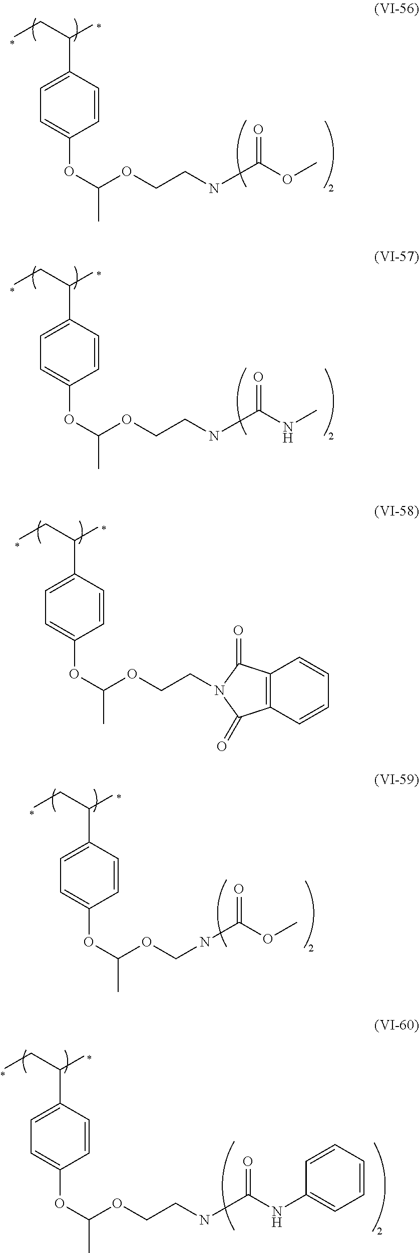

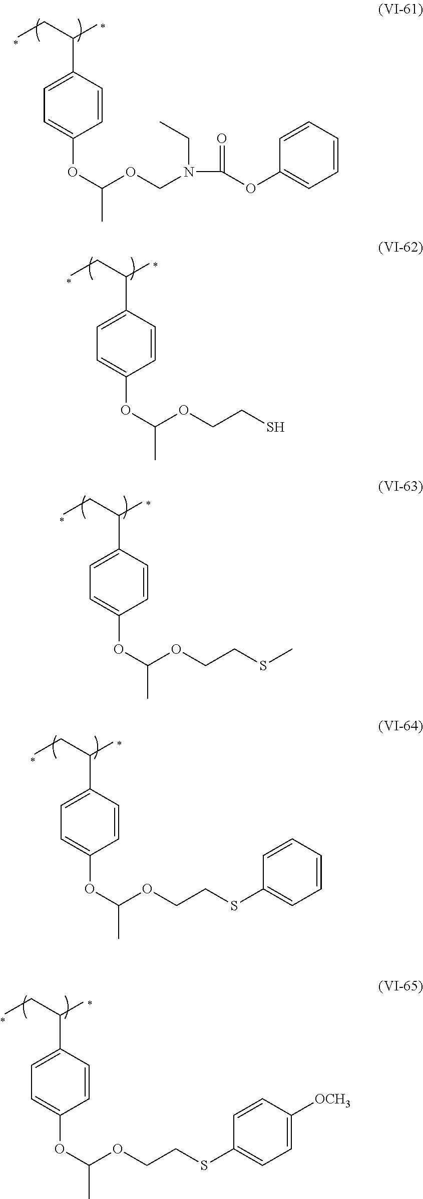

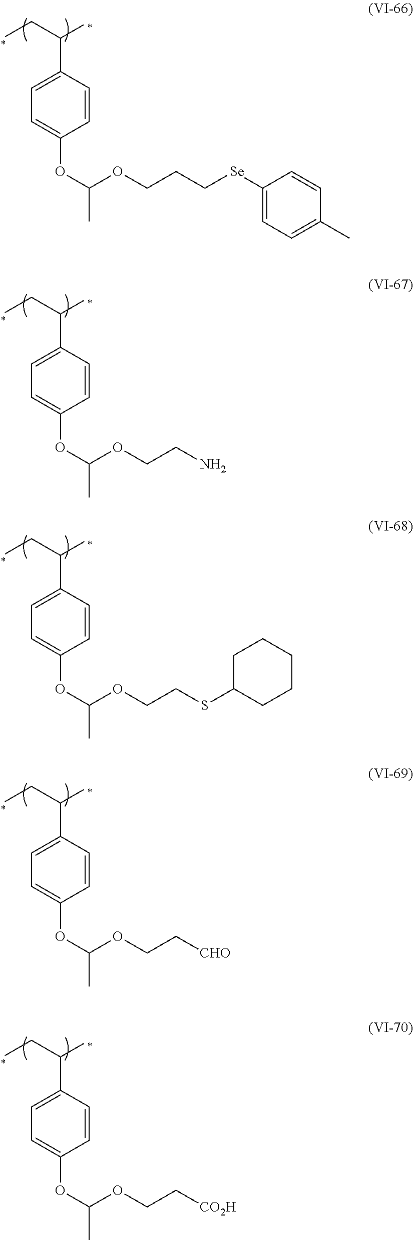

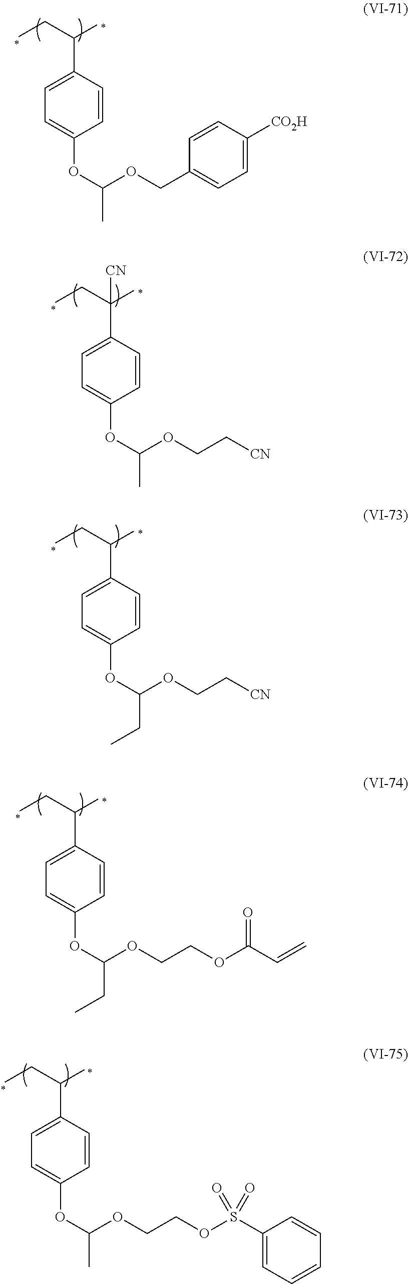

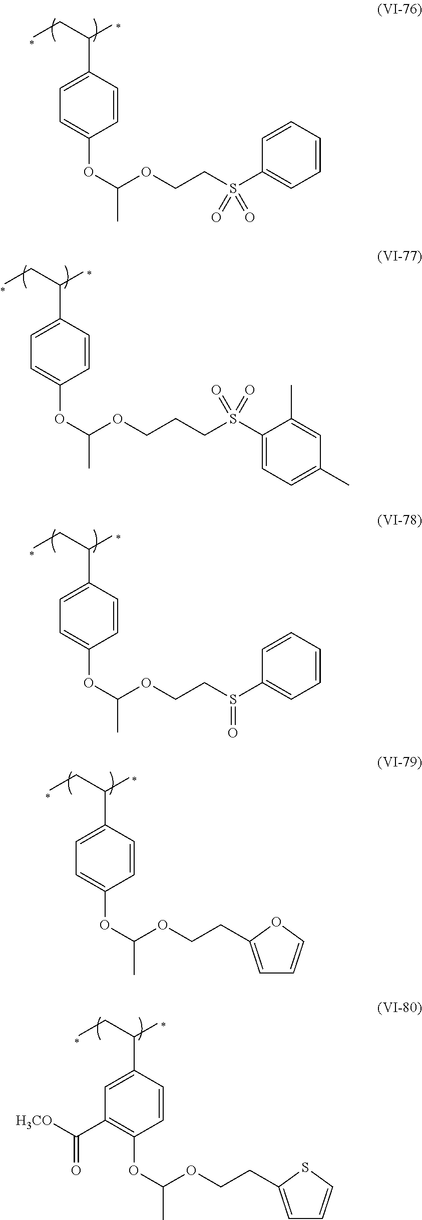

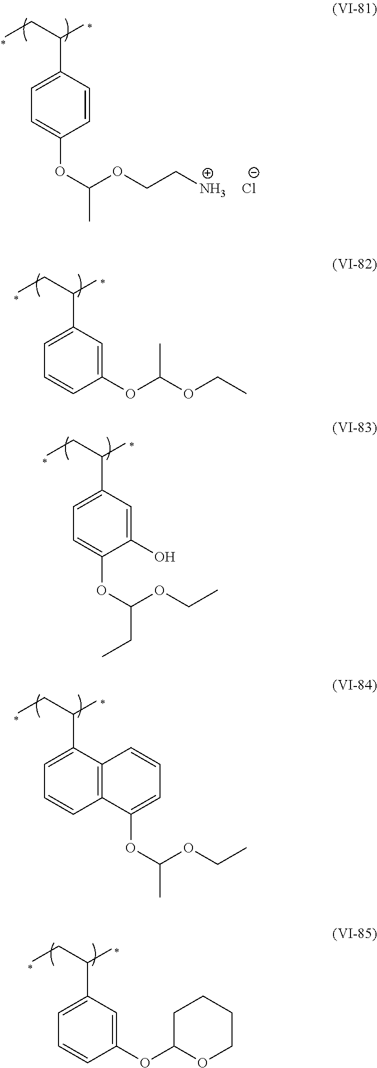

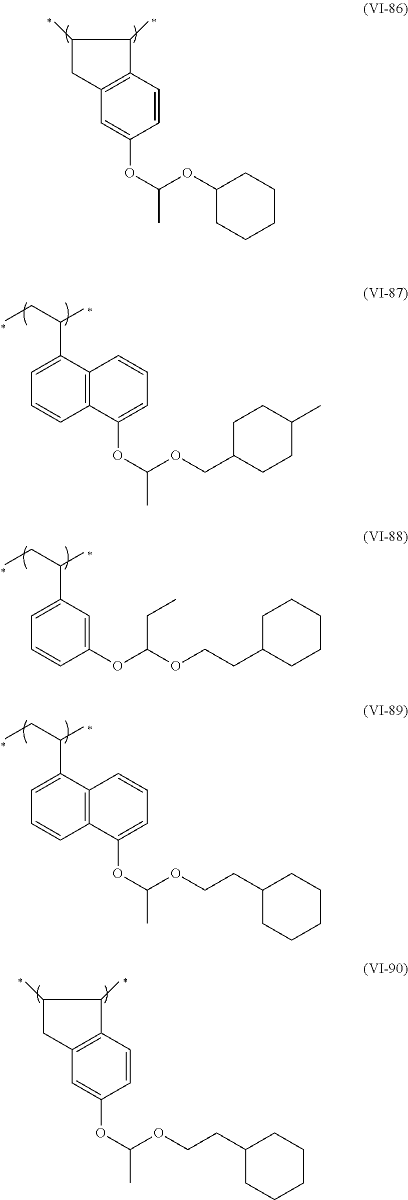

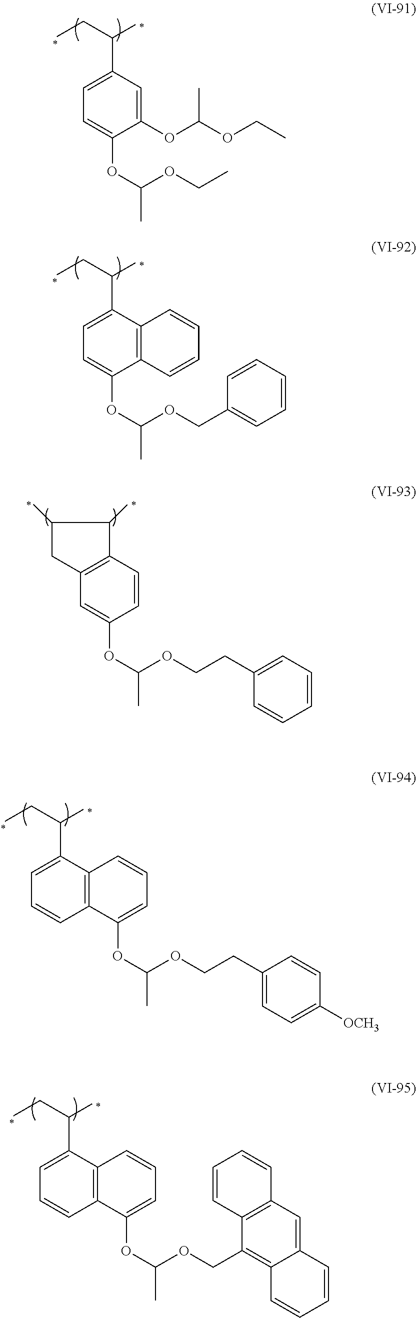

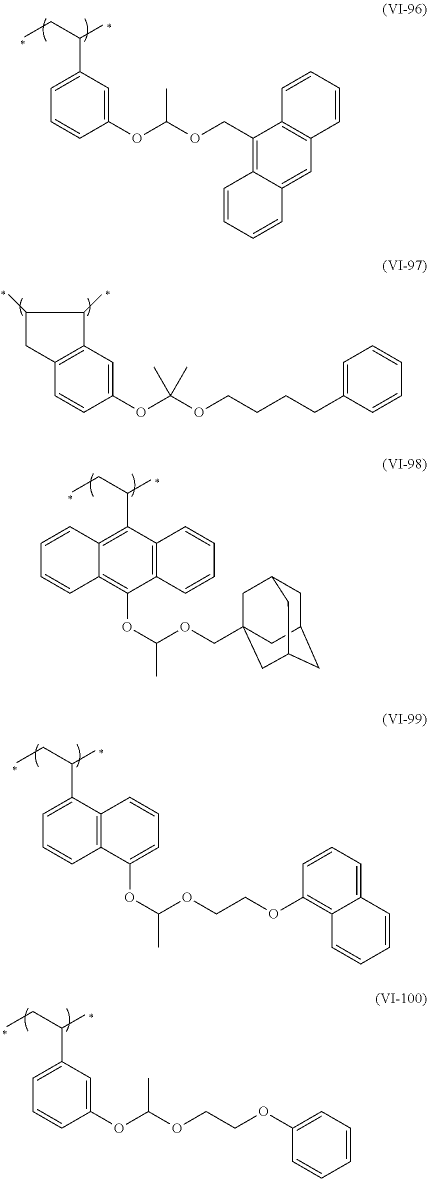

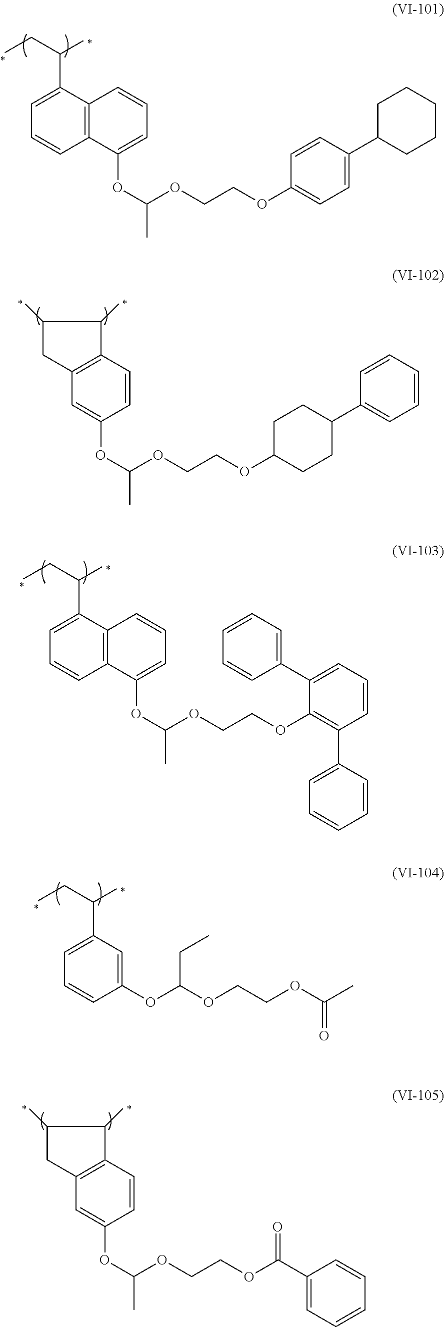

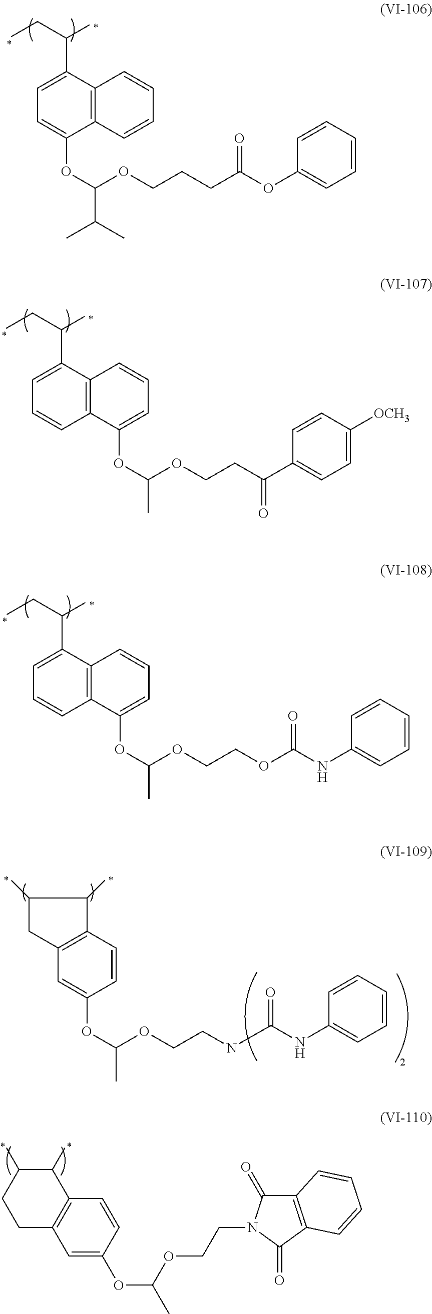

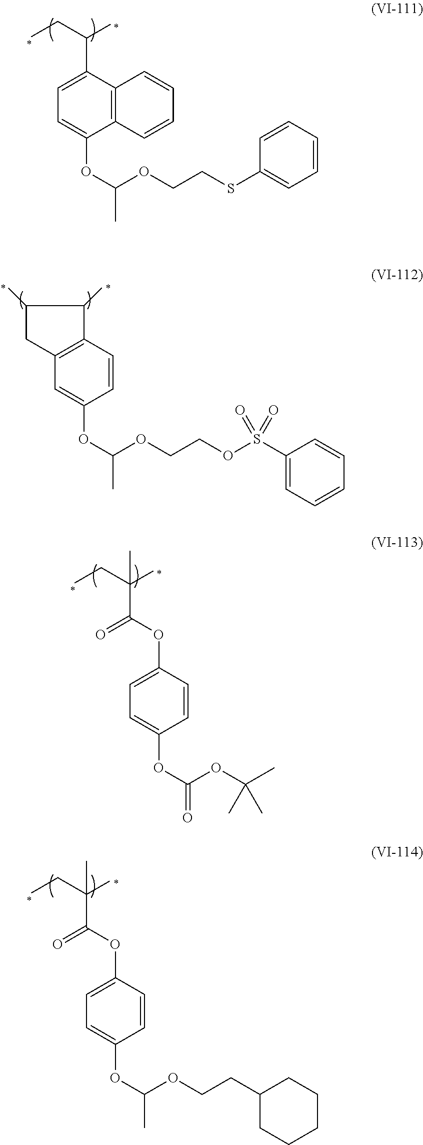

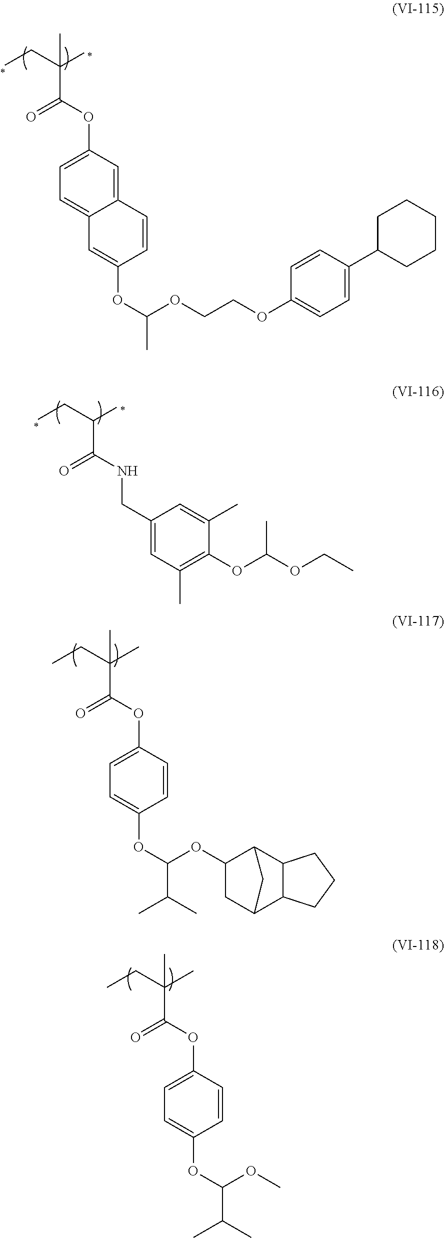

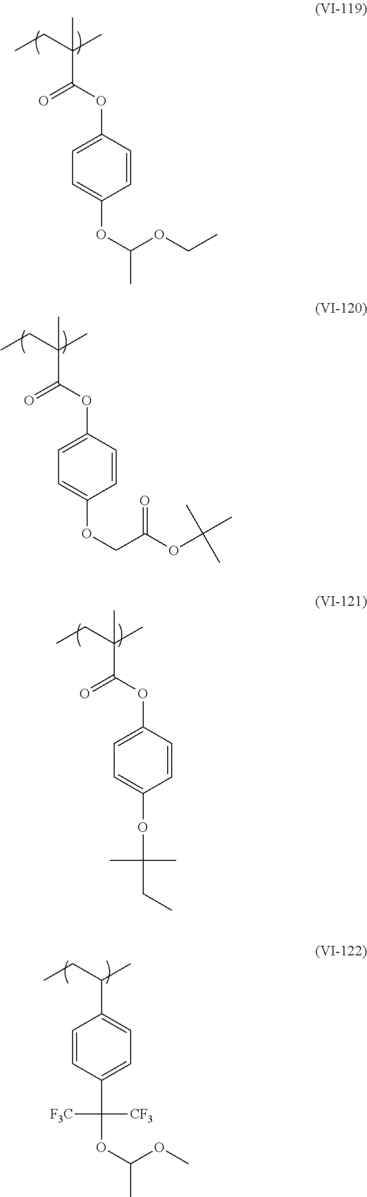

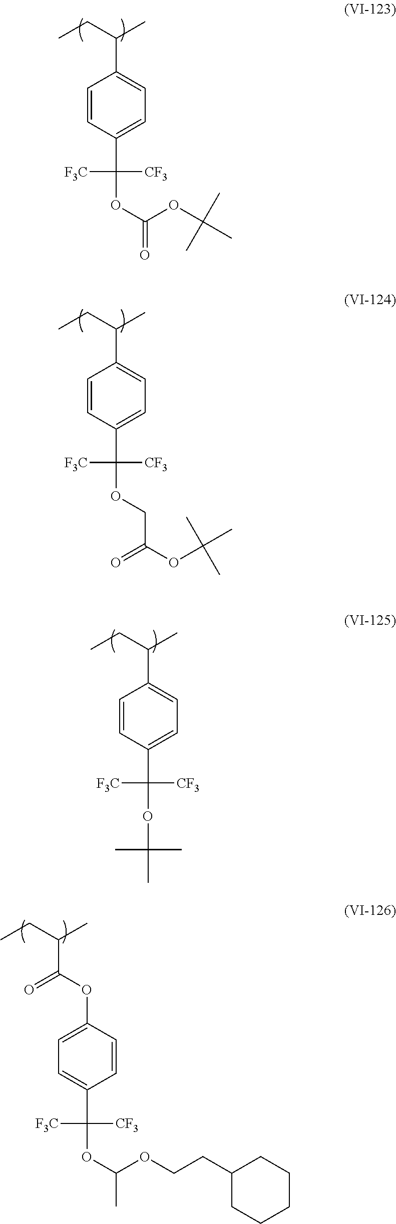

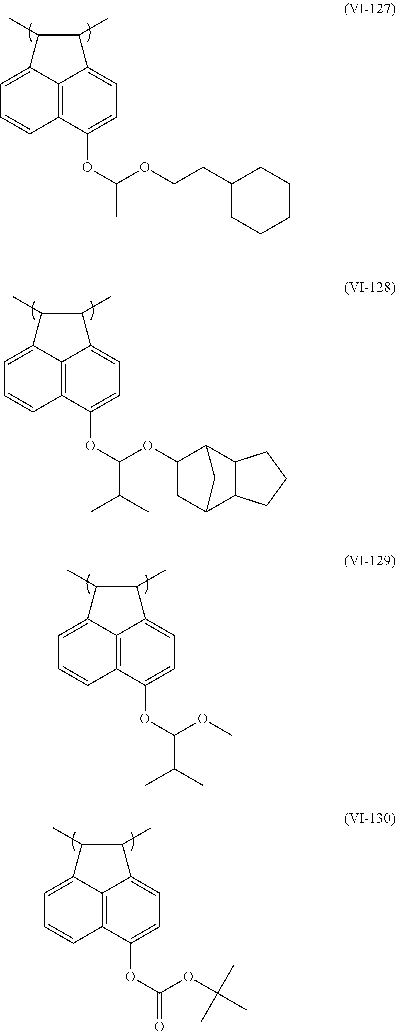

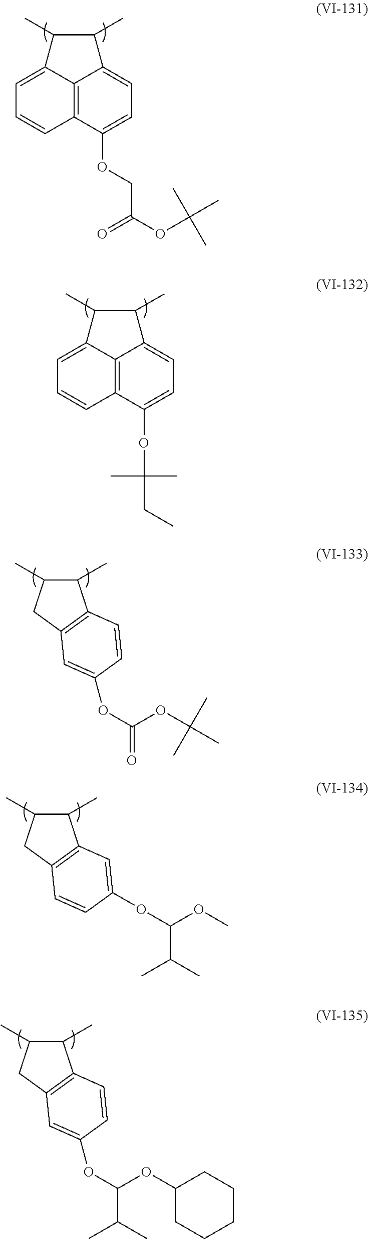

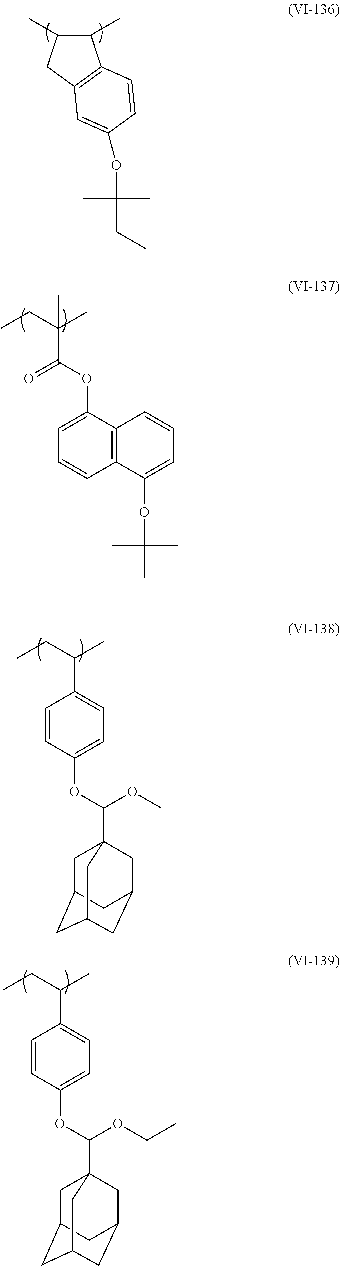

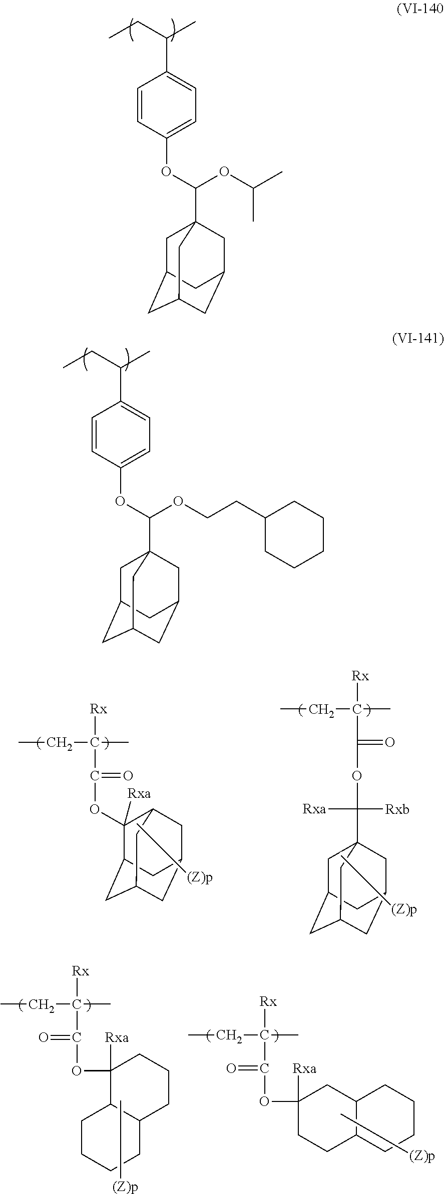

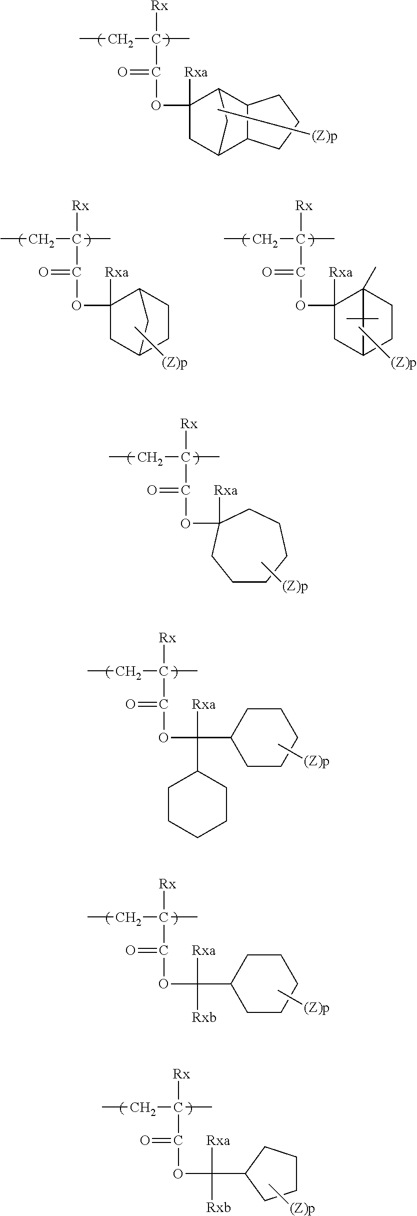

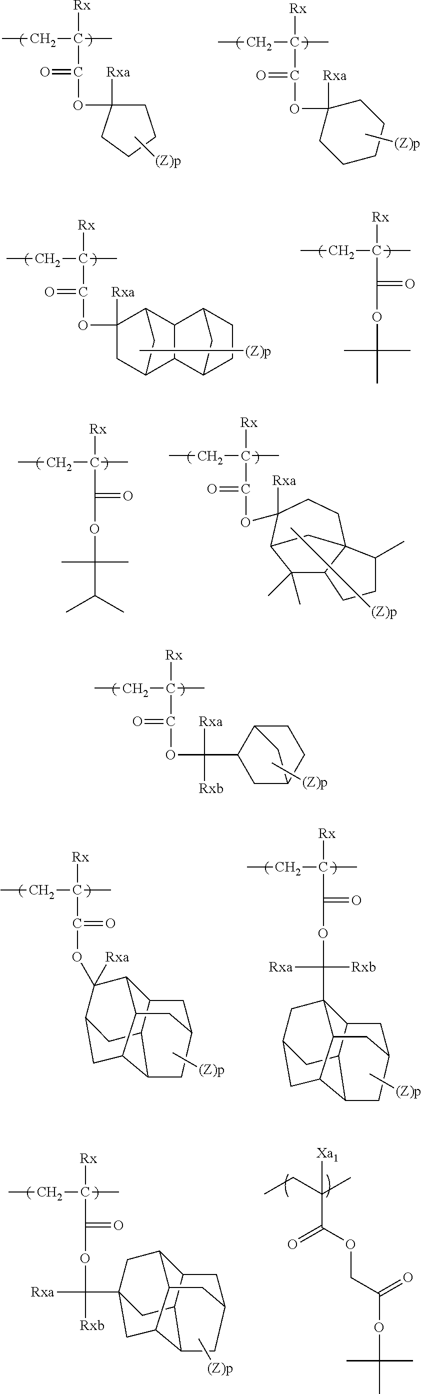

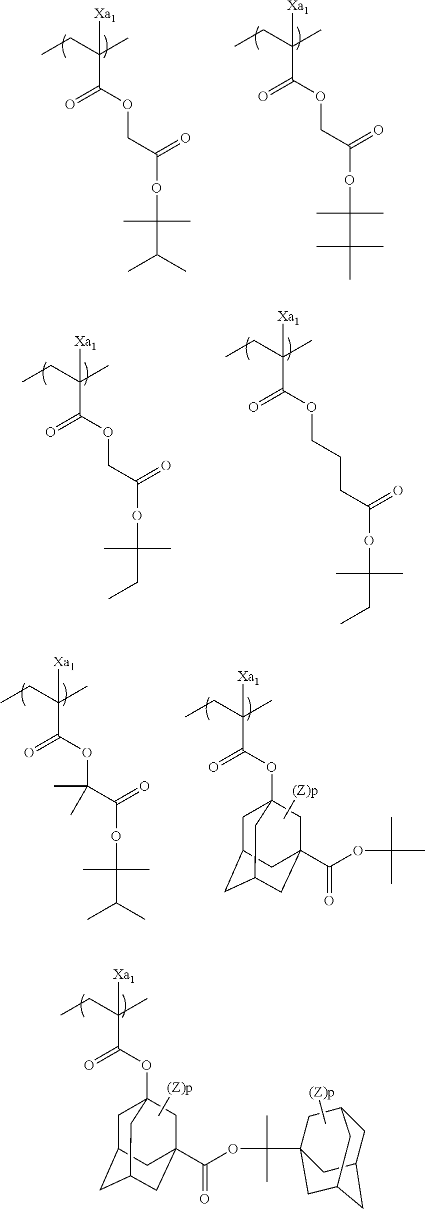

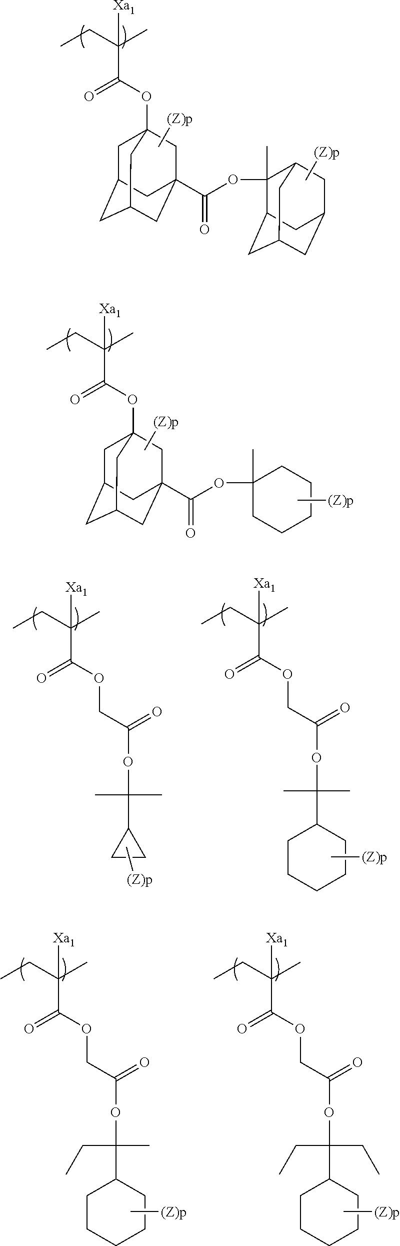

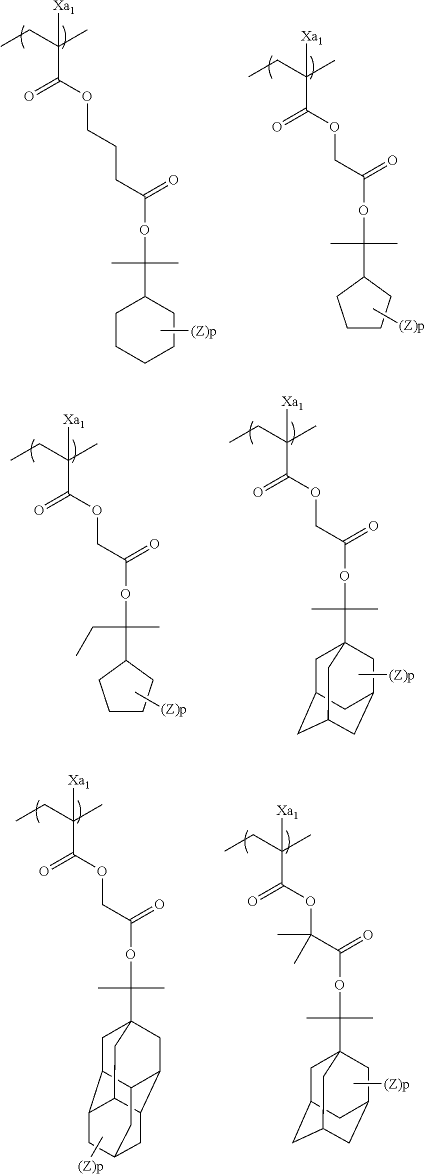

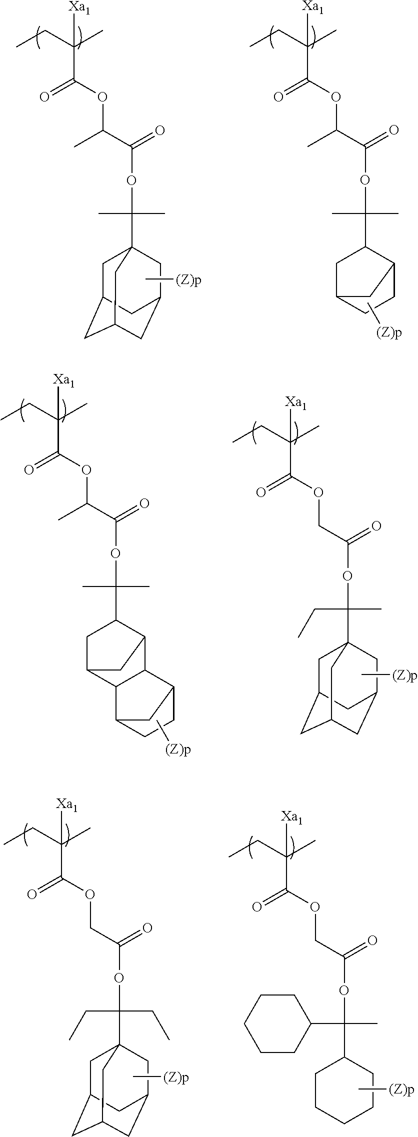

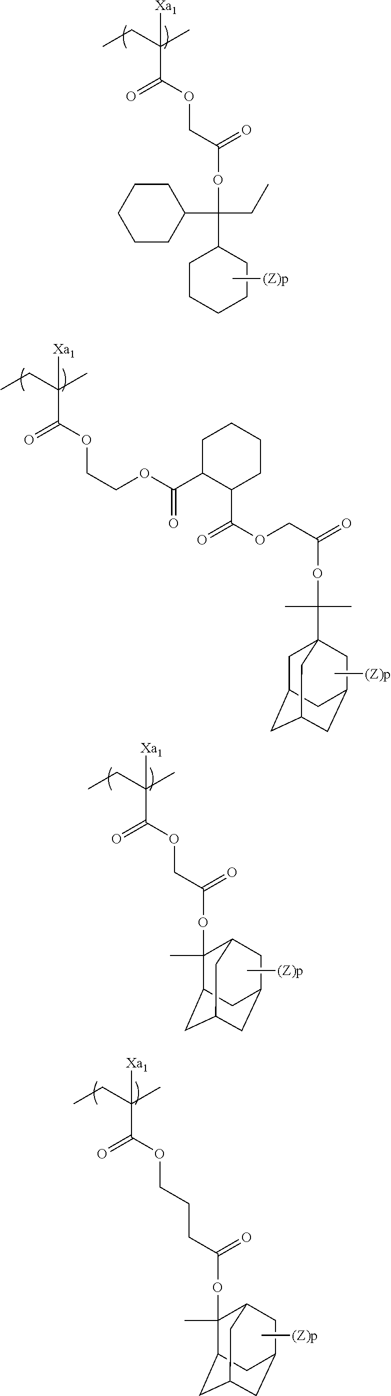

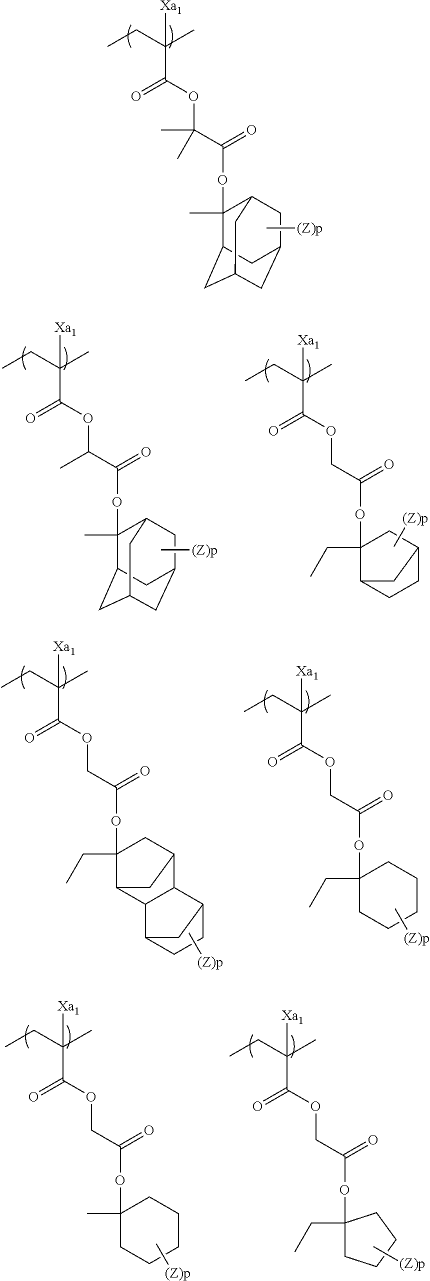

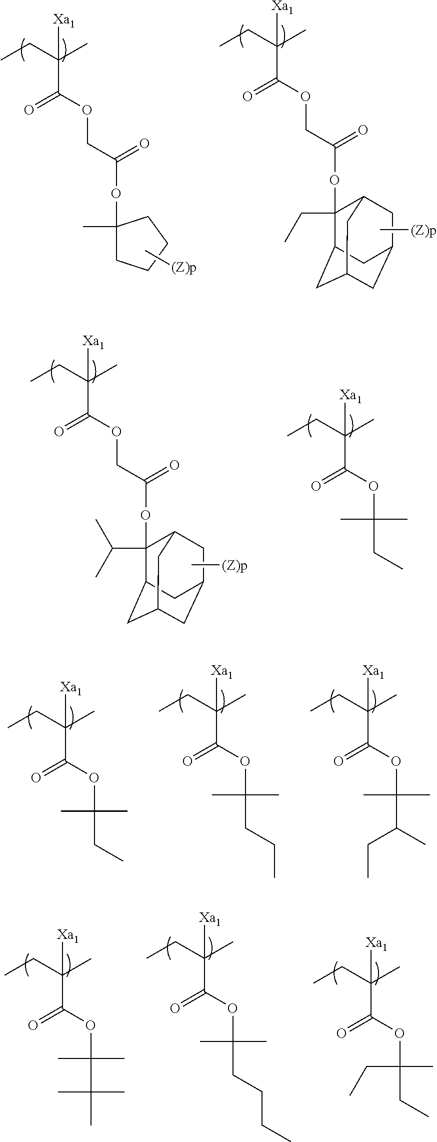

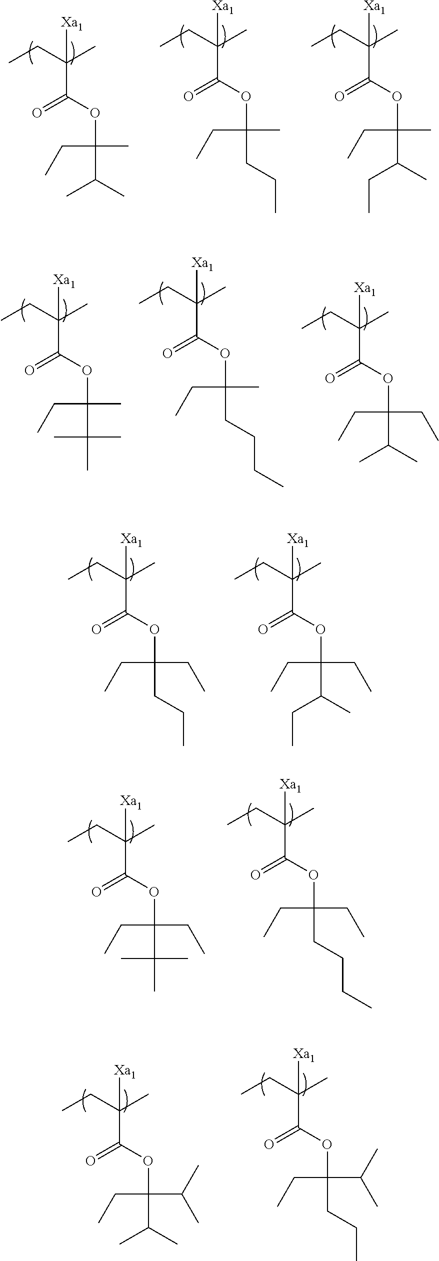

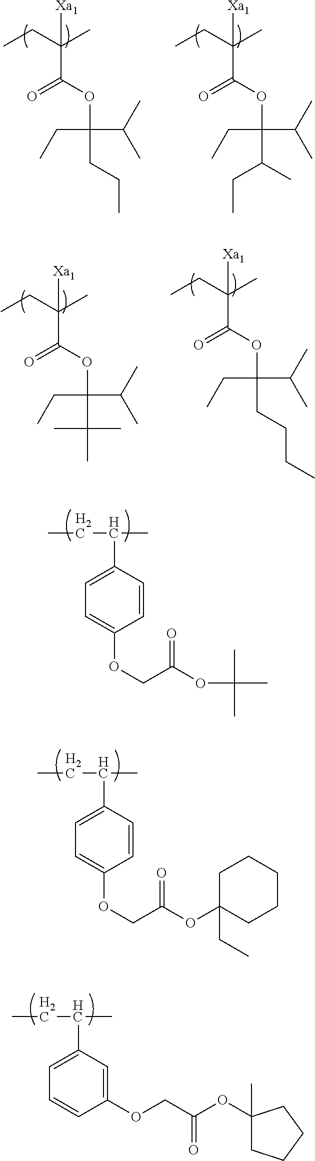

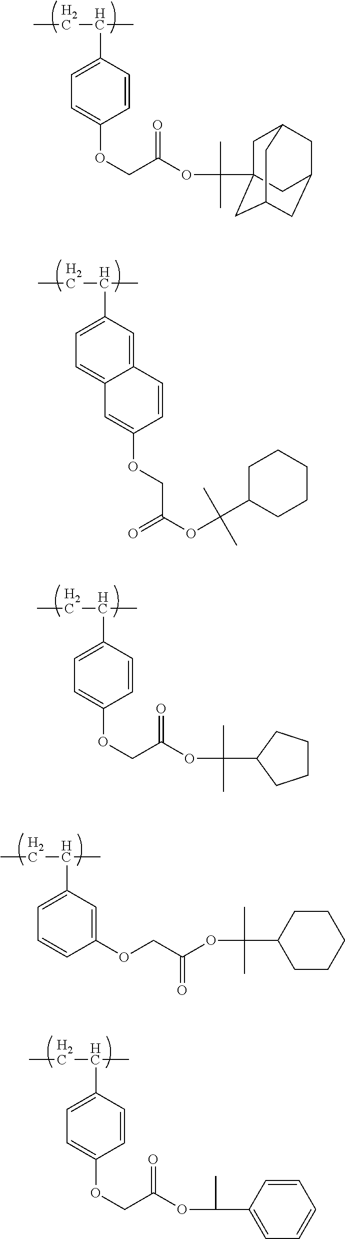

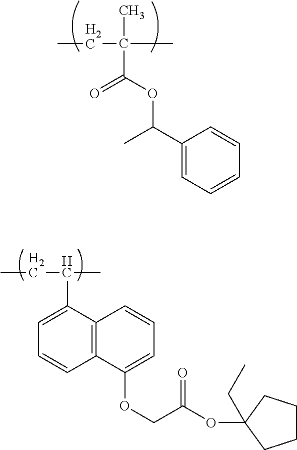

In the resin [P-A], the repeating unit having an acid-decomposable group may be one type, or two or more types thereof may be used in combination.

In the case of forming a positive image by alkali development (that is, in a case where the active light sensitive or radiation sensitive composition is a positive type active light sensitive or radiation sensitive composition), the content of the repeating unit having an acid-decomposable group included in the resin [P-A] is preferably 5 mol % to 70 mol %, more preferably 5 mol % to 60 mol %, and particularly preferably 10 mol % to 50 mol %, with respect to the entirety of repeating units in the resin [P-A]. In the case of forming a negative image by alkali development (that is, in a case where the active light sensitive or radiation sensitive composition is a negative type active light sensitive or radiation sensitive composition), the content of the repeating unit having an acid-decomposable group included in the resin [P-A] is preferably 0.1 mol % to 50 mol %, more preferably 1 mol % to 40 mol %, and particularly preferably 3 mol % to 30 mol %, with respect to the entirety of repeating units in the resin [P-A].

The resin [P-A] preferably has a repeating unit represented by the following General Formula (3).

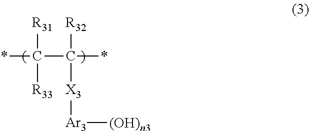

In General Formula (3), each of R₃₁, R₃₂, and R₃₃ independently represents a hydrogen atom, an alkyl group, a cycloalkyl group, a halogen atom, a cyano group, or an alkoxycarbonyl group. R₃₃ may be bonded to Ar₃ to form a ring, and R₃₃ in this case represents an alkylene group.

X₃ represents a single bond or a divalent connecting group.

Ar₃ represents an (n3+1) valent aromatic ring group, and, in the case of being bonded to R₃₃ to form a ring, represents an (n3+2) valent aromatic ring group.

n3 represents an integer of 1 to 4.

Specific examples of an alkyl group, a halogen atom, a cyano group, or an alkoxycarbonyl group, represented by each of R₃₁, R₃₂, and R₃₃ in Formula (3), or substituents which these groups may have are the same as the specific examples described for each group represented by R₁₁, R₁₂, and R₁₃ in General Formula (1) described above.

Ar₃ represents an (n3+1) valent aromatic ring group. The divalent aromatic ring group in a case where n3 is 1 may have a substituent, and preferable examples thereof include an arylene group having 6 to 18 carbon atoms such as a phenylene group, a tolylene group, a naphthylene group, and an anthracenylene group, and aromatic ring groups including a hetero ring, such as thiophene, furan, pyrrole, benzothiophene, benzofuran, benzopyrrole, triazine, imidazole, benzimidazole, triazole, thiadiazole, or thiazole.

Suitable specific examples of the (n3+1) valent aromatic ring group in a case where n3 is an integer of 2 or greater include a group obtained by excluding arbitrary (n3-1) hydrogen atoms from a specific example described above of the divalent aromatic ring group.

The (n3+1) valent aromatic ring group may further have a substituent.

Examples of the substituent which the alkylene group or the (n3+1) valent aromatic ring group described above can have include the alkyl group represented by each of R₅₁ to R₅₃ in General Formula (V), alkoxy groups such as a methoxy group, an ethoxy group, a hydroxyethoxy group, a propoxy group, a hydroxypropoxy group, and a butoxy group, and aryl groups such as a phenyl group.

Examples of the divalent connecting group represented by X₃ include —COO— and —CONR₆₄—.

Examples of the alkyl group represented by R₆₄ in —CONR₆₄— (R₆₄ represents a hydrogen atom or an alkyl group) represented by X₃ include the same as the alkyl group represented by each of R₆₁ to R₆₃.

X₃ is preferably a single bond, —COO—, or —CONH—, and more preferably a single bond or —COO—.

Ar₃ is more preferably an aromatic ring group having 6 to 18 carbon atoms which may have a substituent, and particularly preferably a benzene ring group, a naphthalene ring group, or a biphenylene ring group.

The repeating unit (b) preferably has a hydroxystyrene structure. That is, Ar₃ is preferably a benzene ring group.

n3 represents an integer of 1 to 4, preferably represents 1 or 2, and more preferably represents 1.

Specific examples of a repeating unit represented by General Formula (3) will be described below, but the present invention is not limited thereto. In the formulas, a represents 1 or 2.

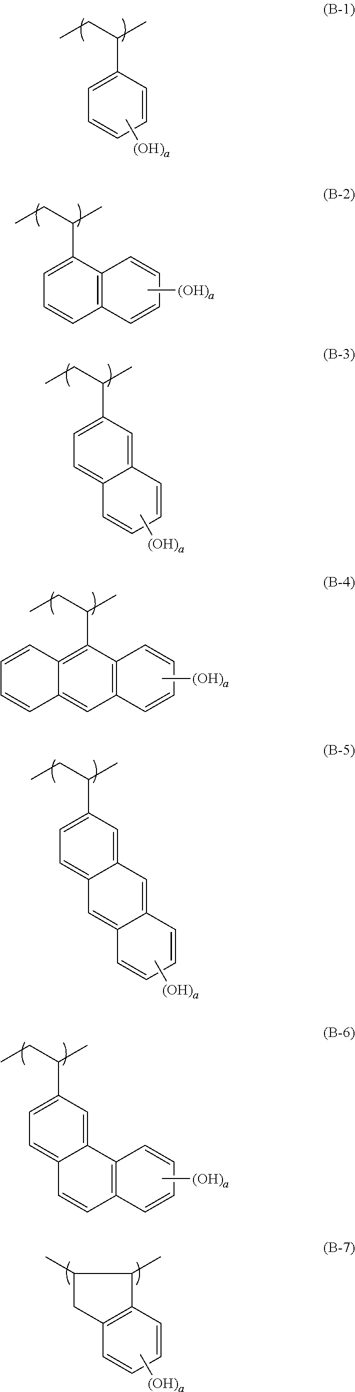

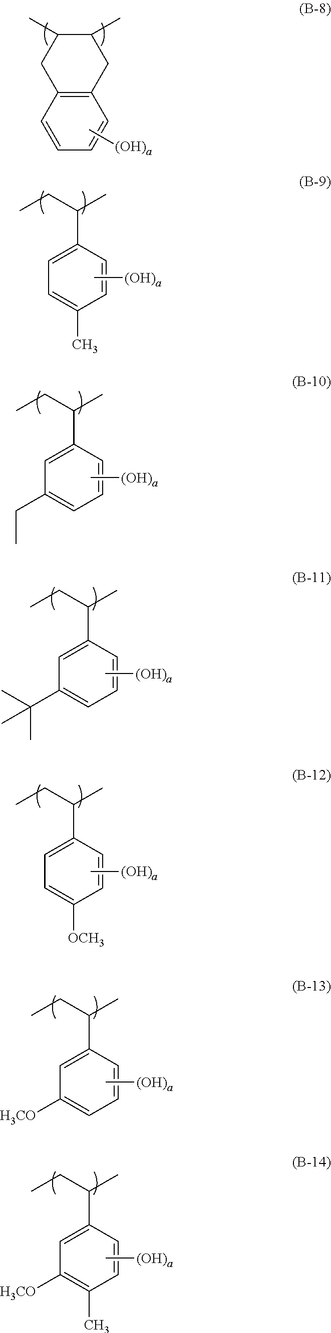

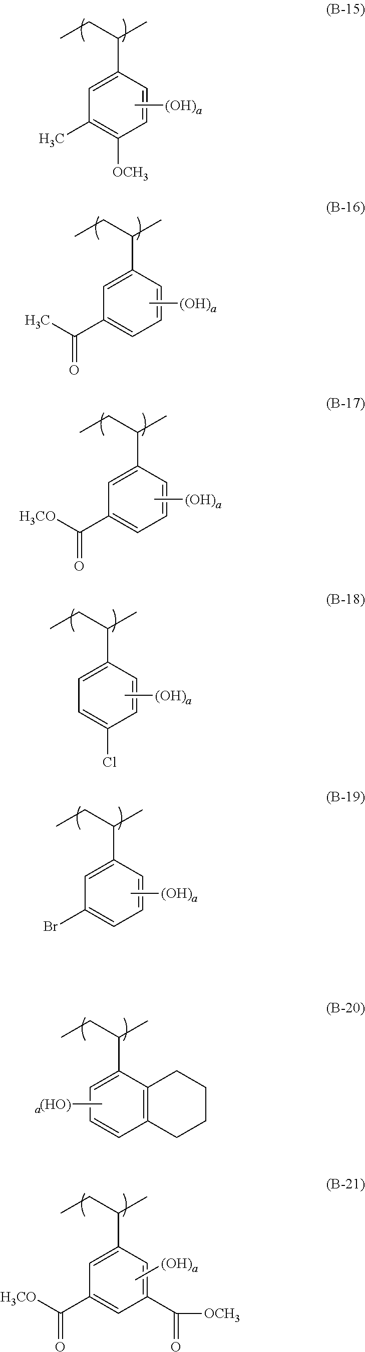

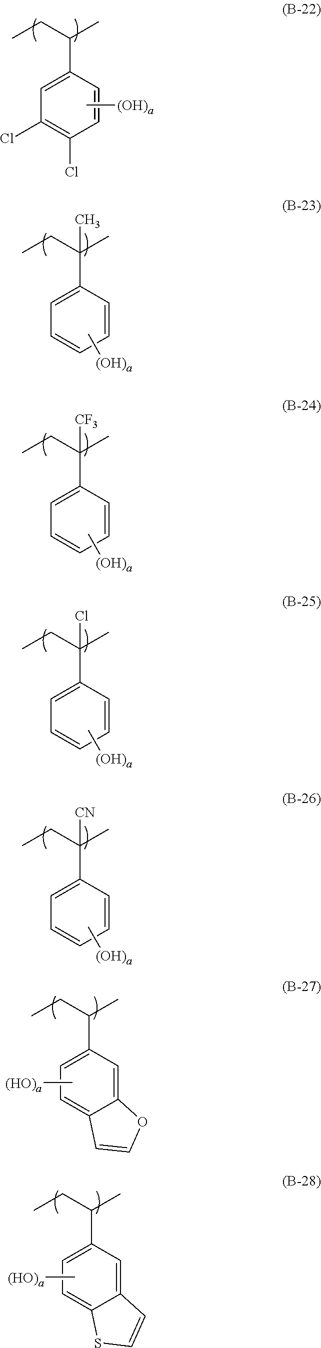

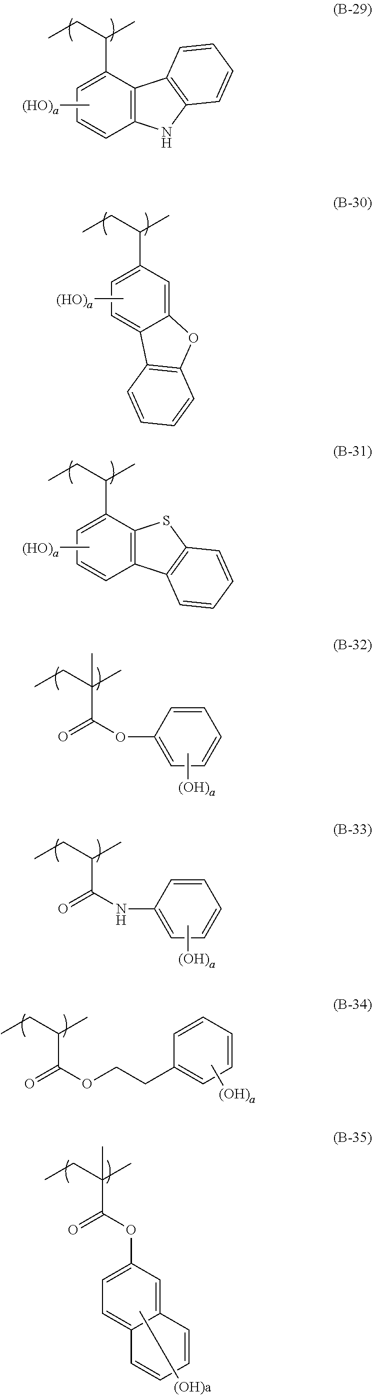

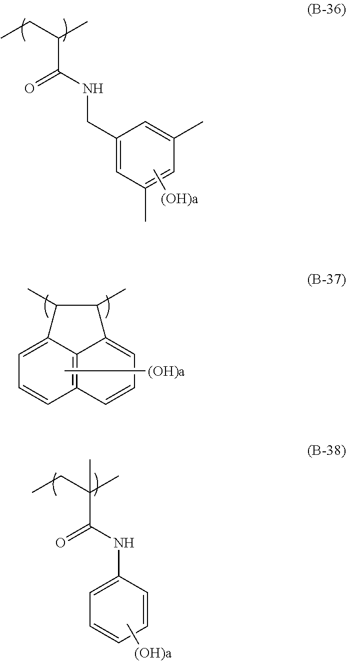

The resin [P-A] may include two or more types of the repeating unit represented by General Formula (3).

The content of the repeating unit represented by General Formula (3) (in the case of containing plural types, the total sum content) is preferably within a range of 3 mol % to 98 mol %, more preferably within a range of 10 mol % to 80 mol %, and still more preferably within a range of 25 mol % to 70 mol %, with respect to the entirety of repeating units in the resin [P-A].

The resin [P-A] may include a repeating unit (c) having a polar group different from the repeating unit represented by General Formula (3). When the resin [P-A] includes the repeating unit (c), for example, the sensitivity of a composition including the resin can be improved. The repeating unit (c) is preferably a non-acid-decomposable repeating unit (that is, a repeating unit which does not include an acid-decomposable group).

As the “polar group” which the repeating unit (c) can include, the following (1) to (4) are exemplified. Moreover, hereinafter, the term “electronegativity” means a value by Pauling.

(1) A functional group including a structure in which an oxygen atom and an atom having a difference in electronegativity with an oxygen atom of 1.1 or greater are bonded by a single bond

Examples of such a polar group include a group including a structure represented by O—H of a hydroxy group or the like.

(2) A functional group including a structure in which a nitrogen atom and an atom having a difference in electronegativity with a nitrogen atom of 0.6 or greater are bonded by a single bond

Examples of such a polar group include a group including a structure represented by N—H of an amino group or the like.

(3) A functional group including a structure in which two atoms having a difference in electronegativity of 0.5 or greater are bonded by a double bond or a triple bond

Examples of such a polar group include a group including a structure represented by C≡N, C═O, N═O, S═O, or C═N.

(4) A functional group having an ionic portion

Examples of such a polar group include a group having a portion represented by N⁺ or S⁺.

Specific examples of a substructure which the “polar group” can include are described below.

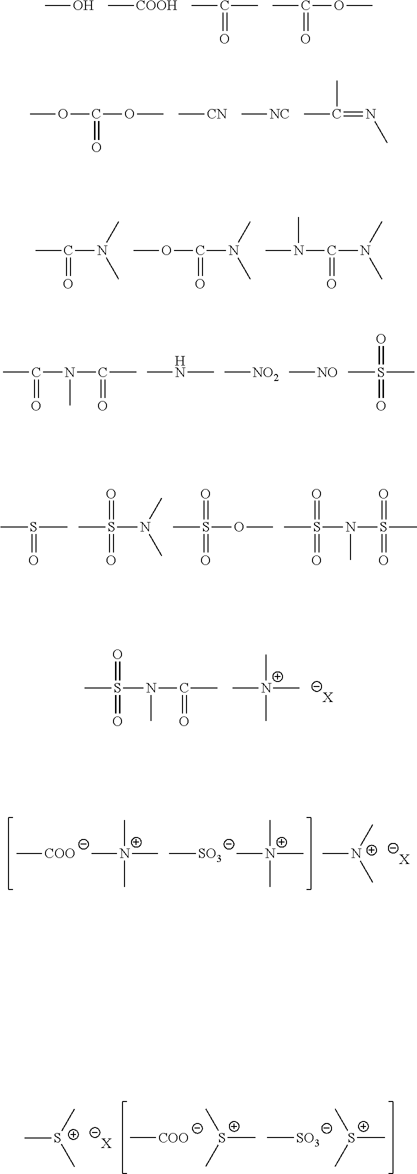

The polar group is preferably selected from a hydroxyl group, a cyano group, a lactone group, a sultone group, a carboxylic acid group, a sulfonic acid group, an amide group, a sulfonamide group, an ammonium group, a sulfonium group, and a group obtained by combining two or more thereof, and an alcoholic hydroxy group, a cyano group, a lactone group, a sultone group, or a group including a cyano lactone structure is particularly preferable.

When the resin further contains a repeating unit having an alcoholic hydroxy group, the exposure latitude (EL) of a composition including the resin can be further improved.

When the resin further contains a repeating unit having a cyano group, the sensitivity of a composition including the resin can be further improved.

When the resin further contains a repeating unit having a lactone group, the dry etching resistance, the coating properties, and the adhesion to a substrate of a composition including the resin can also be further improved.

When the resin further contains a repeating unit having a group including a lactone structure having a cyano group, the sensitivity, the dry etching resistance, the coating properties, and the adhesion to a substrate of a composition including the resin can also be further improved. Additionally, in this manner, a function due to each of a cyano group and a lactone group can be carried out by a single repeating unit, and thus, flexibility of design of the resin can be further increased.

In a case where the polar group which the repeating unit (c) has is an alcoholic hydroxy group, the polar group is preferably represented by at least one selected from the group consisting of the following General Formulas (I-1H) to (I-10H). In particular, the polar group is more preferably represented by at least one selected from the group consisting of the following General Formulas (I-1H) to (I-3H), and still more preferably represented by the following General Formula (I-1H).

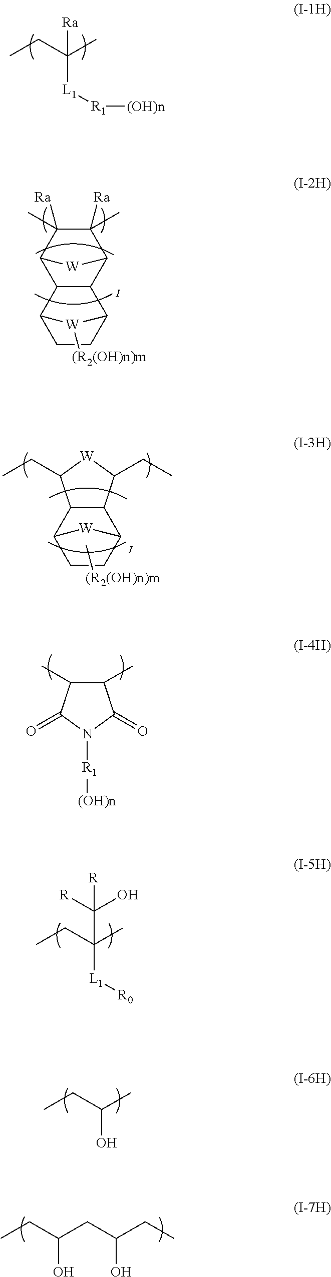

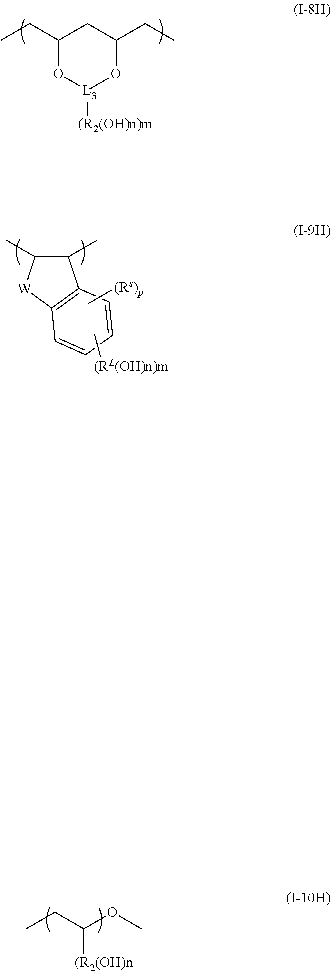

In the formulas, each of Ra's independently represents a hydrogen atom, an alkyl group, or a group represented by —CH₂—O—Ra₂. Here, Ra₂ represents a hydrogen atom, an alkyl group, or an acyl group.

R₁ represents an (n+1) valent organic group.

In a case where m is 2 or greater, each of R₂'s independently represents a single bond or an (n+1) valent organic group.

W represents a methylene group, an oxygen atom, or a sulfur atom.

Each of n and m represents an integer of 1 or greater. In a case where R₂ is a single bond in General Formula (I-2H), (I-3H), or (I-8H), n is 1.

l represents an integer of 0 or greater.

L₁ represents a connecting group represented by —COO—, —OCO—, —CONH—, —O—, —Ar—, —SO₃—, or —SO₂NH—. Here, Ar represents a divalent aromatic ring group.

Each of R's independently represents a hydrogen atom or an alkyl group.

R₀ represents a hydrogen atom or an organic group.

L₃ represents an (m+2) valent connecting group.

In a case where m is 2 or greater, each of R^{L}'s independently represents an (n+1) valent connecting group.

In a case where p is 2 or greater, each of R^{S}'s independently represents a substituent. In a case where p is 2 or greater, a plurality of R^{S}'s may be bonded to each other to form a ring.

p represents an integer of 0 to 3.

Ra represents a hydrogen atom, an alkyl group, or a group represented by —CH₂—O—Ra₂. Ra is preferably a hydrogen atom or an alkyl group having 1 to 10 carbon atoms, and more preferably a hydrogen atom or a methyl group.

W represents a methylene group, an oxygen atom, or a sulfur atom. W is preferably a methylene group or an oxygen atom.

R₁ represents an (n+1) valent organic group. R₁ is preferably a nonaromatic hydrocarbon group. In this case, R₁ may be a chain hydrocarbon group or may be an alicyclic hydrocarbon group. R₁ is more preferably an alicyclic hydrocarbon group.

R₂ represents a single bond or an (n+1) valent organic group. R₂ is preferably a single bond or a nonaromatic hydrocarbon group. In this case, R₂ may be a chain hydrocarbon group or may be an alicyclic hydrocarbon group.

In a case where R₁ and/or R₂ is a chain hydrocarbon group, the chain hydrocarbon group may be linear or may be branched. In addition, the chain hydrocarbon group preferably has 1 to 8 carbon atoms. For example, in a case where R₁ and/or R₂ is an alkylene group, R₁ and/or R₂ is preferably a methylene group, an ethylene group, an n-propylene group, an isopropylene group, an n-butylene group, an isobutylene group, or a sec-butylene group.

In a case where R₁ and/or R₂ is an alicyclic hydrocarbon group, the alicyclic hydrocarbon group may be monocyclic or may be polycyclic. The alicyclic hydrocarbon group has, for example, a monocyclic structure, a bicyclic structure, a tricyclic structure, or a tetracyclic structure. The alicyclic hydrocarbon group typically has 5 or greater carbon atoms, preferably 6 to 30 carbon atoms, and more preferably 7 to 25 carbon atoms.

Examples of the alicyclic hydrocarbon group include an alicyclic hydrocarbon group having one of substructures listed below. Each of these substructures may have a substituent. In addition, the methylene group (—CH₂—) in each of these substructures may be substituted with an oxygen atom (—O—), a sulfur atom (—S—), a carbonyl group [—C(═O)—], a sulfonyl group [—S(═O)₂—], a sulfinyl group [—S(═O)—], or an imino group [—N(R)—] (R is a hydrogen atom or an alkyl group).

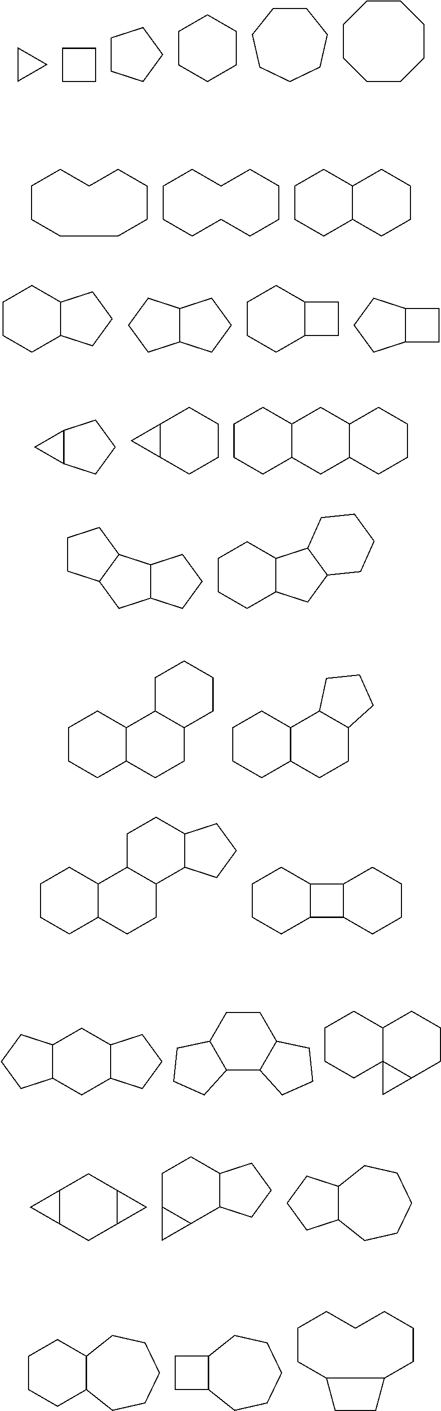

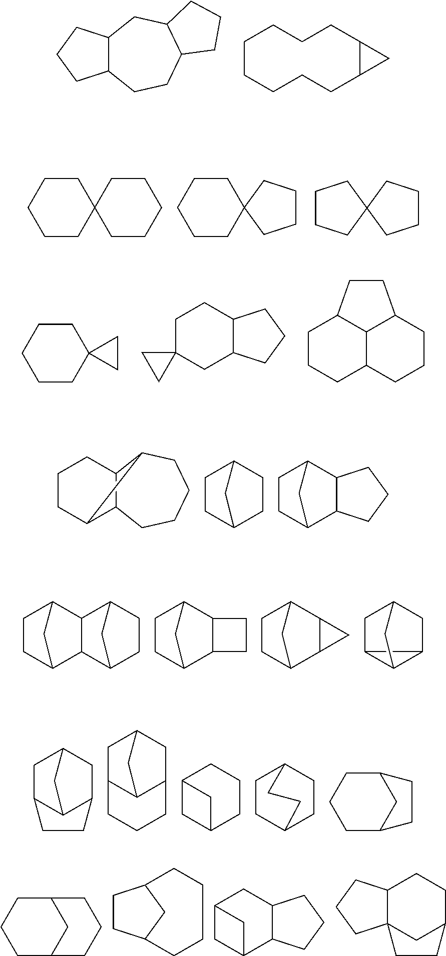

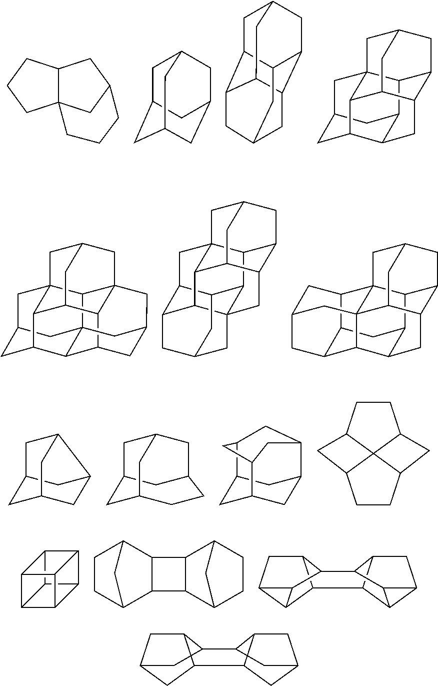

For example, in a case where R₁ and/or R₂ is a cycloalkylene group, R₁ and/or R₂ is preferably an adamantylene group, a noradamantylene group, a decahydronaphthylene group, a tricyclodecanylene group, a tetracyclododecanylene group, a norbornylene group, a cyclopentylene group, a cyclohexylene group, a cycloheptylene group, a cyclooctylene group, a cyclodecanylene group, or a cyclododecanylene group, and more preferably an adamantylene group, a norbornylene group, a cyclohexylene group, a cyclopentylene group, a tetracyclododecanylene group, or a tricyclodecanylene group.

The nonaromatic hydrocarbon group represented by R₁ and/or R₂ may have a substituent. Examples of the substituent include an alkyl group having 1 to 4 carbon atoms, a halogen atom, a hydroxy group, an alkoxy group having 1 to 4 carbon atoms, a carboxy group, and an alkoxycarbonyl group having 2 to 6 carbon atoms. The alkyl group, the alkoxy group, and the alkoxycarbonyl group described above may further have a substituent. Examples of the substituent include a hydroxy group, a halogen atom, and an alkoxy group.

L₁ represents a connecting group represented by —COO—, —OCO—, —CONH—, —O—, —Ar—, —SO₃—, or —SO₂NH—. Here, Ar represents a divalent aromatic ring group. L₁ is preferably a connecting group represented by —COO—, —CONH—, or —Ar—, and more preferably a connecting group represented by —COO— or —CONH—.

R represents a hydrogen atom or an alkyl group. The alkyl group may be linear, or may be branched. The alkyl group preferably has 1 to 6 carbon atoms, and more preferably 1 to 3 carbon atoms. R is preferably a hydrogen atom or a methyl group, and more preferably a hydrogen atom.

R₀ represents a hydrogen atom or an organic group. Examples of the organic group include an alkyl group, a cycloalkyl group, an aryl group, an alkynyl group, and an alkenyl group. R₀ is preferably a hydrogen atom or an alkyl group, and more preferably a hydrogen atom or a methyl group.

L₃ represents an (m+2) valent connecting group. That is, L₃ represents a tri- or higher valent connecting group. Examples of the connecting group include groups corresponding to specific examples listed below.

R^{L} represents an (n+1) valent connecting group. That is, R^{L} represents a di- or higher valent connecting group. Examples of the connecting group include an alkylene group, a cycloalkylene group, and groups corresponding to specific examples listed below. R^{L}'s may be bonded to each other to form a ring structure, or R^{L} may be bonded to R^{S} described below to form a ring structure.

R^{S} represents a substituent. Examples of the substituent include an alkyl group, an alkenyl group, an alkynyl group, an aryl group, an alkoxy group, an acyloxy group, an alkoxycarbonyl group, and a halogen atom.

n is an integer of 1 or greater. n is preferably an integer of 1 to 3, and more preferably 1 or 2. In addition, when n is 2 or greater, dissolution contrast with respect to a developer including an organic solvent can be further improved. Accordingly, by doing this, marginal resolving power and roughness characteristics can be further improved.

m is an integer of 1 or greater. m is preferably an integer of 1 to 3, and more preferably 1 or 2.

l is an integer of 0 or greater. 1 is preferably 0 or 1. p is an integer of 0 to 3.

The content of the repeating unit having an alcoholic hydroxy group is preferably 1 mol % to 60 mol %, more preferably 3 mol % to 50 mol %, and still more preferably 5 mol % to 40 mol %, with respect to the entirety of repeating units in the resin [P-A].

Specific examples of the repeating unit represented by any one of General Formulas (I-1H) to (I-10H) are shown below. Moreover, Ra in specific examples has the same meaning as that in General Formulas (I-1H) to (I-10H).

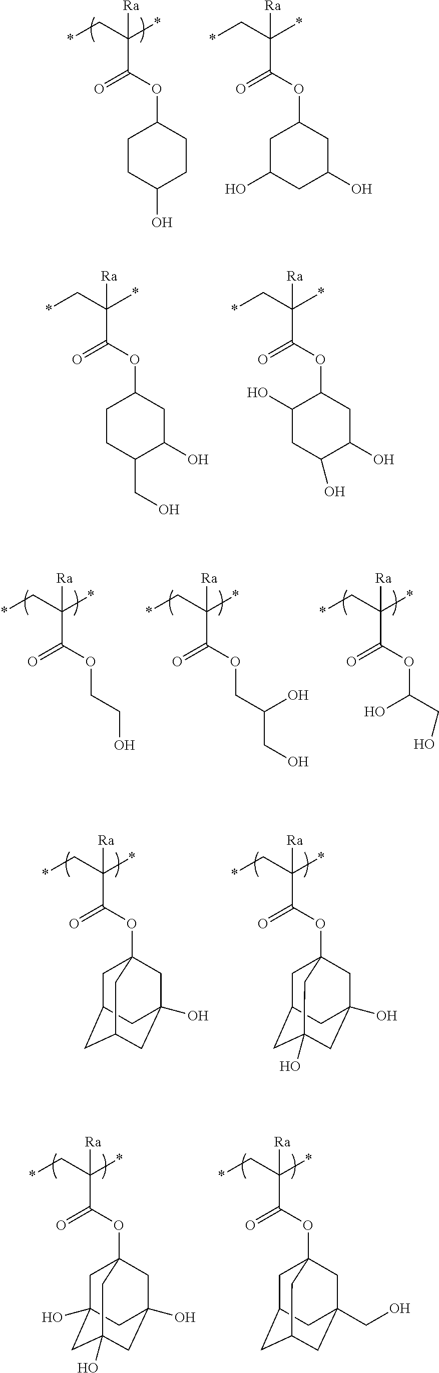

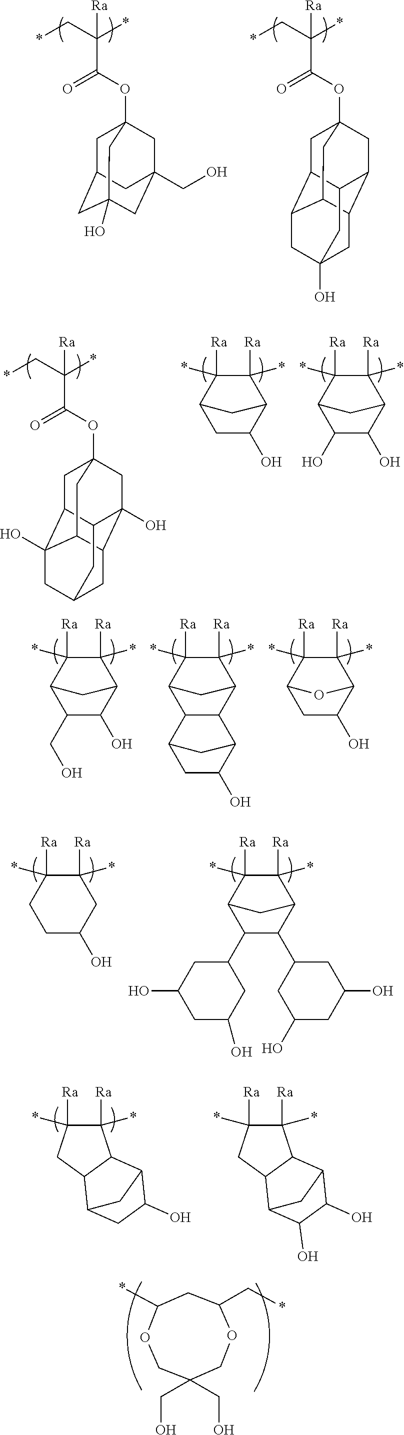

In a case where the polar group which the repeating unit (c) has is an alcoholic hydroxy group or an cyano group, as one aspect of a preferable repeating unit, a repeating unit having an alicyclic hydrocarbon structure substituted with a hydroxyl group or a cyano group is exemplified. At this time, an acid-decomposable group is preferably not included. As the alicyclic hydrocarbon structure in the alicyclic hydrocarbon structure substituted with a hydroxyl group or a cyano group, an adamantyl group, a diadamantyl group, or a norbornane group is preferable. As a preferable alicyclic hydrocarbon structure substituted with a hydroxyl group or a cyano group, the substructures represented by the following General Formulas (VIIa) to (VIIc) are preferable. Thus, adhesion to substrate and developer affinity are improved.

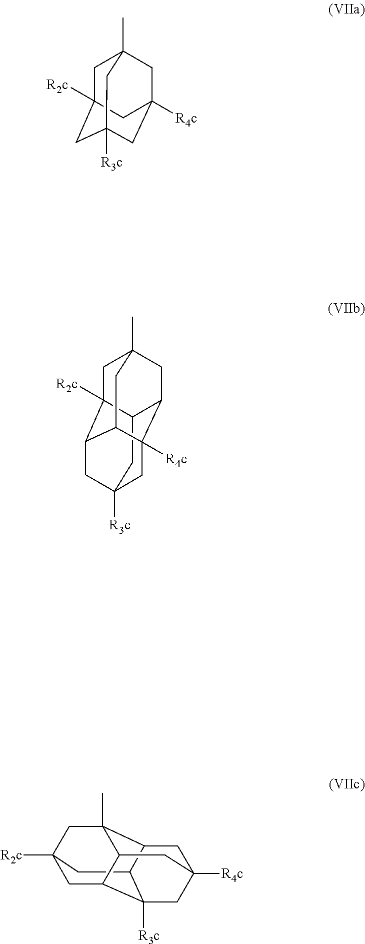

In General Formulas (VIIa) to (VIIc), each of R₂c to R₄c independently represents a hydrogen atom, a hydroxyl group, or a cyano group. Here, at least one of R₂c to R₄c is a hydroxyl group. Preferably, one or two of R₂c to R₄c are hydroxyl groups, and the other is a hydrogen atom. In General Formula (VIIa), more preferably, two of R₂c to R₄c are hydroxyl groups, and the other is a hydrogen atom.

As a repeating unit having a substructure represented by each of General Formulas (VIIa) to (VIIc), the repeating units represented by the following General Formulas (AIIa) to (AIIc) can be exemplified.

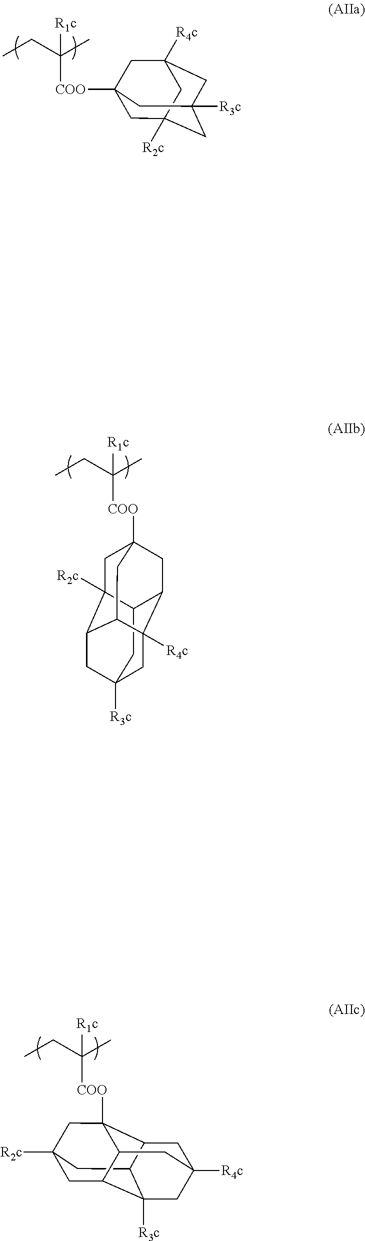

In General Formulas (AIIa) to (AIIc), R₁c represents a hydrogen atom, a methyl group, a trifluoromethyl group, or a hydroxymethyl group.

R₂c to R₄c have the same meaning as R₂c to R₄c in General Formulas (VIIa) to (VIIc), respectively.

Although the resin [P-A] may contain or may not contain a repeating unit having a hydroxyl group or a cyano group, in a case where the resin [P-A] contains the repeating unit, the content of the repeating unit having a hydroxyl group or a cyano group is preferably 1 mol % to 60 mol %, more preferably 3 mol % to 50 mol %, and still more preferably 5 mol % to 40 mol %, with respect to the entirety of repeating units in the resin [P-A].

Specific examples of the repeating unit having a hydroxyl group or a cyano group are described below, but the present invention is not limited thereto.

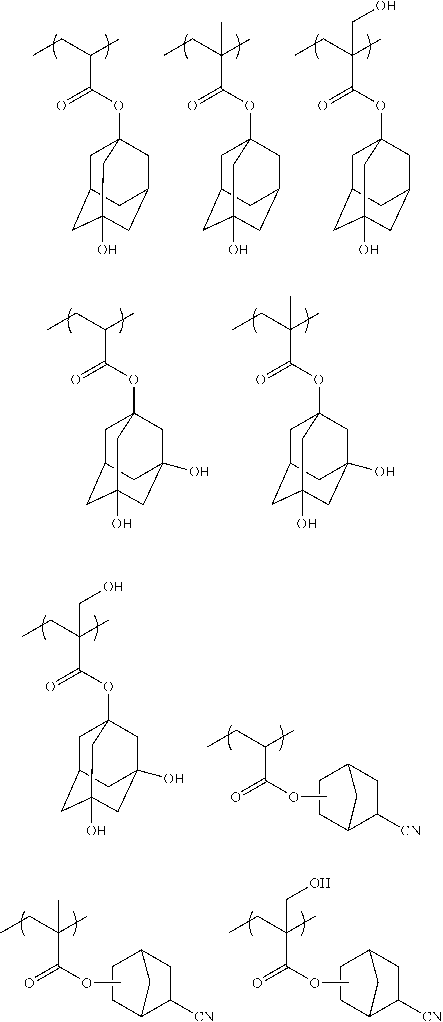

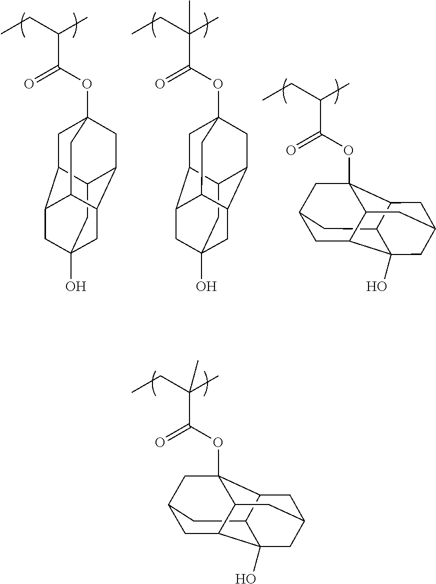

The repeating unit (c) preferably contains a repeating unit having a lactone structure or a sultone (cyclic sulfonic acid ester) structure as a polar group.

As the lactone group or the sultone group, any group can be used as long as the group has a lactone structure or a sultone structure, and the group preferably has a lactone structure or a sultone structure having a 5- to 7-membered ring, and another ring structure is preferably condensed with a lactone structure or a sultone structure having a 5- to 7-membered ring while forming a bicyclo structure or a spiro structure. The group more preferably has a repeating unit having a lactone structure or a sultone structure represented by any one of the following General Formulas (LC1-1) to (LC1-17), (SL1-1), and (SL1-2). In addition, a lactone structure or a sultone structure may be directly bonded to the main chain. As the lactone structure or sultone structure, (LC1-1), (LC1-4), (LC1-5), or (LC1-8) is preferable, and (LC1-4) is more preferable. LWR and development defect are decreased by using a specific lactone structure or sultone structure.

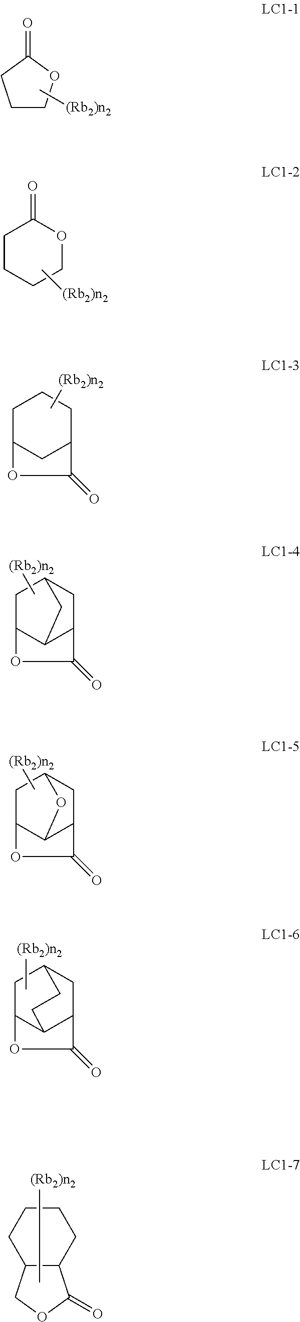

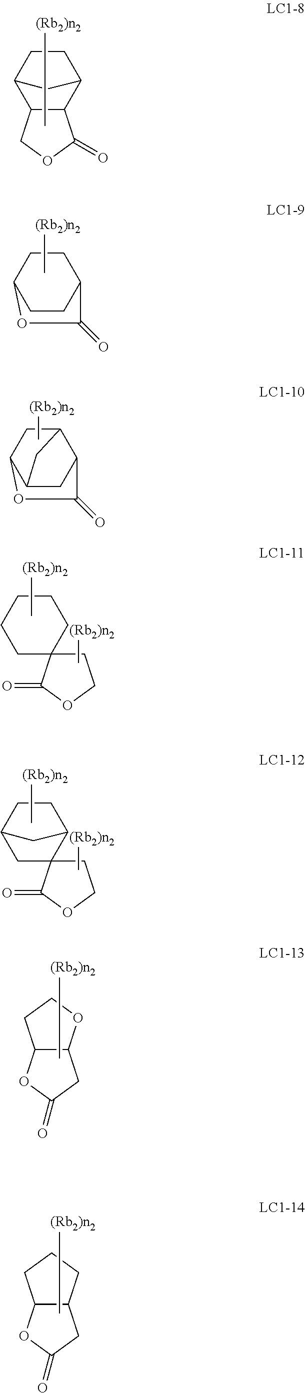

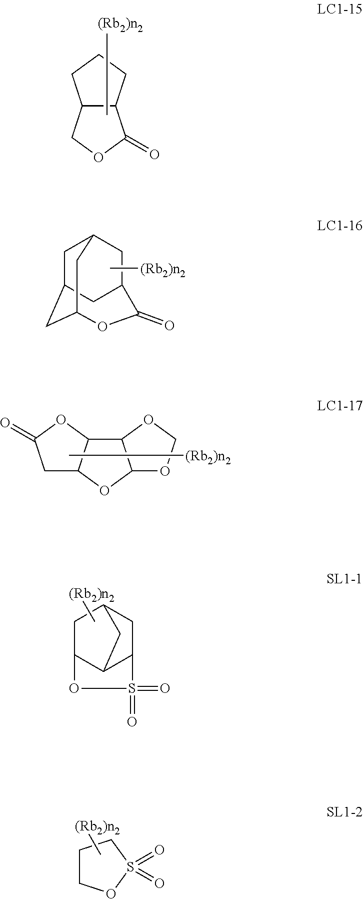

The lactone structure portion or the sultone structure portion may have or may not have a substituent (Rb₂). Preferable examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. The substituent (Rb₂) is more preferably an alkyl group having 1 to 4 carbon atoms, a cyano group, or an acid-decomposable group. n₂ represents an integer of 0 to 4. When n₂ is 2 or greater, plural substituents (Rb₂) present in a molecule may be the same as or different from each other, and plural substituents (Rb₂) present in a molecule may be bonded to each other to form a ring.

The resin [P-A] preferably contains a repeating unit having a lactone structure or a sultone structure represented by the following General Formula (III).

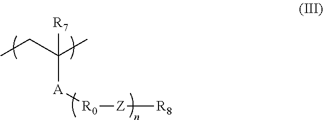

In Formula (III), A represents an ester bond (group represented by —COO—) or an amide bond (group represented by —CONH—).

In a case where a plurality of R₀'s are present, each of R₀'s independently represents an alkylene group, a cycloalkylene group, or a combination thereof.

In a case where a plurality of Z's are present, each of Z's independently represents a single bond, an ether bond, an ester bond, an amide bond, a urethane bond,

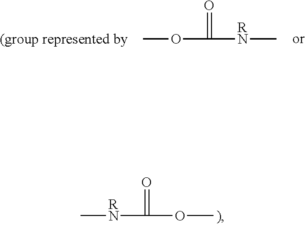

or a urea bond

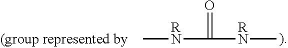

Here, each of R's independently represents a hydrogen atom, an alkyl group, a cycloalkyl group, or an aryl group.

R₈ represents a monovalent organic group having a lactone structure or a sultone structure.

n is the number of repetitions of the structure represented by —R₀—Z—, and represents an integer of 0 to 2.

R₇ represents a hydrogen atom, a halogen atom, or an alkyl group.

The alkylene group and the cycloalkyl group represented by R₀ may have a substituent.

Z is preferably an ether bond or an ester bond, and particularly preferably an ester bond.

The alkyl group represented by R₇ is preferably an alkyl group having 1 to 4 carbon atoms, more preferably a methyl group or an ethyl group, and particularly preferably a methyl group. Each of the alkylene group and the cycloalkylene group represented by R₀, and the alkyl group represented by R₇ may be substituted, and examples of the substituent include a halogen atom such as a fluorine atom, a chlorine atom, or a bromine atom or a mercapto group, an alkoxy group such as a hydroxy group, a methoxy group, an ethoxy group, an isopropoxy group, a t-butoxy group, or a benzyloxy group, and an acetoxy group such as an a cetyloxy group or a propionyloxy group. R₇ is preferably a hydrogen atom, a methyl group, a trifluoromethyl group, or a hydroxymethyl group.

The chain alkylene group represented by R₀ is preferably a chain alkylene group having 1 to 10 carbon atoms, more preferably an alkylene group having 1 to 5 carbon atoms, and examples thereof include a methylene group, an ethylene group, and a propylene group. The cycloalkyl group is preferably a cycloalkyl group having 3 to 20 carbon atoms, and examples thereof include a cyclohexylene group, a cyclopentylene group, a norbornylene group, and an adamantylene group. To exhibit the effects of the present invention, a chain alkylene group is more preferable, and a methylene group is particularly preferable.

A monovalent organic group having a lactone structure or a sultone structure represented by R₈ is not limited as long as it has a lactone structure or a sultone structure, and specific examples thereof include the lactone structure or the sultone structure represented by any one of General Formulas (LC1-1) to (LC1-17), (SL1-1), and (SL1-2), and among these, the structure represented by (LC1-4) is particularly preferable. In addition, n2 in (LC1-1) to (LC1-17), (SL1-1), and (SL1-2) is more preferably 2 or less.

In addition, R₈ is preferably a monovalent organic group having a lactone structure or a sultone structure unsubstituted or a monovalent organic group having a lactone structure or a sultone structure having a methyl group, a cyano group, or an alkoxycarbonyl group as a substituent, and a monovalent organic group having a lactone structure (cyanolactone) or a sultone structure (cyanosultone) having a cyano group as a substituent is more preferable.

In General Formula (III), n is preferably 1 or 2.

Specific examples of the repeating unit having the lactone structure or the sultone structure represented by General Formula (III) are shown below, but the present invention is not limited thereto.

In the following specific examples, R represents a hydrogen atom, an alkyl group which may have a substituent, or a halogen atom, and preferably represents a hydrogen atom, a methyl group, a hydroxymethyl group, or an acetoxymethyl group.

In the following formula, Me represents a methyl group.

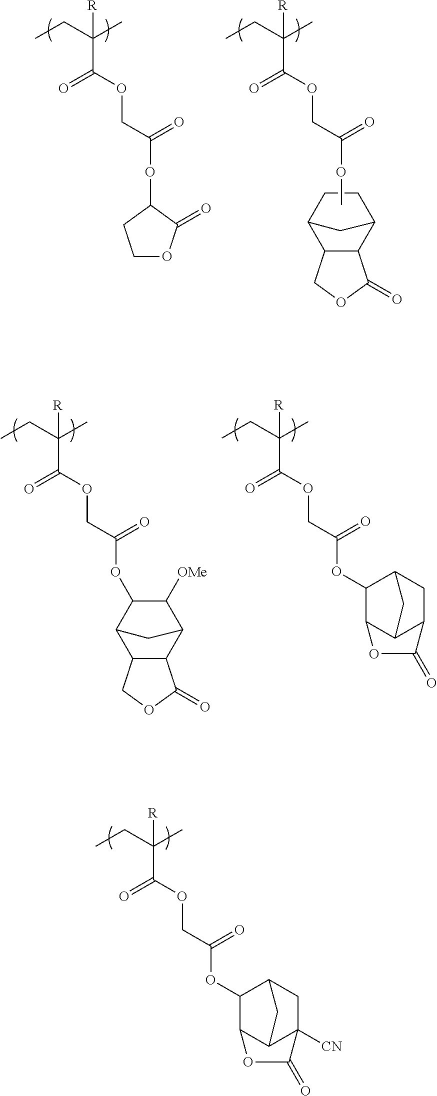

As the repeating unit having a lactone structure or a sultone structure, repeating units represented by the following General Formula (III-1) or (III-1′) are more preferable.

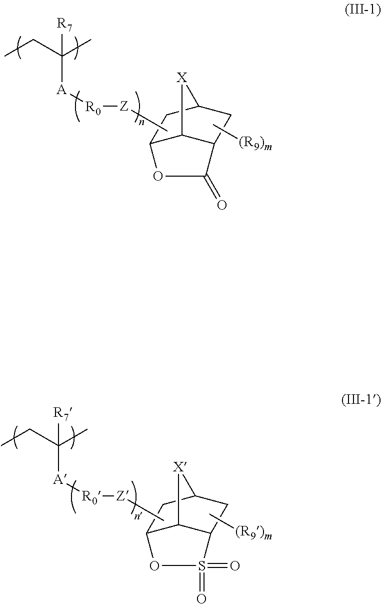

In General Formula (III-1) or (III-1′), each of R₇, A, R₀, Z, and n has the same meaning as that in General Formula (III).

R₇′, A′, R₀′, Z′, and n′ have the same meaning as R₇, A, R₀, Z, and n in General Formula (III), respectively.

In a case where a plurality of R₉'s are present, each of R₉'s independently represents an alkyl group, a cycloalkyl group, an alkoxycarbonyl group, a cyano group, a hydroxyl group, or an alkoxy group, and two R₉'s may be bonded to each other to form a ring.

In a case where a plurality of R₉″s are present, each of R₉″s independently represents an alkyl group, a cycloalkyl group, an alkoxycarbonyl group, a cyano group, a hydroxyl group, or an alkoxy group, and two R₉″s may be bonded to each other to form a ring.

Each of X and X′ independently represents an alkylene group, an oxygen atom, or a sulfur atom.

Each of m and m′ is the number of substituents, and independently represents an integer of 0 to 5. Each of m and m′ is independently preferably 0 or 1.

The alkyl group represented by R₉ or R₉′ is preferably an alkyl group having 1 to 4 carbon atoms, more preferably a methyl group or an ethyl group, and most preferably a methyl group. Examples of the cycloalkyl group include a cyclopropyl group, a cyclobutyl group, a cyclopentyl group, and a cyclohexyl group. Examples of the alkoxycarbonyl group include a methoxycarbonyl group, an ethoxycarbonyl group, an n-butoxycarbonyl group, and a t-butoxycarbonyl group. Examples of the alkoxy group include a methoxy group, an ethoxy group, a propoxy group, an isopropoxy group, and a butoxy group. The groups may have a substituent, and examples of the substituent include an alkoxy group such as a hydroxy group, a methoxy group, or an ethoxy group, a cyano group, and halogen atoms such as a fluorine atom. Each of R₉ and R₉′ is more preferably a methyl group, a cyano group, or an alkoxycarbonyl group, and still more preferably a cyano group.

Examples of the alkylene group represented by X or X′ include a methylene group or an ethylene group. Each of X and X′ is preferably an oxygen atom or a methylene group, and more preferably a methylene group.

In a case where each of m and m′ is 1 or more, at least one of R₉ and R₉′ is preferably substituted at the α-position or the β-position of the carbonyl group in a lactone, and particularly preferably substituted at the α-position.

Specific examples of a group having the lactone structure represented by General Formula (III-1) or (III-1′) or the repeating unit having the sultone structure represented by General Formula (III-1) or (III-1′) are shown, but the present invention is not limited thereto. In the following specific examples, R represents a hydrogen atom, an alkyl group which may have a substituent, or a halogen atom, and preferably represents a hydrogen atom, a methyl group, a hydroxymethyl group, or an acetoxymethyl group.

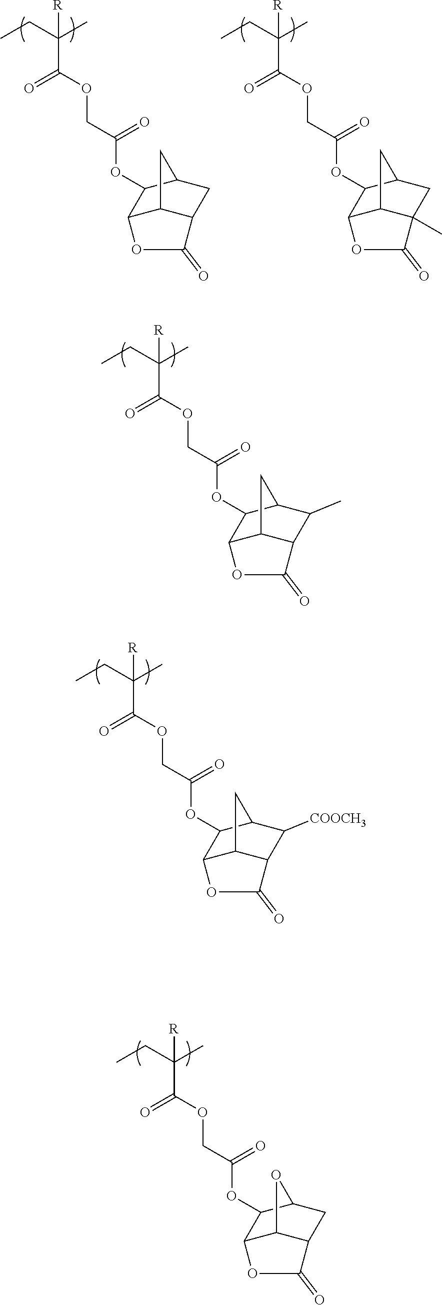

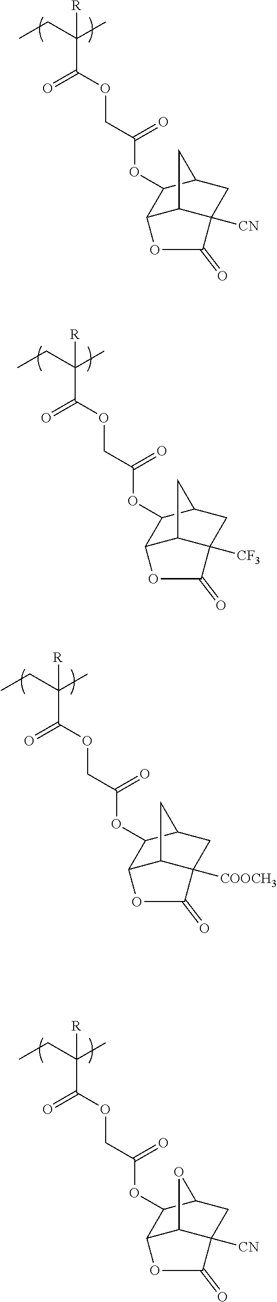

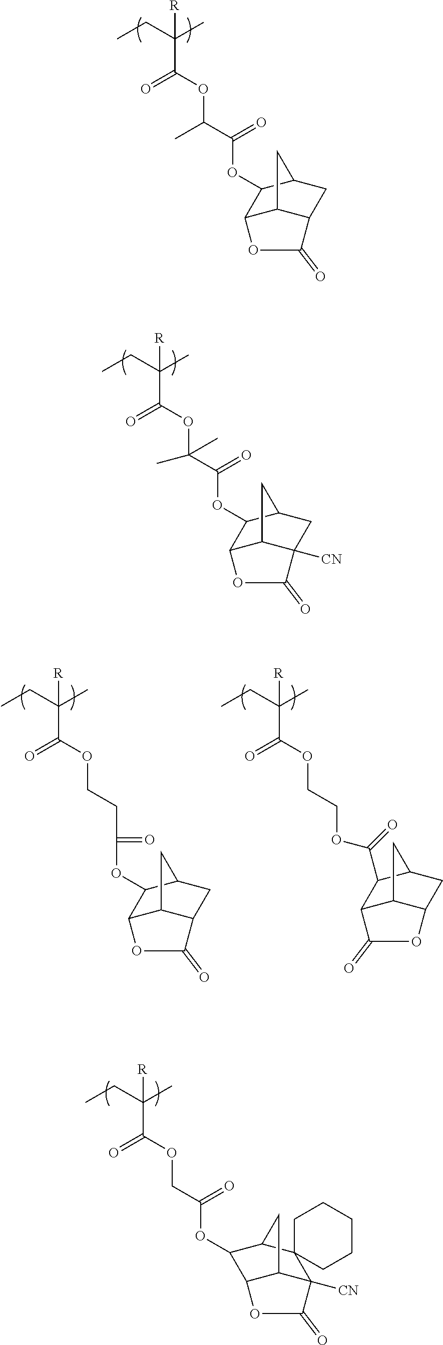

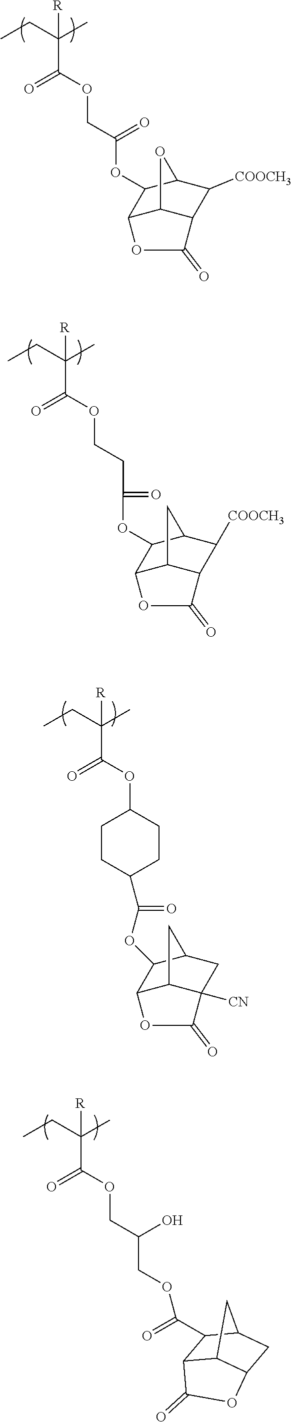

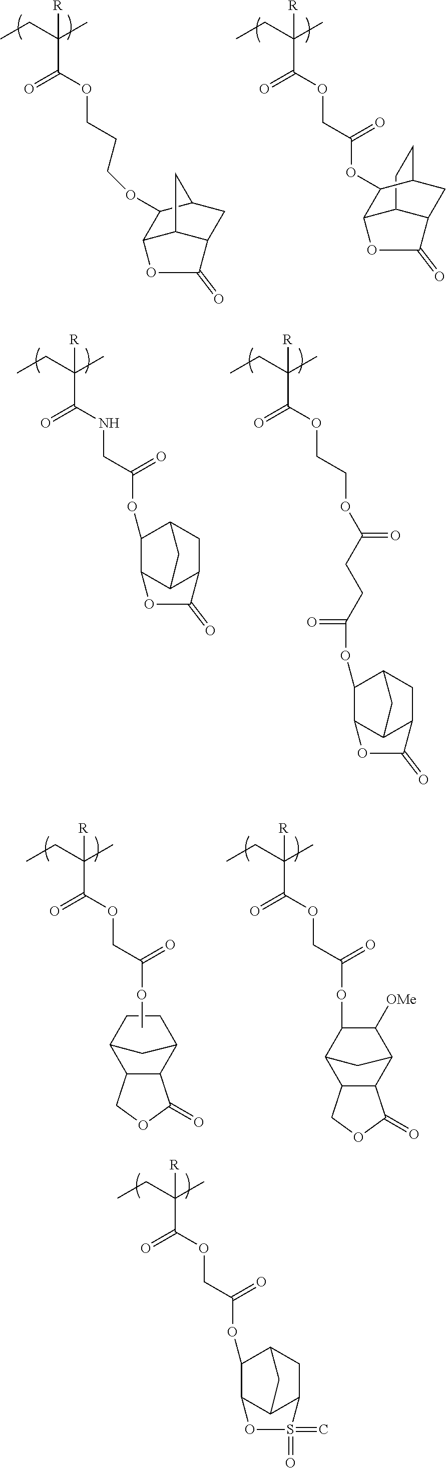

The resin [P-A] may have one type or two or more types of repeating units having a lactone structure or a sultone structure.

The content of the repeating unit having a lactone structure or a sultone structure, in the case of containing plural types, is preferably 1 mol % to 50 mol %, more preferably 3 mol % to 40 mol %, and still more preferably 5 mol % to 30 mol %, with respect to the entirety of repeating units in the resin [P-A] in total.

Specific examples of the repeating unit having a lactone group or a sultone group are described below, in addition to the specific examples described above, but the present invention is not limited thereto.

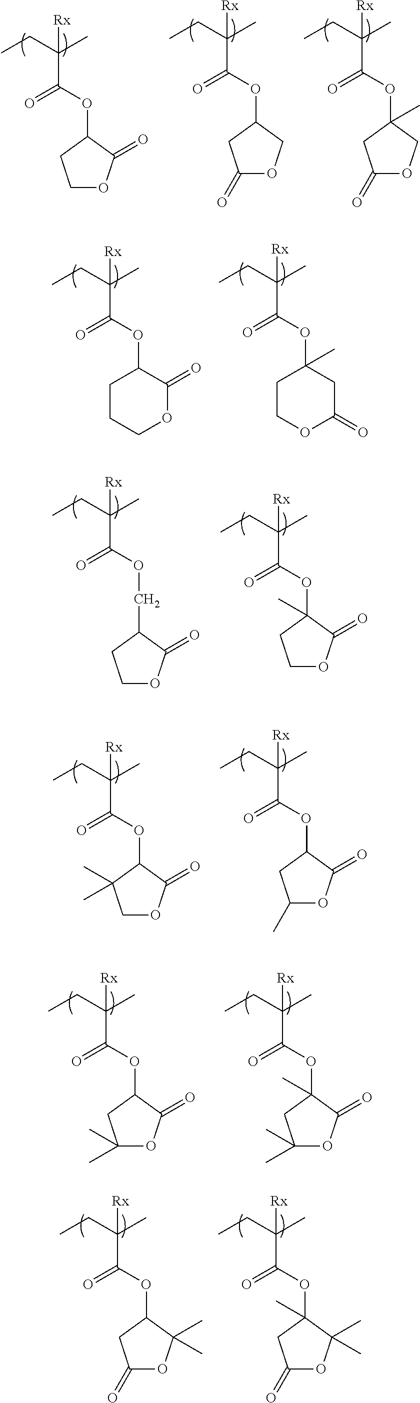

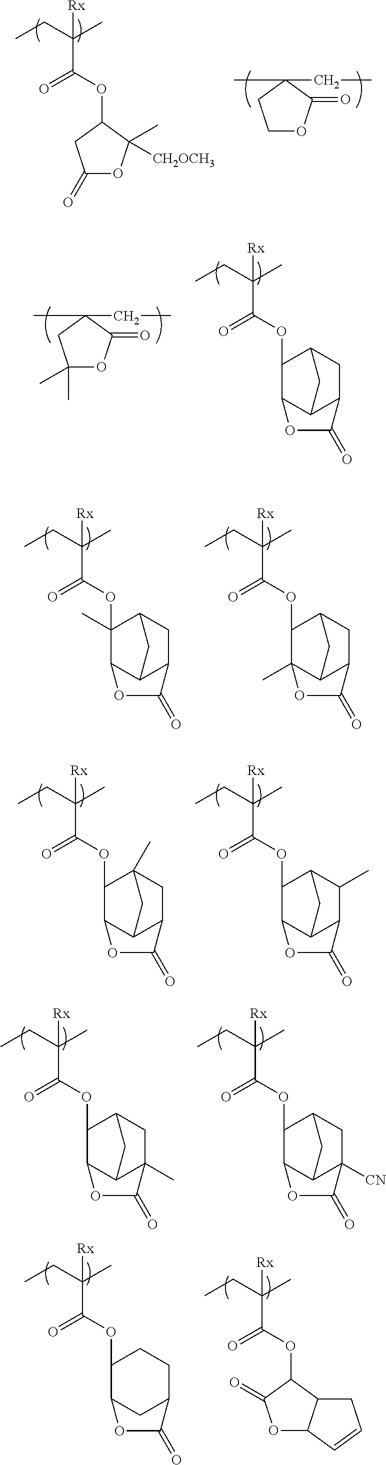

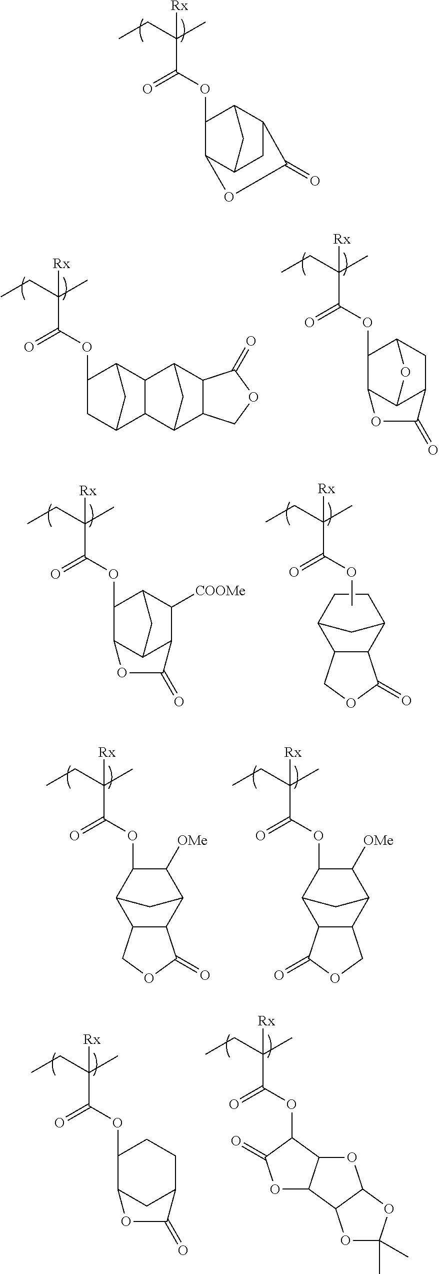

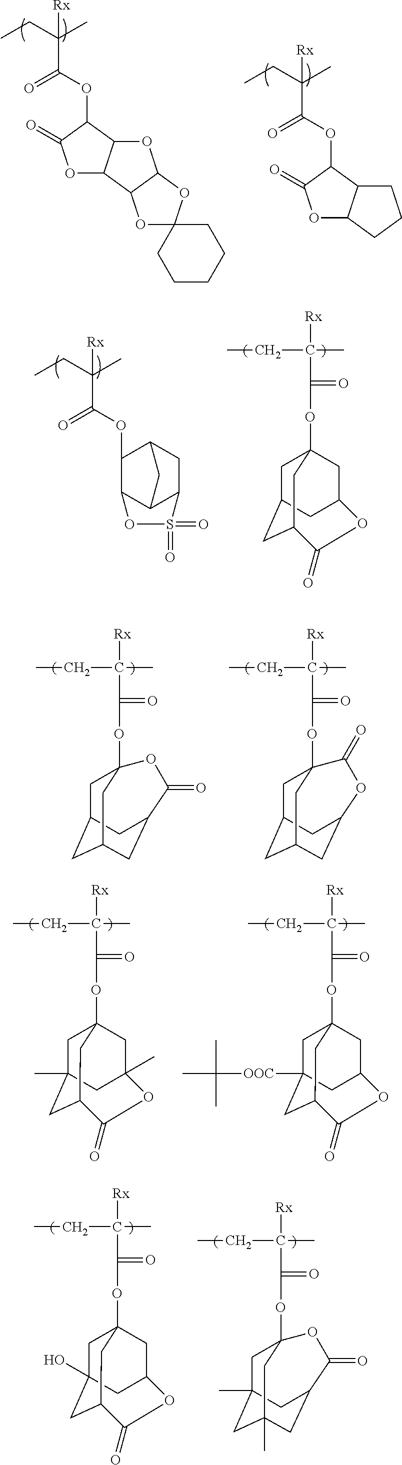

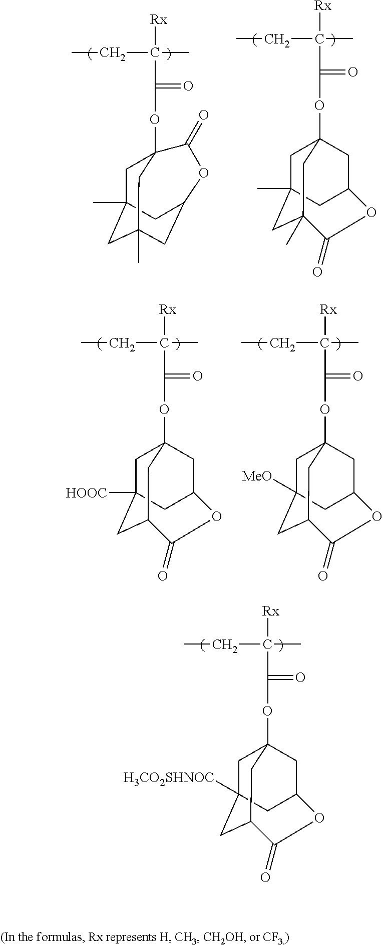

In the above specific examples, as a particularly preferable repeating unit, the following repeating units are exemplified. By selecting the most suitable lactone group or sultone group, the pattern profile and the density dependence are improved.

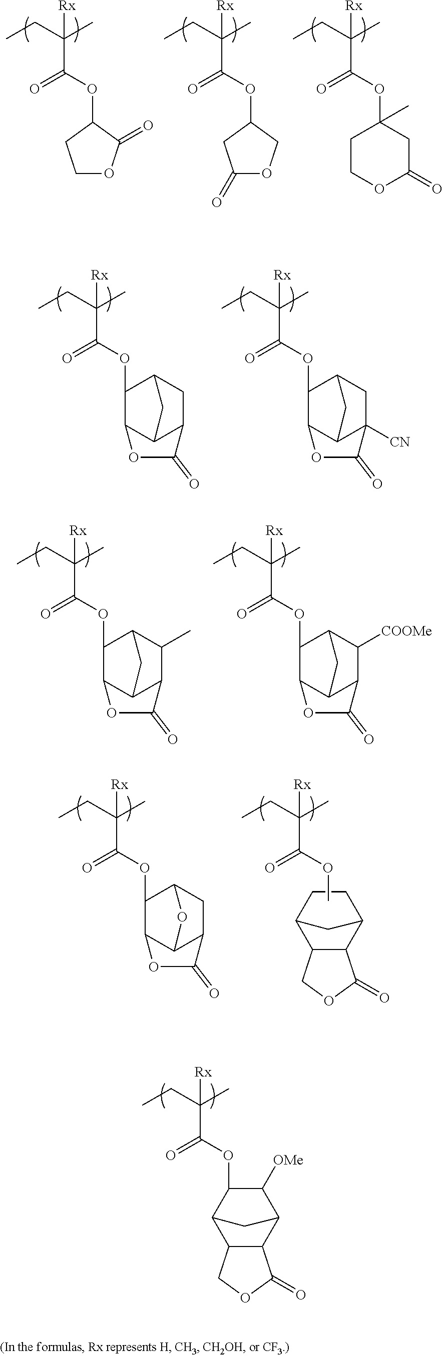

The repeating unit having a lactone group or a sultone group typically has optical isomers, and any optical isomer may be used. In addition, one type of optical isomer may be used alone, or two or more types of optical isomers may be used in combination. In a case where one type of optical isomer is mainly used, the optical purity (ee) is preferably 90% or greater, and more preferably 95% or greater.

It is also a particularly preferable aspect that a polar group which the repeating unit (c) can have is an acidic group. Preferable examples of the acidic group include a phenolic hydroxyl group, a carboxylic acid group, a sulfonic acid group, a fluorinated alcohol group (for example, a hexafluoroisopropanol group), a sulfonamide group, a sulfonyl imide group, a (alkylsulfonyl)(alkylcarbonyl)methylene group, a (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group. Among these, the repeating unit (c) is more preferably a repeating unit having a carboxyl group. Due to a repeating unit having an acidic group being contained, resolution in contact hole use increases. Examples of the repeating unit having an acidic group include a repeating unit of which an acidic group is directly bonded to the main chain of a resin as a repeating unit by acrylic acid or methacrylic acid and a repeating unit of which an acidic group is bonded to the main chain of a resin through a connecting group, and any repeating unit introduced to a terminal of a polymer chain using a polymerization initiator or a chain transfer agent having an acidic group at the time of polymerization is preferable. A repeating unit by acrylic acid or methacrylic acid is particularly preferable.

The acidic group which the repeating unit (c) can have may include or may not include an aromatic ring, and in a case where the acidic group has an aromatic ring, the acidic group is preferably selected from acidic groups other than a phenolic hydroxyl group. In a case where the repeating unit (c) has an acidic group, the content of the repeating unit having an acidic group is preferably 30 mol % or less, and more preferably 20 mol % or less, with respect to the entirety of repeating units in the resin [P-A]. In a case where the resin [P-A] contains a repeating unit having an acidic group, the content of the repeating unit having an acidic group in the resin [P-A] is typically 1 mol % or greater.

Specific examples of the repeating unit having an acidic group are shown below, but the present invention is not limited thereto.

In the specific examples, Rx represents H, CH₃, CH₂OH, or CF₃.

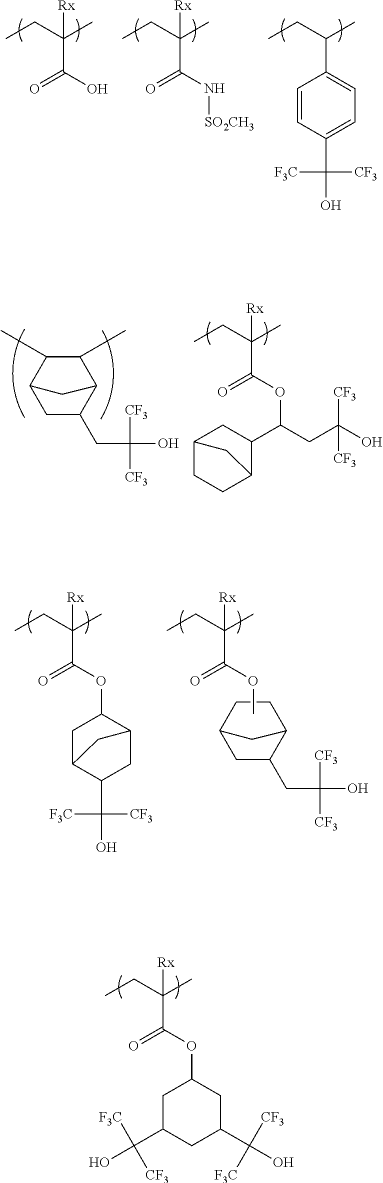

(d) Repeating Unit Having Plurality of Aromatic Rings

The resin [P-A] may have a repeating unit (d) having a plurality of aromatic rings represented by the following General Formula (c1).

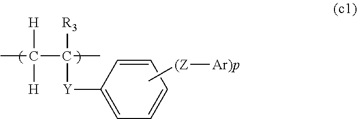

In General Formula (c1), R₃ represents a hydrogen atom, an alkyl group, a halogen atom, a cyano group, or a nitro group, Y represents a single bond or a divalent connecting group, Z represents a single bond or a divalent connecting group, Ar represents an aromatic ring group, and p represents an integer of 1 or greater.

The alkyl group represented by R₃ may be linear or branched, and examples thereof include a methyl group, an ethyl group, an n-propyl group, an i-propyl group, an n-butyl group, a sec-butyl group, a t-butyl group, an n-pentyl group, an n-hexyl group, an n-heptyl group, an n-octyl group, an n-nonyl group, an n-decanyl group, and an i-butyl group. The alkyl group may further have a substituent, and preferable examples of the substituent include an alkoxy group, a hydroxyl group, a halogen atom, and a nitro group. Among these, as the alkyl group having a substituent, a CF₃ group, an alkyloxycarbonyl methyl group, an alkylcarbonyloxy methyl group, a hydroxymethyl group, or an alkoxymethyl group is preferable.

Examples of the halogen atom represented by R₃ include a fluorine atom, a chlorine atom, a bromine atom, and an iodine atom, and a fluorine atom is particularly preferable.

Y represents a single bond or a divalent connecting group, and examples of the divalent connecting group include an ether group (oxygen atom), a thioether group (sulfur atom), an alkylene group, an arylene group, a carbonyl group, a sulfide group, a sulfone group, —COO—, —CONH—, —SO₂NH—, —CF₂—, —CF₂CF₂—, —OCF₂O—, —CF₂OCF₂—, —SS—, —CH₂SO₂CH₂—, —CH₂COCH₂—, —COCF₂CO—, —COCO—, —OCOO—, —OSO₂O—, an amino group (nitrogen atom), an acyl group, an alkylsulfonyl group, —CH═CH—, —C≡C—, an aminocarbonylamino group, an aminosulfonylamino group, and a group obtained by combining these. Y preferably has 15 or less carbon atoms, and more preferably has 10 or less carbon atoms.

Y is preferably a single bond, a —COO— group, a —COS— group, or a —CONH— group, more preferably a —COO— group or a —CONH— group, and particularly preferably a —COO— group.

Z represents a single bond or a divalent connecting group, and examples of the divalent connecting group include an ether group (oxygen atom), a thioether group (sulfur atom), an alkylene group, an arylene group, a carbonyl group, a sulfide group, a sulfone group, —COO—, —CONH—, —SO₂NH—, an amino group (nitrogen atom), an acyl group, an alkylsulfonyl group, —CH═CH—, an aminocarbonylamino group, an aminosulfonylamino group, or a group obtained by combining these.

Z is preferably a single bond, an ether group, a carbonyl group, or —COO—, more preferably a single bond or an ether group, and particularly preferably a single bond.

Ar represents an aromatic ring group, and specific examples thereof include a phenyl group, a naphthyl group, an anthracenyl group, a phenanthrenyl group, a quinolinyl group, a furanyl group, a thiophenyl group, a fluorenyl-9-on-yl group, an anthraquinonyl group, a phenanthraquinonyl group, and a pyrrole group, and a phenyl group is preferable. The aromatic ring group may further have a substituent, and preferable examples of the substituent include an alkyl group, an alkoxy group, a hydroxyl group, a halogen atom, a nitro group, an acyl group, an acyloxy group, an acylamino group, a sulfonylamino group, an aryl group such as a phenyl group, an aryloxy group, an arylcarbonyl group, and a heterocyclic residue. Among these, a phenyl group is preferable from the viewpoint of suppressing deterioration of exposure latitude or a pattern shape due to out band light.

p is an integer of 1 or greater, and is preferably an integer of 1 to 3.

The repeating unit (d) is more preferably a repeating unit represented by the following Formula (c2).

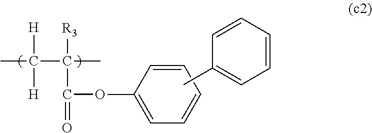

In General Formula (c2), R₃ represents a hydrogen atom or an alkyl group. Preferable alkyl group represented by R₃ is the same as that in General Formula (c1).

Here, regarding extreme ultraviolet rays (EUV light) exposure, leakage light (out of band light) generated in a region of ultraviolet rays having a wavelength of 100 nm to 400 nm deteriorates the surface roughness, and as a result, the resolution or the LWR performance tends to be reduced due to a bridge between patterns or disconnection of a pattern.

However, the aromatic ring in the repeating unit (d) functions as an internal filter capable of absorbing the out of band light. Accordingly, the resin [P-A] preferably contains the repeating unit (d) from the viewpoint of high resolution and low LWR.

Here, the repeating unit (d) preferably does not include a phenolic hydroxyl group (hydroxyl group directly bonded to an aromatic ring) from the viewpoint of obtaining high resolution.

Specific examples of the repeating unit (d) are shown below, but the present invention is not limited thereto.

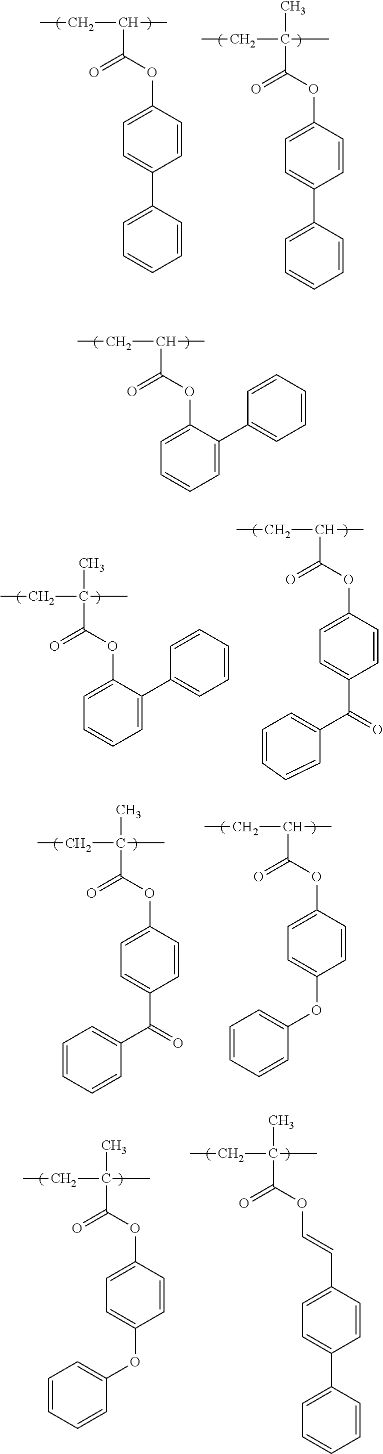

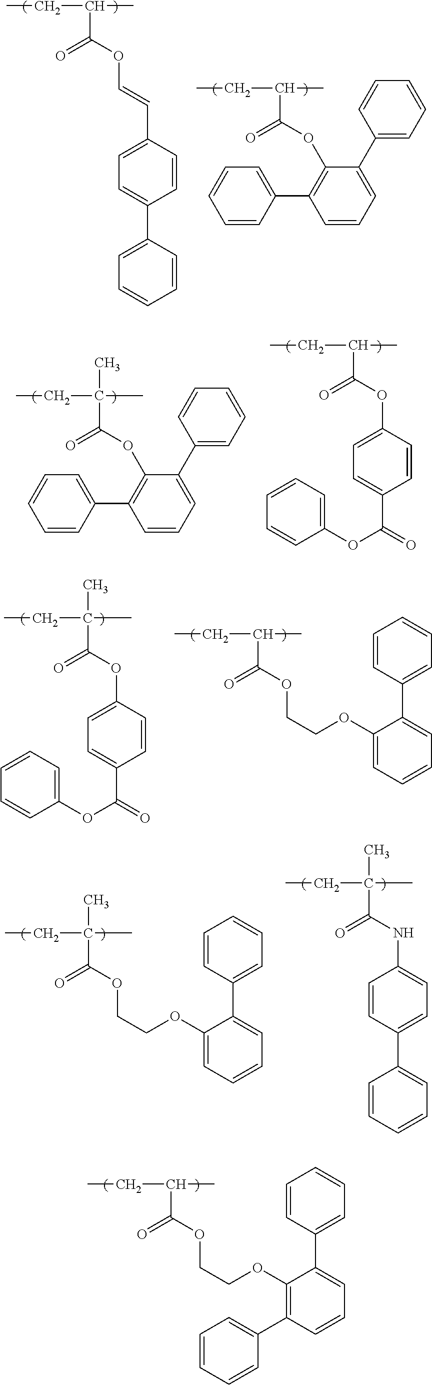

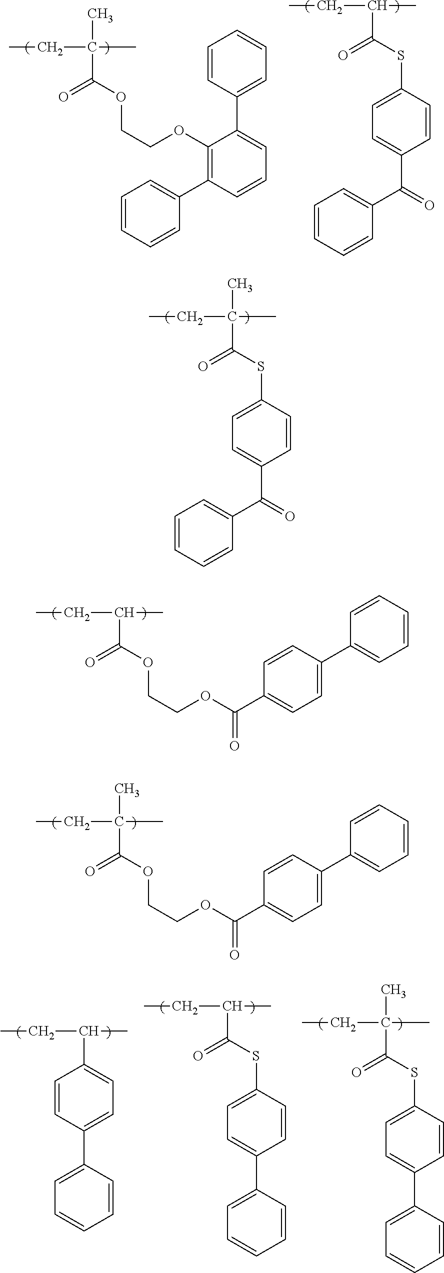

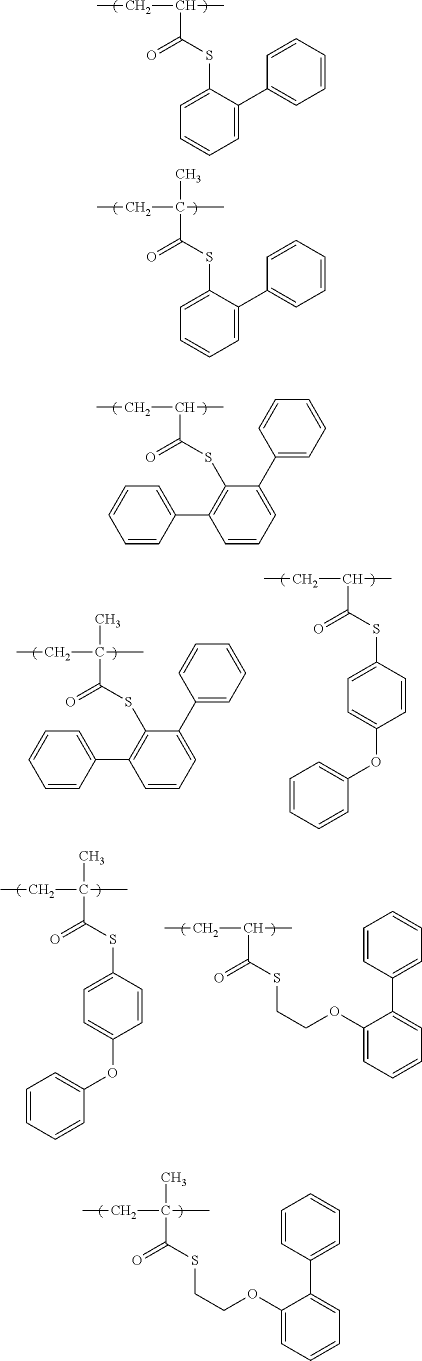

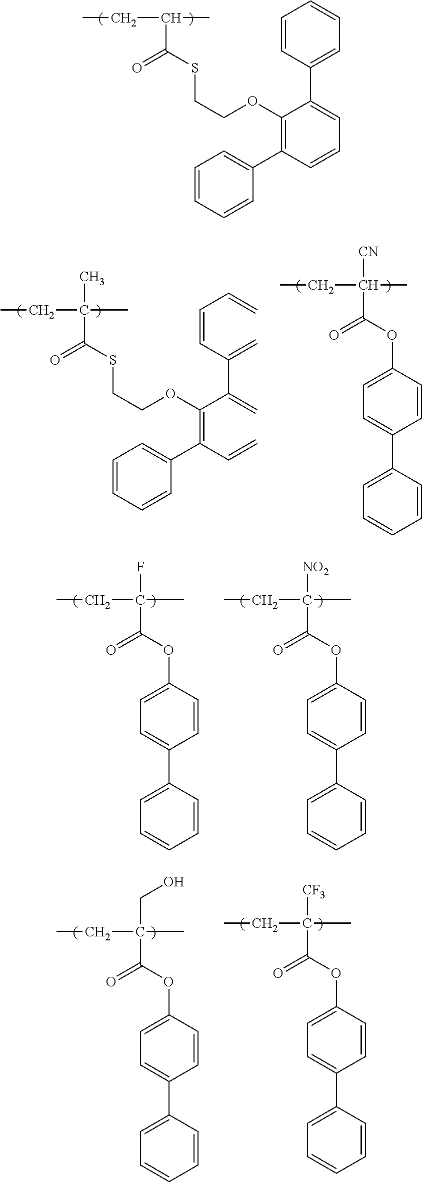

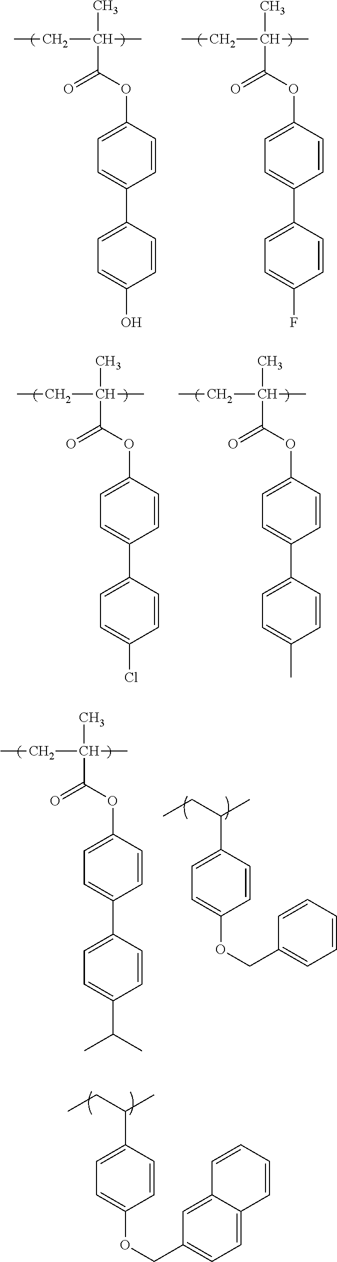

The resin [P-A] may contain or may not contain the repeating unit (d), and in a case where the resin [P-A] contains the repeating unit (d), the content of the repeating unit (d) is preferably within a range of 1 mol % to 30 mol %, more preferably within a range of 1 mol % to 20 mol %, and still more preferably within a range of 1 mol % to 15 mol %, with respect to the entirety of repeating units in the resin [P-A]. The repeating unit (d) included in the resin [P-A] may be included in combination of two or more types thereof.

The resin [P-A] in the present invention may suitably have a repeating unit (hereinafter, also referred to as “other repeating units”) other than the above-described repeating units. One example of such a repeating unit is a repeating unit which has an alicyclic hydrocarbon structure without a polar group (for example, an acid group, a hydroxyl group, or a cyano group described above) and does not exhibit acid-decomposability. As other repeating units, a repeating unit represented by General Formula (IV) is exemplified.

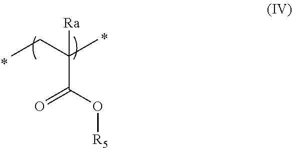

In General Formula (IV), R₅ has at least one ring structure, and represents a hydrocarbon group not having a polar group.

Ra represents a hydrogen atom, an alkyl group, or a —CH₂—O—Ra₂ group. In the formula, Ra₂ represents a hydrogen atom, an alkyl group, or an acyl group. Ra is preferably a hydrogen atom, a methyl group, a hydroxymethyl group, or a trifluoromethyl group, and particularly preferably a hydrogen atom or a methyl group.

A monocyclic hydrocarbon group or a polycyclic hydrocarbon group is included in the ring structure which R₅ has. Examples of the monocyclic hydrocarbon group include a cycloalkyl group having 3 to 12 carbon atoms such as a cyclopentyl group, a cyclohexyl group, a cycloheptyl group, or a cyclooctyl group, and a cycloalkenyl group having 3 to 12 carbon atoms such as a cyclohexenyl group. The monocyclic hydrocarbon group is preferably a monocyclic hydrocarbon group having 3 to 7 carbon atoms, and more preferably a cyclopentyl group or a cyclohexyl group.

A ring-aggregated hydrocarbon group or a crosslinked cyclic hydrocarbon group is included in the polycyclic hydrocarbon group, and examples of the ring-aggregated hydrocarbon group include a bicyclohexyl group and a perhydronaphthalenyl group. Examples of the crosslinked cyclic hydrocarbon ring include a bicyclic hydrocarbon ring such as a pinane ring, a bornane ring, a norpinane ring, a norbornane ring, or a bicyclooctane ring (a bicyclo[2.2.2]octane ring, a bicyclo[3.2.1]octane ring, or the like), a tricyclic hydrocarbon ring such as a homobledane ring, an adamantane ring, a tricyclo[5.2.1.0^{2,6}]decane ring, or a tricyclo[4.3.1.1^{2,5}]undecane ring, and a tetracyclic hydrocarbon ring such as a tetracyclo[4.4.0.1^{2,5}.1^{7,10}]dodecane ring or a perhydro-1,4-methano-5,8-methanonaphthalene ring. In addition, a condensed cyclic hydrocarbon ring, for example, a fused ring obtained by condensation of a plurality of 5- to 8-membered cycloalkane rings, such as a perhydronaphthalene (decalin) ring, a perhydroanthracene ring, a perhydrophenanthrene ring, a perhydroacenaphthene ring, a perhydrofluorene ring, a perhydroindene ring, or a perhydrophenalene ring, is also included in the crosslinked cyclic hydrocarbon ring.

Preferable examples of the crosslinked cyclic hydrocarbon ring include a norbornyl group, an adamantyl group, a bicyclooctanyl group, and a tricyclo[5.2.1.0^{2,6}]decanyl group. More preferable examples of the crosslinked cyclic hydrocarbon ring include a norbornyl group and an adamantyl group.

The alicyclic hydrocarbon group may have a substituent, and preferable examples of the substituent include a halogen atom, an alkyl group, a hydroxyl group in which a hydrogen atom is substituted, and an amino group in which a hydrogen atom is substituted. Preferable examples of the halogen atom include a bromine atom, a chlorine atom, and a fluorine atom, and preferable examples of the alkyl group include a methyl group, an ethyl group, a butyl group, and a t-butyl group. The alkyl group may further have a substituent, and examples of the substituent which the alkyl group may further have include a halogen atom, an alkyl group, a hydroxyl group in which a hydrogen atom is substituted, and an amino group in which a hydrogen atom is substituted.

Examples of the substituent for a hydrogen atom include an alkyl group, a cycloalkyl group, an aralkyl group, a substituted methyl group, a substituted ethyl group, an alkoxycarbonyl group, and an aralkyloxycarbonyl group. Preferable examples of the alkyl group include an alkyl group having 1 to 4 carbon atoms, preferable examples of the substituted methyl group include a methoxymethyl group, a methoxythiomethyl group, a benzyloxymethyl group, a t-butoxymethyl group, and a 2-methoxyethoxymethyl group, preferable examples of the substituted ethyl group include a 1-ethoxyethyl group and a 1-methyl-1-methoxyethyl group, preferable examples of the acyl group include an aliphatic acyl group having 1 to 6 carbon atoms such as a formyl group, an acetyl group, a propionyl group, a butyryl group, an isobutyryl group, a valeryl group, or a pivaloyl group, and examples of the alkoxycarbonyl group include an alkoxycarbonyl group having 1 to 4 carbon atoms.

Although the resin [P-A] may contain or may not contain a repeating unit which has an alicyclic hydrocarbon structure without a polar group and does not exhibit acid-decomposability, in a case where the resin [P-A] contains the repeating unit, the content of the repeating unit is preferably 1 mol % to 20 mol %, and more preferably 5 mol % to 15 mol %, with respect to the entirety of repeating units in the resin [P-A].

Specific examples of the repeating unit which has an alicyclic hydrocarbon structure without a polar group and does not exhibit acid-decomposability are shown below, but the present invention is not limited thereto. In the formulas, Ra represents H, CH₃, CH₂OH, or CF₃.

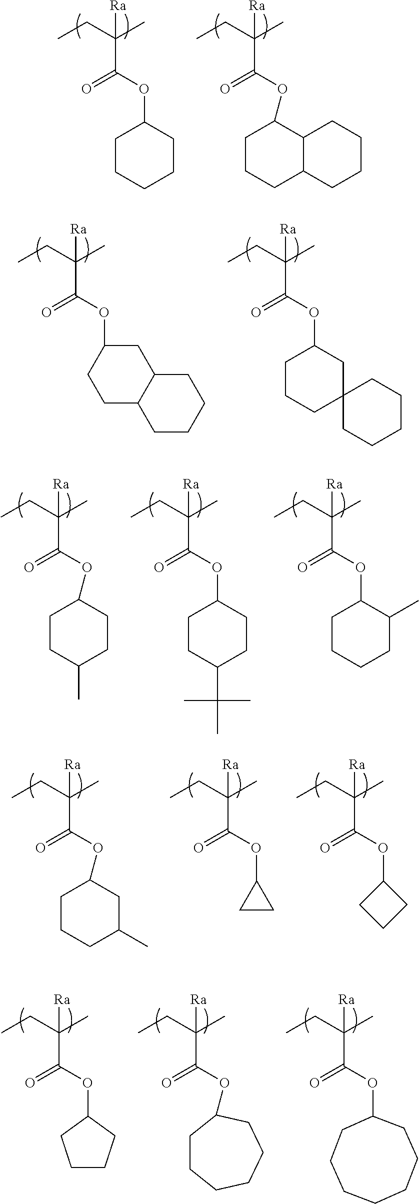

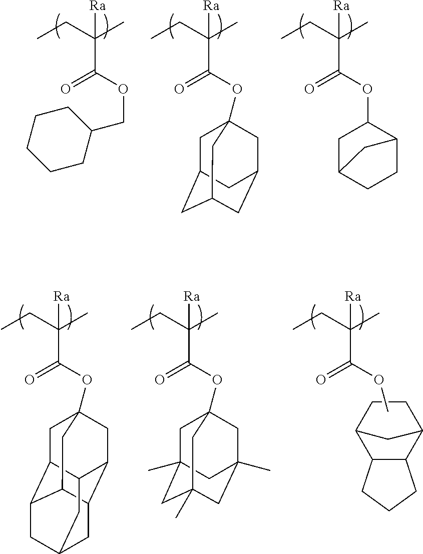

In addition, the resin [P-A] may include the following monomer component in consideration of rise of Tg, improvement of dry etching resistance, and effect of an internal filter with respect to the out of band light described above.

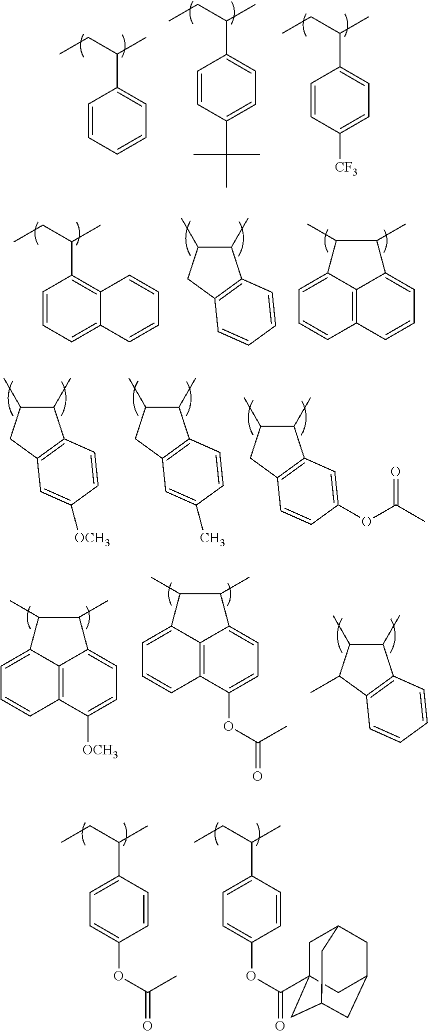

In the resin [P-A] used in the composition of the present invention, the content molar ratio of respective repeating structural units is suitably set to adjust dry etching resistance or standard developer suitability of a resist, adhesion to substrate, a resist profile, and resolving power, heat resistance, and sensitivity which are properties generally required for a resist.

The form of the resin [P-A] of the present invention may be any form of a random form, a block form, a comb form, and a star form.

The resin [P-A] can be synthesized by, for example, polymerizing an unsaturated monomer corresponding to each structure through radical polymerization, cationic polymerization, or anionic polymerization. In addition, by performing a polymer reaction after polymerization is performed using an unsaturated monomer corresponding to a precursor of each structure, a target resin can also be obtained.

Examples of a general synthetic method include a collective polymerization method of performing polymerization by dissolving an unsaturated monomer and a polymerization initiator in a solvent and heating the resultant product and a dropping polymerization method of adding a solution containing an unsaturated monomer and an polymerization initiator dropwise to a heated solvent over a period of 1 hour to 10 hours, and the dropping polymerization method is preferable.

Examples of the solvent used in the polymerization include solvents which can be used in preparing an active light sensitive or radiation sensitive composition described below, and it is more preferable that the polymerization is performed using the same solvent as that used in the composition of the present invention. Thus, generation of particles during storage can be suppressed.

The polymerization reaction is preferably performed in an inert gas atmosphere such as nitrogen or argon. The polymerization is initiated using a commercially available radical initiator as a polymerization initiator (azo-based initiator, peroxide, or the like). As the radical initiator, an azo-based initiator is preferable, and an azo-based initiator having an ester group, a cyano group, or a carboxyl group is preferable. Preferable examples of the initiator include azobisisobutyronitrile, azobisdimethylvaleronitrile, and dimethyl 2,2′-azobis(2-methylpropionate). As necessary, polymerization may be performed in the presence of a chain transfer agent (for example, alkyl mercaptan).

The concentration of the reaction is 5% by mass to 70% by mass, and preferably 10% by mass to 50% by mass. The reaction temperature is typically 10° C. to 150° C., preferably 30° C. to 120° C., and more preferably 40° C. to 100° C.

The reaction time is typically 1 hour to 48 hours, preferably 1 hour to 24 hours, and more preferably 1 hour to 12 hours.

After the reaction ends, cooling is performed to room temperature, and purification is performed. A usual method such as a liquid-liquid extraction method in which a residual monomer or an oligomer component is removed by washing with water or combining suitable solvents, a purification method in a solution state such as ultrafiltration which extracts and removes only substances having a specific molecular weight or less, a reprecipitation method in which a residual monomer or the like is removed by adding a resin solution dropwise to a poor solvent to coagulate the resin in the poor solvent, or a purification method in a solid state in which filtered resin slurry is washed with a poor solvent can be applied to the purification. For example, by bringing into contact with a solvent (poor solvent), which poorly dissolves or does not dissolve the resin, corresponding to 10 times or less the volume amount of the reaction solution, or preferably 5 times to 10 times the volume amount of the reaction solution, the resin is solidified and precipitated.

The solvent (precipitation or reprecipitation solvent) used in the precipitation or reprecipitation operation from the polymer solution may be a poor solvent for the polymer, and depending on the type of polymer, the solvent can be suitably selected from hydrocarbon, halogenated hydrocarbon, a nitro compound, ether, ketone, ester, carbonate, alcohol, carboxylic acid, water, and a mixed solvent including these solvents and used. Among these, as a precipitation or reprecipitation solvent, a solvent including at least alcohol (in particular, methanol) or water is preferable.

Although the amount of precipitation or reprecipitation solvent used can be suitably selected in consideration of efficiency or yield, the amount used is generally 100 parts by mass to 10000 parts by mass, preferably 200 parts by mass to 2000 parts by mass, and more preferably 300 parts by mass to 1000 parts by mass, with respect to 100 parts by mass of the polymer solution.

Although the temperature at the time of precipitation or reprecipitation can be suitably selected in consideration of efficiency or operability, the temperature is typically about 0° C. to 50° C., and preferably around room temperature (for example, about 20° C. to 35° C.). The precipitation or reprecipitation operation can be performed by a known method such as a batch type or a continuous type using a generally used mixing vessel such as a stirring vessel.

The precipitated or reprecipitated polymer is typically subjected to generally used solid-liquid separation such as filtration or centrifugation, dried, and then, provided for use. The filtration is preferably performed under pressure using a solvent-resistant filter medium. The drying is performed at a temperature of about 30° C. to 100° C. at normal pressure or under reduced pressure (preferably, under reduced pressure), and preferably at a temperature of about 30° C. to 50° C.

Moreover, once the resin is precipitated, and after being separated, the resin is again dissolved in a solvent, and may be brought into contact with a solvent which poorly dissolves or does not dissolve the resin. That is, a method which includes a step of precipitating a resin by bringing into contact with a solvent which poorly dissolves or does not dissolve the polymer after the radical polymerization reaction ends (step a), a step of separating the resin from the solution (step b), a step of preparing a resin solution A by dissolving the resin in a solvent again (step c), thereafter, precipitating the resin solid by bringing the resin solution A into contact with a solvent in which the resin is poorly soluble or insoluble, corresponding to less than 10 times the volume amount (preferably 5 times or less the volume amount) of the resin solution A (step d), and a step of separating the precipitated resin (step e) may be performed.

The polymerization reaction is preferably performed in an inert gas atmosphere such as nitrogen or argon. The polymerization is initiated using a commercially available radical initiator as a polymerization initiator (azo-based initiator, peroxide, or the like). As the radical initiator, an azo-based initiator is preferable, and an azo-based initiator having an ester group, a cyano group, or a carboxyl group is preferable. Preferable examples of the initiator include azobisisobutyronitrile, azobisdimethylvaleronitrile, and dimethyl 2,2′-azobis(2-methylpropionate). As necessary, an initiator is additionally added or added by being divided, and after the reaction ends, the reaction product is put into a solvent, and a target polymer is recovered by a powder recovery method or a solid recovery method. The concentration of the reaction is 5% by mass to 50% by mass, and preferably 10% by mass to 30% by mass. The reaction temperature is typically 10° C. to 150° C., preferably 30° C. to 120° C., and more preferably 60° C. to 100° C.

Although the molecular weight of the resin [P-A] according to the present invention is not particularly limited, the weight average molecular weight is preferably within a range of 1000 to 100000, more preferably within a range of 1500 to 60000, and particularly preferably within a range of 2000 to 30000. When the weight average molecular weight is within a range of 1000 to 100000, degradation of heat resistance or dry etching resistance can be prevented, and degradation of developability or degradation of film-forming properties due to increase in viscosity can be prevented. Here, the weight average molecular weight of a resin is a molecular weight in terms of polystyrene measured by using GPC (carrier: THF or N-methyl-2-pyrrolidone (NMP)).

The dispersity (Mw/Mn) is preferably 1.00 to 5.00, more preferably 1.00 to 3.50, and still more preferably 1.00 to 2.50. As the molecular weight distribution becomes lower, the resolution and the resist shape become better, the side wall of the resist pattern becomes smoother, and thus, the roughness becomes excellent.

In the present specification, the weight average molecular weight (Mw) and dispersity of a resin can be determined by using, for example, HLC-8120 (manufactured by TOSOH CORPORATION), TSK gel Multipore HXL-M (manufactured by TOSOH CORPORATION, 7.8 mmHD×30.0 cm) as a column, and THF (tetrahydrofuran) or NMP (N-methyl-2-pyrrolidone) as an eluent.

The resin [P-A] may be the same component as the compound [P-B] below, or may be a different component from the compound [P-B], but is preferably a different component from the compound [P-B].

The resin [P-A] of the present invention can be used alone, or two or more types thereof can be used in combination. The content of the resin [P-A] is preferably 20% by mass to 99% by mass, more preferably 30% by mass to 99% by mass, and still more preferably 40% by mass to 99% by mass, based on the total solid content of the active light sensitive or radiation sensitive composition of the present invention.

[P-B] Compound that Generates Acid by Irradiation with Active Light or Radiation, and of which Solubility in Alkali Developers is Increased Due to Action of Acid

The compound [P-B] (hereinafter, also simply referred to as an acid generator [P-B]) that generates an acid by irradiation with active light or radiation, and of which the solubility in alkali developer aqueous solutions is increased due to the action of an acid is preferably a compound that generates an acid by irradiation with active light or radiation, and has a structure (in the same manner as described above for the resin [P-A], hereinafter, also referred to as “acid-decomposable group”) in which an alkali-soluble group is decomposed due to the action of an acid, which is protected with a leaving group leaving.

The molecular weight range of the compound [P-B] is preferably 100 to 3000, more preferably 100 to 2000, and particularly preferably 100 to 1000.

Specific examples and preferable examples of the alkali-soluble group include the same as the specific examples and the preferable examples of the polar group described above for the resin [P-A].

The alkali-soluble group of an acid-decomposable group and preferable examples include the same as the specific examples and the preferable examples of “the structure in which an alkali-soluble group is decomposed due to the action of an acid, which is protected with a group leaving” described above for the resin [P-A].

In the compound (P-B), the acid-decomposable group is preferably a group that generates a phenolic hydroxyl group or a carboxyl group by being decomposed due to the action of an acid from the viewpoint of further increasing the solubility in an alkali developer.

In the present specification, the phenolic hydroxyl group is a group obtained by substituting a hydrogen atom of an aromatic ring group with a hydroxyl group. The aromatic ring is a monocyclic or polycyclic aromatic ring, and examples thereof include an aromatic hydrocarbon ring which may have a substituent having 6 to 18 carbon atoms, such as a benzene ring, a naphthalene ring, an anthracene ring, a fluorene ring, or a phenanthrene ring, and an aromatic ring hetero ring including a hetero ring, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. Among these, a benzene ring or a naphthalene ring is preferable from the viewpoint of resolution, and a benzene ring is most preferable.

As the acid generator [P-B], compounds represented by the following General Formula (ZI), (ZII), and (ZIII) can be exemplified.

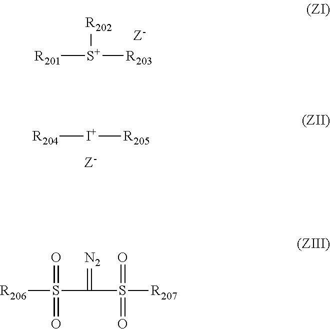

In General Formula (ZI), each of R₂₀₁, R₂₀₂, and R₂₀₃ independently represents an organic group.

The organic group represented by each of R₂₀₁, R₂₀₂, and R₂₀₃ generally has 1 to 30 carbon atoms, and preferably has 1 to 20 carbon atoms.

In addition, two of R₂₀₁ to R₂₀₃ may be bonded to each other to form a ring structure, and an oxygen atom, a sulfur atom, an ester bond, an amide bond, or a carbonyl group may be included in the ring. Examples of the group that two of R₂₀₁ to R₂₀₃ form by bonding to each other include an alkylene group (for example, a butylene group or a pentylene group).

Z⁻ represents a non-nucleophilic anion.

At least one of R₂₀₁, R₂₀₂, R₂₀₃, and Z⁻ has an acid-decomposable group. The preferable aspect of the acid-decomposable group is as described above.

When an acid-decomposable group present at the cation portion is decomposed by active light or radiation, the decomposition product has an acid-decomposable group at the cation portion to be more hydrophobic, and thus, from the viewpoint of capable of more evenly imparting dissolution contrast, at least one of R₂₀₁, R₂₀₂, and R₂₀₃ preferably has an acid-decomposable group.

Examples of the non-nucleophilic anion represented by Z⁻ include a sulfonate anion, a carboxylate anion, a sulfonylimide anion, a bis(alkylsulfonyl)imide anion, and a tris(alkylsulfonyl)methyl anion.

The non-nucleophilic anion is an anion with a very low ability for causing a nucleophilic reaction, and is an anion which can suppress temporal decomposition caused by an intra-molecular nucleophilic reaction. Thus, it is possible to improve the temporal stability of the active light sensitive or radiation sensitive composition.

Examples of the sulfonate anion include an aliphatic sulfonate anion, an aromatic sulfonate anion, and a camphorsulfonate anion.

Examples of the carboxylate anion include an aliphatic carboxylate anion, an aromatic carboxylate anion, and an aralkylcarboxylate anion.

The aliphatic portion in the aliphatic sulfonate anion and the aliphatic carboxylate anion may be an alkyl group or a cycloalkyl group, and preferably an alkyl group having 1 to 30 carbon atoms or a cycloalkyl group having 3 to 30 carbon atoms, such as a methyl group, an ethyl group, a propyl group, an isopropyl group, a n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, or a bornyl group.

The aromatic group in the aromatic sulfonate anion and the aromatic carboxylate anion is preferably an aryl group having 6 to 14 carbon atoms, and examples thereof include a phenyl group, a tolyl group, and a naphthyl group.

The alkyl group, the cycloalkyl group, and the aryl group in an aliphatic sulfonate anion and an aromatic sulfonate anion may have a substituent. Examples of the substituent of the alkyl group, the cycloalkyl group, and the aryl group in an aliphatic sulfonate anion and an aromatic sulfonate anion include a nitro group, a halogen atom (a fluorine atom, a chlorine atom, a bromine atom, or an iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 of 20 carbon atoms), and a cycloalkylalkyloxyalkyloxy group (preferably having 8 to 20 carbon atoms). Regarding the aryl group or a ring structure which each group has, as a substituent, an alkyl group (which preferably has 1 to 15 carbon atoms) can be exemplified.

The aralkyl group in the aralkylcarboxylate anion is preferably an aralkyl group having 7 to 12 carbon atoms, and examples thereof include a benzyl group, a phenethyl group, a naphthylmethyl group, a naphthylethyl group, and a naphthylbutyl group.

The alkyl group, the cycloalkyl group, the aryl group, and the aralkyl group in an aliphatic carboxylate anion, an aromatic carboxylate anion, an aralkylcarboxylate anion may have a substituent. Examples of the substituent include the same as those in the aromatic sulfonate anion, that is, a halogen atom, an alkyl group, a cycloalkyl group, an alkoxy group, and an alkylthio group.

Examples of the sulfonylimide anion include a saccharin anion.

The alkyl group in an bis(alkylsulfonyl)imide anion and a tris(alkylsulfonyl)methide anion is preferably an alkyl group having 1 to 5 carbon atoms, and examples thereof include a methyl group, an ethyl group, a propyl group, an isopropyl group, an n-butyl group, an isobutyl group, a sec-butyl group, a pentyl group, and a neopentyl group. Examples of the substituent of the alkyl group include a halogen atom, an alkyl group substituted with a halogen atom, an alkoxy group, an alkylthio group, an alkyloxysulfonyl group, an aryloxysulfonyl group, and a cycloalkylaryloxysulfonyl group, and an alkyl group substituted with a fluorine atom is preferable.

Examples of other non-nucleophilic anions include fluorophosphate, fluoroborate, and fluoroantimonate.

As the non-nucleophilic anion represented by Z⁻, an aliphatic sulfonate anion in which at least α-position of sulfonic acid is substituted with a fluorine atom, an aromatic sulfonate anion substituted with a fluorine atom or a group having a fluorine atom, a bis (alkylsulfonyl)imide anion in which the alkyl group is substituted with a fluorine atom, or a tris(alkylsulfonyl)methide anion in which the alkyl group is substituted with a fluorine atom is preferable. The non-nucleophilic anion is more preferably a perfluoroaliphatic sulfonate anion having 4 to 8 carbon atoms or a benzenesulfonate anion having a fluorine atom, and still more preferably a nonafluorobutanesulfonate anion, a perfluorooctanesulfonate anion, a pentafluorobenzenesulfonate anion, or a 3,5-bis(trifluoromethyl)benzenesulfonate anion.

The non-nucleophilic anion represented by Z⁻ is preferably an anion that generates an acid represented by the following formula (I).

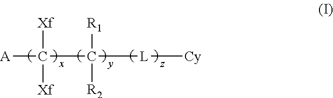

In the formula, each of Xf's independently represents a fluorine atom or an alkyl group substituted with at least one fluorine atom.

Each of R₁ and R₂ independently represents a hydrogen atom, a fluorine atom, or an alkyl group, and in a case where a plurality of R₁'s and R₂'s are present, R₁'s and R₂'s may be the same as or different from each other.

L represents a divalent connecting group, and in a case where a plurality of L's are present, L's may be the same as or different from each other.

Cy represents a cyclic organic group.

A represents HO₃S— or Rf—SO₂—NH—SO₂—. Rf represents an alkyl group having at least one fluorine atom, a cycloalkyl group having at least one fluorine atom, or an aryl group having at least one fluorine atom. (The substitution of the cycloalkyl group or the aryl group may be a substitution with not only a fluorine atom but also an alkyl fluoride such as —CF₃. Specific examples of the alkyl group having at least one fluorine atom represented by Rf are the same as the specific examples of Xf described below, specific examples of the cycloalkyl group having at least one fluorine atom represented by Rf include a perfluorocyclopentyl group and a perfluorocyclohexyl group, and specific examples of the aryl group having at least one fluorine atom represented by Rf include a perfluorophenyl group, and each of these groups may be substituted with a substituent not containing a fluorine atom.)

x represents an integer of 1 to 20, y represents an integer of 0 to 10, and z represents an integer of 0 to 10.

General Formula (I) will be described in more detail.

The alkyl group in the alkyl group substituted with a fluorine atom represented by Xf preferably has 1 to 10 carbon atoms, and more preferably 1 to 4 carbon atoms. In addition, the alkyl group substituted with a fluorine atom represented by Xf is preferably a perfluoroalkyl group.

Xf is preferably a fluorine atom or a perfluoroalkyl group having 1 to 4 carbon atoms. Specific examples of Xf include a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, a fluorine atom or CF₃ is preferable. In particular, both of Xfs are preferably fluorine atoms.

The alkyl group represented by R₁ or R₂ may have a substituent (preferably a fluorine atom), and the alkyl group is preferably an alkyl group having 1 to 4 carbon atoms, and more preferably a perfluoroalkyl group having 1 to 4 carbon atoms. Specific examples of the alkyl group having a substituent, represented by R₁ or R₂, include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, CF₃ is preferable.

Each of R₁ and R₂ is preferably a fluorine atom or CF₃.

y is preferably 0 to 4, and more preferably 0. x is preferably 1 to 8, and among these, x is preferably 1 to 4, and particularly preferably 1. z is preferably 0 to 8, and among these, z is preferably 0 to 4.

The divalent connecting group represented by L is not particularly limited, and examples thereof include —COO—, —OCO—, —CO—, —O—, —S—, —SO—, —SO₂—, an alkylene group, a cycloalkylene group, an alkenylene group, and a connecting group obtained by combining a plurality of these, and a connecting group having 12 or less total carbon atoms is preferable. Among these, —COO—, —OCO—, —CO—, —O—, or —SO₂— is preferable, —COO—, —OCO—, or —SO₂— is more preferable, and —SO₂— is particularly preferable.

The cyclic organic group represented by Cy is not particularly limited as long as it has a ring structure, and examples thereof include an alicyclic group, an aryl group, and a heterocyclic group (which includes not only a heterocyclic group having aromaticity but also a heterocyclic group having no aromaticity, and also includes, for example, a tetrahydropyran ring and a lactone ring structure).

The alicyclic group may be monocyclic or polycyclic, and as the alicyclic group, a monocyclic cycloalkyl group such as a cyclopentyl group, a cyclohexyl group, or a cyclooctyl group, or polycyclic cycloalkyl groups such as a norbornyl group, a tricyclodecanyl group, a tetracyclodecanyl group, a tetracyclododecanyl group, or an adamantyl group is preferable. Among these, an alicyclic group with a bulky structure having 7 or more carbon atoms such as a norbornyl group, a tricyclodecanyl group, a tetracyclodecanyl group, a tetracyclododecanyl group, or an adamantyl group is preferable from the viewpoint of being capable of suppressing in-film diffusibility in a PEB (post exposure bake) step and MEEF (mask error enhancement factor) improvement.

The aryl group may be monocyclic or polycyclic, and the examples thereof include a benzene ring, a naphthalene ring, a phenanthrene ring, and an anthracene ring. Among these, naphthalene having low absorbance is preferable from the viewpoint of light absorbance at 193 nm.

The heterocyclic group may be monocyclic or polycyclic, and the examples thereof include groups derived from a furan ring, a thiophene ring, a benzofuran ring, a benzothiophene ring, a dibenzofuran ring, a dibenzothiophene ring, a pyridine ring, and a decahydroisoquinoline ring. Among these, a group derived from a furan ring, a thiophene ring, a pyridine ring, or a decahydroisoquinoline ring is preferable.

The cyclic organic group may have a substituent, and examples of the substituent include an alkyl group (which may be linear, branched, or cyclic, and preferably has 1 to 12 carbon atoms), a cycloalkyl group (which may be a monocycle, a polycycle, or a spiro ring, and preferably has 3 to 20 carbon atoms), an aryl group (which preferably has 6 to 14 carbon atoms), a hydroxy group, an alkoxy group, an ester group, an amide group, a urethane group, a ureido group, a thioether group, a sulfonamide group, and a sulfonic acid ester group. Moreover, the carbon (carbon which contributes to formation of a ring) configuring the cyclic organic group may be a carbonyl carbon.

In a case where the anion that generates an acid represented by General Formula (I) has an acid-decomposable group, although any group of Xf, R₁, R₂, L, Cy, and Rf may be substituted with an acid-decomposable group, Cy or Rf is preferably substituted with an acid-decomposable group, and Cy is particularly preferably substituted with an acid-decomposable group.

In addition, as such an acid-decomposable group, a group that generates a phenolic hydroxyl group or a carboxyl group by being decomposed due to the action of an acid is preferable.

In a case where the anion that generates an acid represented by General Formula (I) has an acid-decomposable group, the acid-decomposable group may be bonded to the anion through a divalent connecting group, and an aspect in which Cy is substituted with the acid-decomposable group through a divalent connecting group is exemplified.

The divalent connecting group is not particularly limited, and examples thereof include —COO—, —OCO—, —CO—, —O—, —S—, —SO—, —SO₂—, an alkylene group, a cycloalkylene group, an alkenylene group, and a connecting group obtained by combining a plurality of these.

In a case where the anion that generates an acid represented by General Formula (I) has an acid-decomposable group, the compound (A) is preferably a compound represented by the following General Formula (II-4) or (II-5).

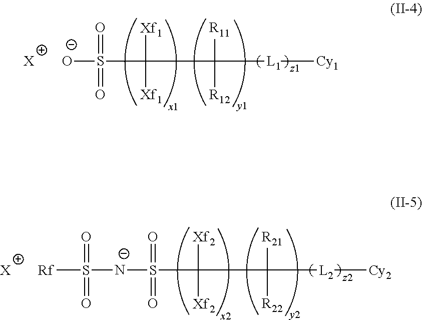

In the above general formulas, each of X's independently represent a counter cation.

Rf has the same meaning as Rf in A in General Formula (I).

Each of Xf₁ and Xf₂ independently has the same meaning as Xf in General Formula (I).

Each of R₁₁, R₁₂, R₂₁, and R₂₂ independently has the same meaning as R₁ and R₂ in General Formula (I).

Each of L₁ and L₂ independently has the same meaning as L in General Formula (I).

Each of Cy₁ and Cy₂ independently has the same meaning as Cy in General Formula (I).

Any of Xf₁, R₁₁, R₁₂, L₁, and Cy₁, may be substituted with a group (acid-decomposable group) having a structure in which a polar group is decomposed due to the action of an acid, which is protected with a leaving group leaving, and any of Xf₂, R₂₁, R₂₂, L₂, Cy₂, and Rf may be substituted with an acid-decomposable group.

Each of x₁ and x₂ independently has the same meaning as x in General Formula (I).

Each of y₁ and y₂ independently has the same meaning as y in General Formula (I).

Each of z₁ and z₂ independently has the same meaning as z in General Formula (I).

Examples of the counter cation of X⁺ include a sulfonium cation in General Formula (ZI) and an iodonium cation in General Formula (ZII).

Specific examples of the anion which has an acid-decomposable group and generates an acid represented by General Formula (I) will be described below, but the present invention is not limited thereto.

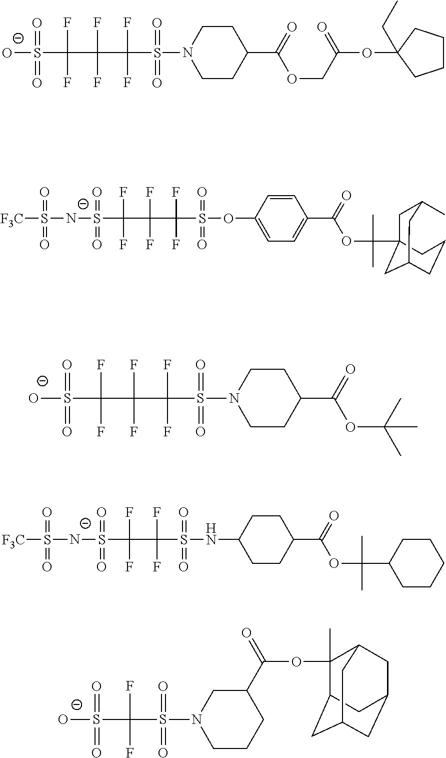

In a case where an acid-decomposable group is included in Z⁻ in General Formulas (ZI) to (ZIII), an aspect in which the acid generator [P-B] is compound represented by the following General Formula (III) is also preferable.

B—Y-A⁻X⁺ (III)

In the formula, A⁻ represents an organic acid anion.

Y represents a divalent connecting group.

X⁺ represents a counter cation.

B represents an acid-decomposable group.

Examples of the organic acid anion represented by A⁻ include a sulfonate anion, a carboxylate anion, and an imide anion, and a sulfonate anion or an imide anion is preferable, and sensitivity is improved.

The divalent connecting group represented by Y is preferably a divalent organic group having 1 to 8 carbon atoms, and examples thereof include an alkylene group and an arylene group (preferably a phenylene group). The divalent connecting group represented by Y is more preferably an alkylene group, and preferably has 1 to 6 carbon atoms, and more preferably has 1 to 4 carbon atoms. A connecting group including an oxygen atom, a nitrogen atom, or a sulfur atom may be included in the alkylene chain. The allkylene group may be substituted with a fluorine atom, and, in this case, the carbon bonded to A⁻ more preferably has the fluorine atom.

Examples of the counter cation of X⁺ include a sulfonium cation in General Formula (ZI) and an iodonium cation in General Formula (ZII).

B is preferably a group that generates a phenolic hydroxyl group or a carboxyl group by being decomposed due to the action of an acid.

Specific examples of the acid anion in General Formula (III) will be described below, but the present invention is not limited thereto.

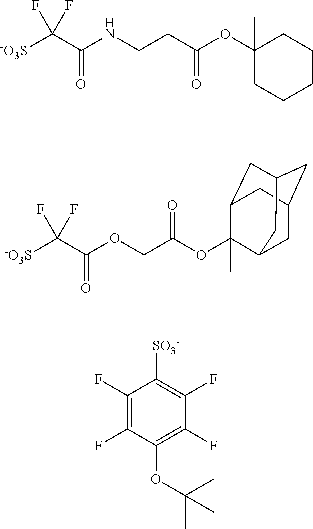

Examples of the organic group represented by each of R₂₀₁, R₂₀₂, and R₂₀₃ include groups corresponding to compounds (ZI-1), (ZI-2), (ZI-3), and (ZI-4) described below.

Moreover, it may be a compound having a plurality of structures represented by General Formula (ZI). For example, it may be a compound which has a structure where at least one of R₂₀₁ to R₂₀₃ of a compound represented by the General Formula (ZI) is bonded to at least one of R₂₀₁ to R₂₀₃ of another compound represented by General Formula (ZI) through a single bond or a connecting group.

Examples of the more preferable (ZI) component include the compounds (ZI-1), (ZI-2), (ZI-3), and (ZI-4) described below.

The compound (ZI-1) is an arylsulfonium compound in which at least one of R₂₀₁ to R₂₀₃ of General Formula (ZI) is an aryl group, that is, a compound having arylsulfonium as a cation.

In the arylsulfonium compound, all of R₂₀₁ to R₂₀₃ may be aryl groups, or a part of R₂₀₁ to R₂₀₃ may be (an) aryl group(s) and the remainder may be (an) alkyl group(s) or (a) cycloalkyl group(s).

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound.

The aryl group of an arylsulfonium compound is preferably a phenyl group or a naphthyl group, and more preferably a phenyl group. The aryl group may be an aryl group having a heterocyclic structure which contains an oxygen atom, a nitrogen atom, a sulfur atom, or the like. Examples of the heterocyclic structure include a pyrrole residue, a furan residue, a thiophene residue, an indole residue, a benzofuran residue, and benzothiophene residue. In a case where the arylsulfonium compound has two or more aryl groups, the two or more aryl groups may be the same as or different from each other.

An alkyl group or a cycloalkyl group which the arylsulfonium compound has, as necessary, is preferably a linear or branched alkyl group having 1 to 15 carbon atoms or a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, and a cyclohexyl group.

At least one of R₂₀₁, R₂₀₂, and R₂₀₃ preferably has an acid-decomposable group. The preferable aspect of the acid-decomposable group is as described above.

The aryl group, the alkyl group, and the cycloalkyl group represented by each of R₂₀₁ to R₂₀₃ may have an alkyl group (having 1 to 15 carbon atoms, for example), a cycloalkyl group (having 3 to 15 carbon atoms, for example), an aryl group (having 6 to 14 carbon atoms, for example), an alkoxy group (having 1 to 15 carbon atoms, for example), a halogen atom, a hydroxyl group, or a phenylthio group, in addition to the acid-decomposable group, as a substituent. The substituent is preferably a linear or branched alkyl group having 1 to 12 carbon atoms, a cycloalkyl group having 3 to 12 carbon atoms, or a linear, branched, or cyclic alkoxy group having 1 to 12 carbon atoms, and more preferably an alkyl group having 1 to 4 carbon atoms or an alkoxy group having 1 to 4 carbon atoms. The substituent may be substituted on any one of the three R₂₀₁ to R₂₀₃, or may be substituted on all of the three R₂₀₁ to R₂₀₃. In addition, in a case where R₂₀₁ to R₂₀₃ are aryl groups, the substituent is preferably substituted at the p-position by the aryl group.

Next, the compound (ZI-2) will be described.

The compound (ZI-2) is a compound in which each of R₂₀₁ to R₂₀₃ in Formula (ZI) independently represents an organic group not having an aromatic ring. The aromatic ring herein also includes an aromatic ring containing a hetero atom.

The organic group not containing an aromatic ring represented by each of R₂₀₁ to R₂₀₃ generally has 1 to 30 carbon atoms, and preferably has 1 to 20 carbon atoms.

Each of R₂₀₁ to R₂₀₃ independently preferably represents an alkyl group, a cycloalkyl group, an allyl group, or a vinyl group, more preferably a linear or branched 2-oxoalkyl group, a 2-oxocycloalkyl group, or an alkoxycarbonylmethyl group, and particularly preferably a linear or branched 2-oxoalkyl group.

Preferable examples of the alkyl group and the cycloalkyl group represented by each of R₂₀₁ to R₂₀₃ include a linear or branched alkyl group having 1 to 10 carbon atoms (for example, a methyl group, an ethyl group, a propyl group, a butyl group, or a pentyl group) and a cycloalkyl group having 3 to 10 carbon atoms (a cyclopentyl group, a cyclohexyl group, or a norbornyl group). More preferable examples of the alkyl group include a 2-oxoalkyl group and an alkoxycarbonylmethyl group. More preferable examples of the cycloalkyl group include a 2-oxocycloalkyl group.

The 2-oxoalkyl group may be linear or branched, and preferable examples thereof include a group having >C═O at the 2-position of the alkyl group described above.

Preferable examples of the 2-oxocycloalkyl group include a group having >C═O at the 2-position of the cycloalkyl group described above.

Preferable examples of the alkoxy group in the alkoxycarbonylmethyl group include an alkoxy group having 1 to 5 carbon atoms (a methoxy group, an ethoxy group, a propoxy group, a butoxy group, or a pentoxy group).

At least one of R₂₀₁, R₂₀₂, and R₂₀₃ preferably has an acid-decomposable group. The preferable aspect of the acid-decomposable group is as described above.

Each of R₂₀₁ to R₂₀₃ may be further substituted with a halogen atom, an alkoxy group (which has 1 to 5 carbon atoms, for example), a hydroxyl group, a cyano group, or a nitro group, other than the acid-decomposable group.

Next, the compound (ZI-3) will be described.

The compound (ZI-3) is a compound which is represented by the following General Formula (ZI-3) and has a phenacylsulfonium salt structure.

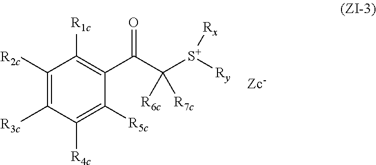

In General Formula (ZI-3), each of R_{1c} to R_{5c} independently represents a hydrogen atom, an alkyl group, a cycloalkyl group, an aryl group, an alkoxy group, an aryloxy group, an alkoxycarbonyl group, an alkylcarbonyl group, a cycloalkylcarbonyloxy group, a halogen atom, a hydroxyl group, a nitro group, an alkylthio group, or an arylthio group.

Each of R_{6c} and R_{7c} independently represents a hydrogen atom, an alkyl group, a cycloalkyl group, a halogen atom, a cyano group, or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group, or a vinyl group.

Any two or more of R_{1c} to R_{5c}, R_{5c} and R_{6c}, R_{6c} and R_{7c}, R_{5c} and Rₓ, and Rₓ and R_{y} may be bonded to each other to form a ring structure, respectively, and the ring structure may include an oxygen atom, a sulfur atom, a ketone group, an ester bond, or an amide bond.

Examples of the ring structure include an aromatic or non-aromatic hydrocarbon ring, an aromatic or non-aromatic heterocycle, or a polycyclic condensed ring formed by combination of two or more of these rings. Examples of the ring structure include 3- to 10-membered rings, and among these, 4- to 8-membered rings are preferable, and 5- or 6-membered rings are more preferable.

Examples of the group that any two or more of R_{1c} to R_{5c}, R_{6c} and R_{7c}, and Rₓ and R_{y} respectively form by bonding to each other, include a butylene group and a pentylene group.

As the group that R_{5c} and R_{6c}, and R_{5c} and Rₓ respectively form by bonding to each other, a single bond or an alkylene group is preferable, and examples of the alkylene group include a methylene group and an ethylene group.

Zc⁻ represents a non-nucleophilic anion, and as Zc⁻, the same as the non-nucleophilic anion represented by Z⁻ in General Formula (ZI) can be exemplified.

The alkyl group represented by each of R_{1c} to R_{7c} may be linear or branched, and, for example, is an alkyl group having 1 to 20 carbon atoms, and preferable examples thereof include a linear or branched alkyl group having 1 to 12 carbon atoms (for example, a methyl group, an ethyl group, a linear or branched propyl group, a linear or branched butyl group, or a linear or branched pentyl group), and examples of the cycloalkyl group represented by each of R_{1c} to R_{7c} include a cycloalkyl group having 3 to 10 carbon atoms (for example, a cyclopentyl group or a cyclohexyl group).

The aryl group represented by each of R_{1c} to R_{5c} is preferably has 5 to 15 carbon atoms, and examples thereof include a phenyl group and a naphthyl group.

The alkoxy group represented by each of R_{1c} to R_{5c} may be linear, branched, or cyclic, and, for example, is an alkoxy group having 1 to 10 carbon atoms, and preferable examples thereof include a linear or branched alkoxy group having 1 to 5 carbon atoms (for example, a methoxy group, an ethoxy group, a linear or branched propoxy group, a linear or branched butoxy group, or a linear or branched pentoxy group) and a cyclic alkoxy group having 3 to 10 carbon atoms (for example, a cyclopentyloxy group or a cyclohexyloxy group).

Specific examples of the alkoxy group in the alkoxycarbonyl group represented by each of R_{1c} to R_{5c} are the same as the specific examples of the alkoxy group represented by each of R_{1c} to R_{5c} described above.

Specific examples of the alkyl group in the alkylcarbonyloxy group and the alkylthio group represented by each of R_{1c} to R_{5c} are the same as the specific examples of the alkyl group represented by each of R_{1c} to R_{5c} described above.

Specific examples of the cycloalkyl group in the cycloalkylcarbonyloxy group represented by each of R_{1c} to R_{5c} are the same as the specific examples of the cycloalkyl group represented by each of R_{1c} to R_{5c} described above.

Specific examples of the aryl group in the aryloxy group and the arylthio group represented by each of R_{1c} to R_{5c} are the same as the specific examples of the aryl group represented by each of R_{1c} to R_{5c} described above.

Any of R_{1c} to R_{5c} is preferably a linear or branched alkyl group, a cycloalkyl group, or a linear, branched, cyclic alkoxy group, and the total number of carbon atoms of R_{1c} to R_{5c} is more preferably 2 to 15. Thus, solvent solubility is more improved and generation of particles during storage can be suppressed.

A ring structure which may be formed by bonding of any two or more of R_{1c} to R_{5c} to each other is preferably a 5- or 6-membered ring, and particularly preferably a 6-membered ring (for example, a phenyl ring).

A ring structure which may be formed by bonding of R_{5c} and R_{6c} to each other is preferably a 4- or more membered ring (particularly preferably a 5- or 6-membered ring) which is formed by configuring a single bond or an alkylene group (a methylene group or an ethylene group) by bonding of R_{5c} and R_{6c} to each other together with a carbonyl carbon atom and carbon atom in General Formula (I).

The aryl group represented by each of R_{6c} to R_{7c} is preferably has 5 to 15 carbon atoms, and examples thereof include a phenyl group and a naphthyl group.

As the aspect of R_{6c} and R_{7c}, a case where both are alkyl groups is preferable. In particular, a case where each of R_{6c} and R_{7c} is a linear or branched alkyl group having 1 to 4 carbon atoms is preferable, and a case where both are methyl groups is particularly preferable.

In a case where R_{6c} and R_{7c} are bonded to each other to form a ring, the group that R_{6c} and R_{7c} form by bonding to each other is preferably an alkylene group having 2 to 10 carbon atoms, and examples thereof include an ethylene group, a propylene group, a butylene group, a pentylene group, and a hexylene group. In addition, a ring formed by bonding of R_{6c} and R_{7c} to each other may have a heteroatom such as an oxygen atom in the ring.

Examples of the alkyl group and the cycloalkyl group represented by Rₓ or R_{y} include the same alkyl group and cycloalkyl group as those represented by R_{1c} to R_{7c}.

Examples of the 2-oxoalkyl group and the 2-oxocycloalkyl group represented by Rₓ or R_{y} include a group having >C═O at the 2-position of the alkyl group or the cycloalkyl group represented by R_{1c} or R_{7c}.

Examples of the alkoxy group in the alkoxycarbonylalkyl group represented by Rₓ or R_{y} include the same alkoxy group as that represented by each of R_{1c} to R_{5c}, and as the alkyl group, an alkyl group having 1 to 12 carbon atoms is exemplified, and a linear alkyl group having 1 to 5 carbon atoms (for examples, a methyl group or an ethyl group) is preferably exemplified.

The allyl group represented by Rₓ or R_{y} is not particularly limited, but an unsubstituted allyl group or an allyl group substituted with a monocyclic or polycyclic cycloalkyl group (preferably a cycloalkyl group having 3 to 10 carbon atoms) is preferable.

The vinyl group represented by Rₓ or R_{y} is not particularly limited, but an unsubstituted vinyl group or a vinyl group substituted with a monocyclic or polycyclic cycloalkyl group (preferably a cycloalkyl group having 3 to 10 carbon atoms) is preferable.

As a ring structure which may be formed by bonding of R_{5c} and Rₓ to each other, a 5- or more membered ring (particularly preferably a 5-membered ring) which is formed by configuring a single bond or an alkylene group (a methylene group or an ethylene group) by bonding of R_{5c} and Rₓ to each other together with a sulfur atom and a carbonyl carbon atom in General Formula (I) is exemplified.

As a ring structure which may be formed by bonding of Rₓ and R_{y} to each other, a 5- or 6-membered ring which divalent Rₓ and R_{y} (for example, a methylene group, an ethylene group, or a propylene group) form together with a sulfur atom in General Formula (ZI-3) is exemplified, and a 5-membered ring (that is, a tetrahydrothiophene ring) is particularly preferably exemplified.

Each of Rₓ and R_{y} is preferably an alkyl group or a cycloalkyl group having 4 or more carbon atoms, more preferably an alkyl group or a cycloalkyl group having 6 or more carbon atoms, and still more preferably an alkyl group or a cycloalkyl group having 8 or more carbon atoms.

At least one of R_{1c} to R_{7c}, Rₓ, and R_{y} preferably has an acid-decomposable group. The preferable aspect of the acid-decomposable group is as described above.

Each of R_{1c} to R_{7c}, Rₓ, and R_{y} may further have a substituent other than the acid-decomposable group, and examples of such a substituent include a halogen atom (for example, a fluorine atom), a hydroxyl group, an carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, and an aryloxycarbonyl group.

Examples of the alkyl group include a linear or branched alkyl group having 1 to 12 carbon atoms such as a methyl group, an ethyl group, an n-propyl group, an i-propyl group, an n-butyl group, a 2-methylpropyl group, a 1-methylpropyl group, or a t-butyl group.

Examples of the cycloalkyl group include a cycloalkyl group having 3 to 10 carbon atoms such as a cyclopentyl group or a cyclohexyl group.

Examples of the aryl group include an aryl group having 6 to 15 carbon atoms such as a phenyl group or a naphthyl group.

Examples of the alkoxy group include a linear, branched, or cyclic alkoxy group having 1 to 20 carbon atoms such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, or a cyclohexyloxy group.

Examples of the aryloxy group include an aryloxy group having 6 to 10 carbon atoms such as a phenyloxy group or a naphthyloxy group.

Examples of the acyl group include a linear or branched acyl group having 2 to 12 carbon atoms such as an acetyl group, a propionyl group, an n-butanoyl group, an i-butanoyl group, an n-heptanoyl group, a 2-methylbutanoyl group, a 1-methylbutanoyl group, or a t-heptanoyl group.

Examples of the arylcarbonyl group include an aryloxy group having 6 to 10 carbon atoms such as a phenylcarbonyl group or a naphthylcarbonyl group.

Examples of the alkoxyalkyl group include a linear, branched, or cyclic alkoxyalkyl group having 2 to 21 carbon atoms such as a methoxymethyl group, an ethoxymethyl group, a 1-methoxyethyl group, a 2-methoxyethyl group, a 1-ethoxyethyl group, or a 2-ethoxyethyl group.

Examples of the aryloxyalkyl group include an aryloxy group having 7 to 12 carbon atoms such as a phenyloxymethyl group, a phenyloxyethyl group, a naphthyloxymethyl group, or a naphthyloxyethyl group.

Examples of the alkoxycarbonyl group include a linear, branched, or cyclic alkoxycarbonyl group having 2 to 21 carbon atoms such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group, or a cyclohexyloxycarbonyl group.

Examples of the aryloxycarbonyl group include an aryloxycarbonyl group having 7 to 11 carbon atoms such as a phenyloxycarbonyl group or a naphthyloxycarbonyl group.

Examples of the alkoxycarbonyloxy group include a linear, branched, or cyclic alkoxycarbonyloxy group having 2 to 21 carbon atoms such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group, or a cyclohexyloxycarbonyloxy group.

Examples of the aryloxycarbonyloxy group include an aryloxycarbonyloxy group having 7 to 11 carbon atoms such as a phenyloxycarbonyloxy group or a naphthyloxycarbonyloxy group.

In General Formula (ZI-3), each of R_{1c}, R_{2c}, R_{4c}, and R_{5c} independently represents a hydrogen atom, and R_{3c} more preferably represents a group other than a hydrogen atom, that is, an alkyl group, a cycloalkyl group, an aryl group, an alkoxy group, an aryloxy group, an alkoxycarbonyl group, an alkylcarbonyl group, a cycloalkylcarbonyloxy group, a halogen atom, a hydroxyl group, a nitro group, an alkylthio group, or an arylthio group.

Next, the compound (ZI-4) will be described.

The compound (ZI-4) is represented by the following General Formula (ZI-4).

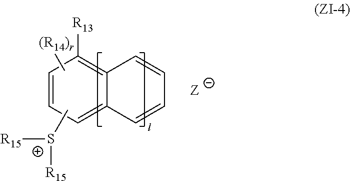

In General Formula (ZI-4), R₁₃ represents a hydrogen atom, a fluorine atom, a hydroxyl group, an alkyl group, a cycloalkyl group, an alkoxy group, an alkoxycarbonyl group, or cycloalkyl group. These groups may have a substituent.

In a case where a plurality of R₁₄'s are present, each of R₁₄'s independently represents a group having a hydroxyl group, an alkyl group, a cycloalkyl group, an alkoxy group, an alkoxycarbonyl group, an alkylcarbonyl group, an alkylsulfonyl group, a cycloalkylsulfonyl group, or a cycloalkyl group. These groups may have a substituent.

Each of R₁₅'s independently represents an alkyl group, a cycloalkyl group, or a naphthyl group. Two R₁₅'s may be bonded to each other to form a ring. These groups may have a substituent.

l is an integer of 0 to 2.

r is an integer of 0 to 8.

Z⁻ represents a non-nucleophilic anion, and as Z⁻, the same non-nucleophilic anions as those represented by Z⁻ in General Formula (ZI) can be exemplified.

In the General Formula (ZI-4), the alkyl group represented by R₁₃, R₁₄, or R₁₅ is linear or branched, and is preferably an alkyl group having 1 to 10 carbon atoms, and examples thereof include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, and an n-decyl group. Among these alkyl groups, a methyl group, an ethyl group, an n-butyl group, or a t-butyl group is preferable.

Examples of the cycloalkyl group represented by R₁₃, R₁₄, or R₁₅ include a monocyclic or polycyclic cycloalkyl group (preferably a cycloalkyl group having 3 to 20 carbon atoms), and examples thereof include a cyclopropyl group, a cyclobutyl group, a cyclopentyl group, a cyclohexyl group, a cycloheptyl group, a cyclooctyl group, a cyclododecanyl group, a cyclopentenyl group, a cyclohexenyl group, a cyclooctadienyl group, a norbornyl group, a tricyclodecanyl group, a tetracyclodecanyl group, and an adamantyl group, and a cyclopropyl group, a cyclopentyl group, a cyclohexyl group, a cycloheptyl group, or a cyclooctyl group is particularly preferable.

The alkoxy group represented by R₁₃ or R₁₄ is linear or branched, and is preferably an alkoxy group having 1 to 10 carbon atoms, and examples thereof include a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, and an n-decyloxy group. Among these alkoxy groups, a methoxy group, an ethoxy group, an n-propoxy group, or an n-butoxy group is preferable.

The alkoxycarbonyl group represented by R₁₃ or R₁₄ is linear or branched, and is preferably an alkoxycarbonyl group having 2 to 11 carbon atoms, and examples thereof include a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, and an n-decyloxycarbonyl group. Among these alkoxycarbonyl groups, a methoxycarbonyl group, an ethoxycarbonyl group, or an n-butoxycarbonyl group is preferable.

Examples of a group having the cycloalkyl group represented by R₁₃ or R₁₄ include a monocyclic or polycyclic cycloalkyl group (preferably a cycloalkyl group having 3 to 20 carbon atoms), and examples thereof include a monocyclic or polycyclic cycloalkyloxy group and an alkoxy group having a monocyclic or polycyclic cycloalkyl group. These groups may further have a substituent.

The monocyclic or polycyclic cycloalkyloxy group represented by R₁₃ or R₁₄ is preferably a monocyclic or polycyclic cycloalkyloxy group having 7 or more total carbon atoms, more preferably a monocyclic or polycyclic cycloalkyloxy group having 7 to 15 total carbon atoms, and preferably has a monocyclic cycloalkyl group. The monocyclic cycloalkyloxy group having 7 or more total carbon atoms is a monocyclic cycloalkyloxy group which has arbitrarily a substituent such as an alkyl group such as a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a t-butyl group, or an iso-amyl group, a hydroxyl group, a halogen atom (fluorine, chlorine, bromine, or iodine), a nitro group, a cyano group, an amide group, a sulfonamide group, an alkoxy group such as a methoxy group, an ethoxy group, a hydroxyethoxy group, a propoxy group, a hydroxypropoxy group, or a butoxy group, an alkoxycarbonyl group such as a methoxycarbonyl group or an ethoxycarbonyl group, an acyl group such as a formyl group, an acetyl group, or a benzoyl group, an acyloxy group such as an acetoxy group or a butyryloxy group, or a carboxy group, on a cycloalkyloxy group such as a cyclopropyloxy group, a cyclobutyloxy group, a cyclopentyloxy group, a cyclohexyloxy group, a cycloheptyloxy group, a cyclooctyloxy group, or a cyclododecanyloxy group, and represents that the number of total carbon atoms combined with the arbitrary substituent on the cycloalkyl group is 7 or more.

In addition, examples of the polycyclic cycloalkyloxy group having 7 or more total carbon atoms include a norbornyloxy group, a tricyclodecanyloxy group, a tetracyclodecanyloxy group, and an adamantyloxy group.

The alkoxy group having the monocyclic or polycyclic cycloalkyloxy group represented by R₁₃ or R₁₄ preferably has 7 or more total carbon atoms, more preferably has 7 to 15 total carbon atoms, and is preferably an alkoxy group having a monocyclic cycloalkyl group. The alkoxy group having the monocyclic cycloalkyl group having 7 or more total carbon atoms is an alkoxy group obtained by substituting an alkoxy group such as a methoxy group, an ethoxy group, a propoxy group, a butoxy group, a pentyloxy group, a hexyloxy group, an heptoxy group, an octyloxy group, a dodecyloxy group, a 2-ethylhexyloxy group, an isopropoxy group, a sec-butoxy group, a t-butoxy group, or an iso-amyloxy group with a monocyclic cycloalkyloxy group which may have a substituent described above, and represents that the number of total carbon atoms also including carbon atoms of the substituent is 7 or more. For example, a cyclohexylmethoxy group, a cyclopentylethoxy group, and a cyclohexylethoxy group are exemplified, and a cyclohexylmethoxy group is preferable.

In addition, examples of the alkoxy group having the polycyclic cycloalkyl group having 7 or more total carbon atoms include a norbornylmethoxy group, a norbornylethoxy group, a tricyclodecanyl methoxy group, a tricyclodecanylethoxy group, a tetracyclodecanylmethoxy group, a tetracyclodecanyl ethoxy group, an adamantylmethoxy group, and an adamantylethoxy group, and a norbornylmethoxy group or a norbornylethoxy group is preferable.

Examples of the alkyl group of the alkylcarbonyl group represented by R₁₄ include the same as the specific examples of the alkyl group represented by each of R₁₃ to R₁₅ described above.

Each of the alkylsulfonyl group and the cycloalkylsulfonyl group represented by R₁₄ is linear, branched, or cyclic, and preferably has 1 to 10 carbon atoms, and examples thereof include a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, and a cyclohexanesulfonyl group. Among these alkylsulfonyl groups and the cycloalkylsulfonyl groups, a methanesulfonyl group, an ethanesulfonyl group, an n-propanesulfonyl group, an n-butanesulfonyl group, a cyclopentanesulfonyl group, or a cyclohexanesulfonyl group is preferable.

Examples of the substituent which each group described above may has include a halogen atom (for example, a fluorine atom), a hydroxy group, a carboxyl group, a cyano group, a nitro group, an alkoxy group, an alkoxyalkyl group, an alkoxycarbonyl group, and an alkoxycarbonyloxy group.

Examples of the alkoxy group include a linear, branched, or cyclic alkoxy group having 1 to 20 carbon atoms such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, or a cyclohexyloxy group.

Examples of the alkoxyalkyl group include a linear, branched, or cyclic alkoxyalkyl group having 2 to 21 carbon atoms such as a methoxymethyl group, an ethoxymethyl group, a 1-methoxyethyl group, a 2-methoxyethyl group, a 1-ethoxyethyl group, or a 2-ethoxyethyl group.

Examples of the alkoxycarbonyl group include a linear, branched, or cyclic alkoxycarbonyl group having 2 to 21 carbon atoms such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group, or a cyclohexyloxycarbonyl group.

Examples of the alkoxycarbonyloxy group include a linear, branched, or cyclic alkoxycarbonyloxy group having 2 to 21 carbon atoms such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group, or a cyclohexyloxycarbonyloxy group.

As a ring structure which may be formed by bonding of two R₁₅'s to each other, a 5- or 6-membered ring which two divalent R₁₅'s form together with a sulfur atom in General Formula (ZI-4) is exemplified, and a 5-membered ring (that is, a tetrahydrothiophene ring) is particularly preferably exemplified, and the rings may be condensed with an aryl group or a cycloalkyl group. The divalent R₁₅ may have a substituent, and examples of the substituent include a hydroxy group, a carboxy group, a cyano group, a nitro group, an alkyl group, a cycloalkyl group, an alkoxy group, an alkoxyalkyl group, an alkoxycarbonyl group, and an alkoxycarbonyloxy group. With regard to the ring structure described above, a plurality of the substituents may be present, and these substituents may be bonded to each other to form a ring (an aromatic or non-aromatic hydrocarbon ring, an aromatic or non-aromatic heterocycle, or a polycyclic condensed ring obtained by combining two or more of these rings).

As R₁₅ in General Formula (ZI-4), a methyl group, an ethyl group, a naphthyl group, and a divalent group in which two R₁₅'s are bonded to each other to form a tetrahydrothiophene ring structure together with a sulfur atom are preferable.

At least one of R₁₃, R₁₄, and R₁₅ preferably has an acid-decomposable group. The preferable aspect of the acid-decomposable group is as described above.

As the substituent which each of R₁₃, R₁₄, and R₁₅ can have other than the acid-decomposable group, a hydroxyl group, an alkoxy group, an alkoxycarbonyl group, or a halogen atom (particularly, a fluorine atom) is preferable.

I is preferably 0 or 1, and more preferably 1.

r is preferably any one of 0 to 2.

Next, General Formulas (ZII) and (ZIII) will be described.

In General Formulas (ZII) and (ZIII), each of R₂₀₄ to R₂₀₇ independently represents an aryl group, an alkyl group, or a cycloalkyl group.

At least one of R₂₀₄, R₂₀₅, and Z⁻ has an acid-decomposable group.

At least one of R₂₀₆ and R₂₀₇ has an acid-decomposable group. The preferable aspect of the acid-decomposable group is as described above.

The aryl group represented by each of R₂₀₄ to R₂₀₇ is preferably a phenyl group or a naphthyl group, and more preferably a phenyl group. The aryl group represented by each of R₂₀₄ to R₂₀₇ may be an aryl group having a heterocyclic structure which includes an oxygen atom, a nitrogen atom, or a sulfur atom. Examples of the skeleton of the aryl group having a heterocyclic structure include pyrrole, furan, thiophene, indole, benzofuran, and benzothiophene.

Preferable examples of the alkyl group and the cycloalkyl group represented by each Of R₂₀₄ to R₂₀₇ include a linear or branched alkyl group having 1 to 10 carbon atoms (for example, a methyl group, an ethyl group, a propyl group, a butyl group, or a pentyl group) and a cycloalkyl group having 3 to 10 carbon atoms (a cyclopentyl group, a cyclohexyl group, or a norbornyl group).

The aryl group, the alkyl group, and the cycloalkyl group represented by each of R₂₀₄ to R₂₀₇ may have a substituent other than the acid-decomposable group. Examples of the substituent which each of the aryl group, the alkyl group, and the cycloalkyl group represented by each of R₂₀₄ to R₂₀₇ may have other than the acid-decomposable group include an alkyl group (having 1 to 15 carbon atoms, for example), a cycloalkyl group (having 3 to 15 carbon atoms, for example), an aryl group (having 6 to 15 carbon atoms, for example), an alkoxy group (having 1 to 15 carbon atoms, for example), a halogen atom, a hydroxyl group, or a phenylthio group.

Z⁻ represents a non-nucleophilic anion, and as Z⁻, the same as the non-nucleophilic anion represented by Z⁻ in General Formula (ZI) can be exemplified.

As the acid generator, the compounds represented by the following General Formula (ZIV), (ZV), or (ZVI) are also exemplified.

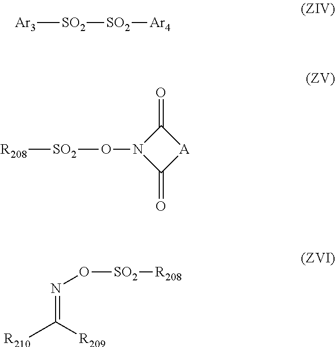

In General Formulas (ZIV) to (ZVI), each of Ar₃ and Ar₄ independently represents an aryl group.

At least one of Ar₃ and Ar₄ has an acid-decomposable group.

In General Formula (ZV), R₂₀₈ represents an alkyl group, a cycloalkyl group, or an aryl group.

A represents an alkylene group, an alkenylene group, or an arylene group.

At least one of R₂₀₈ and A has an acid-decomposable group.

In General Formula (ZVI), each of R₂₀₈, R₂₀₉, and R₂₁₀ independently represents an alkyl group, a cycloalkyl group, or an aryl group.

At least one of R₂₀₈, R₂₀₉, and R₂₁₀ has an acid-decomposable group.

Specific examples of the aryl group represented by Ar₃, Ar₄, R₂₀₈, R₂₀₉, or R₂₁₀ include the same as the specific examples of the aryl group represented by R₂₀₁, R_{202′}, or R₂₀₃ in General Formula (ZI-1).

Specific examples of the alkyl group and the cycloalkyl group represented by R₂₀₈, R₂₀₉, and R₂₁₀ respectively include the same as the specific examples of the alkyl group and the cycloalkyl group represented by R₂₀₁, R₂₀₂, and R₂₀₃ in General Formula (ZI-2).

Examples of the alkylene group represented by A include an alkylene group having 1 to 12 carbon atoms (for example, a methylene group, an ethylene group, a propylene group, an isopropylene group, a butylene group, or an isobutylene group), examples of the alkenylene group represented by A include an alkenylene group having 2 to 12 carbon atoms (for example, an ethenylene group, a propenylene group, or a butenylene group), and examples of the arylene group represented by A include an arylene group having 6 to 10 carbon atoms (for example, a phenylene group, a tolylene group, or a naphthylene group).

In a case where an acid-decomposable group is included in R₂₀₁, R₂₀₂, or R₂₀₃ in General Formula (ZI), the acid generator [P-B] is preferably a compound represented by any one of the following General Formulas (II-1) to (II-3).

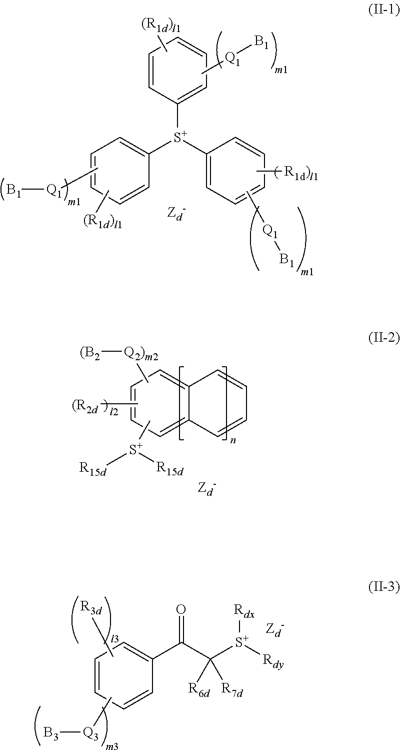

In General Formula (II-1), each of R_{1d}'s independently represents a hydrogen atom or a monovalent organic group. Two R_{1d}'s may be bonded to each other to form a ring. In other words, two R_{1d}'s may be bonded to each other to form a single bond or a divalent connecting group. The divalent connecting group is preferably a connecting group having 4 or less carbon atoms, and examples thereof include a methylene group, an ethylene group, an ether bond, a carbonyl group, and an ester group.

Q₁ represents a single bond or a divalent connecting group.

B₁ represents a group that generates a phenolic hydroxyl group or a carboxyl group by being decomposed due to the action of an acid.

Zd⁻ represents a non-nucleophilic counter anion having a group represented by X (B₁-Q₁)'s.

Each of l1's independently represents an integer of 0 to 5.

Each of m1's independently represents an integer of 0 to 5.

X represents an integer of 0 to 3.

Here, at least one of a plurality of m1's and X represents an integer of 1 or greater. Any one of a plurality of m1's is an integer of 1 or greater.

In General Formula (II-2), each of R_{2d}'s independently represents a hydrogen atom or a monovalent organic group. Two R_{2d}'s may be bonded to each other to form a ring.

Each of R_{15d}'s independently represents an alkyl group which may have a substituent. Two R_{15d}'s may be bonded to each other to form a ring. Two R_{15d}'s may be bonded to each other to form a ring.

Each of a group represented by —S⁺(R_{15d})(R_{15d}), m (B-Q)'s, and I R₄'s may be substituted at any position of any aromatic ring in General Formula (II-2).

Q₂ represents a single bond or a divalent connecting group.

B₂ represents a group that generates a phenolic hydroxyl group or a carboxyl group by being decomposed due to the action of an acid.

Zd⁻ represents a non-nucleophilic counter anion having a group represented by X (B₂-Q₂)'s.

n represents 0 or 1.

Each of I2's independently represents an integer of 0 to 5.

Each of m2's independently represents an integer of 0 to 5.

X represents an integer of 0 to 3.

Here, at least one of m2 and X represents an integer of 1 or greater. m2 is preferably an integer of 1 to 5.

In General Formula (II-3), each of R_{3d}'s independently represents a hydrogen atom or a monovalent organic group. Two R_{3d}'s may be bonded to each other to form a ring.

Each of R_{6d} and R_{7d} independently represents a hydrogen atom or a monovalent organic group. R_{6d} and R_{7d} may be bonded to each other to form a ring.

Each of R_{dx} and R_{dy} independently represents an alkyl group which may have a substituent. R_{dx} and R_{dy} may be bonded to each other to form a ring.

Q₃ represents a single bond or a divalent connecting group.

B₃ represents a group that generates a phenolic hydroxyl group or a carboxyl group by being decomposed due to the action of an acid.

Zd⁻ represents a non-nucleophilic counter anion having a group represented by X (B₃-Q₃)'S.

Each of l3's independently represents an integer of 0 to 5.

Each of m3's independently represents an integer of 0 to 5.

X represents an integer of 0 to 3.

Here, at least one of m3 and X represents an integer of 1 or greater. m3 is preferably an integer of 1 to 5.

The organic group represented by R_{1d}, R_{2d}, or R_{3d} is preferably an alkyl group, a cycloalkyl group, an alkoxy group, or a halogen atom. Two or more R₄'s may be bonded to each other to form a ring structure, and the ring structure may include an oxygen atom, a sulfur atom, an ester bond, or an amide bond. Examples of the group that two or more of R₄'s form by bonding to each other include a butylene group and a pentylene group.

Examples of the alkyl group, the cycloalkyl group, or the alkoxy group represented by R_{1d}, R_{2d}, or R_{3d} include an alkyl group, an cycloalkyl group, and an alkoxy group as the same as R_{1C} to R_{5C} in General Formula (ZI-3).

The alkyl group represented by R_{15d}, R_{dx}, or R_{dy} is linear or branched, and is preferably an alkyl group having 1 to 10 carbon atoms, and examples thereof include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, and an n-decyl group. Among these alkyl groups, a methyl group, an ethyl group, an n-butyl group, or a t-butyl group is preferable. A methyl group, an ethyl group, an n-propyl group, an n-butyl group, or a divalent group in which two R_{15d}'s are bonded to each other (or R_{dx} and R_{dy} are bonded to each other) to form a tetrahydrothiophene ring structure together with a sulfur atom is more preferable.

Examples of the organic group represented by R_{6d} or R_{7d} include an alkyl group and a cycloalkyl group. R_{6d} and R_{7d} may be bonded to each other to form a ring structure, and the ring structure may include an oxygen atom, a sulfur atom, an ester bond, or an amide bond. Examples of the group that R_{6d} and R_{7d} form by bonding to each other include a butylene group and a pentylene group.

Examples of the alkyl group or the cycloalkyl group represented by R_{6d} or R_{7d} include an alkyl group and a cycloalkyl group as the same as R_{6C} to R_{7C} in General Formula (ZI-3), and a 2-oxoalkyl group, a 2-oxocycloalkyl group, or an alkoxycarbonylmethyl group is preferable.

Examples of the 2-oxoalkyl group and the 2-oxocycloalkyl group include a group having >C═O at the 2-position of the alkyl group or the cycloalkyl group represented by R_{1c} or R_{7c}.

Examples of the alkoxy group in the alkoxycarbonylmethyl group include an alkoxy group as the same as R_{1c} to R_{5c}.

Each of R_{6d} and R_{7d} is preferably a hydrogen atom, an alkyl group or a cycloalkyl group having 4 or more carbon atoms, more preferably an alkyl group or a cycloalkyl group having 6 or more carbon atoms, and still more preferably an alkyl group or a cycloalkyl group having 8 or more carbon atoms.

The divalent connecting group represented by each of Q₁, Q₂, and Q₃ is preferably a divalent organic group having 1 to 8 carbon atoms, and examples thereof include an alkylene group (for example, a methylene group, an ethylene group, a propylene group, or a butylene group) and an arylene group (for example, a phenylene group). The divalent connecting group represented by each of Q₁, Q₂, and Q₃ is more preferably an alkylene group, and preferably has 1 to 6 carbon atoms, and more preferably has 1 to 4 carbon atoms. A connecting group such as an oxygen atom or a sulfur atom may be included in the alkylene chain.

Zd⁻ represents a non-nucleophilic counter anion, and as Zd⁻, a non-nucleophilic anion as the same as Z⁻ in General Formula (ZI) can be exemplified, and may be the acid anion in General Formula (III).

Specific examples of the cation in the acid generator [P-B] will be described below, but the present invention is not limited thereto.

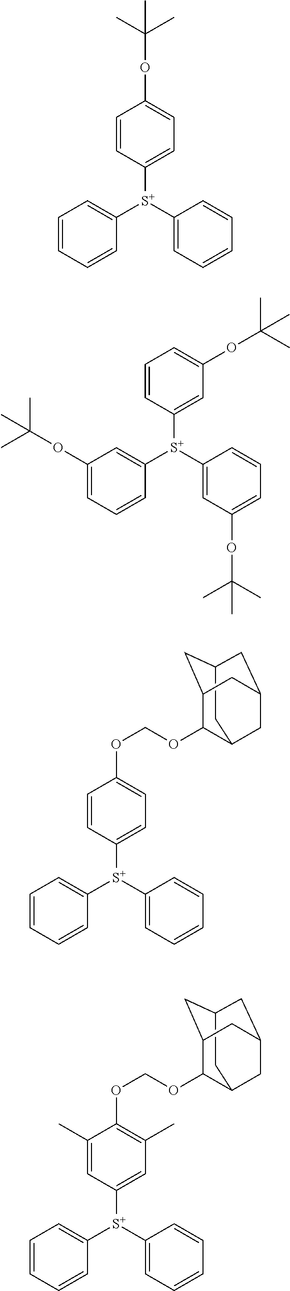 [SMILES: CC(C)(C)Oc1ccc([S+](c2ccccc2)c2ccccc2)cc1 ; CC(C)(C)Oc1cccc([S+](c2cccc(OC(C)(C)C)c2)c2cccc(OC(C)(C)C)c2)c1 ; c1ccc([S+](c2ccccc2)c2ccc(OCOC3C4CC5CC(C4)CC3C5)cc2)cc1 ; Cc1cc([S+](c2ccccc2)c2ccccc2)cc(C)c1OCOC1C2CC3CC(C2)CC1C3]

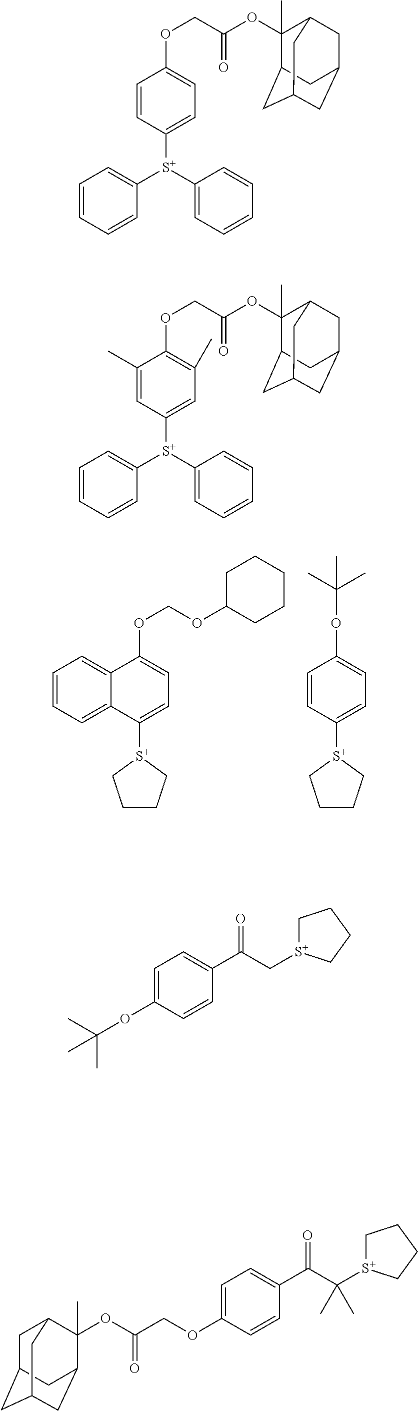 [SMILES: CC1(OC(=O)COc2ccc([S+](c3ccccc3)c3ccccc3)cc2)C2CC3CC(C2)CC1C3 ; Cc1cc([S+](c2ccccc2)c2ccccc2)cc(C)c1OCC(=O)OC1(C)C2CC3CC(C2)CC1C3 ; c1ccc2c([S+]3CCCC3)ccc(OCOC3CCCCC3)c2c1 ; CC(C)(C)Oc1ccc([S+]2CCCC2)cc1 ; CC(C)(C)Oc1ccc(C(=O)C[S+]2CCCC2)cc1 ; CC1(OC(=O)COc2ccc(C(=O)C(C)(C)[S+]3CCCC3)cc2)C2CC3CC(C2)CC1C3]

Specific examples of the acid generator [P-B] will be described below, but the present invention is not limited thereto.

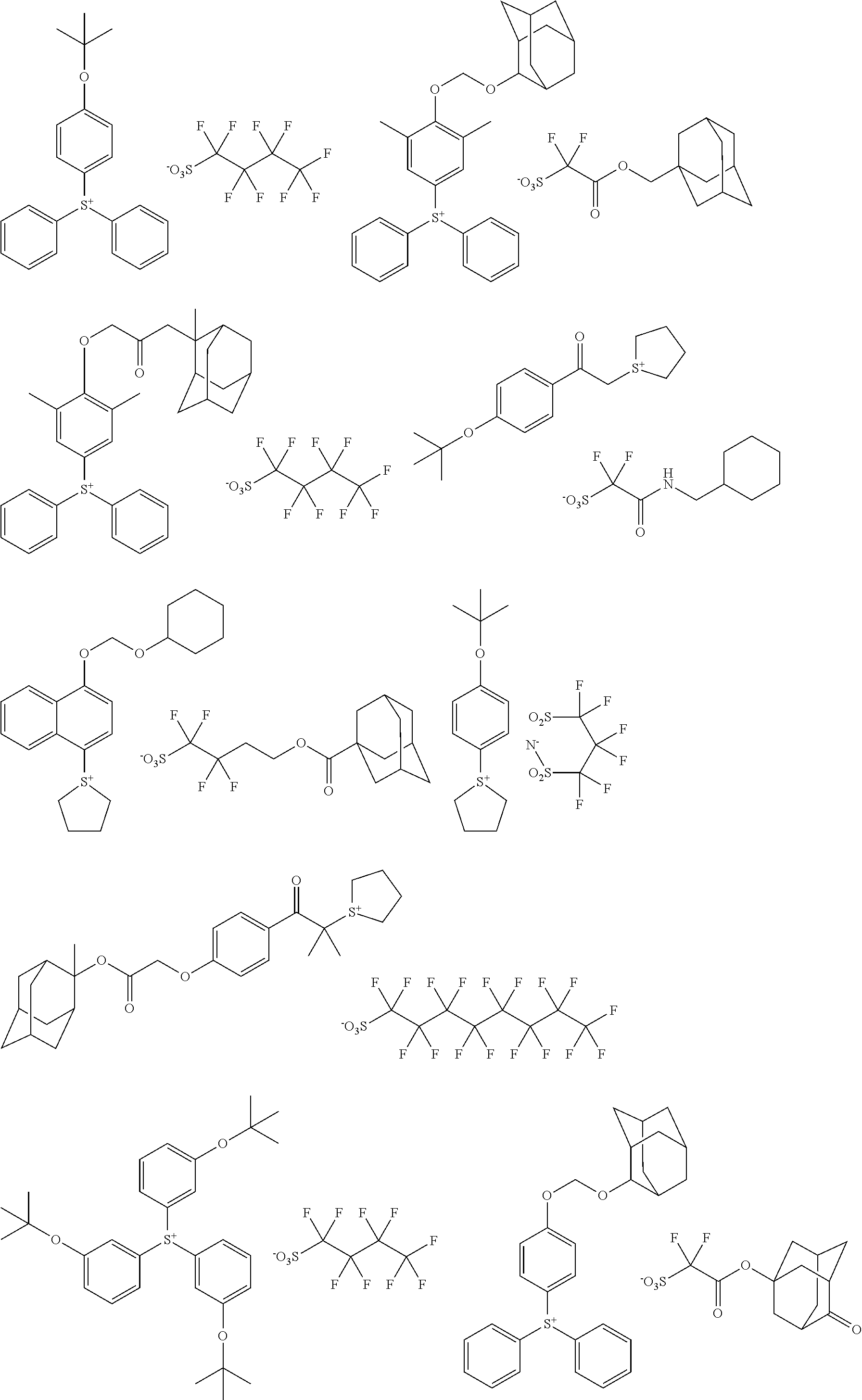

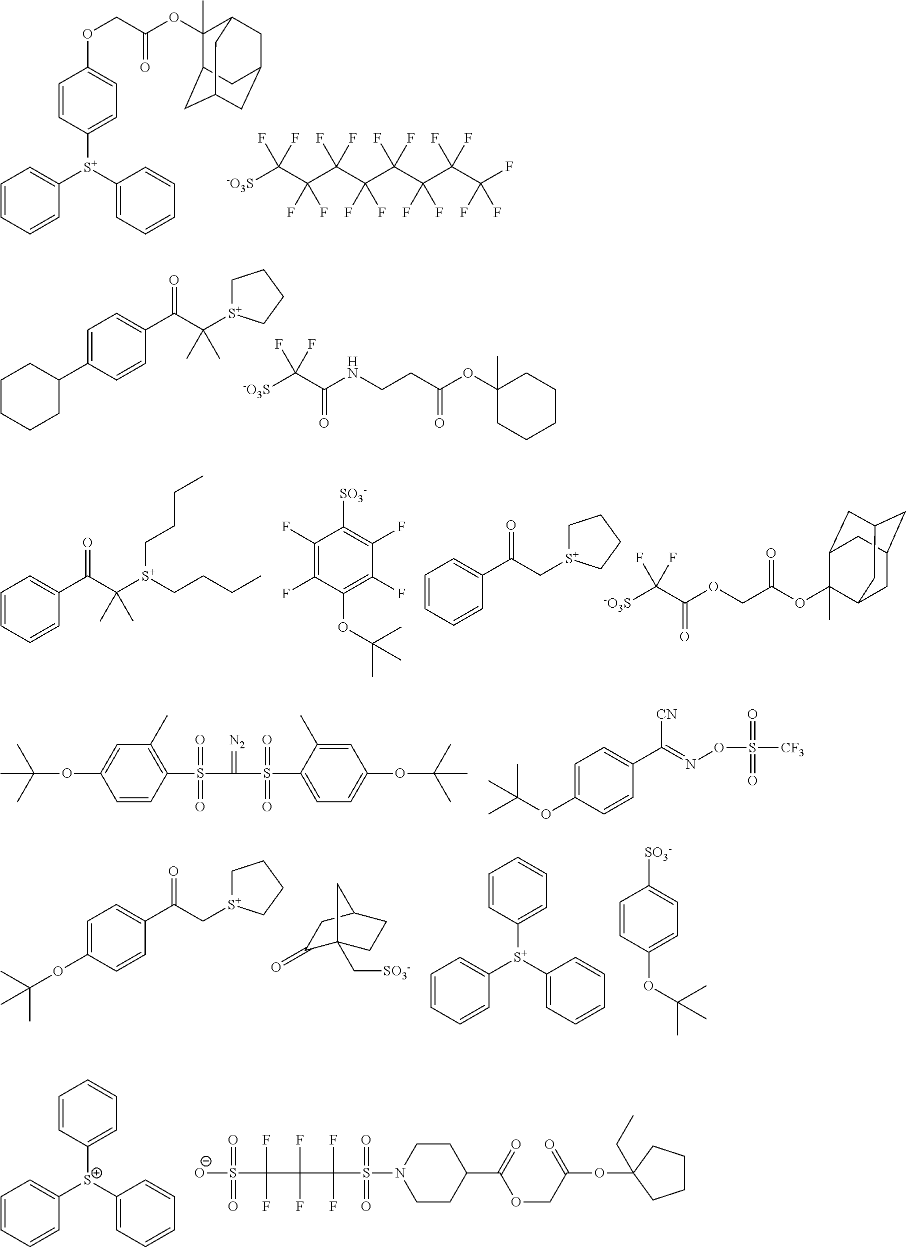

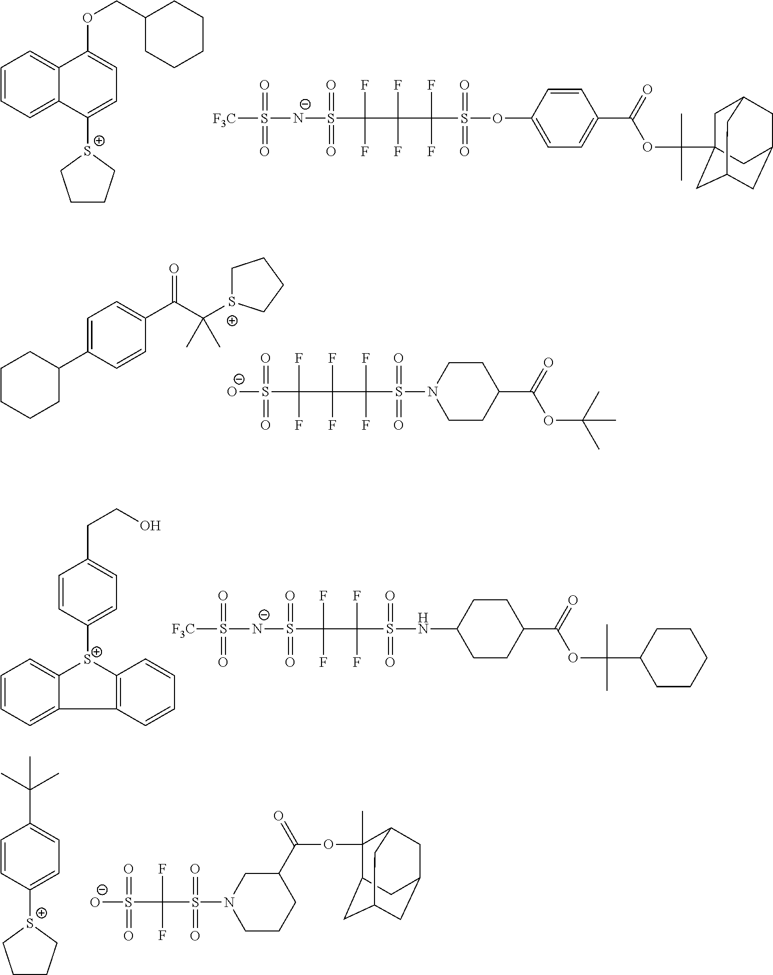

In the active light sensitive or radiation sensitive composition of the present invention, an acid generator [P-B] can be used alone, or two or more types thereof can be used in combination, and the content is preferably 0.1% by mass to 20% by mass, more preferably 0.5% by mass to 15% by mass, and still more preferably 3% by mass to 12% by mass based on the total solid content of the active light sensitive or radiation sensitive composition.

[P-C] Low Molecular Weight Compound of which Solubility in Alkali Developers is Increased Due to Action of Acid

Although the low molecular weight compound [P-C] of which the solubility in alkali developers is increased due to the action of an acid is not particularly limited, the low molecular weight compound [P-C] is preferably a low molecular weight compound having an acid-decomposable group.

Specific examples of the acid-decomposable group include the same as those described in the acid-decomposable group of the resin [P-A], and an acetal group, a carbonate group, and a tertiary ester group are suitably exemplified.

The low molecular weight compound [P-C] is preferably a low molecular compound having a group protected in the form in which the hydrogen atom in an acid group such as a phenolic hydroxyl group, a carboxylic acid group, or a sulfonic acid group is substituted with a group leaving by being decomposed due to the action of an acid.

The molecular weight range of the low molecular weight compound [P-C] is preferably 100 to 1000, more preferably 100 to 700, and particularly preferably 100 to 500.

Here, the low molecular weight compound in the present invention is a low molecular compound having a constant molecular weight (a compound which substantially does not have a molecular weight distribution) of 100 to 1000 (more preferably 100 to 700, and still more preferably 100 to 500), which is not a so-called polymer or oligomer obtained by cleaving the unsaturated bonds of a compound having unsaturated bonds (a so-called polymerizable monomer) while using an initiator and by sequentially growing bonds.

In a case where the low molecular weight compound [P-C] has a tertiary ester structure (that is, in a case where the acid-decomposable group in the low molecular compound [P-C] is a tertiary ester group), the low molecular weight compound [P-C] is particularly preferably a carboxylic acid ester or an unsaturated carboxylic acid ester represented by the following General Formula (1a).

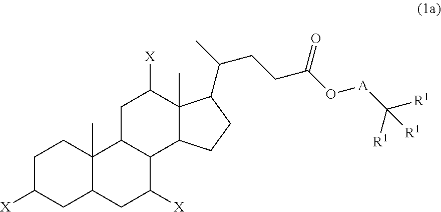

(In General Formula (1a), each of R¹'s independently represents a monovalent alicyclic hydrocarbon group (which preferably has 4 to 20 carbon atoms) or a derivative thereof, or an alkyl group of (which preferably has 1 to 4 carbon atoms), and at least one of R¹'s is the alicyclic hydrocarbon group or a derivative thereof, or any two of R¹'s are bonded to each other to form a divalent alicyclic hydrocarbon group (which preferably has 4 to 20 carbon atoms) or a derivative thereof together with the carbon atom to which each is bonded, and the remaining R¹ is an alkyl group (which preferably has 1 to 4 carbon atoms), or a monovalent alicyclic hydrocarbon group (which preferably has 4 to 20 carbon atoms) or a derivative thereof.

Each of X's independently represents a hydrogen atom or a hydroxy group, and at least one is a hydroxy group.

A represents a single bond or a group represented by -D-COO—, and D is an alkylene group (which preferably has 1 to 4 carbon atoms).

In General Formula (1a), A represents a single bond or a divalent connecting group, and examples of the divalent connecting group include a methylene group, a methylenecarbonyl group, a methylenecarbonyloxy group, an ethylene group, an ethylenecarbonyl group, an ethylenecarbonyloxy group, a propylene group, a propylenecarbonyl group, and a propylenecarbonyloxy group. A methylenecarbonyloxy group is particularly preferable.

In General Formula (1a), as the monovalent alicyclic hydrocarbon group (which preferably has 4 to 20 carbon atoms) represented by R¹ and a divalent alicyclic hydrocarbon group (which preferably has 4 to 20 carbon atoms) formed by bonding of any two of R¹'s to each other, groups consisting of alicyclic rings derived from cycloalkanes such as norbornane, tricyclodecane, tetracyclododecane, adamantane, cyclobutane, cyclopentane, cyclohexane, cycloheptane, and cyclooctane; and groups obtained by substituting groups consisting of these alicyclic rings with one or more types, or one or more of alkyl groups having 1 to 4 carbon atoms such as a methyl group, an ethyl group, an n-propyl group, an i-propyl group, an n-butyl group, a 2-methylpropyl group, a 1-methylpropyl group, and a t-butyl group, and a cycloalkyl groups are exemplified. Among these alicyclic hydrocarbon groups, a group consisting of alicyclic rings derived from norbornane, tricyclodecane, tetracyclododecane, adamantane, cyclopentane or cyclohexane, or a group obtained by substituting a group consisting of these alicyclic rings with the alkyl group is preferable.

In addition, examples of the derivative of the alicyclic hydrocarbon group include a hydroxyl group; a carboxyl group; an oxo group (that is, a ═O group); hydroxyalkyl groups having 1 to 4 carbon atoms such as a hydroxymethyl group, a 1-hydroxyethyl group, a 2-hydroxyethyl group, a 1-hydroxypropyl group, a 2-hydroxypropyl group, a 3-hydroxypropyl group, a 1-hydroxybutyl group, a 2-hydroxybutyl group, a 3-hydroxybutyl group, and a 4-hydroxybutyl group; alkoxyl groups having 1 to 4 carbon atoms such as a methoxy group, an ethoxy group, an n-propoxy group, an i-propoxy group, an n-butoxy group, a 2-methylpropoxy group, a 1-methylpropoxy group, and t-butoxy group; a cyano group; and groups having one or more types or one or more substituents including a cyanoalkyl group having 2 to 5 carbon atoms such as a cyanomethyl group, a 2-cyanoethyl group, a 3-cyanopropyl group, or a 4-cyanobutyl group. Among these substituents, a hydroxyl group, a carboxyl group, a hydroxymethyl group, a cyano group, or a cyanomethyl group is preferable.

In addition, examples of the alkyl group represented by R¹ include alkyl groups having 1 to 4 carbon atoms such as a methyl group, an ethyl group, an n-propyl group, an i-propyl group, an n-butyl group, a 2-methylpropyl group, a 1-methylpropyl group, and a t-butyl group. Among these alkyl groups, a methyl group, an ethyl group, an n-propyl group, or an i-propyl group is preferable.

Preferable specific examples include the following compounds.

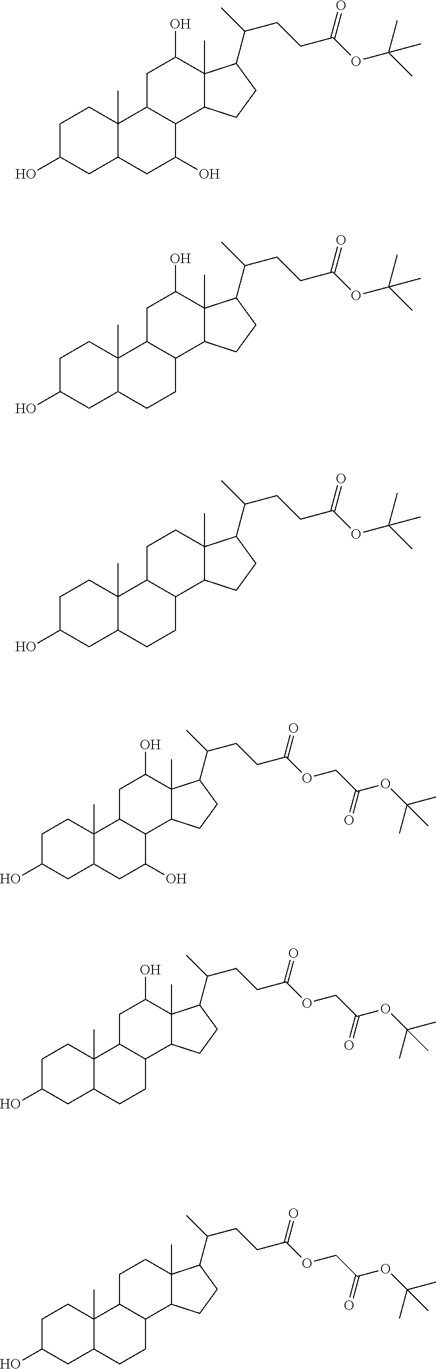 [SMILES: CC(CCC(=O)OC(C)(C)C)C1CCC2C3C(O)CC4CC(O)CCC4(C)C3CC(O)C12C ; CC(CCC(=O)OC(C)(C)C)C1CCC2C3CCC4CC(O)CCC4(C)C3CC(O)C12C ; CC(CCC(=O)OC(C)(C)C)C1CCC2C3CCC4CC(O)CCC4(C)C3CCC12C ; CC(CCC(=O)OCC(=O)OC(C)(C)C)C1CCC2C3C(O)CC4CC(O)CCC4(C)C3CC(O)C12C ; CC(CCC(=O)OCC(=O)OC(C)(C)C)C1CCC2C3CCC4CC(O)CCC4(C)C3CC(O)C12C ; CC(CCC(=O)OCC(=O)OC(C)(C)C)C1CCC2C3CCC4CC(O)CCC4(C)C3CCC12C]

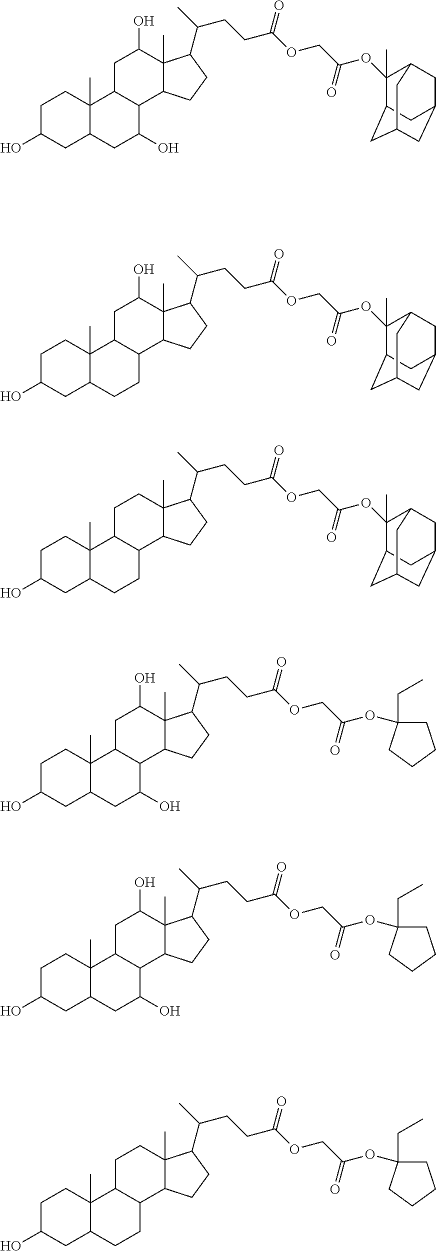 [SMILES: CC(CCC(=O)OCC(=O)OC1(C)C2CC3CC(C2)CC1C3)C1CCC2C3C(O)CC4CC(O)CCC4(C)C3CC(O)C12C ; CC(CCC(=O)OCC(=O)OC1(C)C2CC3CC(C2)CC1C3)C1CCC2C3CCC4CC(O)CCC4(C)C3CC(O)C12C ; CC(CCC(=O)OCC(=O)OC1(C)C2CC3CC(C2)CC1C3)C1CCC2C3CCC4CC(O)CCC4(C)C3CCC12C ; CCC1(OC(=O)COC(=O)CCC(C)C2CCC3C4C(O)CC5CC(O)CCC5(C)C4CC(O)C23C)CCCC1 ; CCC1(OC(=O)COC(=O)CCC(C)C2CCC3C4C(O)CC5CC(O)CCC5(C)C4CC(O)C23C)CCCC1 ; CCC1(OC(=O)COC(=O)CCC(C)C2CCC3C4CCC5CC(O)CCC5(C)C4CCC23C)CCCC1]

In addition, the low molecular weight compound [P-C] may be (meth)acrylic acid esters shown below. Specific examples of a (meth)acrylic acid tertiary ester having a tertiary ester group as an acid-decomposable group are shown below, but the present invention is not limited thereto.

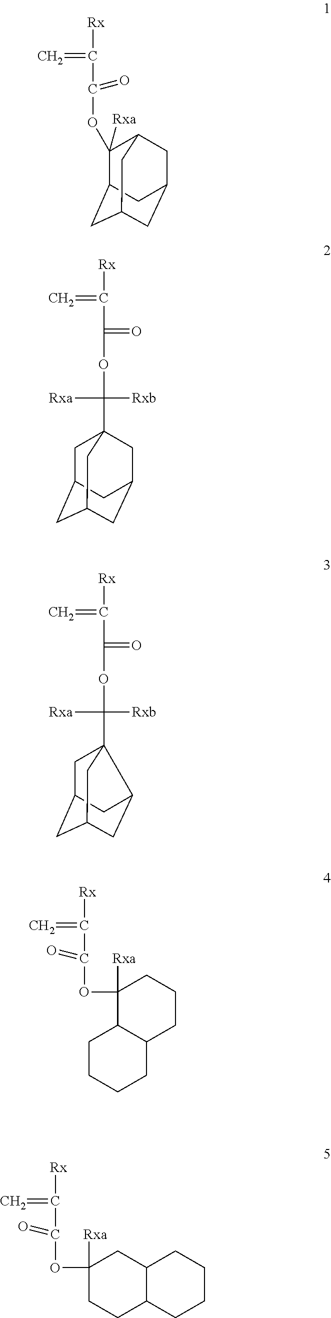

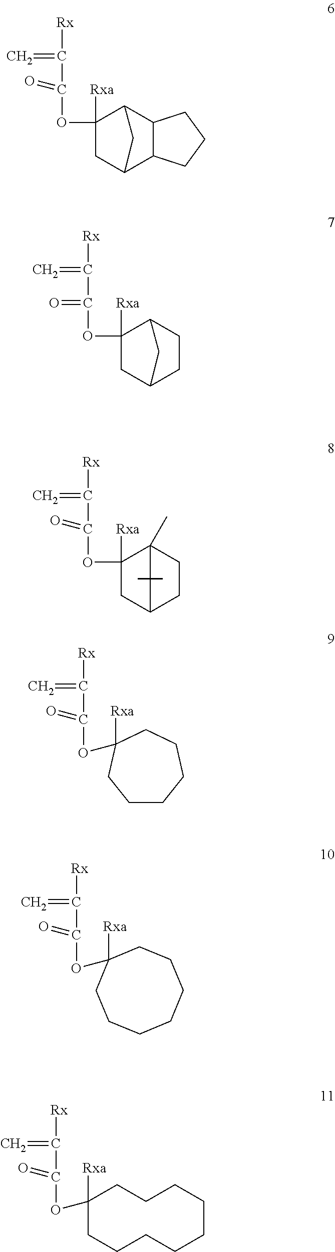

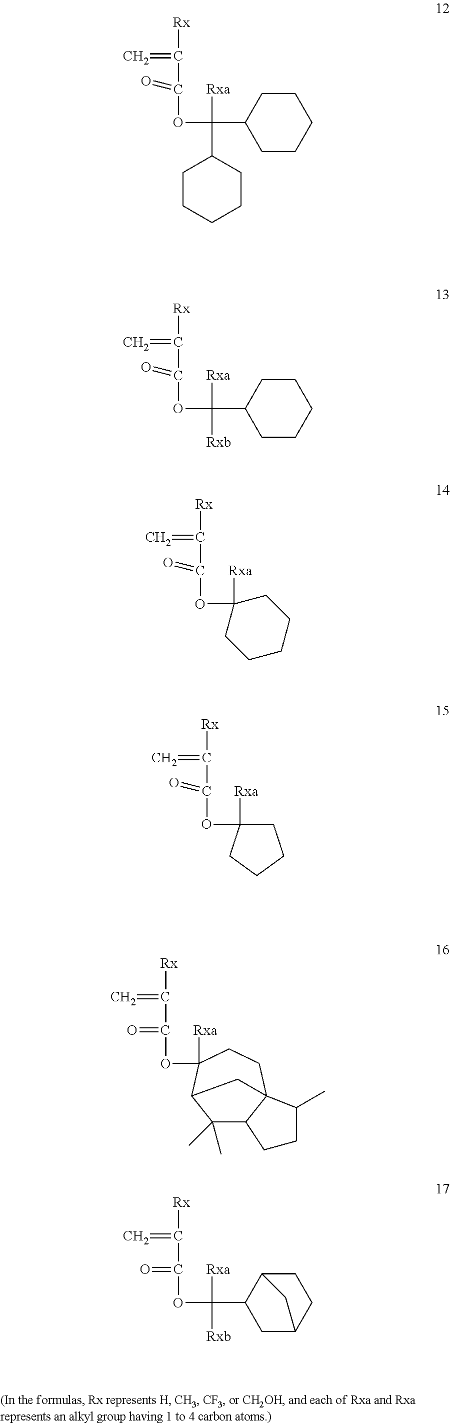

The low molecular weight compound [P-C] may be the same component as the compound [P-B], or may be a different component from the compound [P-B], but is preferably a different component from the compound [P-B].

In the active light sensitive or radiation sensitive composition of the present invention, the low molecular weight compound [P-C] can be used alone, or two or more types thereof can be used in combination, and the content is preferably 0.1% by mass to 20% by mass, more preferably 0.5% by mass to 10% by mass, and still more preferably 1% by mass to 5% by mass based on the total solid content of the active light sensitive or radiation sensitive composition.

[2] (N) at Least One Compound Selected from Group Consisting of Following [N-A], [N-B], and [N-C]

The active light sensitive or radiation sensitive composition of the present invention contains at least one compound (hereinafter, also referred to as a compound (N)) selected from the group consisting of the following [N-A], [N-B], and [N-C].

[N-A] Resin of which the solubility in alkali developers is decreased by the action of an acid, active light or radiation, or an activated species

[N-B] Compound that generates an acid by irradiation with active light or radiation, and of which the solubility in alkali developers is decreased by the action of an acid, active light or radiation, or an activated species

[N-C] Low molecular weight compound of which the solubility in alkali developers is decreased by the action of an acid, active light or radiation, or an activated species

Each of the resin [N-A], the compound [N-B], and the low molecular weight compound [N-C] may be any compound of the following (N-1), (n-2), and (N-3).

(N-1) Compound of which the solubility in alkali developers is decreased due to the action of an acid

(N-2) Compound of which the solubility in alkali developers is decreased by irradiation with active light or radiation

(N-3) Compound of which the solubility in alkali developers is decreased by an activated species

Here, examples of the activated species in (N-3) include a radical, a cationic species, and an anionic species.

The resin [N-A], the compound [N-B], and the low molecular weight compound [N-C] will be described in detail below.

[N-A] Resin of which Solubility in Alkali Developers is Decreased by Action of Acid, Active Light or Radiation, or Activated Species

Although the resin of which the solubility in alkali developers is decreased by the action of an acid, active light or radiation, or an activated species is not particularly limited, a resin of which the solubility in alkali developers is decreased due to the action of an acid generated from an acid generator (A) described below, the acid generator [P-B], or an acid generator [N-B] described below by irradiation with active light or radiation or an active species such as radicals generated by irradiation with active light or radiation is preferable.

As the resin [N-A], a resin having a group which is polymerized by the action of an acid, active light or radiation, or an activated species is exemplified, and the resin [N-A] is preferably a resin having one or more types of repeating units selected from repeating units represented by the following General Formulas (L-1) to (L-4).

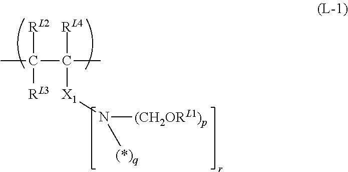

R^{L1} represents a hydrogen atom, an alkyl group, or a cycloalkyl group. p represents 1 or 2. q represents an integer represented by (2-p). * represents a direct bond with other atoms constituting the repeating unit (L-1). In a case where p is 2 or r is 2 or greater, a plurality of R^{L1}'s may be the same as or may be different from each other.

The alkyl group represented by R^{L1} may be any one of a linear alkyl group or a branched alkyl group, and examples thereof include an alkyl group having 1 to 20 carbon atoms (for example, a methyl group, an ethyl group, a propyl group, an isopropyl group, a butyl group, an isobutyl group, a t-butyl group, an n-pentyl group, an n-hexyl group, an n-octyl group, or an n-dodecyl group). An alkyl group having 1 to 8 carbon atoms is preferable, an alkyl group having 1 to 6 carbon atoms is more preferable, and an alkyl group having 1 to 4 carbon atoms is particularly preferable.

The cycloalkyl group represented by R^{L1} may be any one of a monocyclic type or a polycyclic type, and examples thereof include a cycloalkyl group having 3 to 17 carbon atoms (for example, a cyclopentyl group, a cyclohexyl group, a norbornanyl group, or an adamantyl group). A cycloalkyl group having 5 to 12 carbon atoms is preferable, a cycloalkyl group having 5 to 10 carbon atoms is more preferable, and a cycloalkyl group having 5 or 6 carbon atoms is particularly preferable.

As R^{L1} in General Formula (L-1), a hydrogen atom or an alkyl group having 1 to 8 carbon atoms is preferable, a hydrogen atom or an alkyl group having 1 to 6 carbon atoms is more preferable, and a hydrogen atom or an alkyl group having 1 to 4 carbon atoms is particularly preferable.

Each of R^{L2}, R^{L3}, and R^{L4} independently represents a hydrogen atom, an alkyl group, a cycloalkyl group, a halogen atom, a cyano group, or an alkoxycarbonyl group.

X₁ represents a single bond, a linear or branched hydrocarbon group, a cyclic hydrocarbon group which may contain a heteroatom as a ring member, —O—, —S—, —CO—, —SO₂—, —NR— (R is a hydrogen atom, an alkyl group, or a group represented by —CH₂OR^{L1}), or an (r+1) valent group selected from the group consisting of groups obtained by combining these. Moreover, R^{L1} in a group represented by —CH₂OR^{L1} has the same meaning as R^{L1} in General Formula (L-1).

r is an integer of 1 to 5. Here, in a case where X₁ is a single bond, r is 1.

Specific examples and preferable examples of the alkyl group represented by R^{L2}, R^{L3}, or R^{L4} include the same as those described in the alkyl group represented by R^{L1}.

Specific examples and preferable examples of the cycloalkyl group represented by R^{L2}, R^{L3}, or R^{L4} include the same as the specific examples of the cycloalkyl group represented by R^{L1}.

Examples of the halogen atom represented by R^{L2}, R^{L3}, or R^{L4} include a fluorine atom, a chlorine atom, a bromine atom, and an iodine atom, and a fluorine atom is more preferable.

Specific examples and preferable examples of the alkyl portion of the alkoxycarbonyl group represented by R^{L2}, R^{L3}, or R^{L4} include the same as those described in the alkyl group represented by R^{L1}.

Each of R^{L2} and R^{L3} is preferably independently a hydrogen atom or an alkyl group, and more preferably independently a hydrogen atom.

R^{L4} is preferably a hydrogen atom, an alkyl group, or a halogen atom, and more preferably a hydrogen atom or an alkyl group.

The linear or branched hydrocarbon group is preferably a linear or branched hydrocarbon group having 1 to 5 carbon atoms, and preferably a linear or branched hydrocarbon group having 1 to 3 carbon atoms.

The cyclic hydrocarbon group which may contain a heteroatom as a ring member may be an aromatic ring group, or may be a nonaromatic ring group.

The aromatic ring in the aromatic ring group preferably has 3 to 12 carbon atoms, and more specific examples thereof include a benzene ring, a naphthalene ring, a furan ring, a pyrrole ring, a thiophene ring, a pyrazole ring, an oxazole ring, a thiazole ring, a pyridine ring, a pyrazine ring, a pyrimidine ring, and a triazine ring.

The nonaromatic ring in the nonaromatic ring group preferably has 4 to 12 carbon atoms, and more specific examples thereof include a cyclopentane ring, a cyclohexane ring, and a tetrahydrofuran ring.

In General Formula (L-1), in a case where p is 1 (that is, q is 1), * may be bonded to X₁ through a connecting group (for example, an alkylene group, a carbonyl group, —O—, —S—, —CO—, —SO₂—, or a group obtained by combination thereof) to form a ring, but, * is preferably bonded to a hydrogen atom or a monovalent organic group (for example, an alkyl group, a cycloalkyl group, a halogen atom, a cyano group, —O—, —S—, —CO—, —SO₂—, or a group obtained by combination thereof).

r is preferably an integer of 1 to 3, and more preferably 1 or 2.

Specific examples of the repeating unit represented by General Formula (L-1) will be described below, but the present invention is not limited thereto. In the specific examples, R′ represents a hydrogen atom or a methyl group.

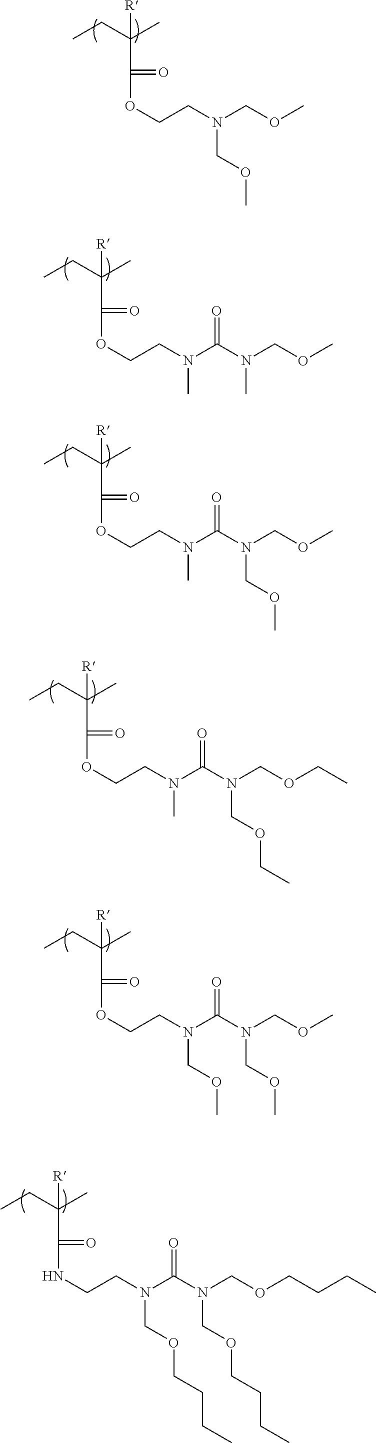

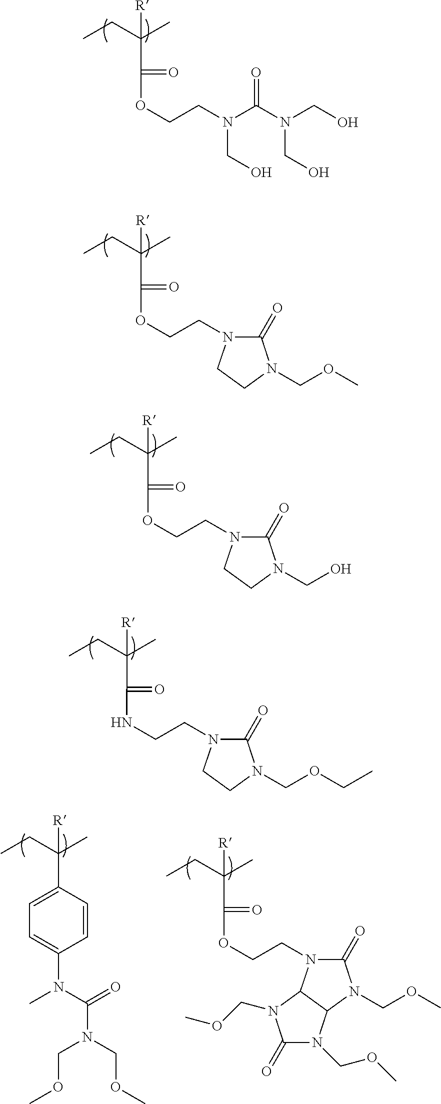

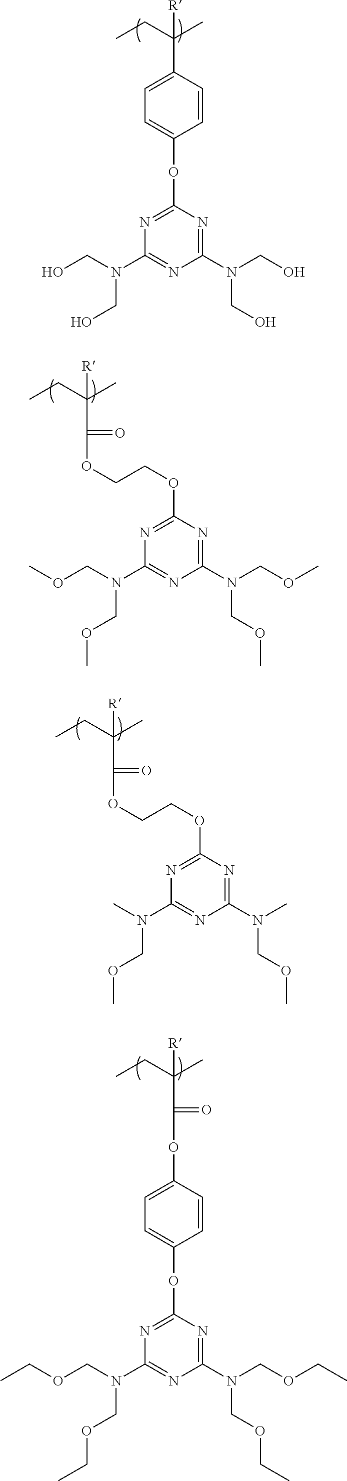

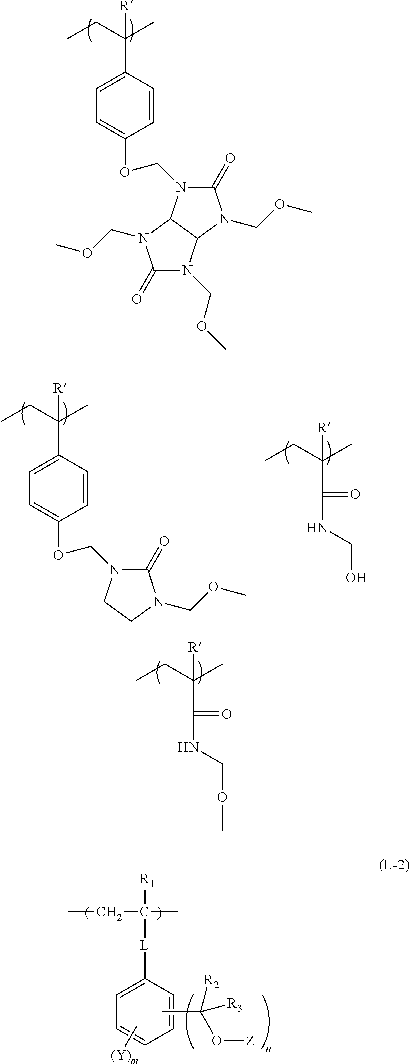

In General Formula (L-2), R₁ represents a hydrogen atom, an methyl group, or a halogen atom; Each of R₂ and R₃ represents a hydrogen atom, an alkyl group, or a cycloalkyl group; L represents a divalent connecting group or single bond; Y represents a monovalent substituent excluding a methylol group; Z represents a hydrogen atom or a monovalent substituent; m represents an integer of 0 to 4; n represents an integer of 1 to 5; m+n is 5 or less; In a case where m is 2 or greater, a plurality of Y's may be the same as or may be different from each other, and the plurality of Y's may be bonded to each other to form a ring structure; and in a case where n is 2 or greater, a plurality of R₂'s, R₃'s, and Z's may be the same as or may be different from each other.

The methyl group represented by R₁ may have a substituent, and examples of the substituent include a halogen atom such as a fluorine atom, a chlorine atom, a bromine atom, or an iodine atom, a hydroxyl group, and an isopropyl group. Examples of the methyl group which may have a substituent include a methyl group, a trifluoromethyl group, and a hydroxymethyl group. Examples of the halogen atom represented by R₁ include fluorine, chlorine, bromine, and iodine.

R₁ is preferably a hydrogen atom or a methyl group.

Examples of the alkyl group represented by R₂ or R₃ include a linear or branched alkyl group having 1 to 10 carbon atoms, and examples of the cycloalkyl group include a cycloalkyl group having 3 to 10 carbon atoms. Specifically, a hydrogen atom, a methyl group, a cyclohexyl group, and a t-butyl group are exemplified. The alkyl group and the cycloalkyl group here may have may have a substituent. Examples of the substituent include the same as those described below as a substituent which a monovalent substituent represented by Y has.

Examples of the divalent connecting group represented by L include a monocyclic or polycyclic aromatic ring which may have a substituent having 6 to 18 carbon atoms, —C(═O)—, —O—C(═O)—, —CH₂—O—C(═O)—, a thiocarbonyl group, a linear or branched alkylene group (preferably having 1 to 10 carbon atoms, and more preferably 1 to 6 carbon atoms), a cycloalkylene group (preferably having 3 to 10 carbon atoms, and more preferably 3 to 6 carbon atoms), a sulfonyl group, —O—, —NH—, —S—, and a divalent connecting group obtained by combining these (preferably having 1 to 50 total carbon atoms, more preferably 1 to 30 total carbon atoms, and still more preferably 1 to 20 total carbon atoms).

Preferable examples of the aromatic ring represented by L in General Formula (L-2) include an aromatic hydrocarbon ring which may have a substituent having 6 to 18 carbon atoms, such as a benzene ring, a naphthalene ring, an anthracene ring, a fluorene ring, and a phenanthrene ring, or an aromatic ring hetero ring including a hetero ring, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. Among these, a benzene ring or a naphthalene ring is preferable from the viewpoint of resolution, and a benzene ring is most preferable.

Examples of the monovalent substituent represented by Y include an alkyl group (which may be linear or branched, and preferably has 1 to 12 carbon atoms), an alkenyl group (which preferably has 2 to 12 carbon atoms), an alkynyl group (which preferably has 2 to 12 carbon atoms), a cycloalkyl group (which may be a monocycle or a polycycle, and preferably has 3 to 12 carbon atoms), an aryl group (which preferably has 6 to 18 carbon atoms), a hydroxy group, an alkoxy group, an ester group, an amide group, a urethane group, a ureido group, a thioether group, a sulfonamide group, a halogen atom, a haloalkyl group, and a sulfonic acid ester group. Preferable examples thereof include an alkyl group, a cycloalkyl group, a halogen atom, a haloalkyl group, a hydroxy group, an alkoxy group, an aryloxy group, an ester group, and an aryl group, and more preferable examples thereof include an alkyl group, a halogen atom, a hydroxy group, and an alkoxy group.

The monovalent substituent represented by Y may further have a substituent, and examples of the substituent include a hydroxyl group, a halogen atom (for example, a fluorine atom), an alkyl group, a cycloalkyl group, an alkoxy group, a carboxyl group, an alkoxycarbonyl group, an aryl group, an alkoxyalkyl group, and a group obtained by combining these, and the substituent preferably has 8 or less carbon atoms.

In addition, when m is 2 or greater, a plurality of Y's may be bonded to each other to form a ring structure through a single bond or a connecting group. Examples of the connecting group in this case include an ether bond, a thioether bond, an ester bond, an amide bond, a carbonyl group, and an alkylene group.

Examples of the halogen atom include the same as those exemplified as R₁.

Examples of the haloalkyl group include an alkyl group and a cycloalkyl group, having 1 to 12 carbon atoms, in which at least one or more hydrogen atoms was substituted with a fluorine atom, a chlorine atom, a bromine atom, or an iodine atom. Specific examples thereof include a fluoromethyl group, a trifluoromethyl group, a pentafluoroethyl group, a heptafluoropropyl group, and a undecafluorocyclohexyl group.

Examples of the monovalent substituent represented by Z include an alkyl group (which may be linear or branched, and preferably has 1 to 12 carbon atoms), an alkenyl group (which preferably has 2 to 12 carbon atoms), an alkynyl group (which preferably has 2 to 12 carbon atoms), a cycloalkyl group (which preferably has 3 to 8 carbon atoms), an aryl group (which may be a monocycle or a polycycle, and preferably has 6 to 18 carbon atoms), a haloalkyl group, an alkanoyl group, an alkoxycarbonyl group, an aryloxycarbonyl group, an alkylsulfonyl group, an arylsulfonyloxy group, an alkylsulfonyl group, an arylsulfonyl group, a cyano group, an alkylthio group, an arylthio group, an alkoxyalkyl group, and a heterocyclic group. Preferable examples thereof include a hydrogen atom, an alkyl group, a cycloalkyl group, an alkanoyl group, an alkenyl group, a haloalkyl group, and an alkoxyalkyl group.

Preferable examples of the haloalkyl group include the same as those exemplified as Y in General Formula (L-2).

As the alkanoyl group, an alkanoyl group having 2 to 20 carbon atoms is preferable, and examples thereof include an acetyl group, a propanoyl group, a butanoyl group, a trifluoromethylcarbonyl group, a pentanoyl group, a benzoyl group, a 1-naphthoyl group, a 2-naphthoyl group, a 4-methylsulfanylbenzoyl group, a 4-phenylsulfanylbenzoyl group, a 4-dimethylaminobenzoyl group, a 4-diethylaminobenzoyl group, a 2-chlorobenzoyl group, a 2-methylbenzoyl group, a 2-methoxybenzoyl group, a 2-butoxybenzoyl group, a 3-chlorobenzoyl group, a 3-trifluoromethylbenzoyl group, a 3-cyanobenzoyl group, a 3-nitrobenzoyl group, a 4-fluorobenzoyl group, a 4-cyanobenzoyl group, and a 4-methoxybenzoyl group.

As the alkoxycarbonyl group, an alkoxycarbonyl group having 2 to 20 carbon atoms is preferable, and examples thereof include a methoxycarbonyl group, an ethoxycarbonyl group, a propoxycarbonyl group, a butoxycarbonyl group, a hexyloxycarbonyl group, an octyloxycarbonyl group, a decyloxycarbonyl group, an octadecyloxycarbonyl group, and a trifluoromethyloxycarbonyl group.

As the aryloxycarbonyl group, an aryloxycarbonyl group having 7 to 30 carbon atoms are exemplified, and examples thereof include a phenoxycarbonyl group, a 1-naphthyloxycarbonyl group, a 2-naphthyloxycarbonyl group, a 4-methylsulfanylphenyloxycarbonyl group, a 4-phenylsulfanylphenyloxycarbonyl group, a 4-dimethylaminophenyloxycarbonyl group, a 4-diethylaminophenyloxycarbonyl group, a 2-chlorophenyloxycarbonyl group, a 2-methylphenyloxycarbonyl group, a 2-methoxyphenyloxycarbonyl group, a 2-butoxyphenyloxycarbonyl group, a 3-chlorophenyloxycarbonyl group, a 3-trifluoromethylphenyloxycarbonyl group, 3-cyanophenyloxycarbonyl group, a 3-nitrophenyloxycarbonyl group, a 4-fluorophenyloxycarbonyl group, a 4-cyanophenyloxycarbonyl group, and a 4-methoxyphenyloxycarbonyl group.

As the alkylsulfonyloxy group, an alkylsulfonyloxy group having 1 to 20 carbon atoms is preferable, and examples thereof include a methylsulfonyloxy group, an ethylsulfonyl group, a propylsulfonyl group, an isopropylsulfonyloxy group, a butylsulfonyloxy group, a hexylsulfonyloxy group, a cyclohexylsulfonyl group, an octylsulfonyloxy group, a 2-ethylhexylsulfonyloxy group, a decanoylsulfonyloxy group, a dodecanoylsulfonyloxy group, an octadecanoylsulfonyloxy group, a cyanomethylsulfonyloxy group, a methoxymethylsulfonyloxy group, and a perfluoroalkylsulfonyloxy group.

As the arylsulfonyloxy group, an arylsulfonyloxy group having 6 to 30 carbon atoms is preferable, and examples thereof include a phenylsulfonyloxy group, a 1-naphthylsulfonyloxy group, a 2-naphthylsulfonyloxy group, a 2-chlorophenylsulfonyloxy group, a 2-methylphenylsulfonyloxy group, a 2-methoxyphenylsulfonyloxy group, a 2-butoxyphenylsulfonyl group, a 3-chlorophenylsulfonyloxy group, a 3-trifluoromethylphenylsulfonyloxy group, a 3-cyanophenylsulfonyl group, a 3-nitrophenylsulfonyloxy group, a 4-fluorophenylsulfonyloxy group, a 4-cyanophenylsulfonyloxy group, a 4-methoxyphenylsulfonyloxy group, a 4-methylsulfanylphenylsulfonyloxy group, a 4-phenylsulfanylphenylsulfonyloxy group, and a 4-dimethylaminophenylsulfonyloxy group.

As the alkylsulfonyl group, an alkylsulfonyl group having 1 to 20 carbon atoms is preferable, and examples thereof include a methylsulfonyl group, an ethylsulfonyl group, a propylsulfonyl group, an isopropylsulfonyl group, a butylsulfonyl group, a hexylsulfonyl group, a cyclohexylsulfonyl group, an octylsulfonyl group, a 2-ethylhexylsulfonyl group, a decanoylsulfonyl group, a dodecanoylsulfonyl group, an octadecanoylsulfonyl group, a cyanomethylsulfonyl group, a methoxymethylsulfonyl group, and a perfluoroalkylsulfonyl group.

As the arylsulfonyl group, an arylsulfonyl group having 6 to 30 carbon atoms is preferable, and examples thereof include a phenylsulfonyl group, a 1-naphthylsulfonyl group, a 2-naphthylsulfonyl group, a 2-chlorophenylsulfonyl group, a 2-methylphenylsulfonyl group, a 2-methoxyphenylsulfonyl group, a 2-butoxyphenylsulfonyl group, a 3-chlorophenylsulfonyl group, a 3-trifluoromethylphenylsulfonyl group, a 3-cyanophenylsulfonyl group, a 3-nitrophenylsulfonyl group, a 4-fluorophenylsulfonyl group, a 4-cyanophenylsulfonyl group, a 4-methoxyphenylsulfonyl group, a 4-methylsulfanylphenylsulfonyl group, a 4-phenylsulfanylphenylsulfonyl group, and a 4-dimethylaminophenylsulfonyl group.

As the alkylthio group, an alkylthio group having 1 to 30 carbon atoms is exemplified, and examples thereof include a methylthio group, an ethylthio group, a propylthio group, an n-butylthio group, a trifluoromethylthio group, a hexylthio group, a t-butylthio group, a 2-ethylhexylthio group, a cyclohexylthio group, a decylthio group, and a dodecylthio group.

As the arylthio group, an arylthio group having 6 to 30 carbon atoms is exemplified, and examples thereof include a phenylthio group, a 1-naphthylthio group, a 2-naphthylthio group, a tolylthio group, a methoxyphenylthio group, a naphthylthio group, a chlorophenylthio group, a trifluoromethylphenylthio group, a cyanophenylthio group, and a nitrophenylthio group.

As the heterocyclic group, preferably, aromatic or aliphatic heterocyclic groups including a nitrogen atom, an oxygen atom, a sulfur atom, or a phosphorus atom are exemplified. Examples of the heterocyclic group include a thienyl group, a benzo[b]thienyl group, a naphtho[2,3-b]thienyl group, a thianthrenyl group, a furyl group, a pyranyl group, an isobenzofuranyl group, a chromenyl group, a xanthenyl group, a phenoxathiinyl group, a 2H-pyrrolyl group, a pyrrolyl group, an imidazolyl group, a pyrazolyl group, a pyridyl group, a pyrazinyl group, a pyrimidinyl group, a pyridazinyl group, an indolizinyl group, an isoindolyl group, a 3H-indolyl group, an indolyl group, a 1H-indazolyl group, a purinyl group, a 4H-quinolizinyl group, an isoquinolyl group, a quinolyl group, a phthalazinyl group, a naphthyridinyl group, a quinoxalinyl group, a quinazolinyl group, a cinnolinyl group, a pteridinyl group, a 4aH-carbazolyl group, a carbazolyl group, a β-carbolinyl group, a phenanthridinyl group, an acridinyl group, a perimidinyl group, a phenanthrolinyl group, a phenazinyl group, a phenarsazinyl group, an isothiazolyl group, a phenothiazinyl group, an isoxazolyl group, a furazanyl group, a phenoxazinyl group, an isochromanyl group, a chromanyl group, a pyrrolidinyl group, a pyrrolinyl group, an imidazolidinyl group, an imidazolinyl group, a pyrazolidinyl group, a pyrazolinyl group, a piperidyl group, a piperazinyl group, an indolinyl group, an isoindolinyl group, a quinuclidinyl group, a tetrahydropyrimidinyl group, a tetrahydro-2-pyrimidinonyl group, a triazinyl group, a morpholinyl group, and a thioxantholyl group.

n preferably represents an integer of 1 to 4, more preferably an integer of 2 to 4, and particularly preferably an integer of 2 or 3. m is preferably 0 to 1.

In addition, the repeating unit represented by General Formula (L-2) is preferably a repeating unit represented by the following General Formula (2) or (3).

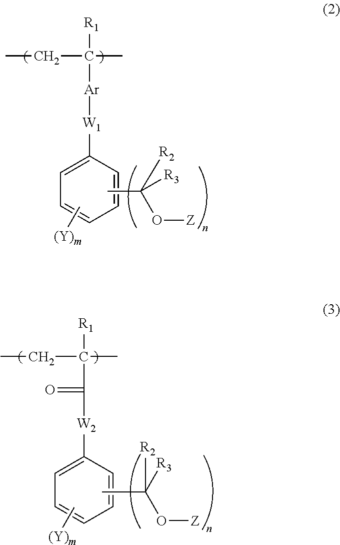

In General Formulas (2) and (3), each of R₁, R₂, R₃, Y, Z, m, and n has the same definition as that in General Formula (L-2).

Ar represents an aromatic ring group.

Each of W₁ and W₂ represents a divalent connecting group or a single bond.

Specific examples of R₁, R₂, R₃, Y, Z, m, and n include the same as those described in General Formula (L-2), respectively, and the preferable range thereof is also the same.

Specific examples of the aromatic ring represented by Ar include the same as the specific examples in a case where L in General Formula (L-2) is an aromatic ring, and the preferable range thereof is also the same.

Examples of the divalent connecting group represented by W₁ or W₂ include a monocyclic or polycyclic aromatic hydrocarbon ring which may have a substituent having 6 to 18 carbon atoms, —C(═O)—, —O—C(═O)—, —CH₂—O—C(═O)—, a thiocarbonyl group, a linear or branched alkylene group (preferably having 1 to 10 carbon atoms, and more preferably 1 to 6 carbon atoms), a cycloalkylene group (preferably having 3 to 10 carbon atoms, and more preferably 3 to 6 carbon atoms), a sulfonyl group, —O—, —NH—, —S—, and a divalent connecting group obtained by combining these.

In addition, the repeating unit represented by General Formula (L-2) is more preferably a repeating unit represented by the following General Formula (2′) or (3′).

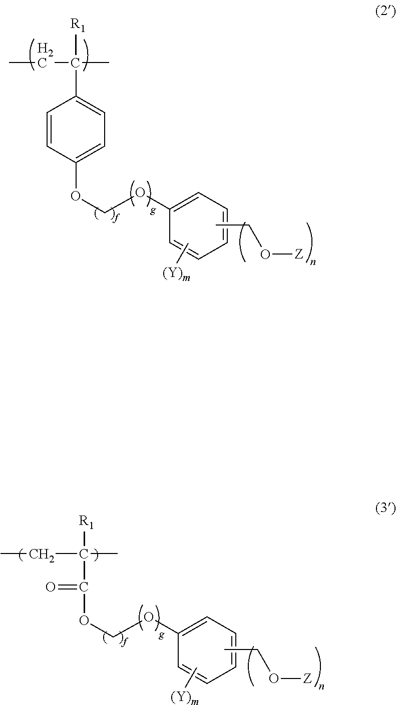

Each of R₁, Y, Z, m, and n in General Formulas (2′) and (3′) has the same meaning as each group in General Formula (L-2), and the specific examples and the preferable range thereof are also the same.

In General Formulas (2′) and (3′), f is an integer of 0 to 6. f is preferably an integer of 0 to 3, and more preferably an integer of 1 to 3.

In General Formulas (2′) and (3′), g is 0 or 1.

In addition, the repeating unit represented by General Formula (L-2) is particularly preferably a repeating unit represented by any one of the following General Formulas (1-a) to (1-c).

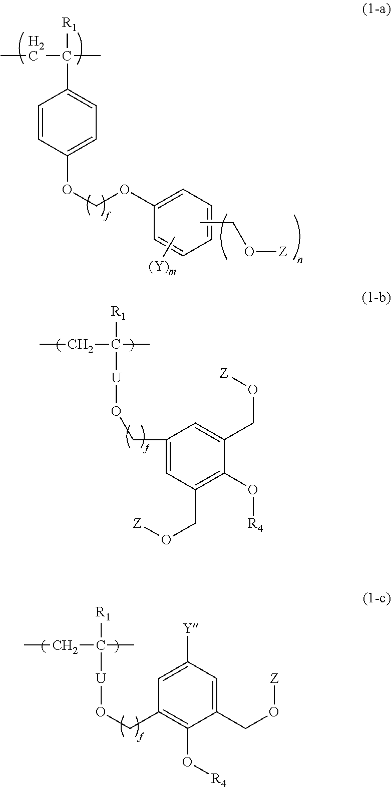

Each of R₁, Y, and Z in General Formulas (1-a) to (1-c) has the same definition as each group in General Formula (L-2), and the specific examples and the preferable range thereof are also the same.

In General Formulas (1-b) and (1-c), U represents a phenylene group or a carbonyl group.

Y″ represents a hydrogen atom or a monovalent substituent. Examples of the monovalent substituent include the same monovalent substituents as those represented by Y described above. Here, Y″ may be a methylol group.

R₄ represents a hydrogen atom or a monovalent substituent. Specific examples of the monovalent substituent include the same as those in a case where Z in General Formula (L-2) is a monovalent substituent.

f represents an integer of 1 to 6. The preferable range thereof is the same as that described in each of General Formulas (2′) and (3′).

m is 0 or 1, and n represents an integer of 1 to 3.

In General Formulas (1-b) and (1-c), examples of R₄ include a hydrogen atom, an alkyl group (which may be linear or branched, and preferably has 1 to 12 carbon atoms), an alkenyl group (which preferably has 2 to 12 carbon atoms), an alkynyl group (which preferably has 2 to 12 carbon atoms), a cycloalkyl group (which preferably has 3 to 8 carbon atoms), an aryl group (which may be a monocycle or a polycycle, and preferably has 6 to 18 carbon atoms), a haloalkyl group, an alkanoyl group, an alkoxycarbonyl group, an aryloxycarbonyl group, an alkylsulfonyloxy group, an arylsulfonyloxy group, an alkylsulfonyl group, an arylsulfonyl group, a cyano group, an alkylthio group, an arylthio group, and a heterocyclic group. Preferable examples thereof include a hydrogen atom, an alkyl group, a cycloalkyl group, and an alkanoyl group.

Specific examples of a haloalkyl group, an alkanoyl group, an alkoxycarbonyl group, an aryloxycarbonyl group, an alkylsulfonyloxy group, an arylsulfonyloxy group, an alkylsulfonyl group, an arylsulfonyl group, a cyano group, an alkylthio group, an arylthio group, and a heterocyclic group include the same as Y in General Formula (L-2), and the preferable range thereof is also the same.

Specific examples of the repeating unit represented by General Formula (L-2) will be described below, but the present invention is not limited thereto.

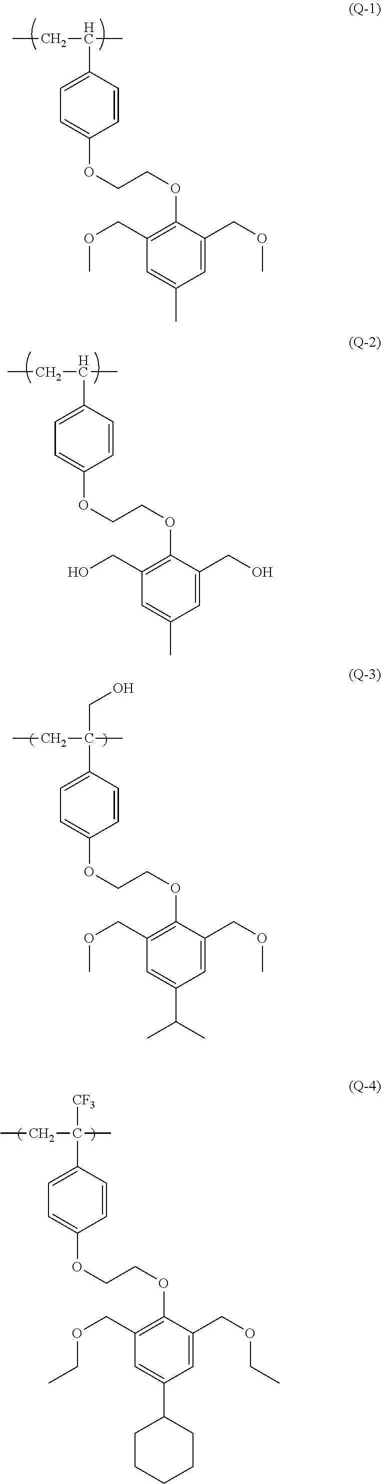

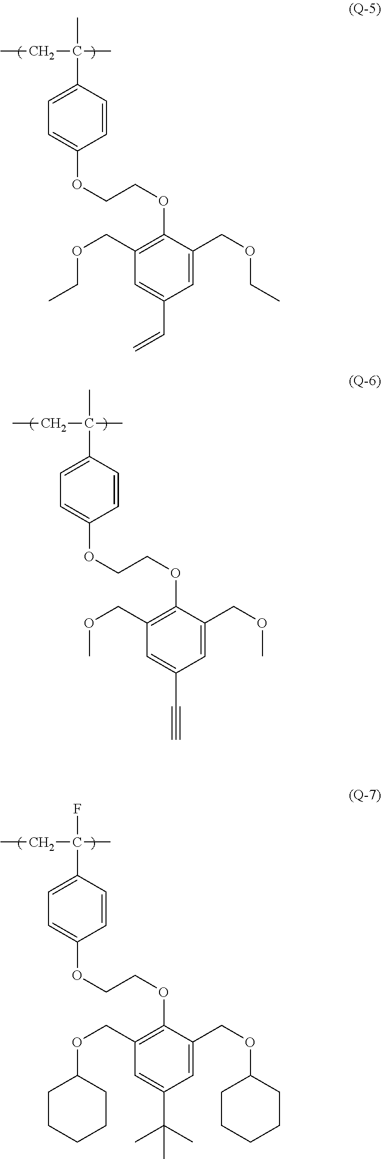

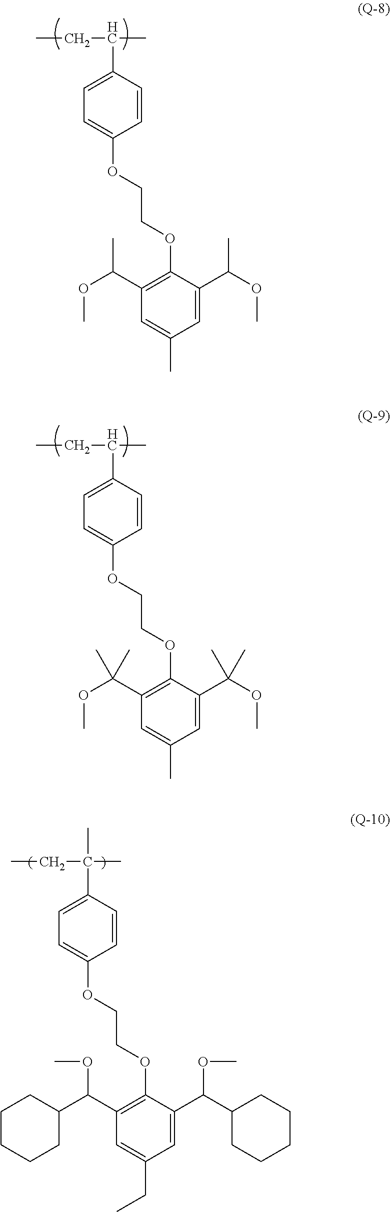

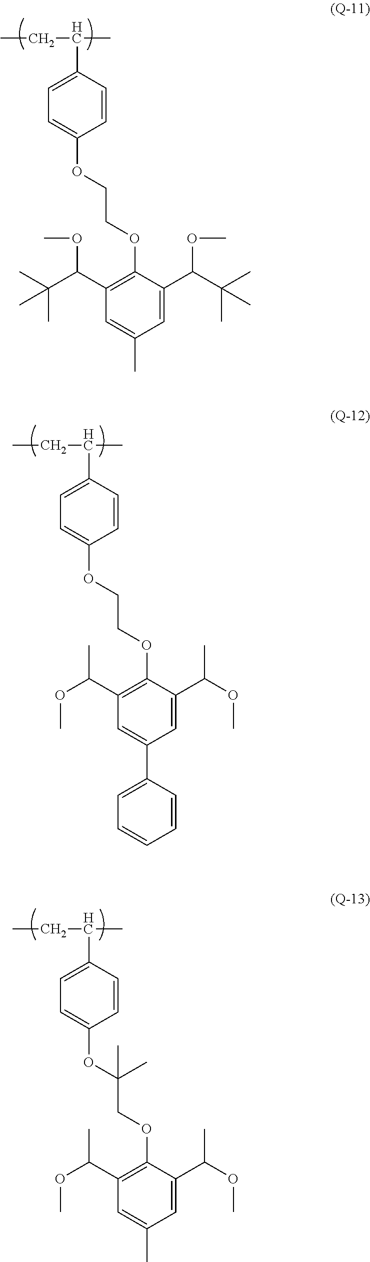

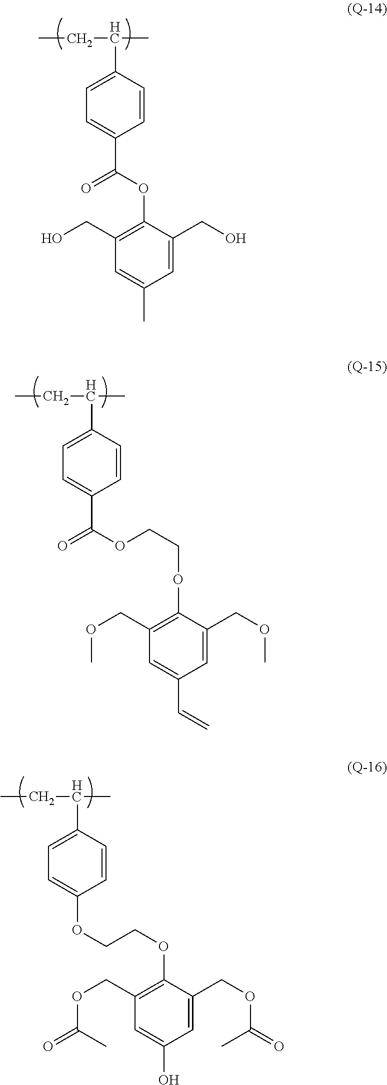

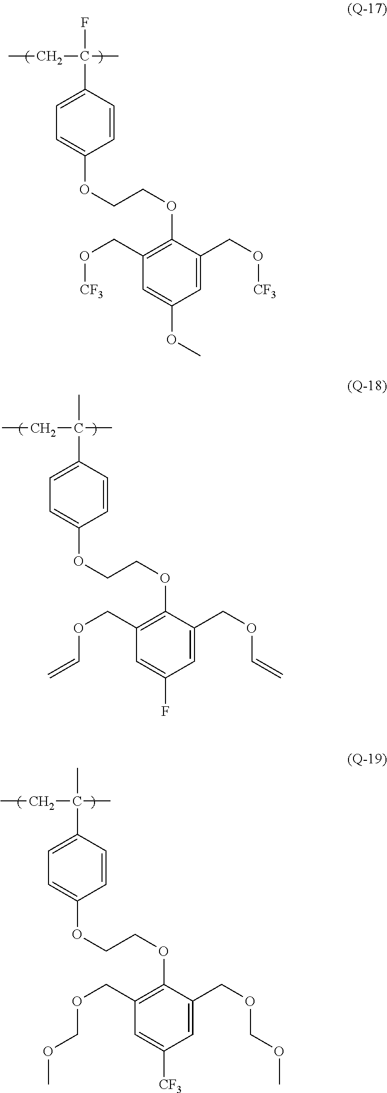

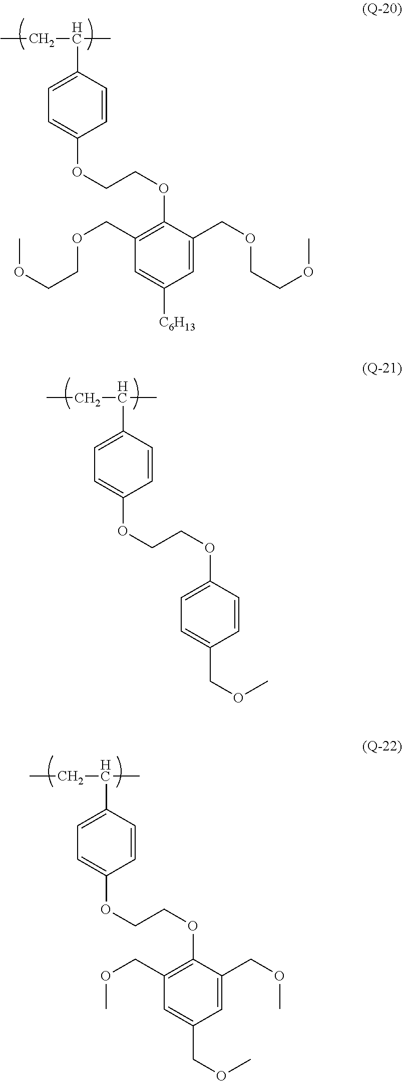

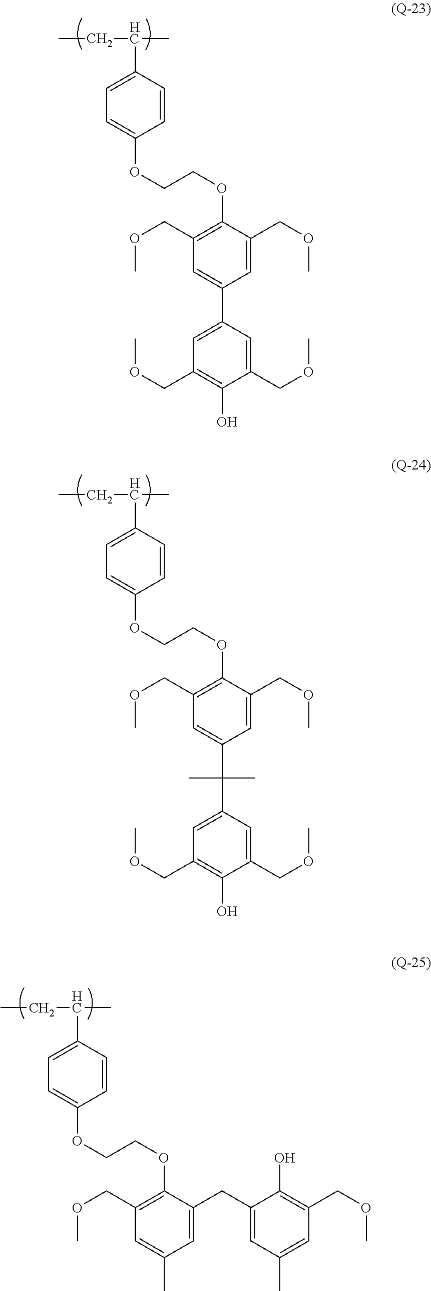

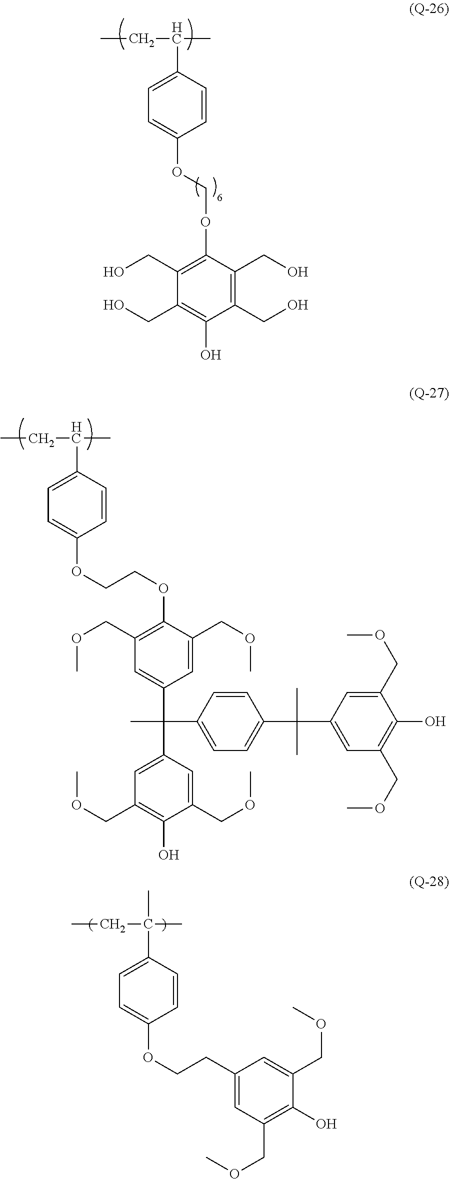

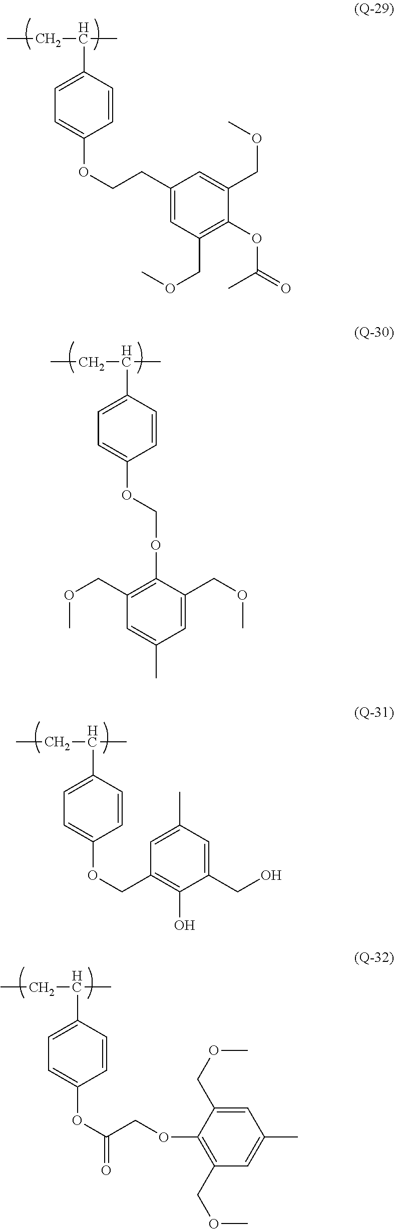

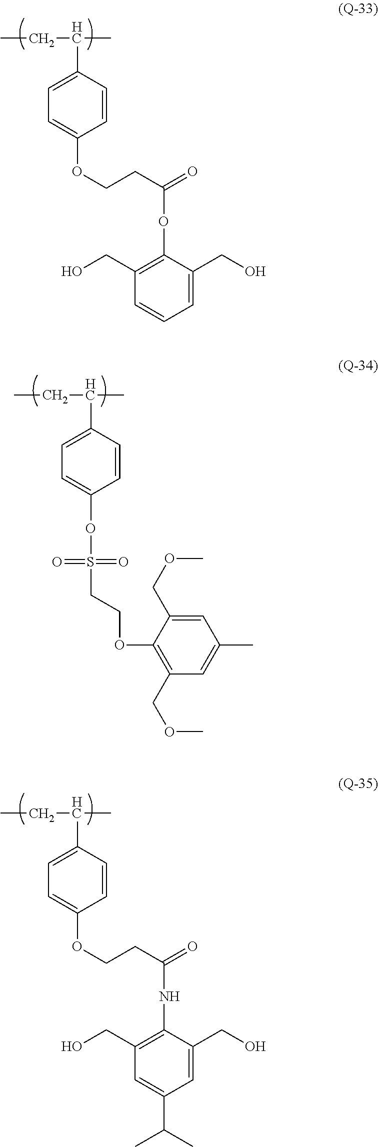

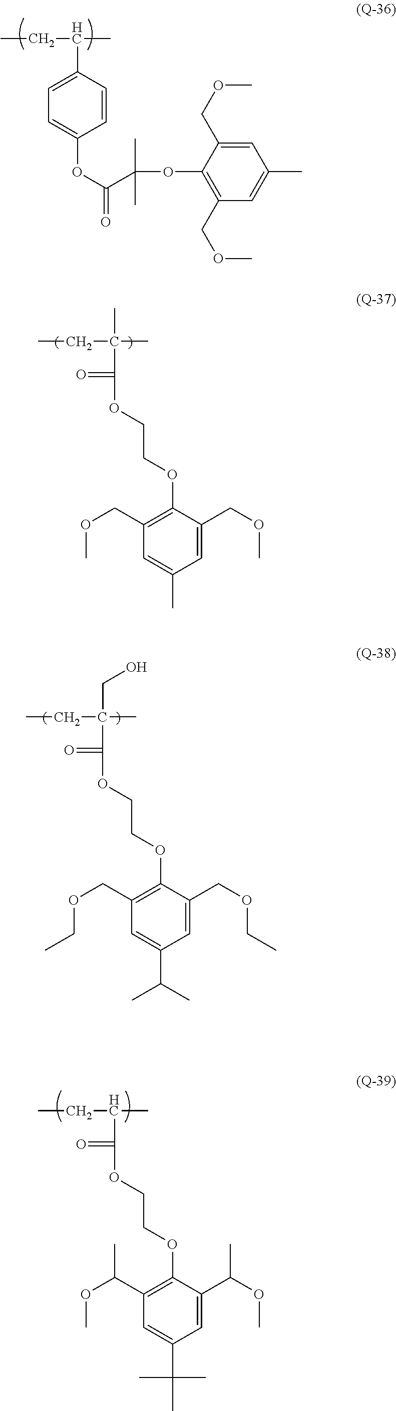

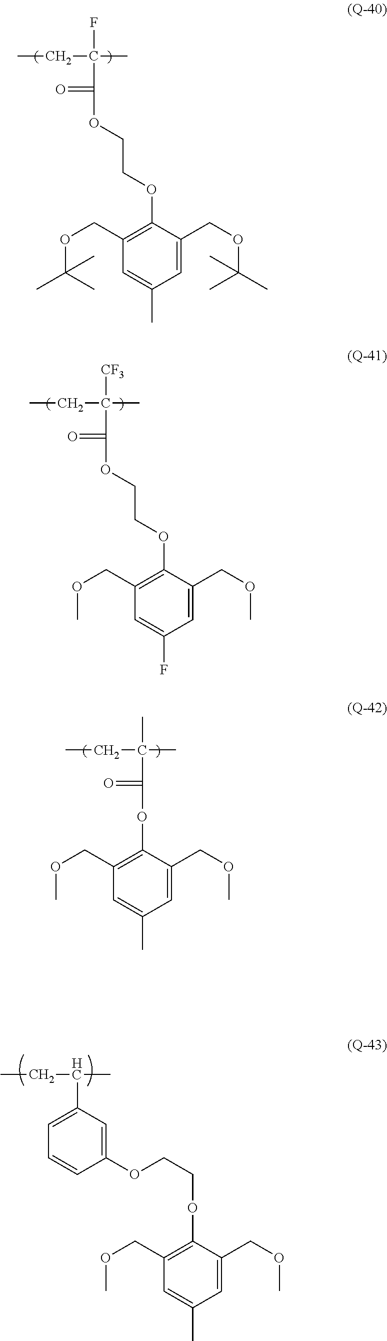

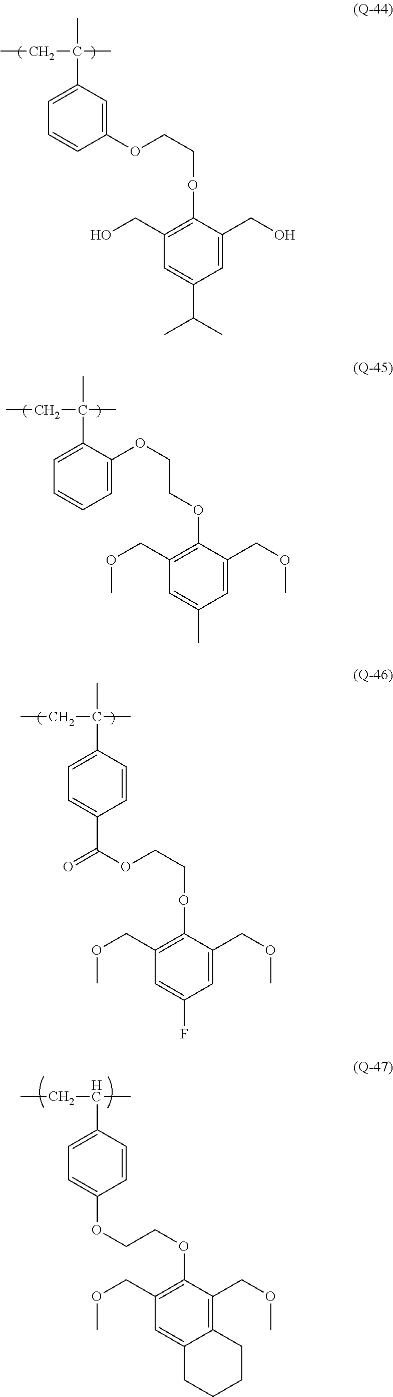

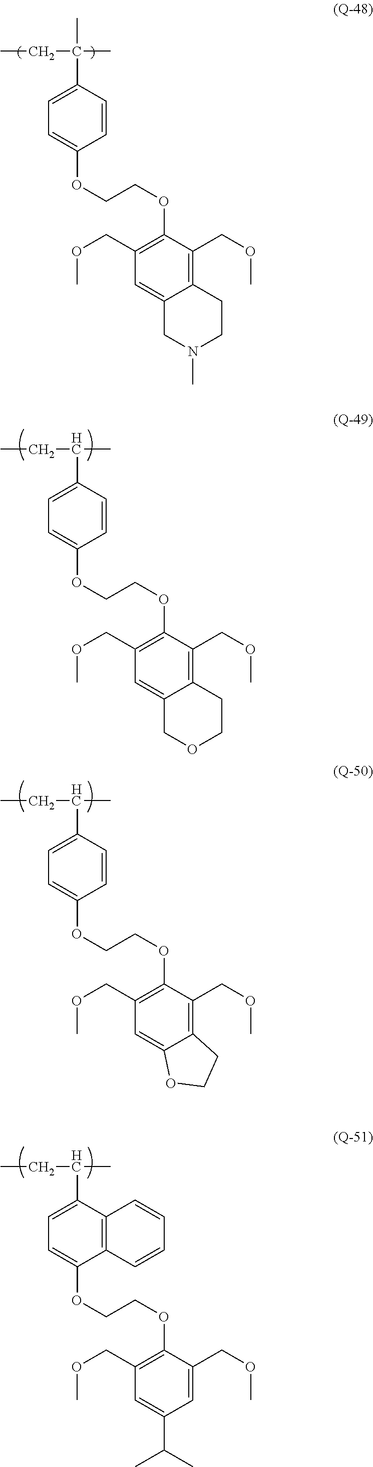

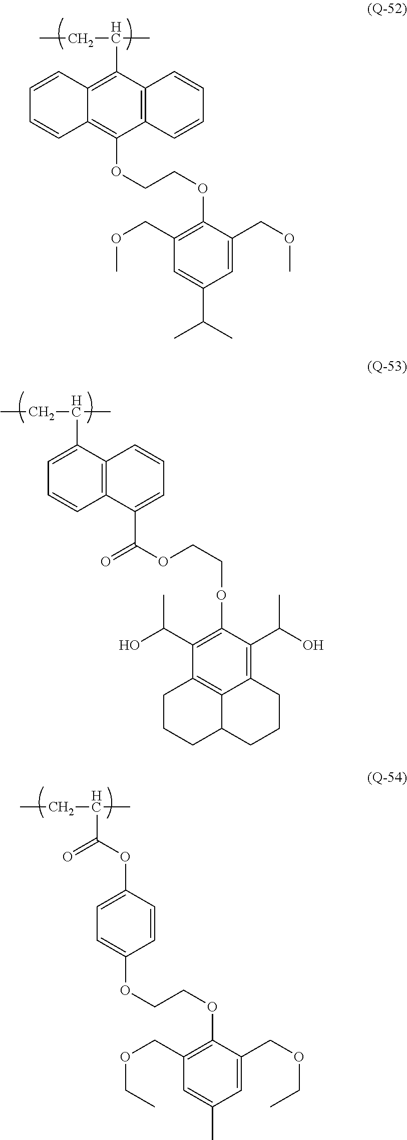

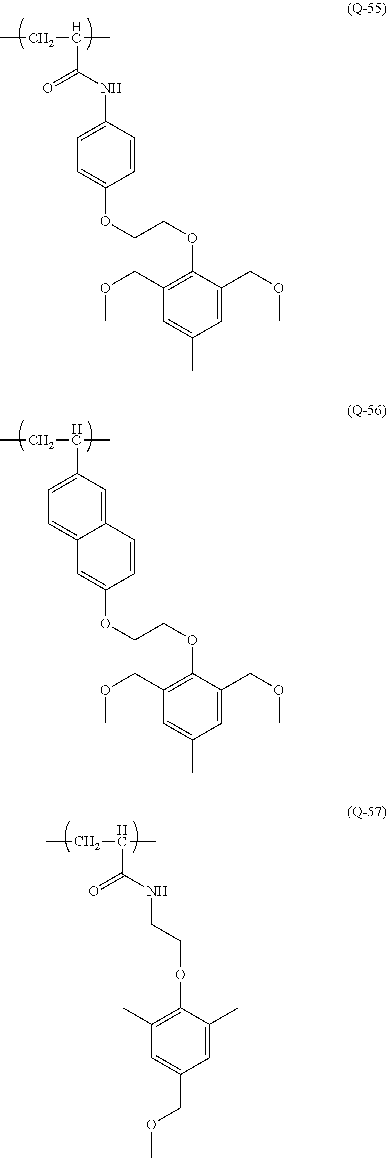

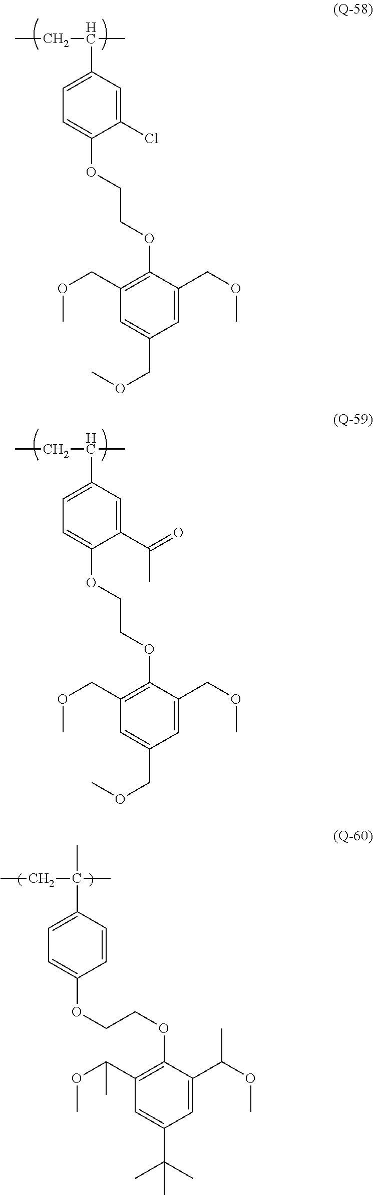

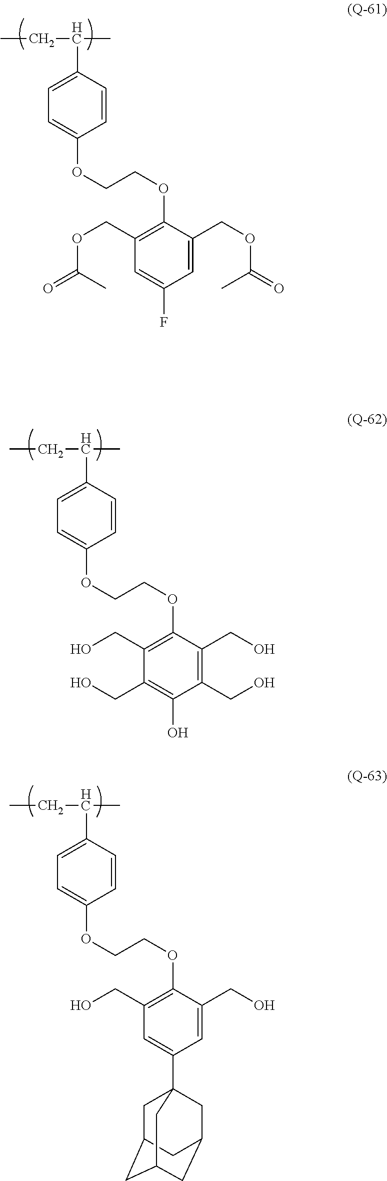

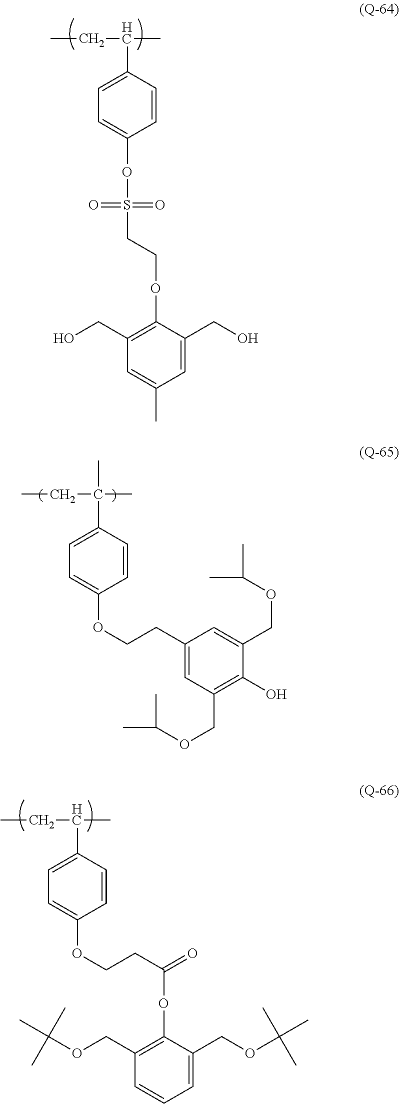

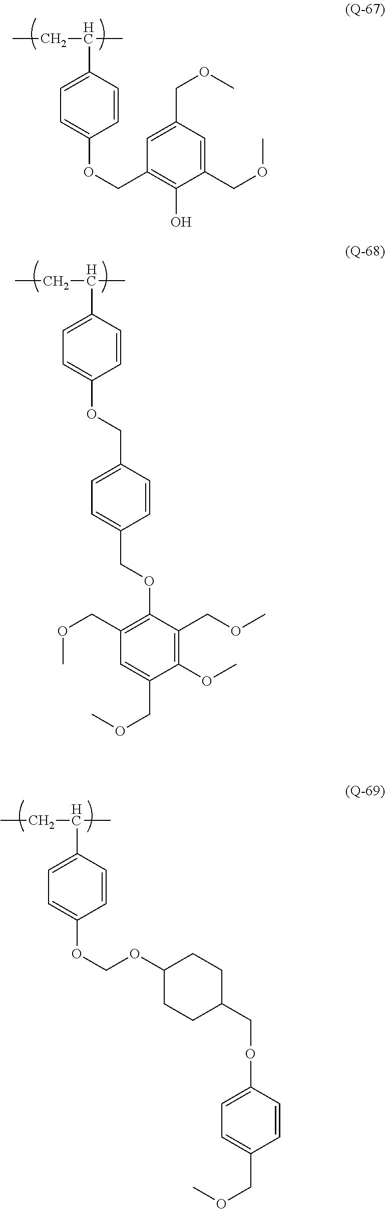

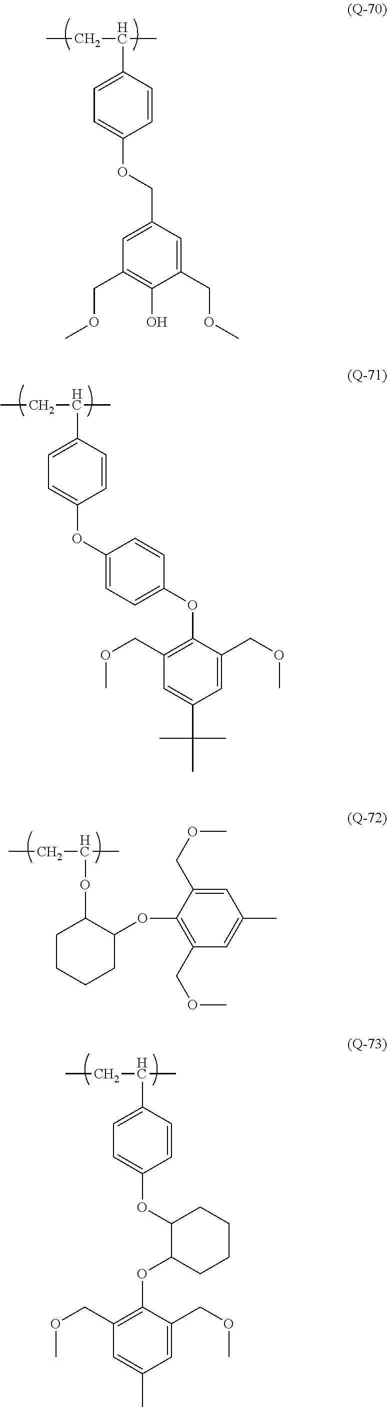

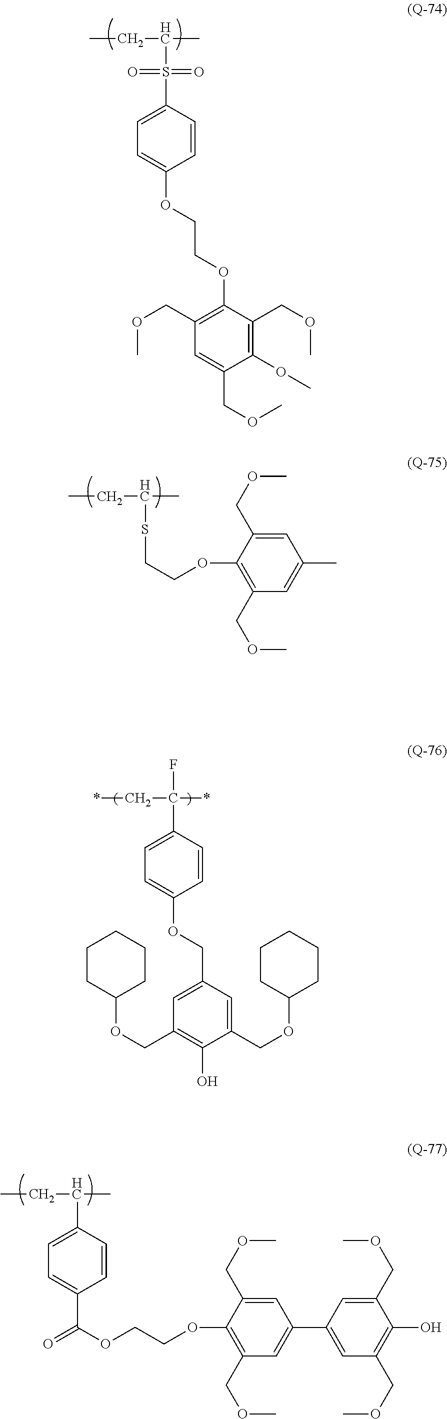

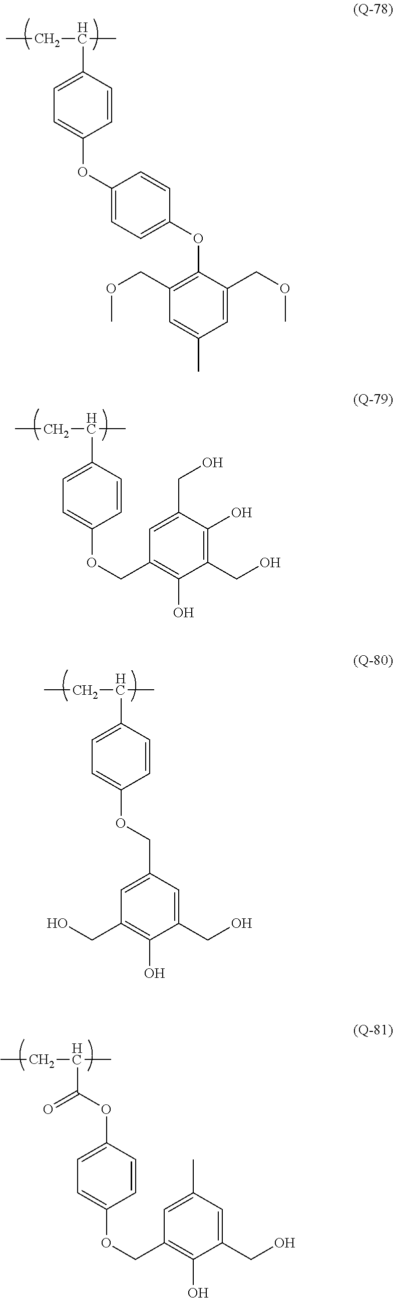

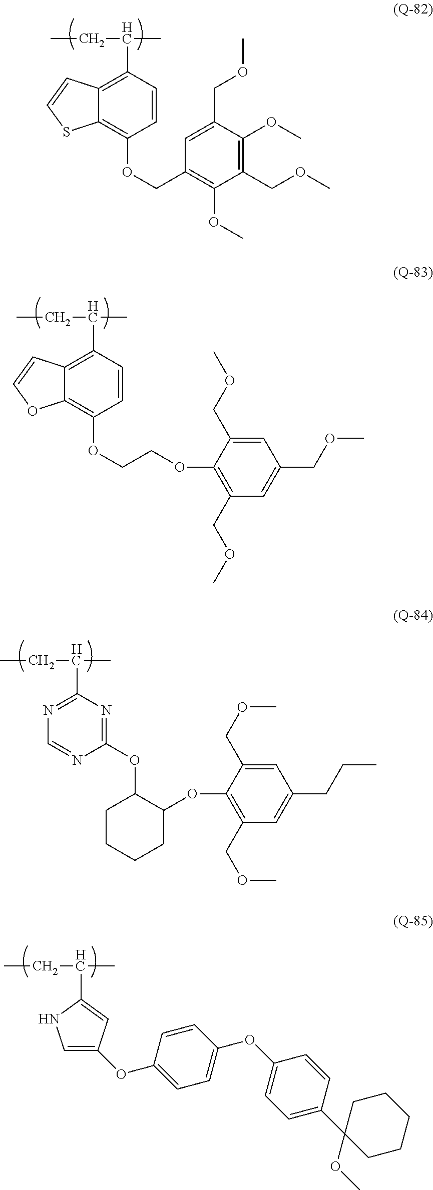

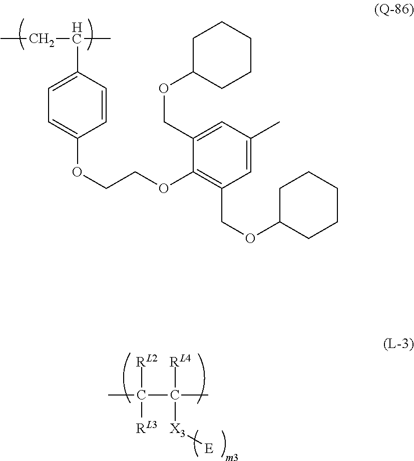

Each of R^{L2}, R^{L3}, and R^{L4} in General Formula (L-3) has the same meaning as each of R^{L2}, R^{L3}, and R^{L4} General Formula (L-1). X₃ represents a single bond, a linear or branched hydrocarbon group, a cyclic hydrocarbon group which may contain a heteroatom as a ring member, —O—, —S—, —CO—, —SO₂—, —NR— (R is a hydrogen atom, an alkyl group, or a group represented by —CH₂OR^{L1}), or an (m3+1) valent group selected from the group consisting of groups obtained by combining these. Moreover, R^{L1} in a group represented by —CH₂OR^{L1} has the same meaning as R^{L1} in General Formula (L-1).

E represents a group having an epoxy structure or an oxetane structure. m3 represents an integer of 1 to 5.

Specific examples and preferable examples of R^{L2}, R^{L3}, R^{L4}, or X₃ include the same as the specific examples and preferable examples of R^{L2}, R^{L3}, R^{L4}, or X₁ in General Formula (L-1).

Specific examples of the repeating unit represented by General Formula (L-3) will be described below, but the present invention is not limited thereto. In the following specific examples, R represents a hydrogen atom or a methyl group.

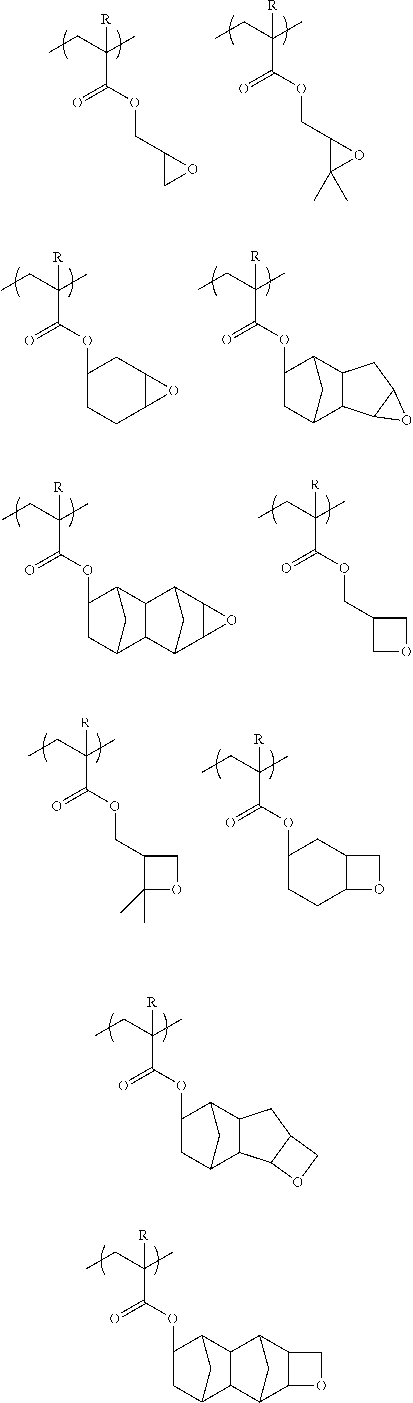

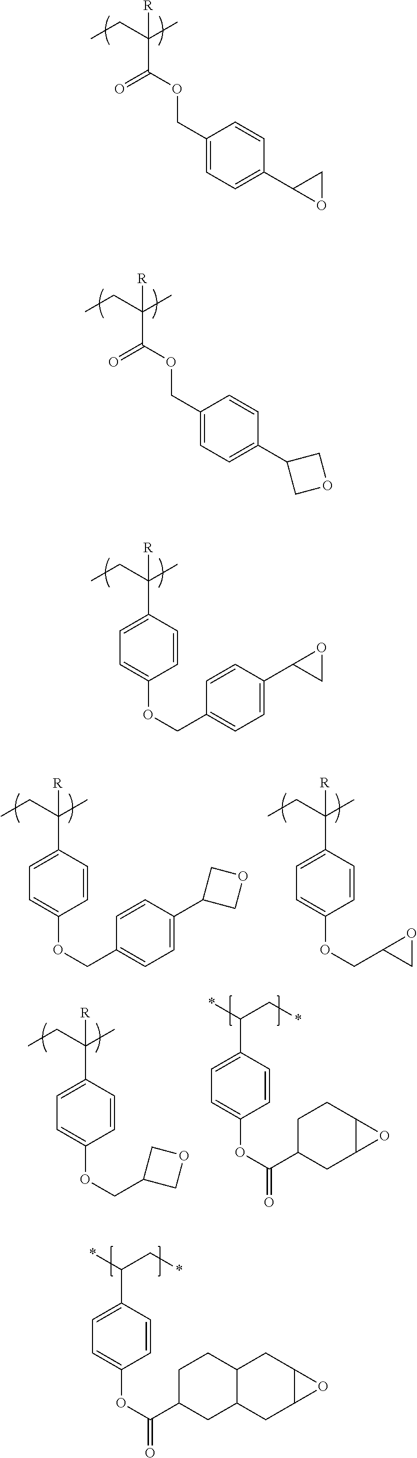

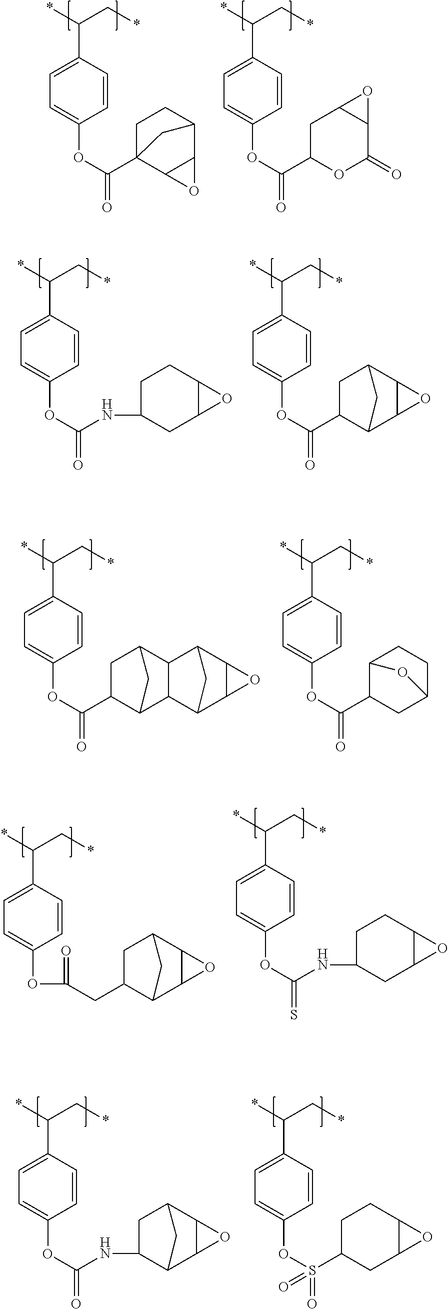

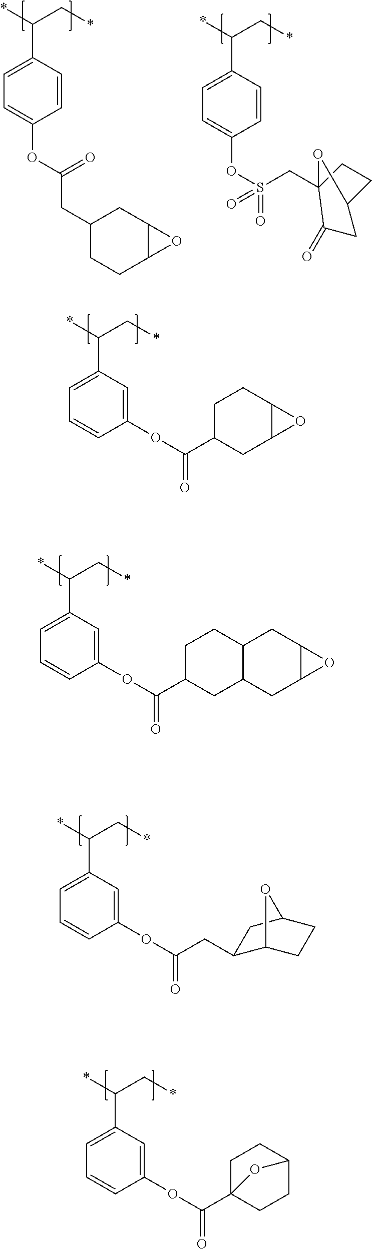

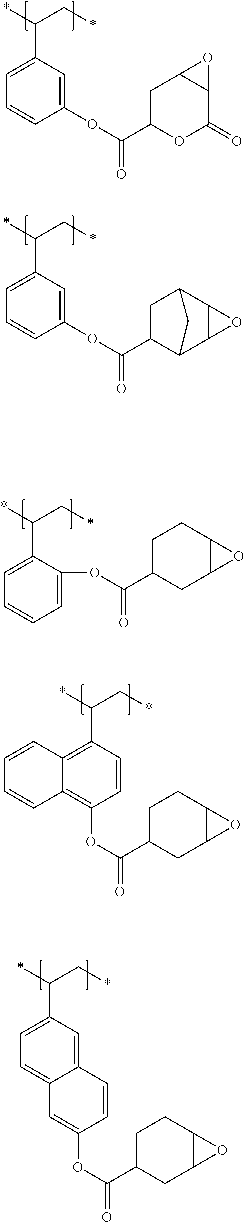

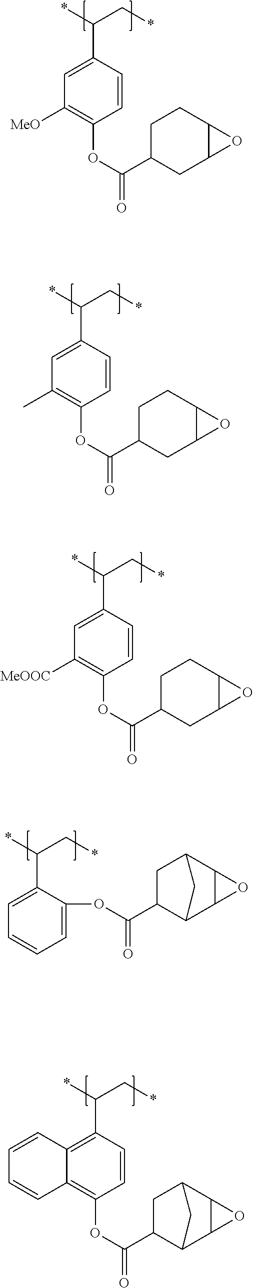

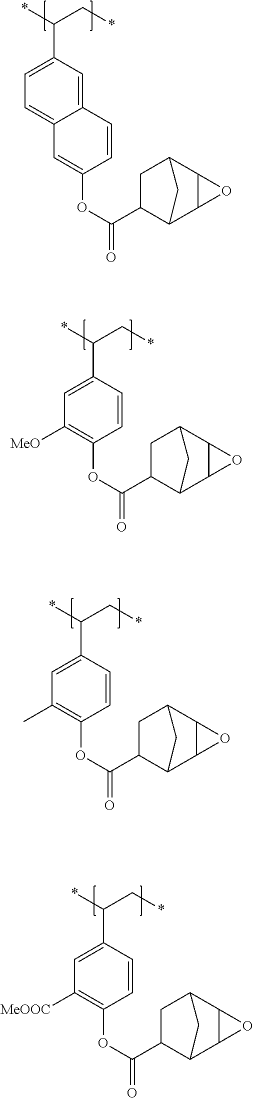

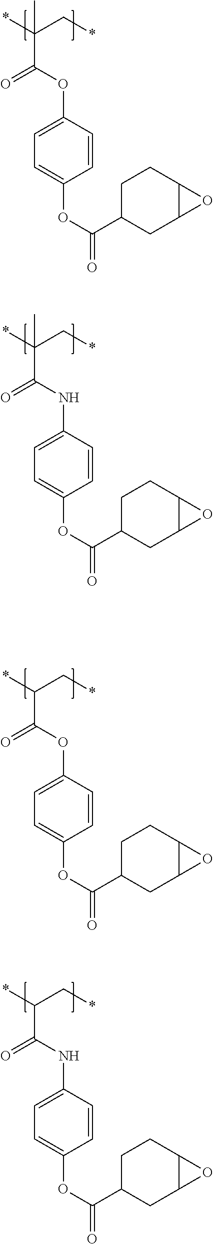

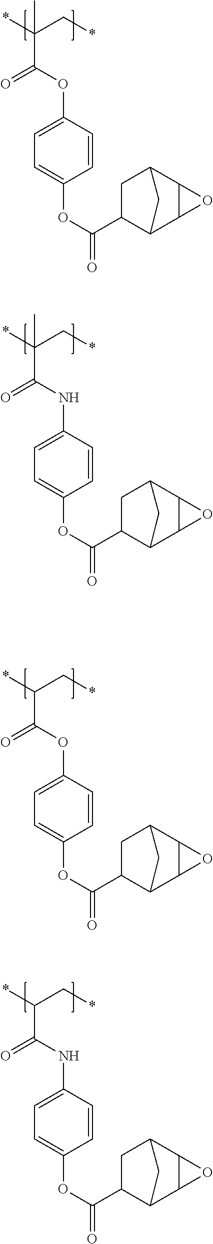

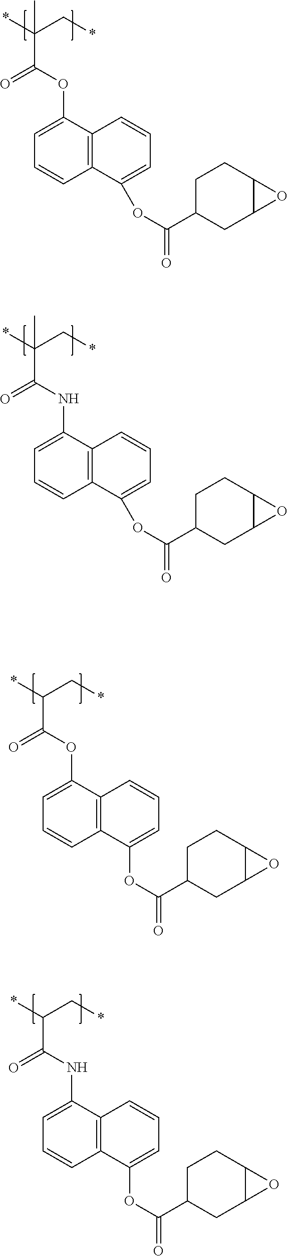

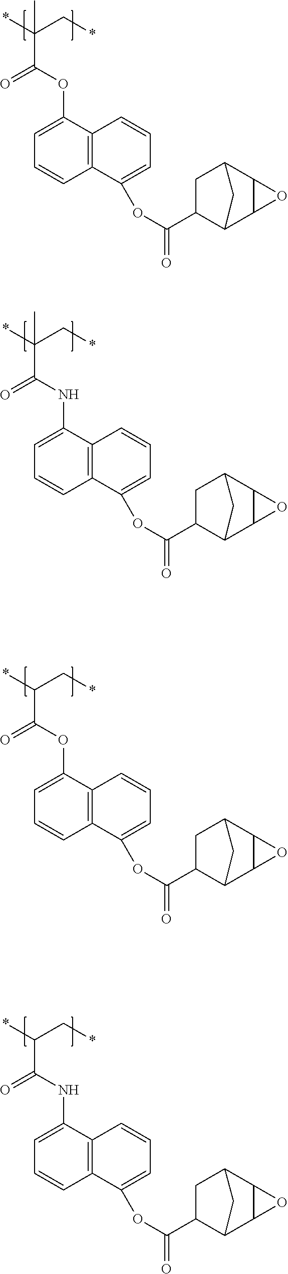

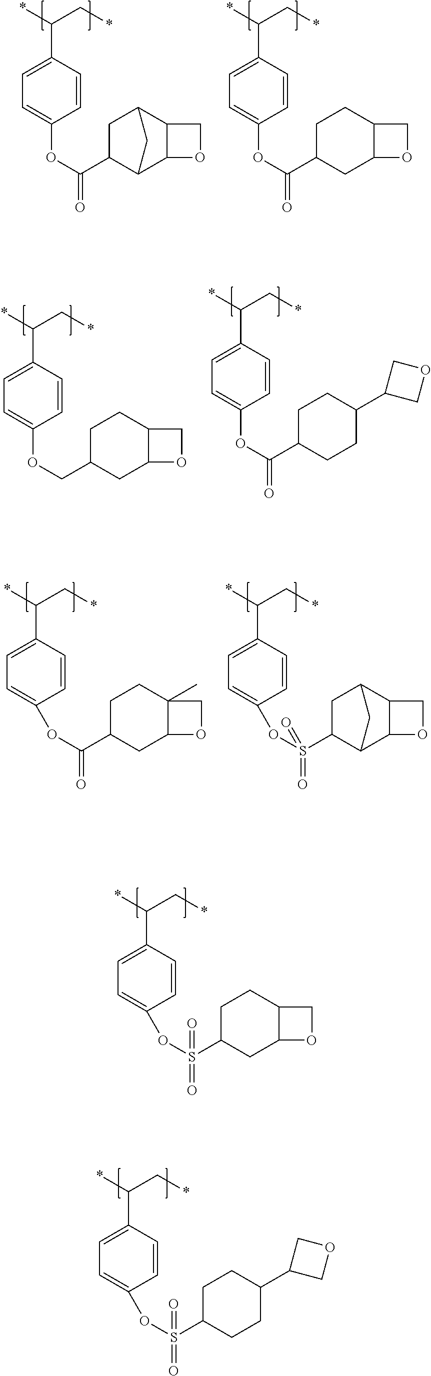

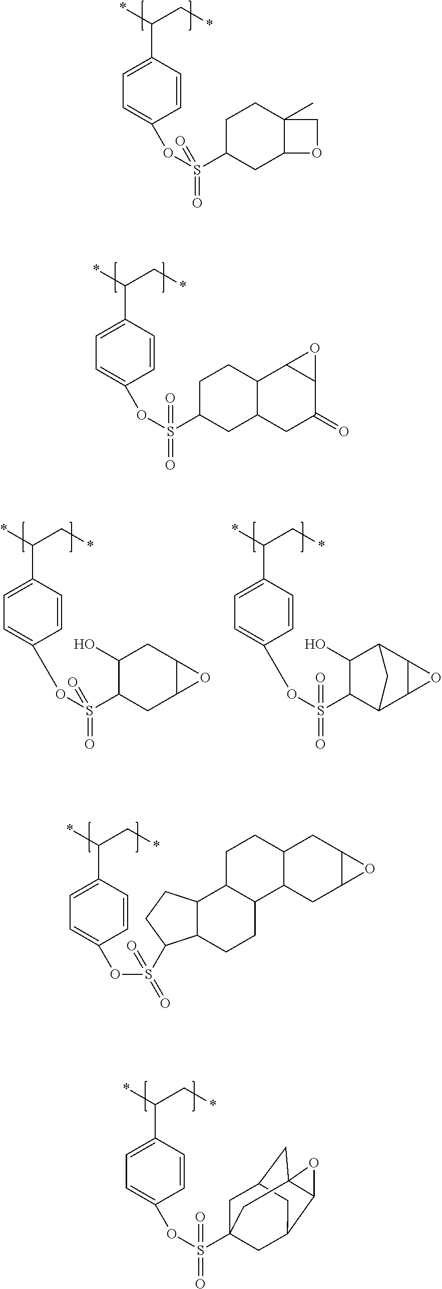

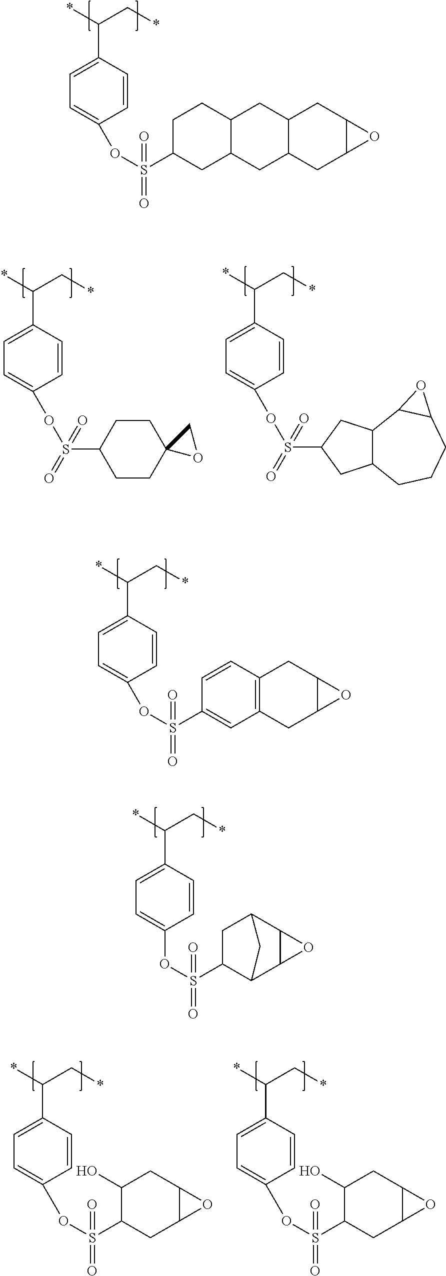

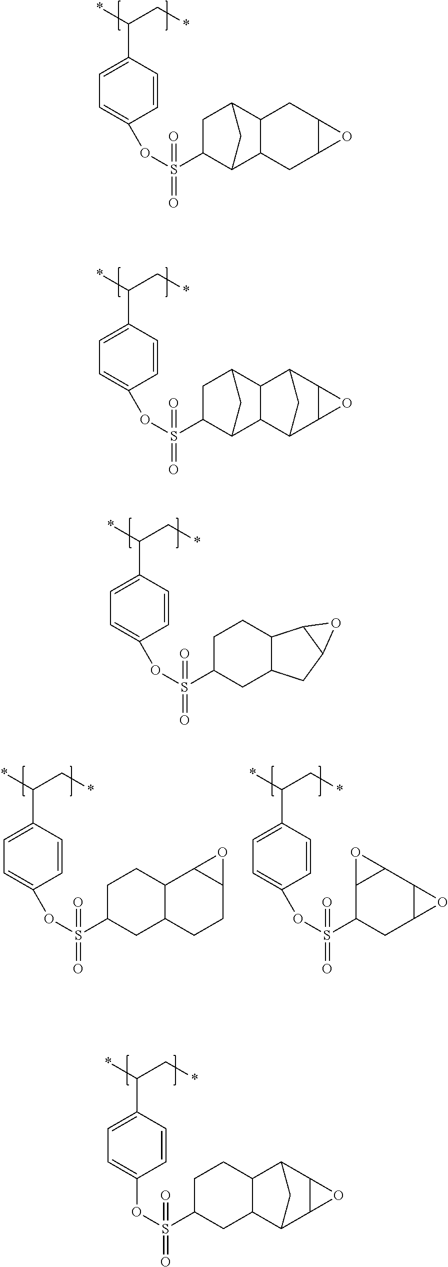

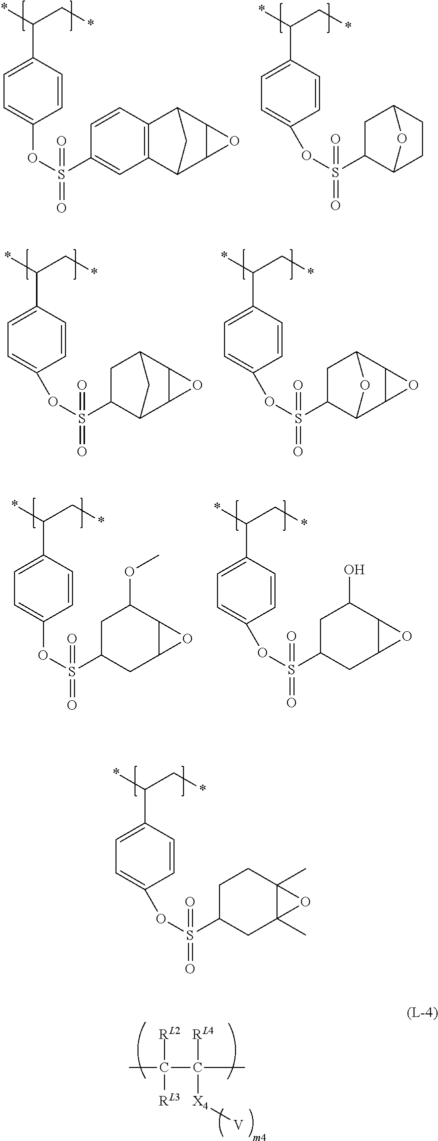

In General Formula (L-4), each of R^{L2}, R^{L3}, and R^{L4} has the same meaning as each of R^{L2}, R^{L3}, and R^{L4} General Formula (L-1). X₄ represents a single bond, a linear or branched hydrocarbon group, a cyclic hydrocarbon group which may contain a heteroatom as a ring member, —O—, —S—, —CO—, —SO₂—, —NR— (R is a hydrogen atom, an alkyl group, or a group represented by —CH₂OR^{L1}), or an (m4+1) valent group selected from the group consisting of groups obtained by combining these. Moreover, R^{L1} in a group represented by —CH₂OR^{L1} has the same meaning as R^{L1} in General Formula (L-1).

V represents a group having an ethylenically unsaturated bond. m4 represents an integer of 1 to 5.

Specific examples and preferable examples of R^{L2}, R^{L3}, R^{L4}, or X₄ include the same as the specific examples and preferable examples of R^{L2}, R^{L3}, R^{L4}, or X₁ in General Formula (L-1).

The group having an ethylenically unsaturated bond represented by V is particularly preferably a group represented by any one of the following General Formulas (1) to (3).

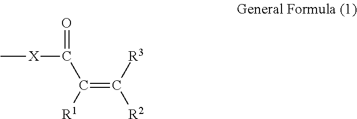

In General Formula (1), each of R¹ to R³ independently represents a hydrogen atom or a monovalent organic group, and R¹ is preferably a hydrogen atom or an alkyl group which may have a substituent, and among these, a hydrogen atom or a methyl group is preferable from the viewpoint of high radical reactivity. In addition, each of R² and R³ independently represents a hydrogen atom, a halogen atom, an amino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent, or an arylsulfonyl group which may have a substituent, and among these, a hydrogen atom, a carboxyl group, an alkoxycarbonyl group, an alkyl group which may have a substituent, or an aryl group which may have a substituent is preferable from the viewpoint of high radical reactivity.

X represents an oxygen atom, a sulfur atom, or —N(R¹²)—, and R¹² represents a hydrogen atom or a monovalent organic group. Here, examples of the monovalent organic group include an alkyl group which may have a substituent, and among these, R¹² is preferably a hydrogen atom, a methyl group, an ethyl group, an isopropyl group from the viewpoint of high radical reactivity.

Here, examples of the substituent which can be introduced include an alkyl group, an alkenyl group, an alkynyl group, an aryl group, an alkoxy group, an aryloxy group, a halogen atom, an amino group, an alkylamino group, an arylamino group, a carboxyl group, an alkoxycarbonyl group, a sulfo group, a nitro group, a cyano group, an amide group, an alkylsulfonyl group, and an arylsulfonyl group.

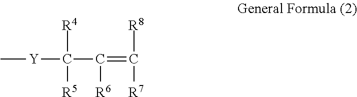

In General Formula (2), each of R⁴ to R⁸ independently represents a hydrogen atom or a monovalent organic group, and preferable examples of R⁴ to R⁸ include a hydrogen atom, a halogen atom, an amino group, a dialkylamino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent, and an arylsulfonyl group which may have a substituent, and among these, a hydrogen atom, a carboxyl group, an alkoxycarbonyl group, an alkyl group which may have a substituent, or an aryl group which may have a substituent is preferable.

As the substituent which can be introduced, the same substituents as those in General Formula (1) are exemplified. In addition, Y represents an oxygen atom, a sulfur atom, or —N(R¹²)—. R¹² has the same meaning as R¹² in General Formula (1), and the preferable examples thereof are also the same.

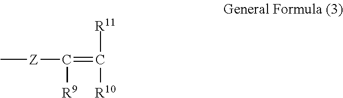

In General Formula (3), R⁹ represents a hydrogen atom or a monovalent organic group, and preferable examples thereof include a hydrogen atom or an alkyl group which may have a substituent, and among these, a hydrogen atom or a methyl group is preferable from the viewpoint of high radical reactivity. Each of R¹⁰ and R¹¹ independently represents a hydrogen atom, a halogen atom, an amino group, a dialkylamino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent, or an arylsulfonyl group which may have a substituent, and among these, a hydrogen atom, a carboxyl group, an alkoxycarbonyl group, an alkyl group which may have a substituent, or an aryl group which may have a substituent is preferable from the viewpoint of high radical reactivity.

Z represents an oxygen atom, a sulfur atom, —N(R¹²)—, or a phenylene group. R¹² has the same meaning as R¹² in General Formula (1), and the preferable examples thereof are also the same.

Specific examples of the repeating unit represented by General Formula (L-4) will be described below, but the present invention is not limited thereto. In the following specific examples, R represents a hydrogen atom or a methyl group.

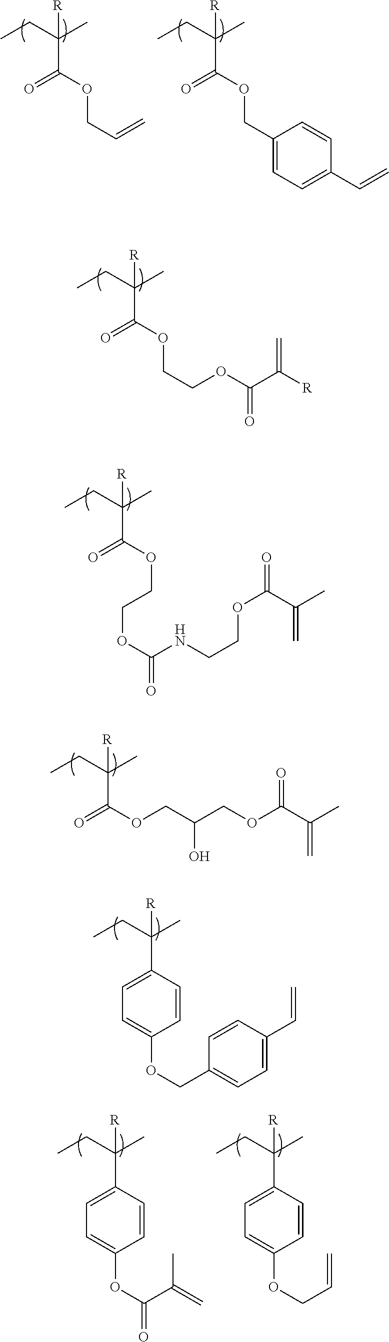

In the case of forming a negative image (that is, in a case where the active light sensitive or radiation sensitive composition is a negative type active light sensitive or radiation sensitive composition), the content of one or more types of repeating units selected from the repeating units represented by General Formulas (L-1) to (L-4) is preferably 5 mol % to 50 mol %, and more preferably 10 mol % to 40 mol %, with respect to the entirety of repeating units included in the resin [N-A]. In the case of forming a positive image (that is, in a case where the active light sensitive or radiation sensitive composition is a positive type active light sensitive or radiation sensitive composition), the content of one or more repeating units selected from the repeating units represented by General Formulas (L-1) to (L-4) is preferably 0.1 mol % to 30 mol %, more preferably 1 mol % to 20 mol %, and particularly preferably 1 mol % to 10 mol %.

The resin [N-A] may contain the repeating unit represented by General Formula (3), the repeating unit (c) having a polar group, the repeating unit (d) having a plurality of aromatic rings described in the resin [P-A], or other repeating units, in addition to one ore more types of repeating units selected from the repeating units represented by General Formulas (L-1) to (L-4), and the preferable range of the content of each repeating unit with respect to the entirety of repeating units in the resin [N-A] is the same as the preferable range of the content of each repeating unit with respect to the entirety of repeating units in the resin [P-A].

In addition, the synthetic method, and the preferable ranges of the mass average molecular weight and dispersity of the resin [N-A] are the same as those described in the resin [P-A].

The resin [N-A] may be the same component as the resin [P-A], or may be a different component from the resin [P-A]. The resin in a case where the components of the resin [N-A] and the resin [P-A] are the same is preferably a resin having a repeating unit having the acid-decomposable group and one or more types of repeating units selected from the repeating units represented by General Formulas (L-1) to (L-4).

The resin [N-A] may be the same component as the compound [N-B] below, or may be a different component from the compound [N-B], but is preferably a different component from the compound [N-B].

The resin [N-A] of the present invention can be used alone, or two or more types thereof can be used in combination. The content of the resin [N-A] is preferably 20% by mass to 99% by mass, more preferably 30% by mass to 99% by mass, and still more preferably 40% by mass to 99% by mass, based on the total solid content of the active light sensitive or radiation sensitive composition of the present invention.

[N-B] Compound that Generates Acid by Irradiation with Active Light or Radiation, and of which Solubility in Alkali Developers is Decreased by Action of Acid, Active Light or Radiation, or Activated Species

The compound [N-B] (hereinafter, also simply referred to as an acid generator [N-B]) that generates an acid by irradiation with active light or radiation, and of which the solubility in alkali developers is decreased by the action of an acid, active light or radiation, or an activated species is preferably a compound which has a polymerizable group and generates an acid by irradiation with active light or radiation.

The molecular weight range of the compound [N-B] is preferably 100 to 3000, more preferably 100 to 2000, and particularly preferably 100 to 1000.

The polymerizable group is preferably a polymerizable group which can be polymerized by the action of an acid, active light or radiation, or an activated species, and preferably a polymerizable group which can be polymerized by the action of an acid or an activated species (for example, a radical). In addition, a cross-linking group can also be included in the polymerizable group.

Example of the acid generator [N-B] include a diazonium salt, a phosphonium salt, a sulfonium salt, an iodonium salt, imide sulfonate, oxime sulfonate, diazodisulfone, disulfone, and o-nitrobenzyl sulfonate, and an onium salt compound such as a sulfonium salt is preferable, and a salt represented by the following General Formula (ZI′) is more preferable.

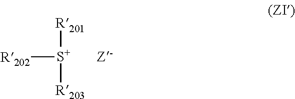

In General Formula (ZI′), each of R′₂₀₁, R′₂₀₂, and R′₂₀₃ independently represents an organic group.

The organic group represented by each of R′₂₀₁, R′₂₀₂, and R′₂₀₃ generally has 1 to 30 carbon atoms, and preferably has 1 to 20 carbon atoms.

In addition, two of R′₂₀₁ to R′₂₀₃ may be bonded to each other to form a ring structure, and an oxygen atom, a sulfur atom, an ester bond, an amide bond, or a carbonyl group may be included in the ring. Examples of the group that two of R′₂₀₁ to R′₂₀₃ form by bonding to each other include an alkylene group (for example, a butylene group and a pentylene group).

Z′⁻ represents a non-nucleophilic anion.

At least one of R′₂₀₁, R′₂₀₂, R′₂₀₃, and Z′⁻ has a polymerizable group. From the viewpoint of suppressing diffusion of the generated acid, Z′⁻ preferably has a polymerizable group.

The polymerizable group in the acid generator [N-B] is not particularly limited, and examples thereof include an ethylenically unsaturated group, an epoxy group, an oxetane group, and a group represented by the following General Formula (ZII).

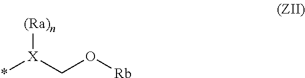

In General Formula (ZII), X represents an oxygen atom, a nitrogen atom, or a (n+2) valent aromatic group, and each of Ra and Rb independently represents a hydrogen atom or a monovalent organic group.

n represents an integer of 0 to 6, and in a case where X is an oxygen atom, n is 0, in a case where X is an nitrogen atom, n is 1, and in a case where X is a (n+2) valent aromatic group, n is an integer of 0 to 6. * represents a direct bond.

The (n+2) valent aromatic group represented by X is preferably an aromatic group having 6 to 10 carbon atoms, and examples thereof include a benzene ring group and a naphthalene ring group.

Examples of the monovalent organic group represented by Ra or Rb include an alkyl group, an aryl group, —COORc, —CON(Rc)₂, and —CORc (Rc represents a monovalent organic group).

Each of Ra and Rb is particularly preferably a hydrogen atom, an alkyl group, a cycloalkyl group, an aryl group, —COORc, —CON(Rc)₂, or —CORc.

Examples of the monovalent organic group represented by Rc include an alkyl group, a cycloalkyl group, an aryl group, and an alkyl group or an aryl group is preferable.

Examples of the alkyl group represented by each of Ra to Rc include an alkyl group having 1 to 10 carbon atoms, and a group having 1 to 4 carbon atoms such as a methyl group, an ethyl group, an n-propyl group, an isopropyl group, an n-butyl group, an isobutyl group, or a t-butyl group is preferable.

Examples of the cycloalkyl group represented by each of Ra to Rc include a cycloalkyl group having 3 to 20 carbon atoms such as a cyclopentyl group or a cyclohexyl group.

The aryl group represented by each of Ra to Rc is preferably has 6 to 10 carbon atoms, and specific examples thereof include a phenyl group and a naphthyl group.

Examples of the ethylenically unsaturated group as the polymerizable group include a (meth)acrylate group, a vinyl group, a crotonate group, an isocrotonate group, an itaconate group, and a malate group, and a (meth)acrylate group or a vinyl group is preferable, and a (meth)acrylate group is more preferable.

The polymerizable group which the acid generator [N-B] has is particularly preferably a (meth)acrylate group, an epoxy group, or a group represented by General Formula (ZII).

Although the number of polymerizable groups in one molecule of the acid generator [N-B] is not particularly limited, the number of polymerizable groups is preferably 1 to 10, more preferably 1 to 5, and particularly preferably 1 to 3.

Specific examples and preferable examples of the non-nucleophilic anion represented by Z′⁻ include the same as those described for the non-nucleophilic anion represented by Z⁻ in General Formula (ZI) which is the acid generator [P-B]. Here, the non-nucleophilic anion represented by Z′⁻ preferably does not have an acid-decomposable group.

In a case where the non-nucleophilic anion represented by Z′⁻ is represented by General Formula (I) in the acid generator [P-B], and the polymerizable group is included in the anion represented by General Formula (I), the polymerizable group may be included in any group of Xf, R₁, R₂, L, Cy, and Rf, but is preferably included in Rf or Cy, and particularly preferably included in Cy.

Specific examples and preferable examples of the polymerizable group are as described above.

In a case where the anion Z′⁻ (for example, anion that generates an acid represented by General Formula (I)) has a polymerizable group, the polymerizable group may be bonded to the anion through a divalent connecting group, and an aspect in which Cy is substituted with the polymerizable group through a divalent connecting group is exemplified.

The divalent connecting group is not particularly limited, and examples thereof include —COO—, —OCO—, —O—, an alkylene group, or a connecting group obtained by combining a plurality of these.

Examples of a more preferable structure of the compound represented by General Formula (ZI′) include the compounds (ZI-1), (ZI-2), (ZI-3), and (ZI-4) described in the acid generator [P-B]. Here, the compounds (ZI-1), (ZI-2), (ZI-3), and (ZI-4) as the compound represented by General Formula (ZI′) preferably do not have an acid-decomposable group.

In the case of having a polymerizable group on the cation in the compound (ZI-1) as the compound represented by General Formula (ZI′), at least one of R₂₀₁ to R₂₀₃ (corresponding to R′₂₀₁ to R′₂₀₃ in General Formula (ZI′), respectively,) can have a polymerizable group.

Specific examples and preferable examples of the polymerizable group which R₂₀₁ to R₂₀₃ can have are as described above.

In a case where at least one of R₂₀₁ to R₂₀₃ has a polymerizable group, the polymerizable group may be bonded to the cation structure through a divalent connecting group.

The divalent connecting group is not particularly limited, and examples thereof include —COO—, —OCO—, —O—, —CO—, —NH—, an alkylene group, or a connecting group obtained by combining a plurality of these.

In particular, in a case where the polymerizable group is a group represented by General Formula (ZII), and X in General Formula (ZII) is an (n+2) valent aromatic group, at least one aryl group of R₂₀₁ to R₂₀₃ may be X which is an (n+2) valent aromatic group.

In the case of having a polymerizable group on the cation in the compound (ZI-2) as the compound represented by General Formula (ZI′), at least one of R₂₀₁ to R₂₀₃ (corresponding to R′₂₀₁ to R′₂₀₃ in General Formula (ZI′), respectively,) can have a polymerizable group.

Specific examples and preferable examples of the polymerizable group which R₂₀₁ to R₂₀₃ can have are as described above.

In a case where at least one of R₂₀₁ to R₂₀₃ has a polymerizable group, the polymerizable group may be bonded to the cation structure through a divalent connecting group.

The divalent connecting group is not particularly limited, and examples thereof include —COO—, —OCO—, —O—, —CO—, —NH—, an alkylene group, or a connecting group obtained by combining a plurality of these.

In the case of having a polymerizable group on the cation in the compound (ZI-3) as the compound represented by General Formula (ZI′), any of R_{1c} to R_{7c} may be a polymerizable group, and at least one of R_{1c} to R_{7c}, Rₓ, and R_{y} may have the polymerizable group as a substituent.

In addition, the polymerizable group may be bonded to the cation structure through a divalent connecting group.

The divalent connecting group is not particularly limited, and examples thereof include —COO—, —OCO—, —O—, —CO—, —NH—, an alkylene group, or a connecting group obtained by combining a plurality of these.

Specific examples and preferable examples of the polymerizable group are as described above.

In particular, in a case where the polymerizable group is a group represented by General Formula (ZII), and X in General Formula (ZII) is an (n+2) valent aromatic group, the benzene ring in General Formula (ZI-3) may be X which is an (n+2) valent aromatic group.

In the case of having a polymerizable group on the cation in the compound (ZI-4) as the compound represented by General Formula (ZI′), any one of R₁₃ and R₁₄ may be a polymerizable group, and at least one of R₁₃ to R₁₅ may have the polymerizable group as a substituent.

In addition, the polymerizable group may be bonded to the cation structure through a divalent connecting group.

The divalent connecting group is not particularly limited, and examples thereof include —COO—, —OCO—, —O—, —CO—, —NH—, an alkylene group, or a connecting group obtained by combining a plurality of these.

Specific examples and preferable examples of the polymerizable group are as described above.

In particular, in a case where the polymerizable group is a group represented by General Formula (ZII), Ra in General Formula (ZII) and the aromatic ring to which R₁₃ in General Formula (ZI-4) is bonded may be bonded to each other to form a ring (preferably, a 5- or 6-membered ring).

Specific examples of the acid generator [N-B] will be described below, but the present invention is not limited thereto.

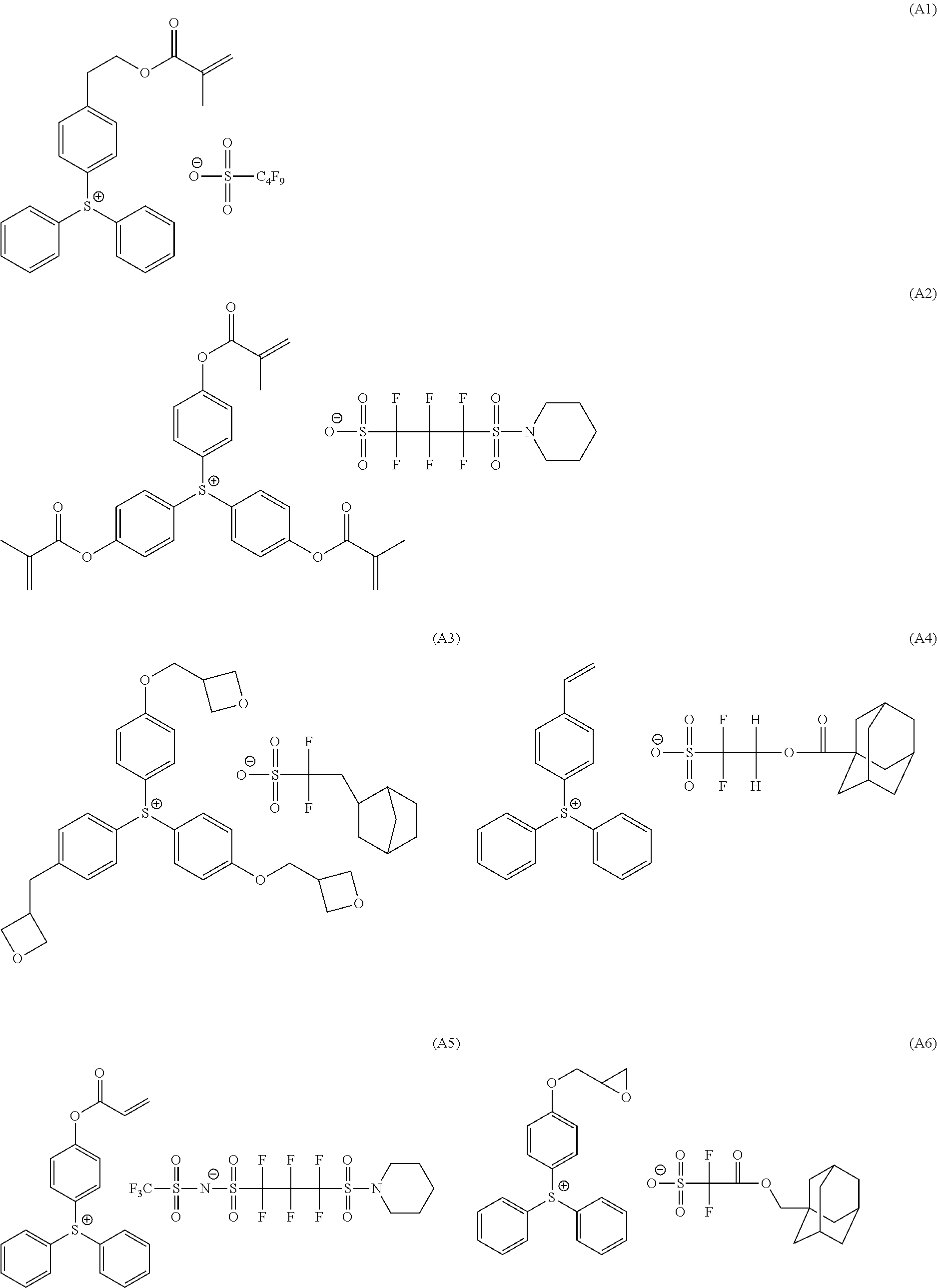

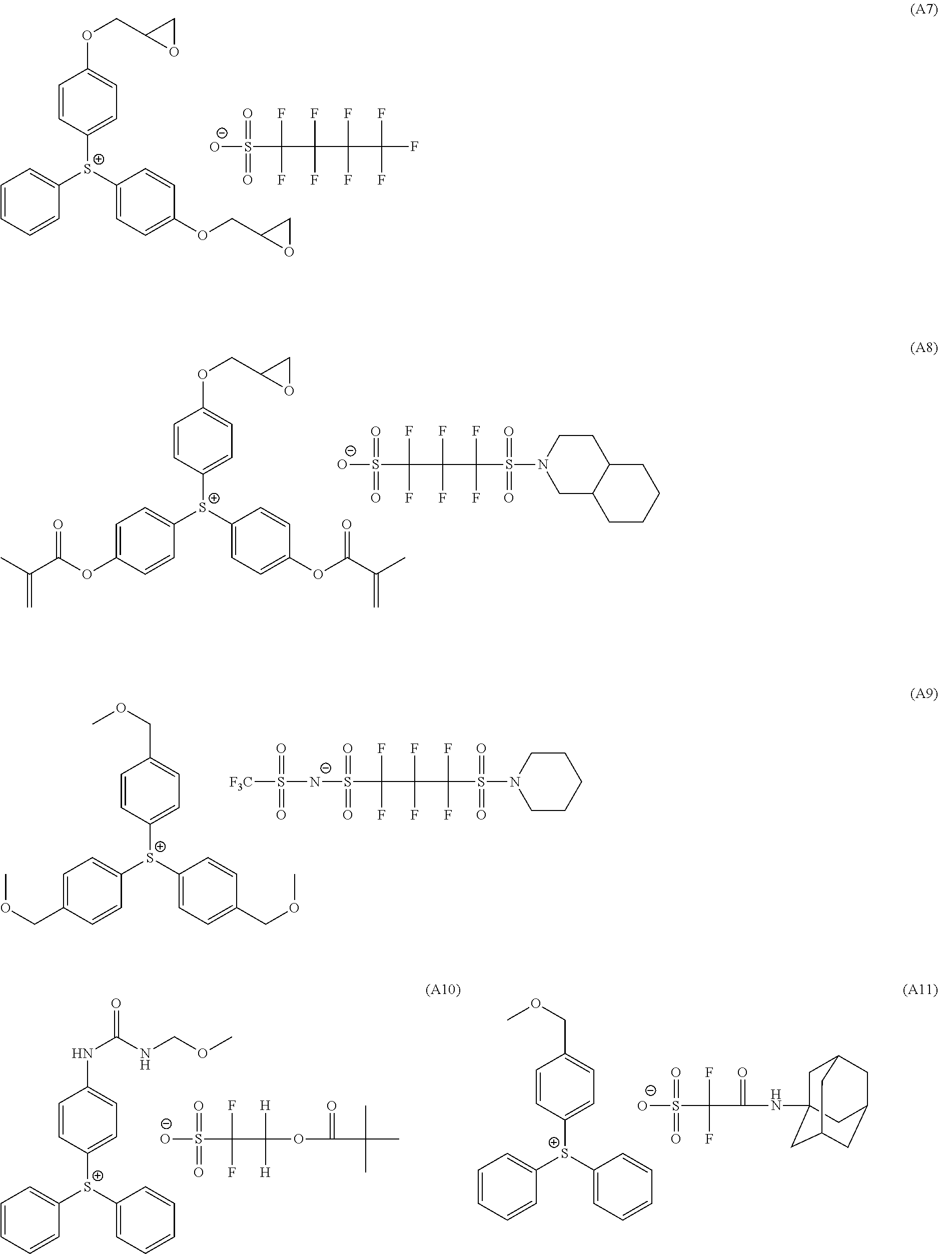

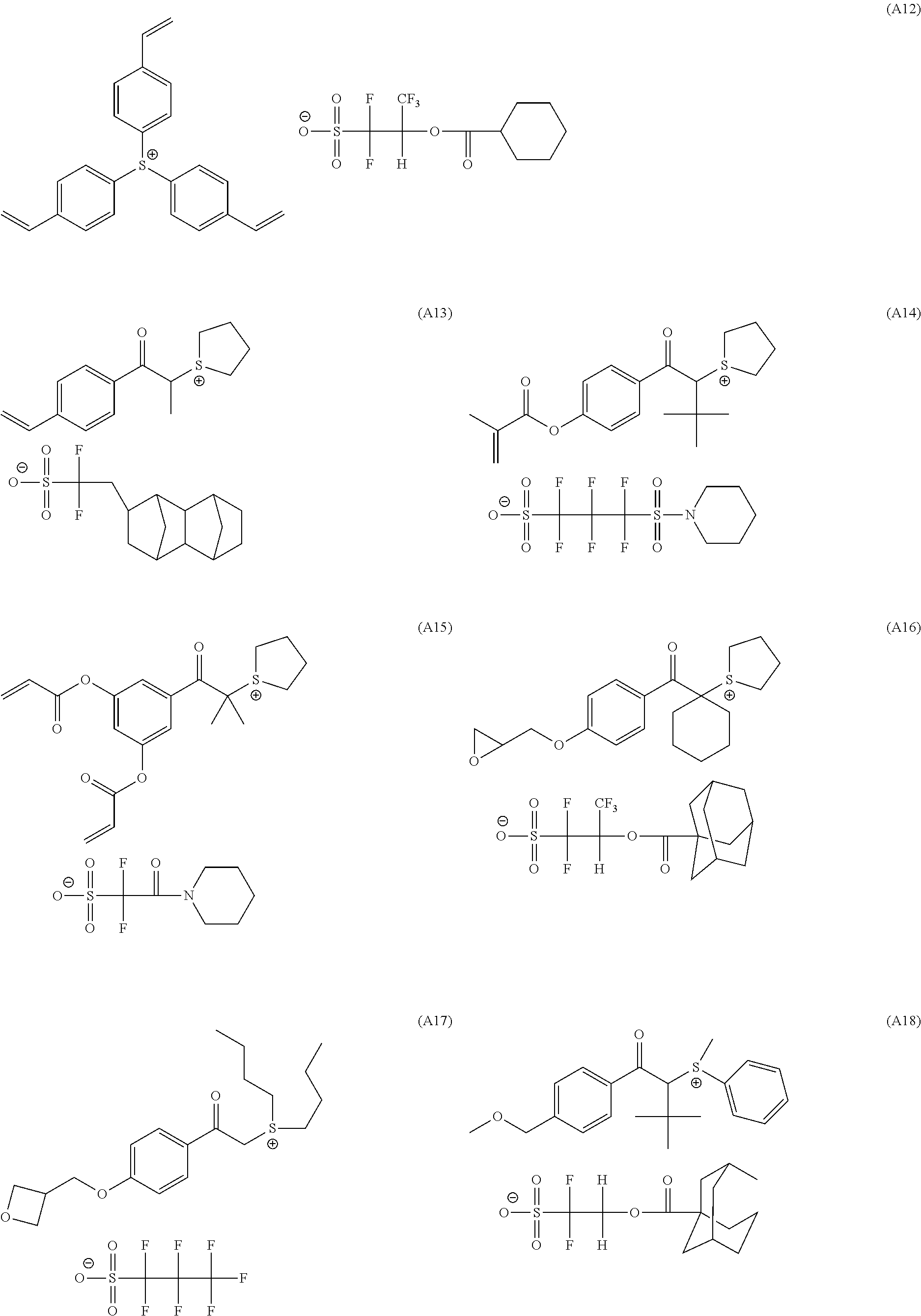

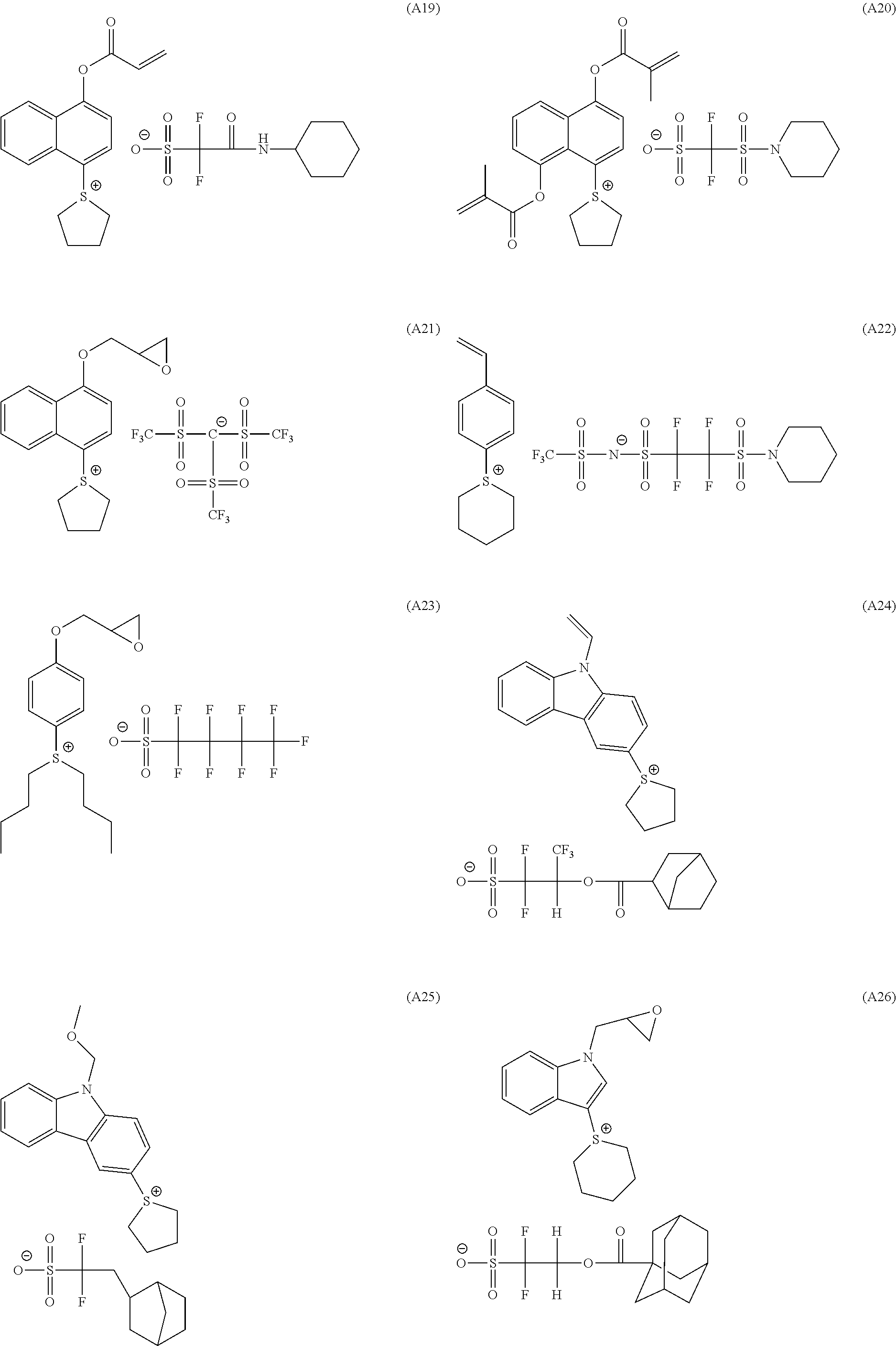

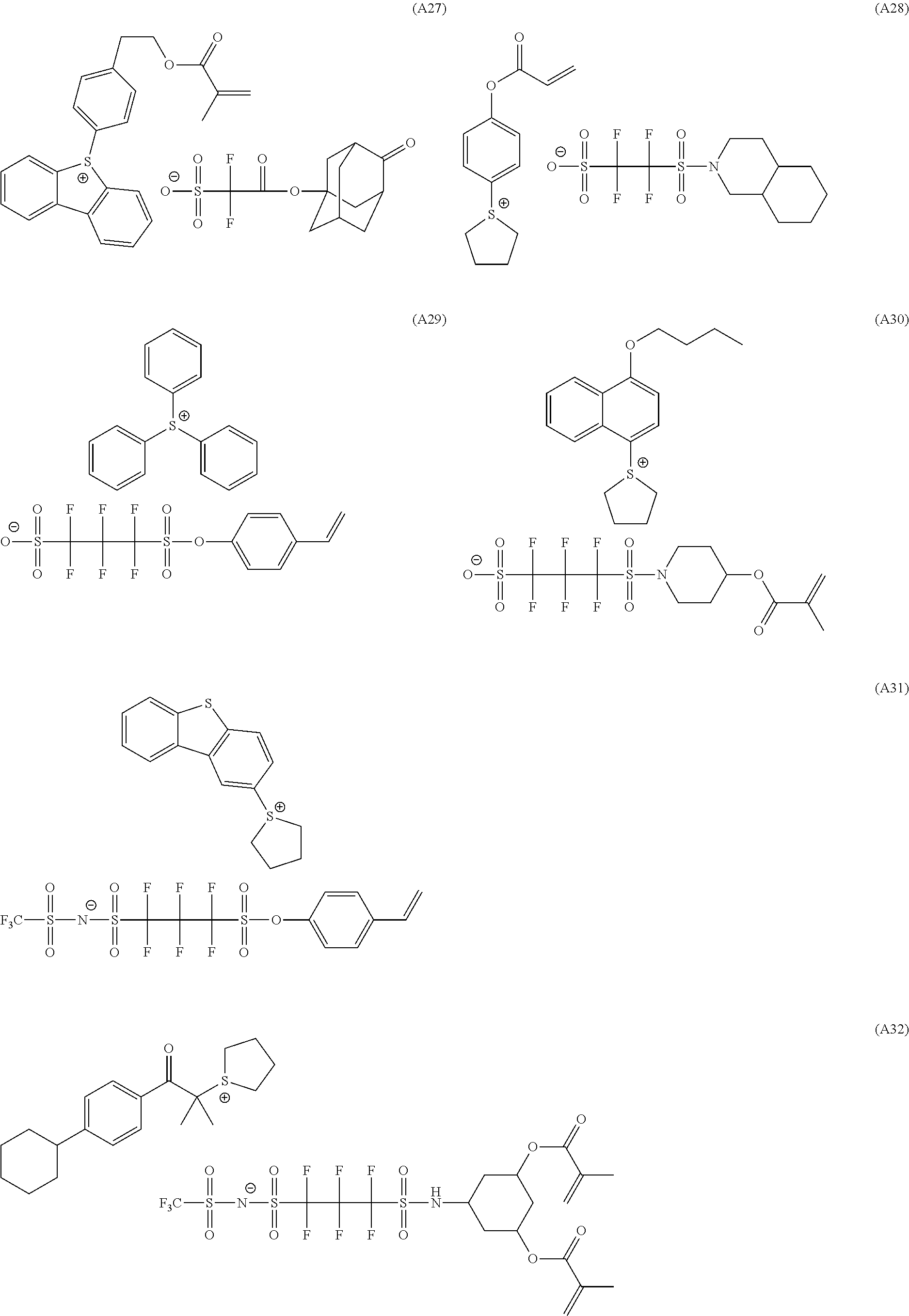

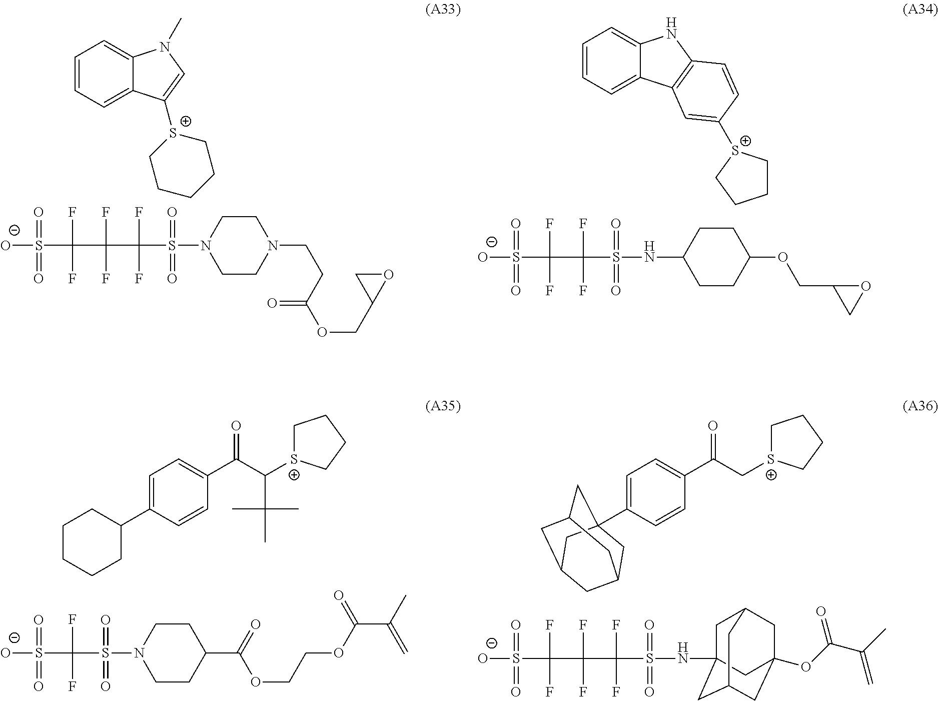

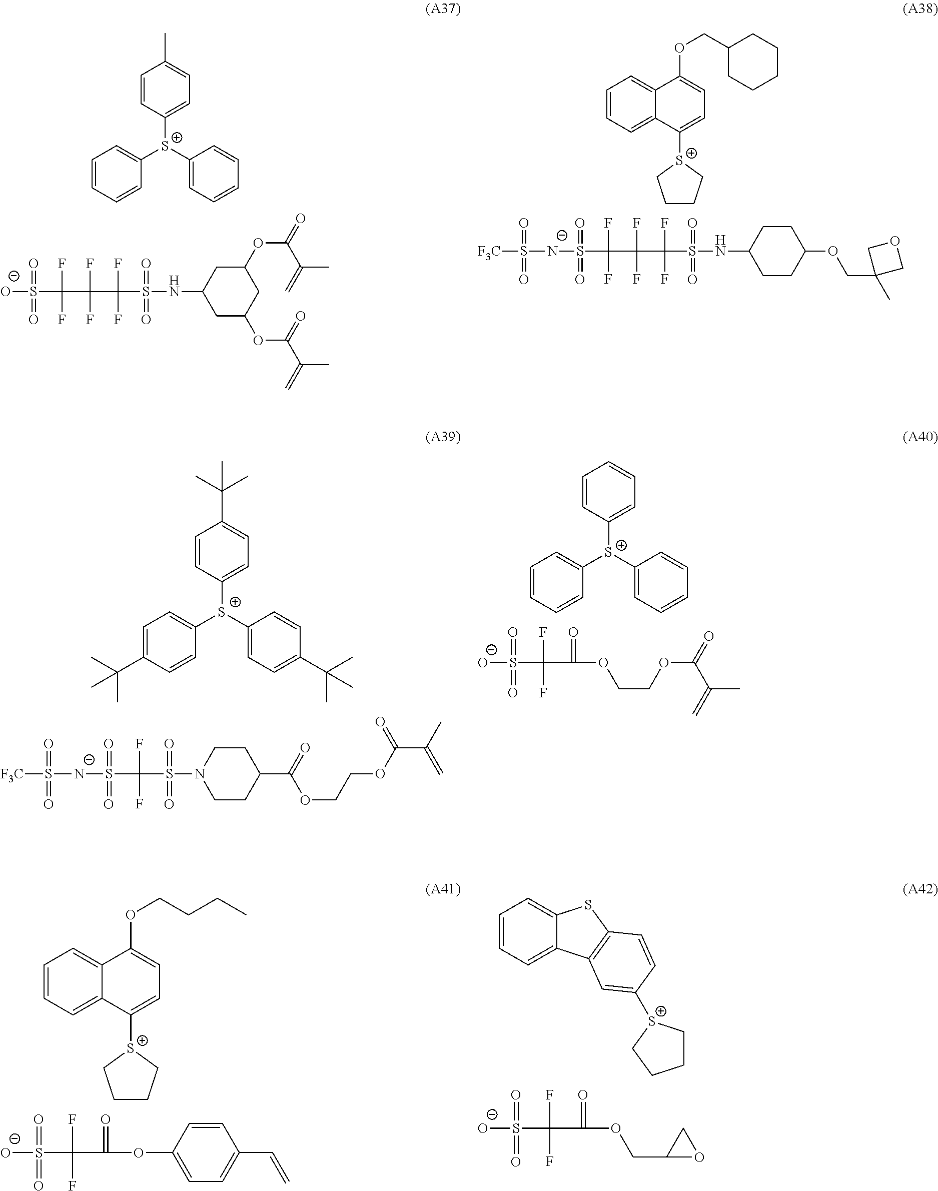

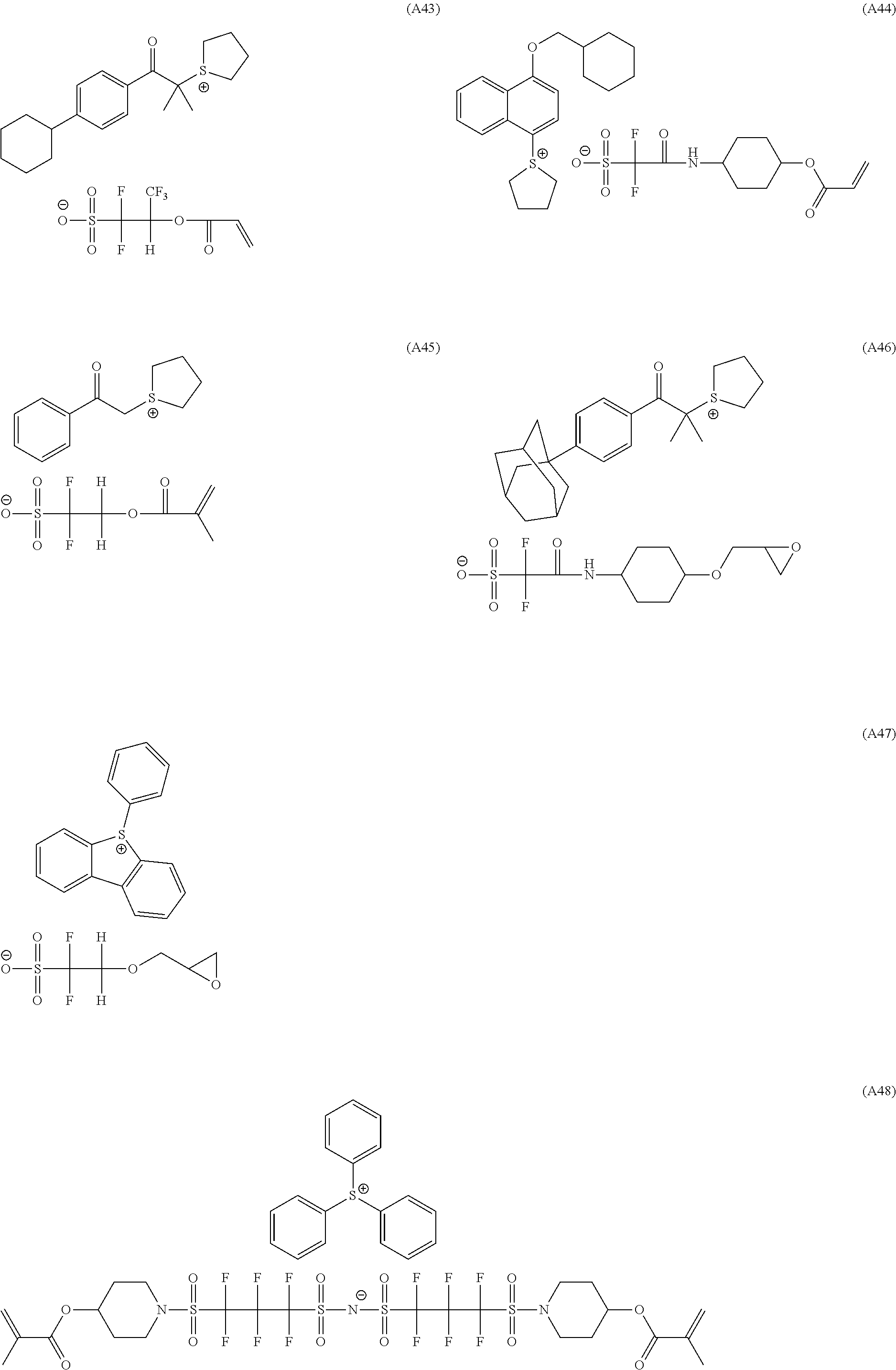

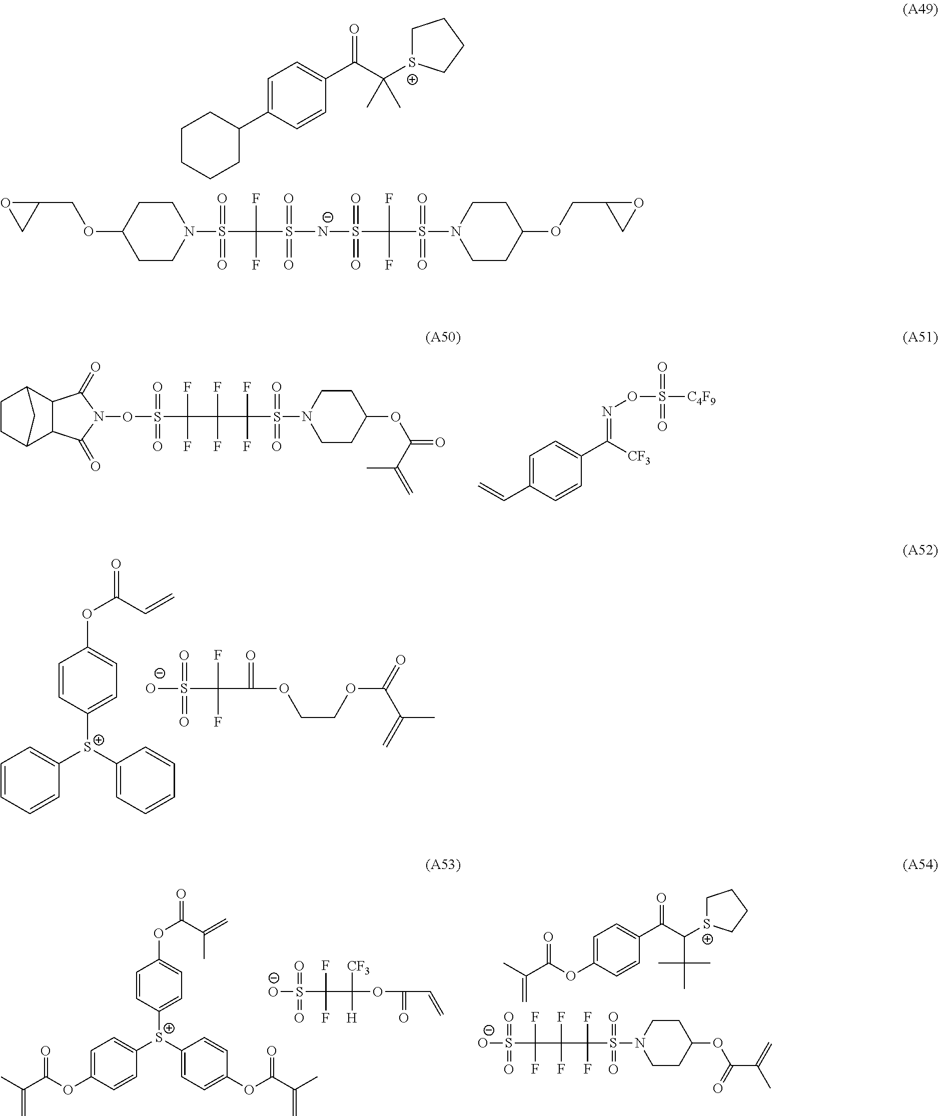

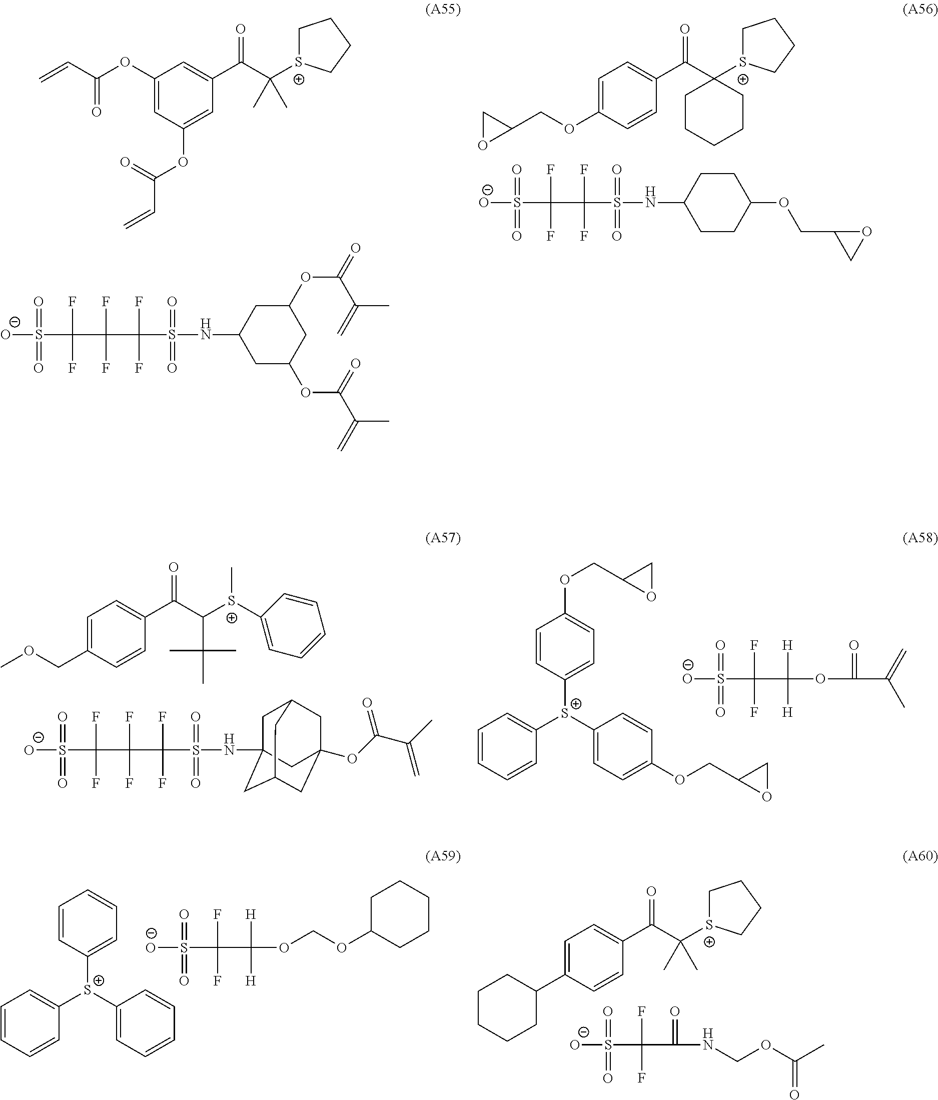

In the active light sensitive or radiation sensitive composition according to the present invention, the acid generator [N-B] can be used alone, or two or more types thereof can be used in combination, and the content is preferably 0.1% by mass to 20% by mass, more preferably 0.5% by mass to 15% by mass, and still more preferably 3% by mass to 12% by mass based on the total solid content of the active light sensitive or radiation sensitive composition.

[N-C] Low Molecular Weight Compounds of which Solubility in Alkali Developers is Decreased by Action of Acid, Active Light or Radiation, or Activated Species.

Although the low molecular weight compound [N-C] of which the solubility in alkali developers is decreased by the action of an acid, active light or radiation, or an activated species is not particularly limited, a compound, which is polymerized by an acid generated from a compound (A) described below, the acid generator [P-B], or the acid generator [N-B] by irradiation with active light or radiation or an active species such as radicals generated by irradiation with active light or radiation, of which the solubility in alkali developers is decreased, is exemplified.

The molecular weight range of the low molecular weight compound [N-C] is preferably 100 to 1000, more preferably 200 to 900, and particularly preferably 300 to 800.

Here, the low molecular weight compound in the present invention is a compound having a constant molecular weight (a compound which substantially does not have a molecular weight distribution) of 100 to 1000 (more preferably 100 to 700, and still more preferably 100 to 500), which is not a so-called polymer or oligomer obtained by cleaving the unsaturated bonds of a compound having unsaturated bonds (a so-called polymerizable monomer) while using an initiator and by sequentially growing bonds.

Examples of the low molecular weight compound [N-C] include an addition-polymerizing compound having a double bond. In this case, the low molecular weight compound [N-C] is selected from compounds having at least one terminated ethylenically unsaturated bond, preferably from compounds having two or more terminated ethylenically unsaturated bonds. Such compound groups are widely known in the industrial fields, and can be used without any particular limitation in the present invention. These compounds have a chemical form such as a monomer, a prepolymer, that is, a dimer, a trimer or an oligomer, or a copolymer thereof or a mixture thereof. Examples of the monomer include an unsaturated carboxylic acid (for example, acrylic acid, methacrylic acid, itaconic acid, crotonic acid, isocrotonic acid, or maleic acid), esters thereof, and amides thereof, and esters obtained from an unsaturated carboxylic acid and an aliphatic polyol compound, or amides obtained from an unsaturated carboxylic acid and an aliphatic polyvalent amine compound are preferably used. In addition, a product of an addition reaction between unsaturated carboxylic acid esters or amides, which have a nucleophilic substituent such as a hydroxyl group, an amino group, or a mercapto group, and monofunctional or polyfunctional isocyanates or epoxies, a product of a dehydration condensation reaction between the unsaturated carboxylic acid esters or amides and monofunctional or polyfunctional carboxylic acids, or the like is also suitably used. Moreover, a product of an addition reaction between unsaturated carboxylic acid esters or amides, which have an electrophilic substituent such as an isocyanate group or an epoxy group, and monofunctional or polyfunctional alcohols, amines, or thiols, or a product of a substitution reaction between unsaturated carboxylic acid esters or amides, which have a leaving substituent such as a halogen atom or a tosyloxy group, and monofunctional or polyfunctional alcohols, amines, or thiols is also suitably used. Furthermore, as other examples, instead of the above unsaturated carboxylic acids, compound groups such as unsaturated phosphonic acids, styrenes, and vinyl ethers can also be used.

Specific examples of the monomer of an ester obtained by reacting an aliphatic polyol compound with an unsaturated carboxylic acid include ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl)isocyanurate, isocyanuric acid ethyleneoxide (EO)-modified triacrylate, and a polyester acrylate oligomer, as an acrylic acid ester.

Examples of the methacrylic acid ester include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethyl methane, and bis-[p-(methacryloxyethoxy)phenyl]dimethyl methane.

Examples of the itaconic acid ester include ethylene glycol diitaconate, propylene glycol diitaconate, 1,3-butanediol diitaconate, 1,4-butanediol diitaconate, tetramethylene glycol diitaconate, pentaerythritol diitaconate, and sorbitol tetraitaconate. Examples of the crotonic acid ester include ethylene glycol dicrotonate, tetramethylene glycol dicrotonate, pentaerythritol dicrotonate, and sorbitol tetradicrotonate. Examples of the isocrotonic acid ester include ethylene glycol diisocrotonate, pentaerythritol diisocrotonate, and sorbitol tetraisocrotonate. Examples of the maleic acid ester include ethylene glycol dimaleate, triethylene glycol dimaleate, pentaerythritol dimaleate, and sorbitol tetramaleate.

As examples of other esters, for example, aliphatic alcohol-based esters described in each of JP1976-47334B (JP-S51-47334B) and JP1982-196231A (JP-S57-196231A), esters having an aromatic skeleton described in each of JP1984-5240A (JP-S59-5240A), JP1984-5241A (JP-S59-5241A), and JP1990-226149A (JP-H02-226149A), and esters containing an amino group described in JP1989-165613A (JP-H01-165613A) can also be suitably used. Furthermore, the polyester monomer described above can also be used as a mixture.

In addition, specific examples of the amide monomer of an aliphatic polyvalent amine compound and an unsaturated carboxylic acid include methylene bis-acrylamide, methylene bis-methacrylamide, 1,6-hexamethylene-bis-acrylamide, 1,6-hexamethylene-bis-methacrylamide, diethylenetriamine trisacrylamide, xylylene bis-acrylamide, and xylylene bis-methacrylamide. As other preferable amide-based monomers, an amide-based monomer having a cyclohexylene structure described in JP1979-21726B (JP-S54-21726B) can be exemplified.

In addition, a urethane-based addition polymerizing compound manufactured by an addition reaction between isocyanate and a hydroxyl group is also suitable, and specific examples thereof include a vinyl urethane compound containing two or more polymerizable vinyl groups in a molecule obtained by adding a vinyl monomer containing a hydroxyl group represented by the following General Formula (A) to a polyisocyanate compound having two or more isocyanate groups in a molecule described in JP1973-41708B (JP-S48-41708B).

CH₂═C(R₄)COOCH₂CH(R₅)OH (A)

(Here, each of R₄ and R₅ represents H or CH₃.)

In addition, urethane acrylates described in JP1976-37193A (JP-S51-37193A), JP1990-32293B (JP-H02-32293B), and JP1990-16765B (JP-H02-16765B), and urethane compounds having an ethylene oxide skeleton described in JP1983-49860B (JP-S58-49860B), JP1981-17654B (JP-S56-17654B), JP1987-39417B (JP-S62-39417B), and JP1987-39418B (JP-S62-39418B) are also suitable. Furthermore, by using addition-polymerizing compounds having an amino structure or a sulfide structure in the molecule, described in JP1988-277653A (JP-S63-277653A), JP1988-260909A (JP-S63-260909A), and JP1989-105238A (JP-H01-105238A), it is possible to obtain a photopolymerizing composition having excellent photosensitive speed.

Other examples thereof include polyfunctional acrylates and methacrylates such as polyester acrylates and epoxy acrylates obtained by reacting epoxy resins with (meth)acrylic acids as described in each of JP1973-64183A (JP-S48-64183A), JP1974-43191B (JP-S49-43191B), and JP1977-30490B (JP-S52-30490B). Specific unsaturated compounds described in each of JP1971-43946B (JP-546-43946B), JP1989-40337B (JP-H01-40337B), and JP1989-40336B (JP-H01-40336B), or vinylphosphonic acid-based compounds described in JP1990-25493A (JP-H02-25493A) can also be exemplified. In any case, a structure containing a perfluoroalkyl group described in JP1986-22048A (JP-561-22048A) is suitably used. Furthermore, those introduced as the photocurable monomers and oligomers in Bulletin of Nihon Setchaku Kyokai, Vol. 20, No. 7, pp. 300 to 308 (1984) can also be used.

As the low molecular weight compound [N-C], a compound (hereinafter, refer to as a cross-linking agent) crosslinking the resin (A) due to the action of an acid described below can be suitably exemplified. Here, a known cross-linking agent can be effectively used.

The cross-linking agent, for example, is a compound having a cross-linking group which can crosslink the resin (A), and preferable examples of the cross-linking group include a hydroxymethyl group, an alkoxymethyl group, an acyloxymethyl group, a compound or a resin having two or more alkoxymethyl groups, and an epoxy compound.

More preferable examples thereof include an alkoxymethylated or acyloxymethylated melamine compound or resin, an alkoxymethylated or acyloxymethylated urea compound or resin, a hydroxymethylated, or alkoxymethylated phenol compound or resin, and an alkoxymethyl etherified phenol compound or resin.

As the particularly preferable cross-linking agent, a phenol derivative which has a molecular weight of 1200 or less, include three to five benzene rings in the molecule, and further has two or more combined hydroxy methyl groups or alkoxy methyl groups, in which the hydroxy methyl groups and the alkoxy methyl groups are concentrated on at least one benzene ring or distributably bonded thereto. By using such a phenol derivative, the effects of the present invention are more significantly exhibited. The alkoxymethyl groups which are bonded to the benzene ring preferably have 6 or less carbon atoms. Specifically, examples thereof preferably include a methoxy methyl group, an ethoxy methyl group, an n-propoxy methyl group, an i-propoxy methyl group, an n-butoxy methyl group, an i-butoxy methyl group, a sec-butoxy methyl group, and a t-butoxy methyl group. Furthermore, similarly to a 2-methoxy ethoxy group, and a 2-methoxy-1-propoxy group, an alkoxy-substituted alkoxy group is also preferable.

The cross-linking agent is preferably a phenol compound having a benzene ring in the molecule, more preferably a phenol compound having two or more benzene rings in the molecule, and preferably a phenol compound which does not include a nitrogen atom.

The cross-linking agent is preferably a phenol compound having 2 to 8 cross-linking groups which can crosslink the resin (A), per molecule, and more preferably a phenol compound having 3 to 6 cross-linking groups.

Among the phenol derivatives, particularly preferable examples are exemplified below. In the formula, L¹ to L⁸ indicate cross-linking groups such as an alkoxymethyl group, which may be the same as or different from each other, and the cross-linking group preferably indicates a hydroxymethyl group, a methoxymethyl group, or an ethoxymethyl group.

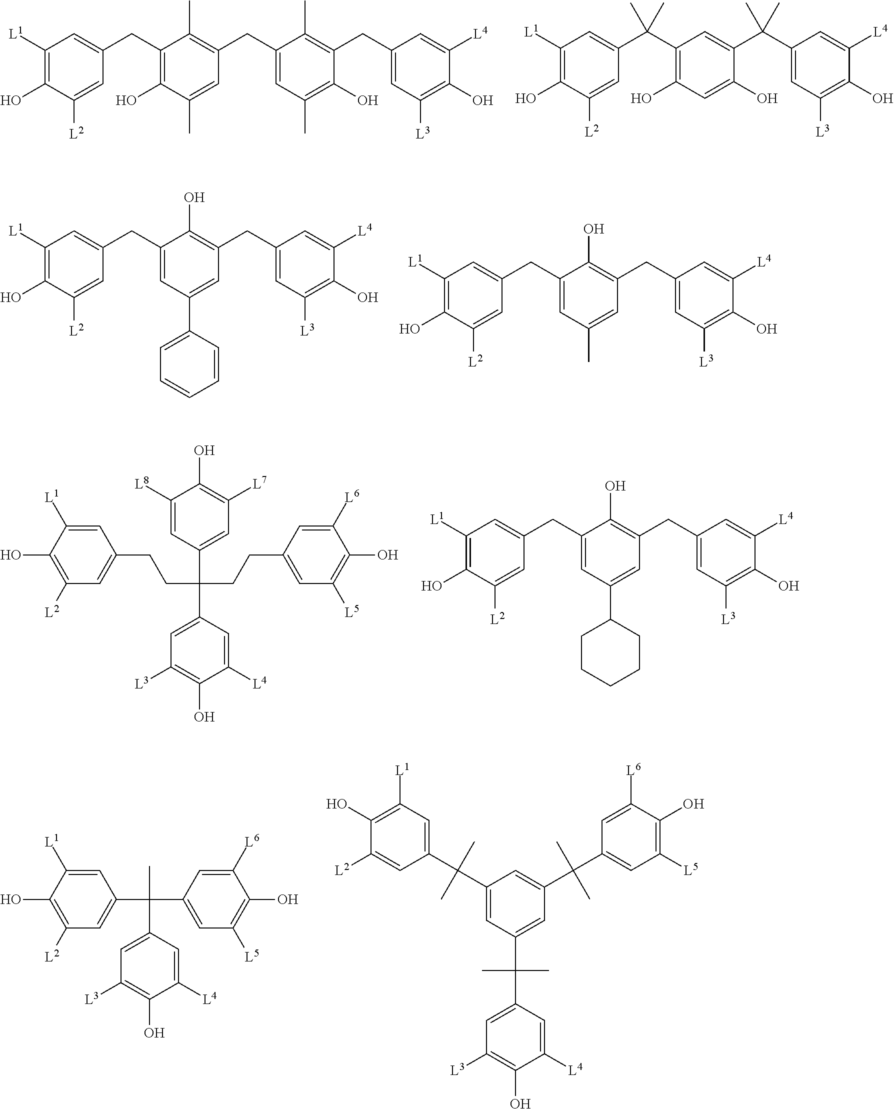

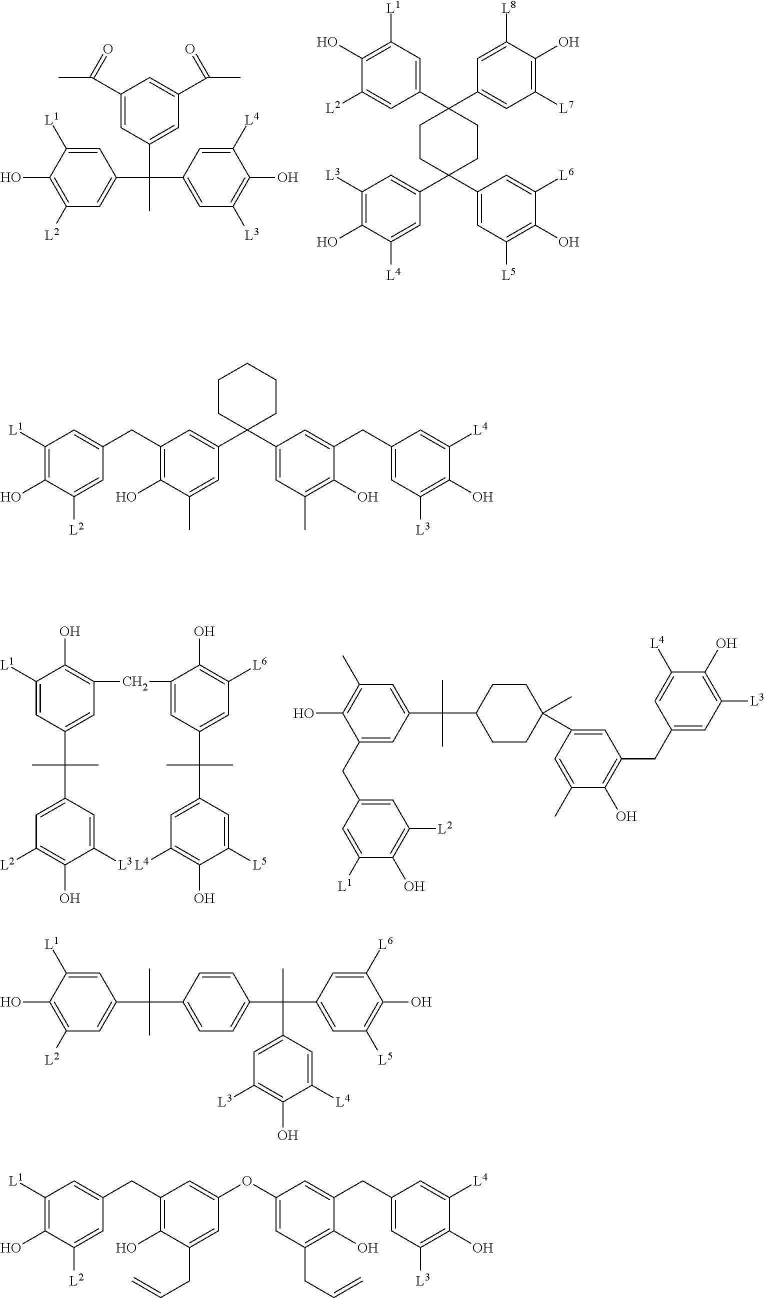

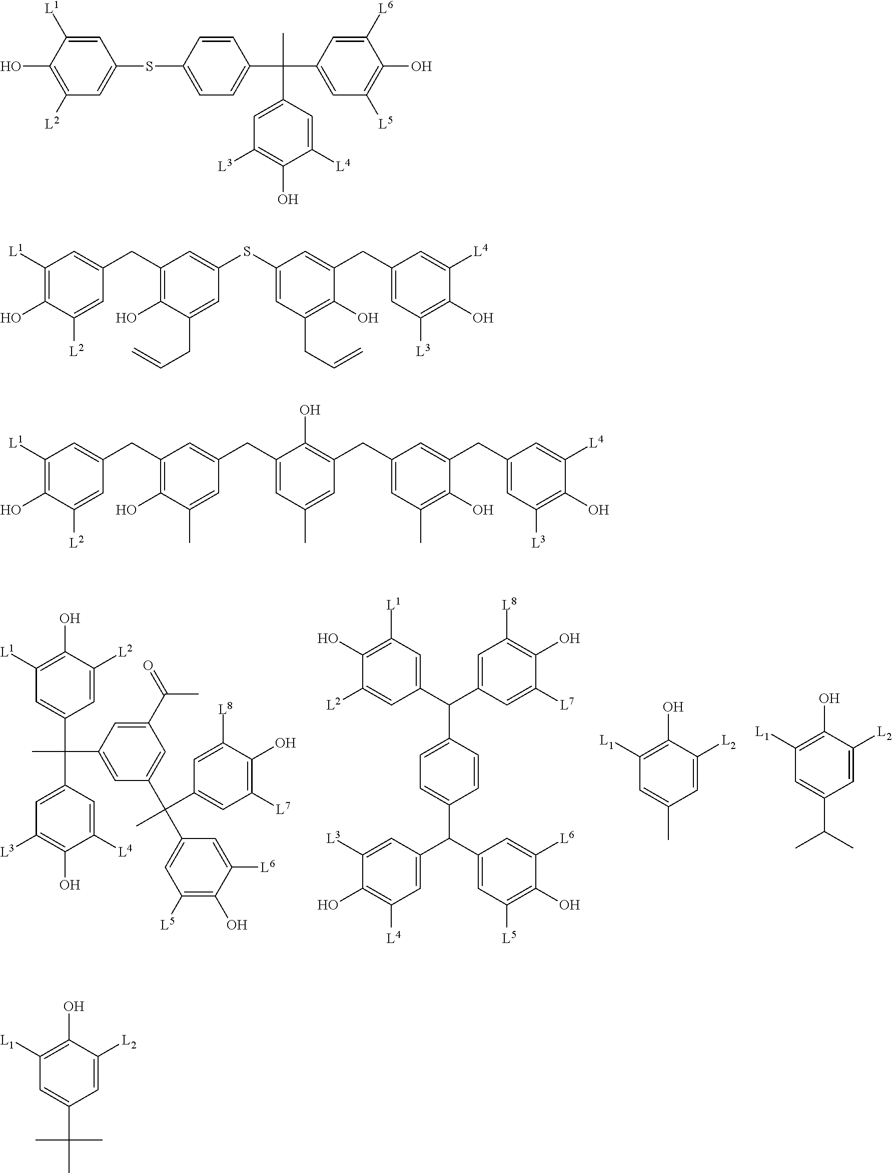

As the cross-linking agent, commercially available products can also be used, or the cross-linking agent can also be synthesized by a known method. For example, the phenol derivatives having a hydroxymethyl group can be obtained by reacting a phenol compound which does not have a corresponding hydroxymethyl group (compound where L¹ to L⁸ in the above-described formula are hydrogen atoms) with formaldehyde in the presence of a base catalyst. In such a case, in order to prevent resinification or gelation, the reaction is preferably performed at a reaction temperature of 60° C. or lower. Specifically, synthesis can be performed by the methods described in JP1994-282067A (JP-H06-282067A), and JP1995-64285A (JP-H07-64285A).

The phenol derivative having an alkoxymethyl group can be obtained by reacting a phenol derivative which has a corresponding hydroxymethyl group with an alcohol in the presence of an acid catalyst. In such a case, in order to prevent resinification or gelation, the reaction is preferably performed at a reaction temperature of 100° C. or lower. Specifically, it is possible for the compounds to be synthesized with the methods which are described in EP632003A1 and the like. The phenol derivative having a hydroxymethyl group or an alkoxymethyl group, synthesized in this manner is preferable from the viewpoint of stability during storage, and, the phenol derivative having an alkoxymethyl group is particularly preferable from the viewpoint of stability during storage. The phenol derivatives which have two or more combined hydroxy methyl groups or alkoxy methyl groups in which either are concentrated in the benzene rings or distributably bonded thereto may be used alone, or may be used in combination of two or more types.

In addition, as the cross-linking agent, (i) a compound having the following an N-hydroxymethyl group, an N-alkoxymethyl group, or an N-acyloxymethyl group, and (ii) an epoxy compound can also be exemplified.

As (i) the compound having an N-hydroxymethyl group, an N-alkoxymethyl group, or an N-acyloxymethyl group, a compound having two or more (more preferably two to eight) substructures which are represented by the following General Formula (CLNM-1) is preferable.

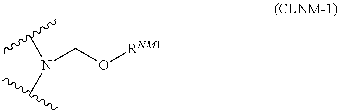

In General Formula (CLNM-1), R^{NM1} represents a hydrogen atom, an alkyl group, a cycloalkyl group, or an oxoalkyl group.

In General Formula (CLNM-1), the alkyl group represented by R^{NM1} is preferably a linear or branched alkyl group having 1 to 6 carbon atoms. The cycloalkyl group represented by R^{NM1} is preferably a cycloalkyl group having 5 or 6 carbon atoms. The oxoalkyl group represented by R^{NM1} is preferably an oxoalkyl group having 3 to 6 carbon atoms, and examples thereof include a β-oxopropyl group, a β-oxobutyl group, a β-oxopentyl group, and a β-oxohexyl group.

Examples of more preferable aspects of the compound having two or more substructures represented by General Formula (CLNM-1) include a urea-based cross-linking agent represented by the following General Formula (CLNM-2), an alkylene urea-based cross-linking agent represented by the following General Formula (CLNM-3), a glycoluril-based cross-linking agent represented by the following General Formula (CLNM-4), and a melamine cross-linking agent represented by the following General Formula (CLNM-5).

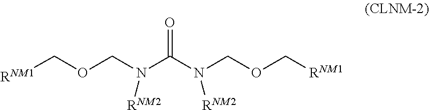

In General Formula (CLNM-2), each of R^{NM1}'s is independently the same as R^{NM1} in General Formula (CLNM-1).

Each of R^{NM2}'s independently represents a hydrogen atom, an alkyl group (preferably having 1 to 6 carbon atoms), or a cycloalkyl group (preferably having 5 or 6 carbon atoms).

Specific examples of the urea-based cross-linking agent represented by General Formula (CLNM-2) include N,N-di(methoxymethyl)urea, N,N-di(ethoxymethyl)urea, N,N-di(propoxymethyl)urea, N,N-di(isopropoxymethyl)urea, N,N-di(butoxymethyl)urea, N,N-di(t-butoxymethyl)urea, N,N-di(cyclohexyloxymethyl)urea, N,N-di(cyclopentyloxymethyl)urea, N,N-di(adamantyloxymethyl)urea, and N,N-di(norbornyloxymethyl)urea.

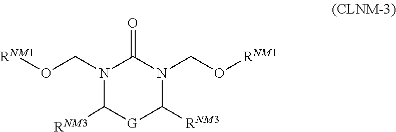

In General Formula (CLNM-3), each of R^{NM1}'s is independently the same as R^{NM1} in General Formula (CLNM-1).

Each of R^{NM3}'s independently represents hydrogen atom, a hydroxyl group, a linear or branched alkyl group (preferably having 1 to 6 carbon atoms), a cycloalkyl group (preferably having 5 or 6 carbon atoms), an oxoalkyl group (preferably having 1 to 6 carbon atoms), an alkoxy group (preferably having 1 to 6 carbon atoms), or an oxoalkoxy group (preferably having 1 to 6 carbon atoms).

G represents a single bond, an oxygen atom, a sulfur atom, an alkylene group (preferably having 1 to 3 carbon atoms), or a carbonyl group. More specific examples thereof include a methylene group, an ethylene group, a propylene group, a 1-methyl ethylene group, a hydroxymethylene group, and a cyano methylene group.

Specific examples of the alkylene urea-based cross-linking agent represented by General Formula (CLNM-3) include N,N-di(methoxymethyl)-4,5-di(methoxymethyl)ethylene urea, N,N-di(ethoxymethyl)-4,5-di(ethoxymethyl)ethylene urea, N,N-di(propoxymethyl)-4,5-di(propoxymethyl)ethylene urea, N,N-di(isopropoxymethyl)-4,5-di(isopropoxymethyl)ethylene urea, N,N-di(butoxymethyl)-4,5-di(butoxymethyl)ethylene urea, N,N-di(t-butoxymethyl)-4,5-di(t-butoxymethyl)ethylene urea, N,N-di(cyclohexyloxymethyl)-4,5-di(cyclohexyloxymethyl)ethylene urea, N,N-di(cyclopentyloxymethyl)-4,5-di(cyclopentyloxymethyl)ethylene urea, N,N-di(adamantyloxymethyl)-4,5-di(adamantyloxymethyl)ethylene urea, and N,N-di(norbornyloxymethyl)-4,5-di(norbornyloxymethyl)ethylene urea.

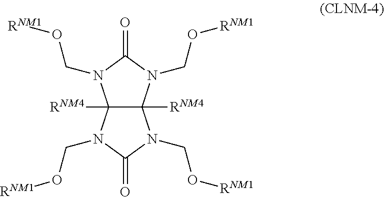

In General Formula (CLNM-4), each of R^{NM1}'s is independently the same as R^{NM1} in General Formula (CLNM-1).

Each of R^{NM4}'s independently represents a hydrogen atom, a hydroxyl group, an alkyl group, a cycloalkyl group, or an alkoxy group.

More specific examples of the alkyl group (preferably having 1 to 6 carbon atoms), the cycloalkyl group (preferably having 5 or 6 carbon atoms), or the alkoxy group (preferably having 1 to 6 carbon atoms) represented by R^{NM4} include a methyl group, an ethyl group, a butyl group, a cyclopentyl group, a cyclohexyl group, a methoxy group, an ethoxy group, and a butoxy group.

Specific examples of the glycoluril-based cross-linking agent represented by General Formula (CLNM-4) include, for example, N,N,N,N-tetra(methoxymethyl)glycoluril, N,N,N,N-tetra(ethoxymethyl)glycoluril, N,N,N,N-tetra(propoxymethyl)glycoluril, N,N,N,N-tetra(isopropoxymethyl)glycoluril, N,N,N,N-tetra(butoxymethyl)glycoluril, N,N,N,N-tetra(t-butoxymethyl)glycoluril, N,N,N,N-tetra(cyclohexyloxymethyl)glycoluril, N,N,N,N-tetra(cyclopentyloxymethyl)glycoluril, N,N,N,N-tetra(adamantyloxymethyl)glycoluril, and N,N,N,N-tetra(norbornyl oxymethyl)glycoluril.

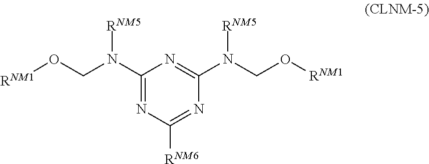

In General Formula (CLNM-5), each of R^{NM1}'s is independently the same as R^{NM1} in General Formula (CLNM-1).

Each of R^{NM5}'s independently represents a hydrogen atom, an alkyl group, a cycloalkyl group, an aryl group, or an atomic group represented by the following General Formula (CLNM-5′).

R^{NM6} represents a hydrogen atom, an alkyl group, a cycloalkyl group, an aryl group, or an atomic group represented by the following General Formula (CLNM-5″).

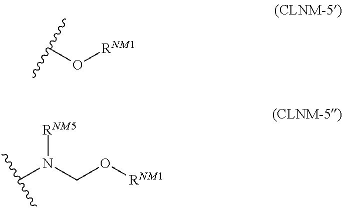

In General Formula (CLNM-5′), R^{NM1} is the same as R^{NM1} in General Formula (CLNM-1).

In General Formula (CLNM-5″), R^{NM1} is the same as R^{NM1} in General Formula (CLNM-1) and R^{NM5} is the same as R^{NM5} in General Formula (CLNM-5).

More specific examples of the alkyl group (preferably having 1 to 6 carbon atoms), the cycloalkyl group (preferably having 5 or 6 carbon atoms), or the aryl group (preferably having 6 to 10 carbon atoms) represented by R^{NM5} and R^{NM6} include a methyl group, an ethyl group, a propyl group, an isopropyl group, a butyl group, an isobutyl group, a t-butyl group, a pentyl group, a cyclopentyl group, a hexyl group, a cyclohexyl group, a phenyl group, and a naphthyl group.

Examples of the melamine-based cross-linking agent represented by General Formula (CLNM-5) include N,N,N,N,N,N-hexa(methoxymethyl)melamine, N,N,N,N,N,N-hexa(ethoxymethyl)melamine, N,N,N,N,N,N-hexa(propoxymethyl)melamine, N,N,N,N,N,N-hexa(isopropoxymethyl)melamine, N,N,N,N,N,N-hexa(butoxymethyl)melamine, N,N,N,N,N,N-hexa(t-butoxymethyl)melamine, N,N,N,N,N,N-hexa(cyclohexyloxymethyl)melamine, N,N,N,N,N,N-hexa(cyclopentyloxy methyl)melamine, N,N,N,N,N,N-hexa(adamantyloxymethyl)melamine, N,N,N,N,N,N-hexa(norbornyloxymethyl)melamine, N,N,N,N,N,N-hexa(methoxymethyl)acetoguanamine, N,N,N,N,N,N-hexa(ethoxymethyl)acetoguanamine, N,N,N,N,N,N-hexa(propoxymethyl)acetoguanamine, N,N,N,N,N,N-hexa(isopropoxymethyl)acetoguanamine, N,N,N,N,N,N-hexa(butoxymethyl)acetoguanamine, N,N,N,N,N,N-hexa(t-butoxymethyl)acetoguanamine, N,N,N,N,N,N-hexa(methoxymethyl)benzoguanamine, N,N,N,N,N,N-hexa(ethoxymethyl)benzoguanamine, N,N,N,N,N,N-hexa(propoxymethyl)benzoguanamine, N,N,N,N,N,N-hexa(isopropoxymethyl)benzoguanamine, N,N,N,N,N,N-hexa(butoxymethyl)benzoguanamine, and N,N,N,N,N,N-hexa(t-butoxymethyl)benzoguanamine.

In General Formulas (CLNM-1) to (CLNM-5), the group represented by each of R^{NM1} to R^{NM6} may further have a substituent. Examples of the substituent which each of R^{NM1} to R^{NM6} may have include a halogen atom, a hydroxyl group, a nitro group, a cyano group, a carboxyl group, a cycloalkyl group (preferably having 3 to 20 carbon atoms), an aryl group (preferably having 6 to 14 carbon atoms), an alkoxy group (preferably having 1 to 20 carbon atoms), a cycloalkoxy group (preferably having 3 to 20 carbon atoms), an acyl group (preferably having 2 to 20 carbon atoms), and an acyloxy group (preferably having 2 to 20 carbon atoms).

Specific examples of the compound having two or more substructures represented by General Formula (CLNM-1) are exemplified below, but the present invention is not limited thereto.

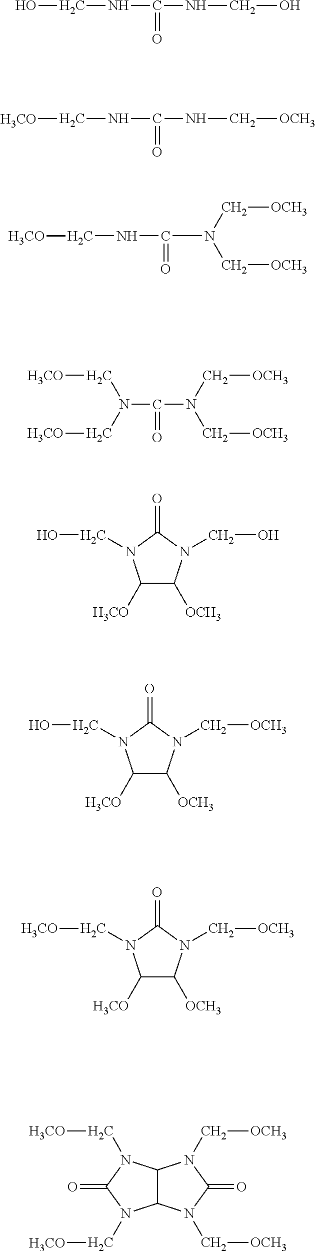

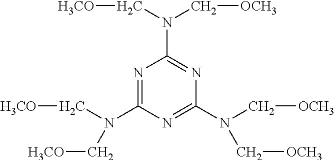

Examples of (ii) the epoxy compound include a compound represented by the following General Formula (EP1).

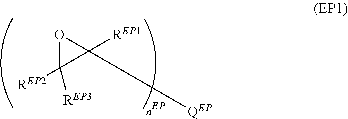

In Formula (EP1), each of R^{EP1} to R^{EP3} independently represent a hydrogen atom, a halogen atom, an alkyl group, or a cycloalkyl group, and the alkyl group and the cycloalkyl group may have a substituent. In addition, R^{EP1} and R^{EP2}, and R^{EP2} and R^{EP3} may be bonded to each other to form a ring structure, respectively.

Examples of the substituent which the alkyl group or the cycloalkyl group may have include a hydroxyl group, a cyano group, an alkoxy group, an alkyl carbonyl group, an alkoxycarbonyl group, an alkyl carbonyloxy group, an alkylthio group, an alkyl sulfone group, an alkylsulfonyl group, an alkyl amino group, and an alkyl amide group.

Q^{EP} represents a single bond or an organic group having an n^{EP} value. R^{EP1} to R^{EP3} may be bonded to not only each other but also Q^{EP} to form a ring structure.

n^{EP} represents an integer of 2 or greater, preferably an integer of 2 to 10, and more preferably an integer of 2 to 6. Here, in a case where Q^{EP} is a single bond, n^{EP} is 2.

In a case where Q^{EP} is an organic group having an n^{EP} value, an organic group having an n^{EP} value, which has a structure in which a divalent connecting group such as an ether group, an ester group, an amide group, a sulfonamide group, or an alkylene group (preferably having 1 to 4 carbon atoms, and more preferably being methylene), a trivalent connecting group such as —N(-)₂, or a combination of these is linked to a chained or cyclic saturated hydrocarbon group having an n^{EP} value (preferably having 2 to 20 carbon atoms), an aromatic ring group having an n^{EP} value (preferably having 6 to 30 carbon atoms), or a chained or cyclic saturated hydrocarbon or aromatic hydrocarbon, is preferable.

Specific examples of (B) the compound having an epoxy structure are exemplified below, but the present invention is not limited thereto.

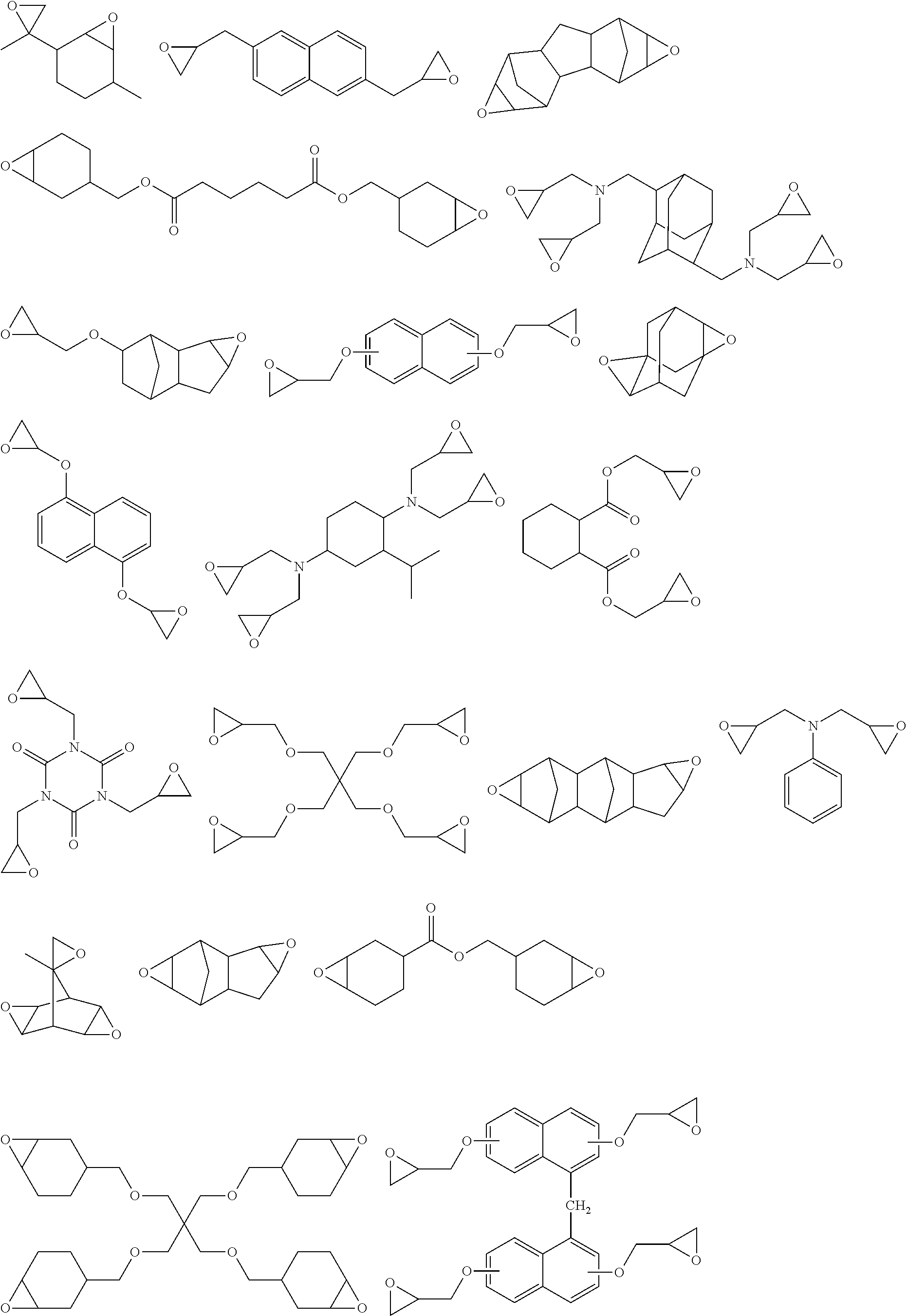

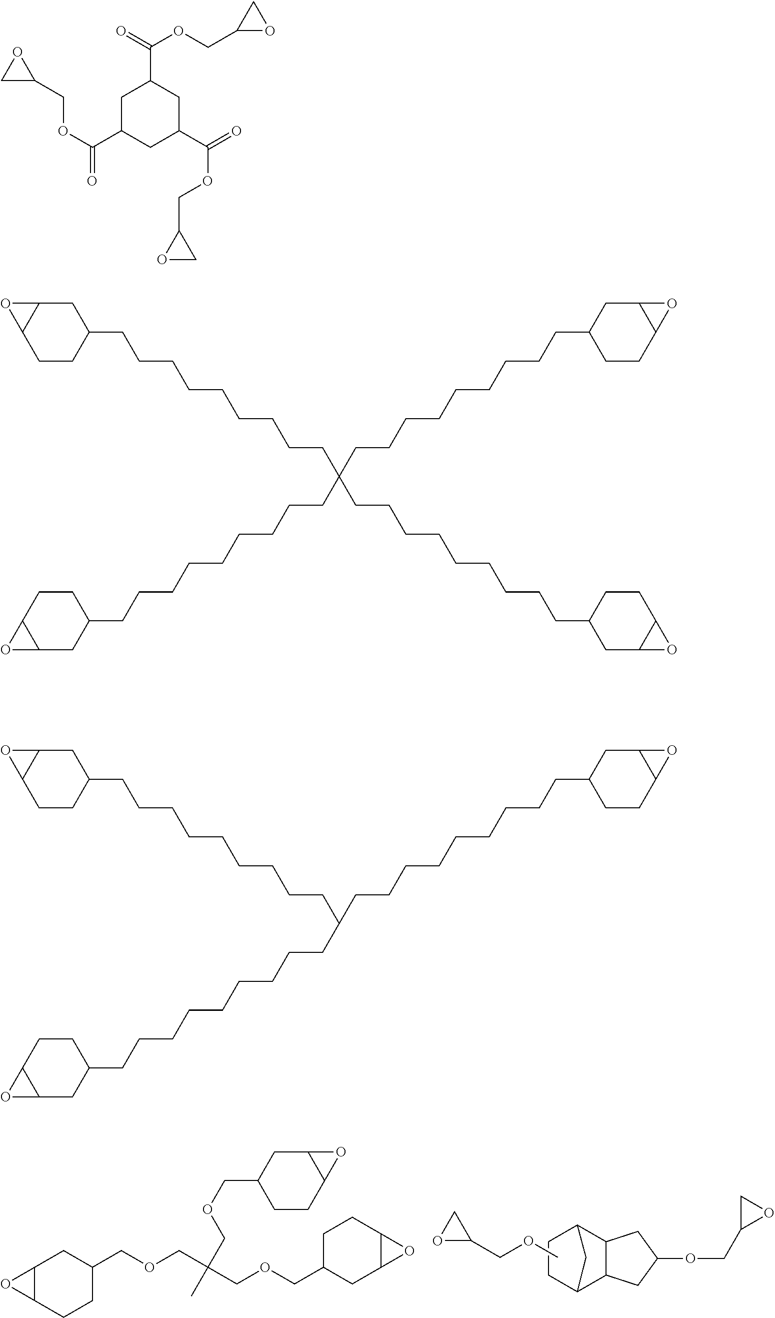

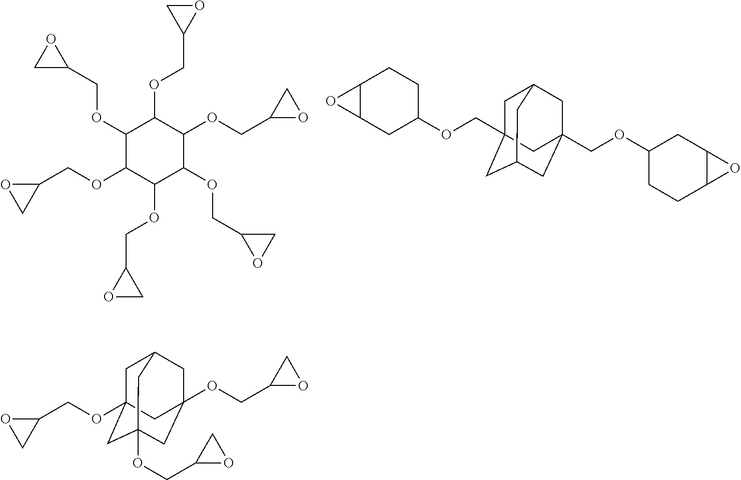

In the present invention, the low molecular weight compound [N-C] may be used alone, or two or more types thereof may be used in combination.

The low molecular weight compound [N-C] may be the same component as the compound [N-B], or may be a different component from the compound [N-B], but is preferably a different component from the compound [N-B].

In the case of forming a negative image (that is, in a case where the active light sensitive or radiation sensitive composition is a negative type active light sensitive or radiation sensitive composition), the content of the low molecular weight compound [N-C] is preferably 3% by mass to 65% by mass, more preferably 5% by mass to 50% by mass, and still more preferably 10% by mass to 45% by mass, in the total solid content of the active light sensitive or radiation sensitive composition of the present invention. In the case of forming a positive image (that is, in a case where the active light sensitive or radiation sensitive composition is a positive type active light sensitive or radiation sensitive composition), the content of the low molecular weight compound [N-C] is preferably 0.1% by mass to 20% by mass, and more preferably 1% by mass to 10% by mass, in the total solid content of the active light sensitive or radiation sensitive composition of the present invention.

As a preferable embodiment of the active light sensitive or radiation sensitive composition of the present invention, an embodiment which is a negative type active light sensitive or radiation sensitive composition in which the content of the compound (N) is 10% by mass or greater with respect to the total solid content of the active light sensitive or radiation sensitive composition is exemplified. In the embodiment, the content of the compound (N) is preferably 10% by mass to 99% by mass, and more preferably 10% by mass to 70% by mass, with respect to the total solid content of the active light sensitive or radiation sensitive composition.

In addition, as a preferable embodiment of the active light sensitive or radiation sensitive composition of the present invention, an embodiment which is a positive type active light sensitive or radiation sensitive composition in which the content of the compound (N) is 1% by mass or greater with respect to the total solid content of the active light sensitive or radiation sensitive composition is exemplified. In the embodiment, the content of the compound (N) is preferably 1% by mass to 40% by mass, and more preferably 1% by mass to 20% by mass, with respect to the total solid content of the active light sensitive or radiation sensitive composition.

The active light sensitive or radiation sensitive composition of the present invention preferably contains a compound having a molecular weight of 500 or greater as the compound (N), and due to this, at the time of a prebake, a post bake, or exposure, volatilization from a film can be suppressed in vacuum.

In addition, the active light sensitive or radiation sensitive composition of the present invention preferably contains the compound (N-1) of which the solubility in alkali developers is decreased due to the action of an acid as the compound (N), and due to this, higher addition effects (high resolving power, pattern shape, and LWR) can be obtained. It is thought this is because the reaction by an acid substantially occurs with little deactivation in the film.

In particular, in a form in which the active light sensitive or radiation sensitive composition of the present invention contains the cross-linking agent as the low molecular weight compound [N-C], the active light sensitive or radiation sensitive composition is preferably contains the resin (A) which is crosslinked by a cross-linking agent due to the action of an acid.

As the resin (A), a known resin which can be crosslinked with the cross-linking agent (B) can be used.

The resin (A) may contain an acid group.

Examples of the acid group include a phenolic hydroxyl group, a carboxyl group, a fluorinated alcohol group, a sulfonic acid group, a sulfonamide group, a sulfonyl imide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

Preferable examples of the acid group include a phenolic hydroxyl group, a carboxyl group, a fluorinated alcohol group (preferably, a hexafluoroisopropanol group), and a sulfonic acid group.

Hydroxystyrene, partially hydrogenated hydroxystyrene, a novolak resin, a (meth)acryl-based polymer ((meth)acrylic acid-containing polymer or the like), a hydroxyl group-containing polymer, polyvinyl acetate, a diene copolymer, and an epoxy group-containing polymer can be exemplified as the resin (A) which can be preferably used.

From the viewpoint of the secondary electron generation efficiency in electron beam exposure or EUV light exposure, the resin (A) preferably has a benzene ring, and more preferably contains the repeating unit represented by General Formula (3) described in the resin [P-A].

The resin (A) can also have the repeating unit represented by General Formula (3) and at least one type of repeating unit represented by any one of General Formulas (a) to (c).

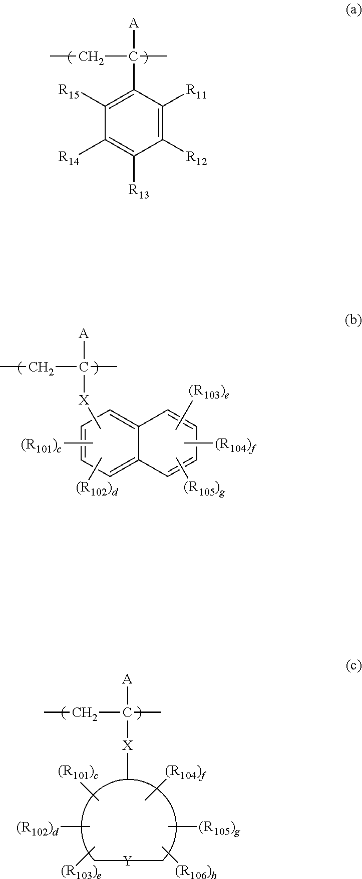

In General Formulas (a) to (c), A has the same meaning as R₃₂ in General Formula (3).

X represents a single bond, a —COO— group, a —O— group, or a —CON(R₁₆)— group, and R₁₆ represents a hydrogen atom or an alkyl group having 1 to 3 carbon atoms (a methyl group, an ethyl group, or a propyl group). X is preferably a single bond, —COO—, or —CON(R₁₆)—, and particularly preferably a single bond or a —COO— group.

The ring structure represented by Y represents a polycyclic aromatic hydrocarbon ring structure having three or more rings, and preferably represents any one represented by the following structural formulas.

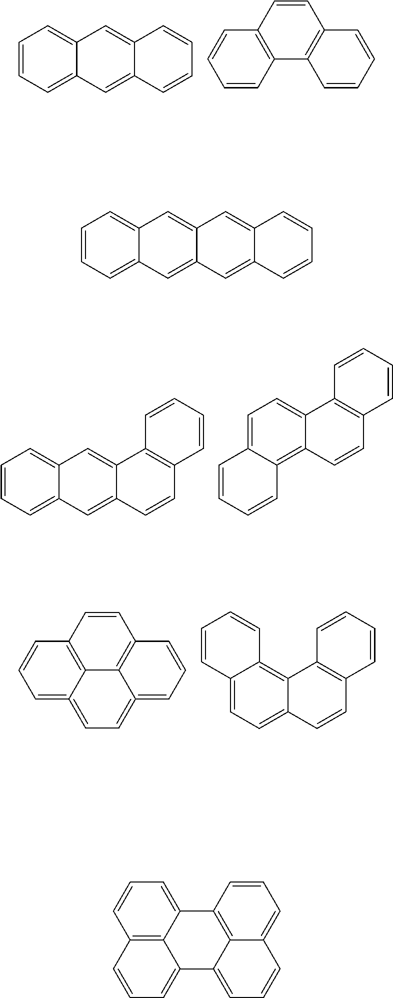

Each of R₁₁ to R₁₅ independently represents a hydrogen atom, a halogen atom, an alkyl group, a cycloalkyl group, an aryl group, an alkenyl group, an aralkyl group, an alkoxy group, an alkylcarbonyloxy group, an alkylsulfonyloxy group, an arylcarbonyloxy group, a nitro group, or a cyano group. R₁₁ to R₁₅ may be bonded to each other to form a ring (which is preferably 5- or 6-membered ring). As the halogen atom, the alkyl group, the cycloalkyl group, the aryl group, the alkenyl group, the aralkyl group, the alkoxy group, the alkylcarbonyloxy group, and the alkylsulfonyloxy group represented by each of R₁₁ to R₁₅, specifically, the same as R in General Formula (1) is exemplified. The arylcarbonyloxy group represented by each of R¹¹ to R¹⁵ is preferably an arylcarbonyloxy group having 7 to 16 carbon atoms which may have a substituent.

Each of R₁₀₁ to R₁₀₆ independently represents a hydroxy group, a halogen atom (Cl, Br, F, or I), a linear or branched alkyl group having 1 to 8 carbon atoms which may have a substituent, a linear or branched alkoxy group having 1 to 8 carbon atoms which may have a substituent, a linear or branched alkylcarbonyloxy group having 2 to 8 carbon atoms which may have a substituent, a linear or branched alkylsulfonyloxy group having 1 to 8 carbon atoms which may have a substituent, an alkenyl group having 1 to 8 carbon atoms which may have a substituent, an aryl group having 6 to 15 carbon atoms which may have a substituent, an aralkyl group having 7 to 16 carbon atoms which may have a substituent, or a perfluoroalkyl group having 1 to 4 carbon atoms which may have a carboxyl group or a hydroxyl group.

Each of c to h independently represents an integer of 0 to 3.

Specific examples of these substituents include an alkyl group (a methyl group, an ethyl group, a propyl group, an isopropyl group, a butyl group, a t-butyl group, or a hexyl group), an aryl group (a phenyl group or a naphthyl group), an aralkyl group, a hydroxyl group, an alkoxy group (a methoxy group, an ethoxy group, a butoxy group, an octyloxy group, or a dodecyloxy group), an acyl group (an acetyl group, a propanoyl group, or a benzoyl group), and an oxo group, and a substituent having 15 or less carbon atoms is preferable.

Each of R₁₀₁ to R₁₀₆ independently preferably represents a halogen atom, an alkyl group having 1 to 4 carbon atoms which may have a substituent, an alkoxy group having 1 to 4 carbon atoms which may have a substituent, or an alkylcarbonyloxy group having 2 to 4 carbon atoms which may have a substituent, and particularly preferably a chlorine atom, a bromine atom, an iodine atom, an alkyl group having 1 to 3 carbon atoms (a methyl group, an ethyl group, a propyl group, or an isopropyl group), an alkoxy group having 1 to 3 carbon atoms (a methoxy group, an ethoxy group, a propyloxy group, or an isopropyloxy group), or an alkylcarbonyloxy group having 2 or 3 carbon atoms (an acetoxy group or a propionyloxy group).

The resin (A) used in the present invention may be any one of a resin having only one type of repeating unit represented by General Formula (3), a resin having two or more types of repeating unit represented by General Formula (3), or a resin having the repeating unit represented by General Formula (3) and at least one type of repeating unit represented by any one of General Formulas (a) to (c), and other polymerizable monomers which can control film-forming properties and solvent solubility may be copolymerized.

Examples of these polymerizable monomers include styrene, alkyl-substituted styrene, alkoxy styrene, acyloxy styrene, hydrogenated hydroxy styrene, maleic anhydride, an acrylic acid derivative (acrylic acid or acrylic acid ester), a methacrylic acid derivative (methacrylic acid or methacrylic acid ester), N-substituted maleimide, acrylonitrile, and methacrylonitrile, and the present invention is not limited thereto.

In addition, examples of a preferable repeating unit of the resin also include a unit having a ring structure (a unit derived from a monomer having an indene structure or the like) in the main chain, a unit having a naphthol structure, and a repeating unit having a —C(CF₃)₂OH group, separately from those described above.

In the present invention, the resin (A) may be used alone, or two or more kinds thereof may be used in combination.

The content of the repeat unit represented by General Formula (3) in the resin (A) used in the present invention is generally within a range of 50 mol % to 100 mol %, and preferably within a range of 70 mol % to 100 mol %.

In the resin (A), the ratio between the repeating unit represented by General Formula (3) and the repeating units represented by General Formulas (a) to (c) is preferably 100/0 to 50/50, more preferably 100/0 to 60/40, and particularly preferably 100/0 to 70/30, in a molar ratio.

The molecular weight of the resin (A) is 1000 to 50000, and more preferably 2000 to 20000, as a mass averaged molecular weight.

The preferable molecular weight distribution (Mw/Mn) of the resin (A) is 1.0 to 2.0, and more preferably 1.0 to 1.35.

The amount of the resin (A) added (total sum amount in a case where a plurality of resins are used in combination) is 30% by mass to 95% by mass, preferably 40% by mass to 90% by mass, and particularly preferably 50% by mass to 80% by mass, with respect to the total solid content of the composition. Moreover, the molecular weight and the molecular weight distribution of the resin are defined as values that are measured by GPC and expressed in terms of polystyrene.

The resin (A) can be synthesized by a known radical polymerization method or an anionic polymerization method. For example, in the radical polymerization method, a vinyl monomer is dissolved in a suitable organic solvent, and the resultant product is reacted at room temperature or under heating conditions using a peroxide (benzoyl peroxide or the like), a nitrile compound (azobisisobutyronitrile or the like), or a redox compound (cumene hydroperoxide-iron (II) salt) as an initiator, whereby a polymer is obtained. In addition, in the anionic polymerization method, a vinyl monomer is dissolved in a suitable organic solvent, and the resultant product is reacted, typically, under cooling conditions using a metal compound (butyllithium or the like) as an initiator, whereby a polymer is obtained.

Specific examples of the resin (A) used in the present invention are shown below, but the present invention is not limited thereto.

n in the specific examples represents a positive integer.

Each of x, y, and z represents a molar ratio of a resin composition, and in a resin consisting of two components, the components are used within a range in which x is 10 to 95 and y is 5 to 90, and preferably within a range in which x is 40 to 90 and y is 10 to 60. In a resin consisting of three components, the components are used within a range in which x is 10 to 90, y is 5 to 85, and z is 5 to 85, and preferably within a range in which x is 40 to 80, y is 10 to 50, and z is 10 to 50. In addition, these may be used alone or two or more types thereof may be used in combination.

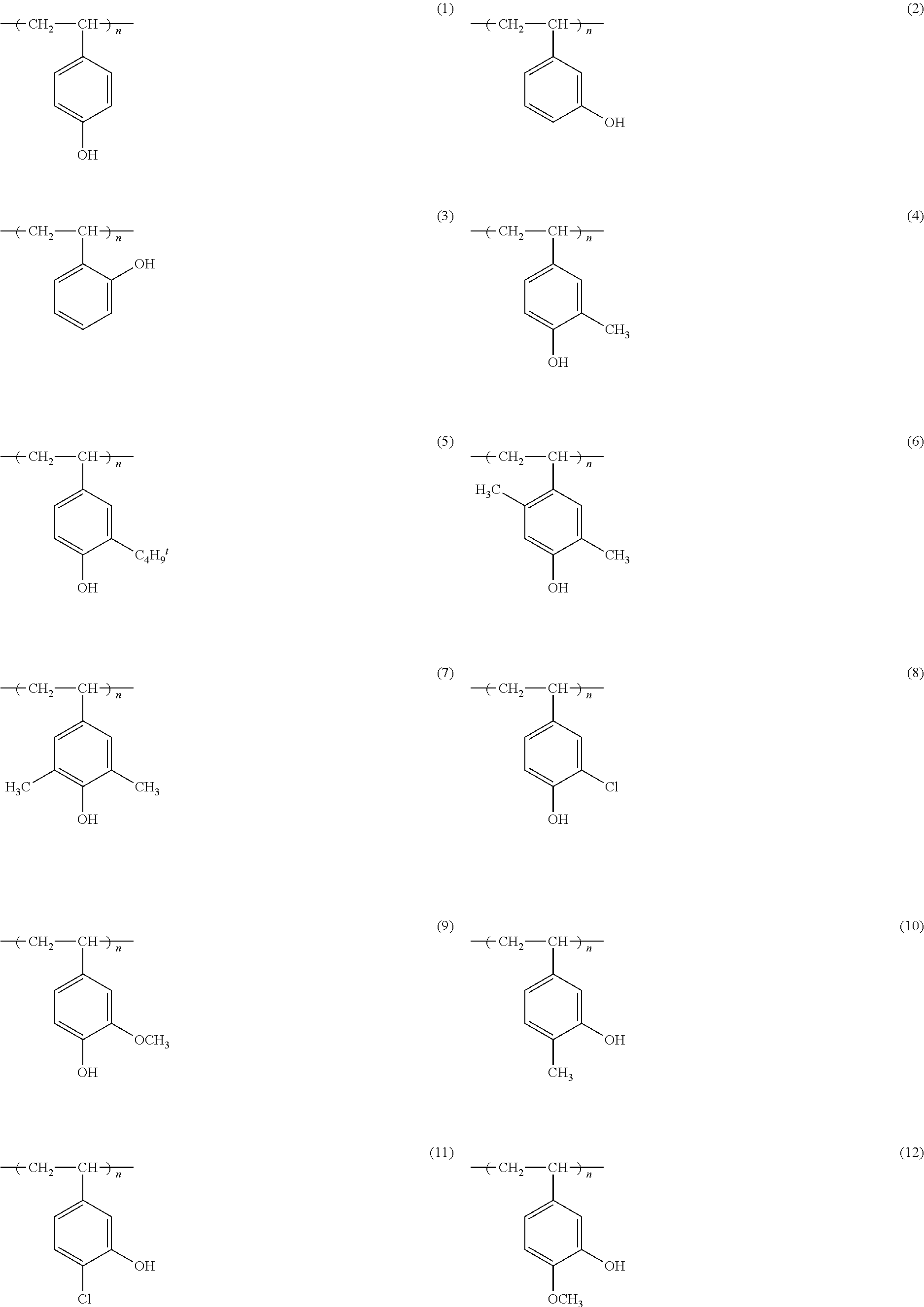

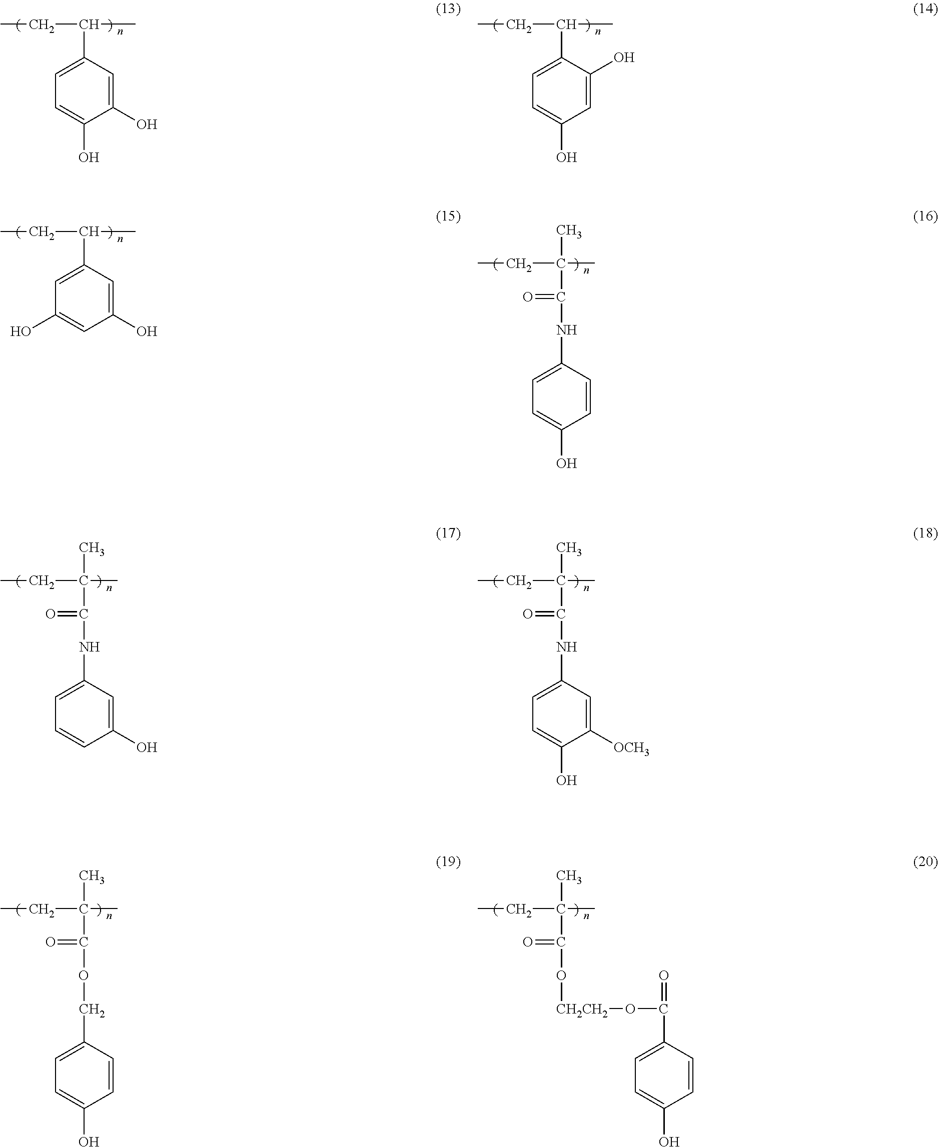

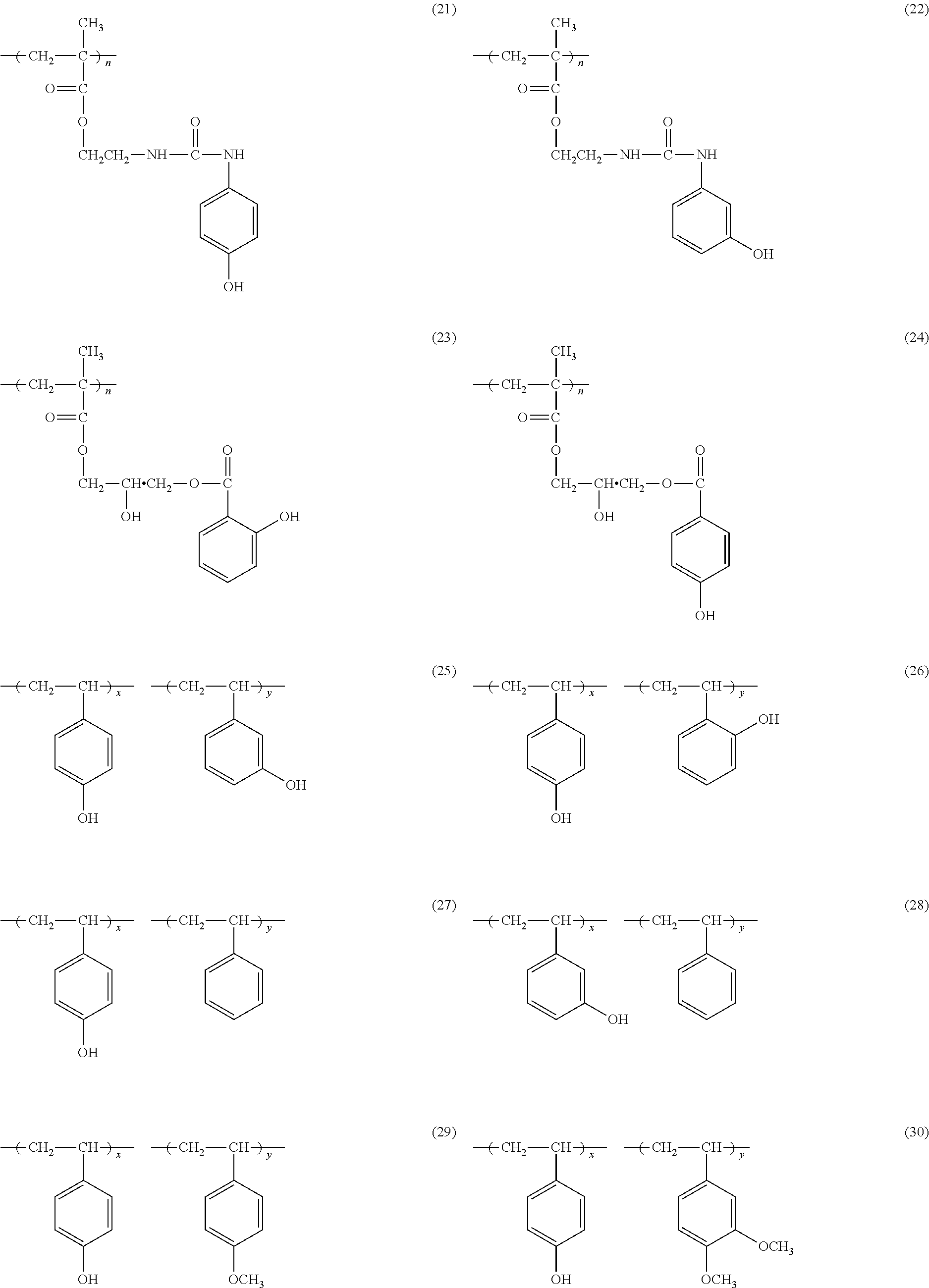

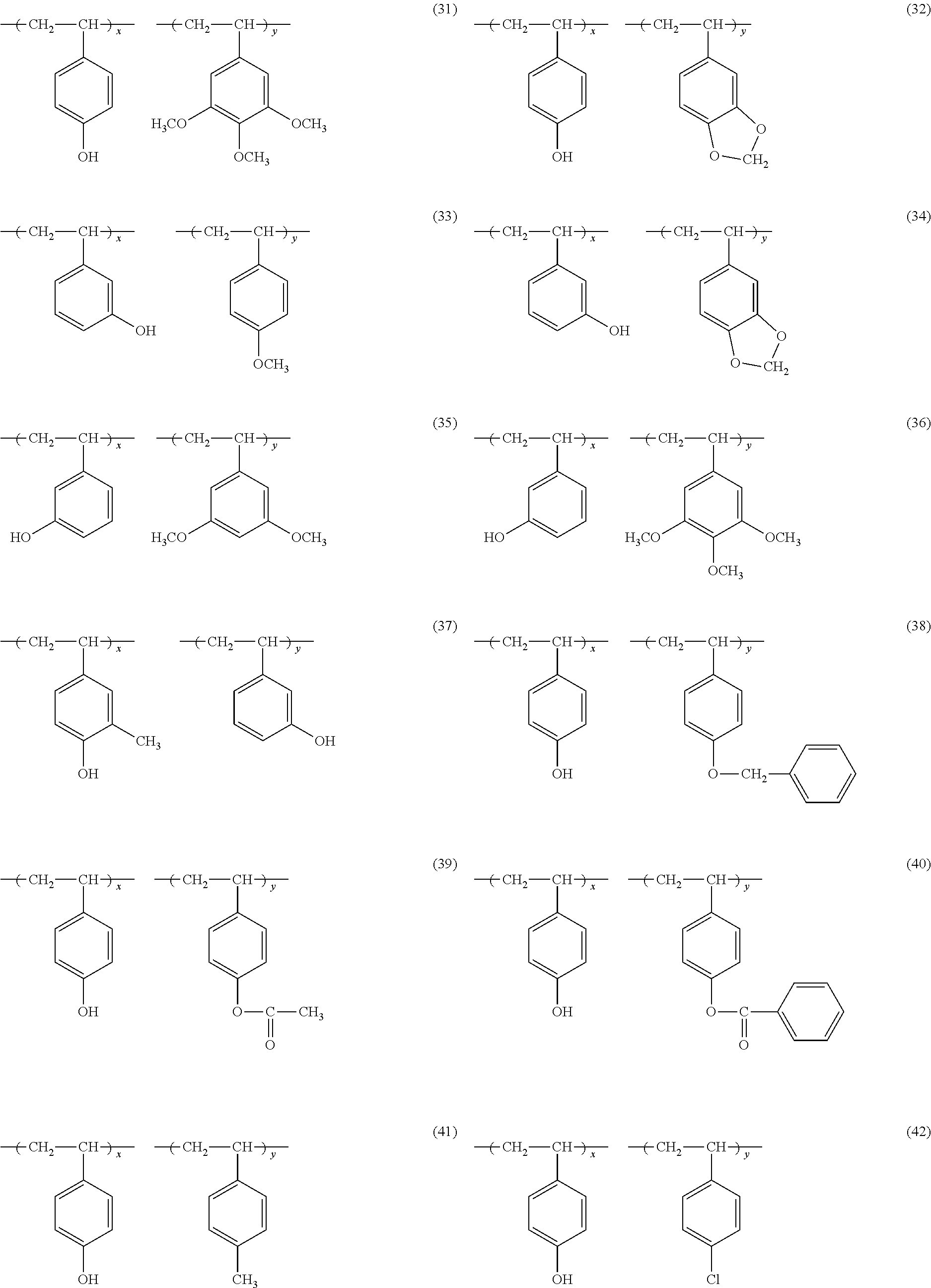

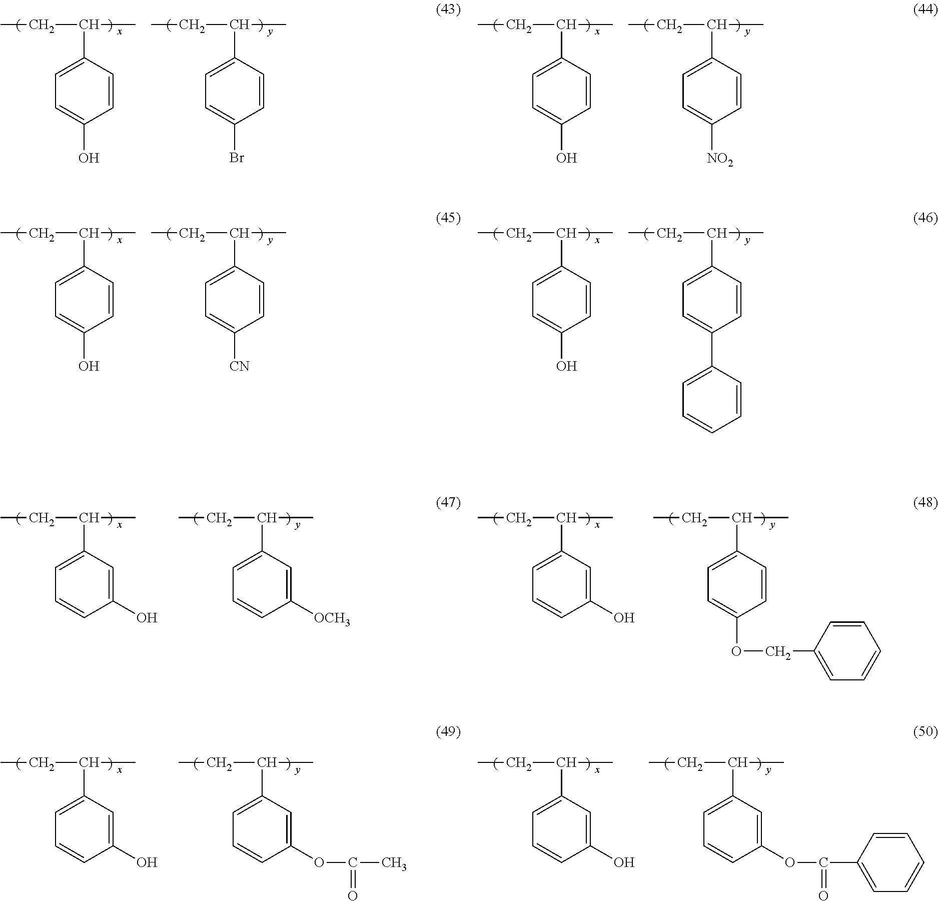

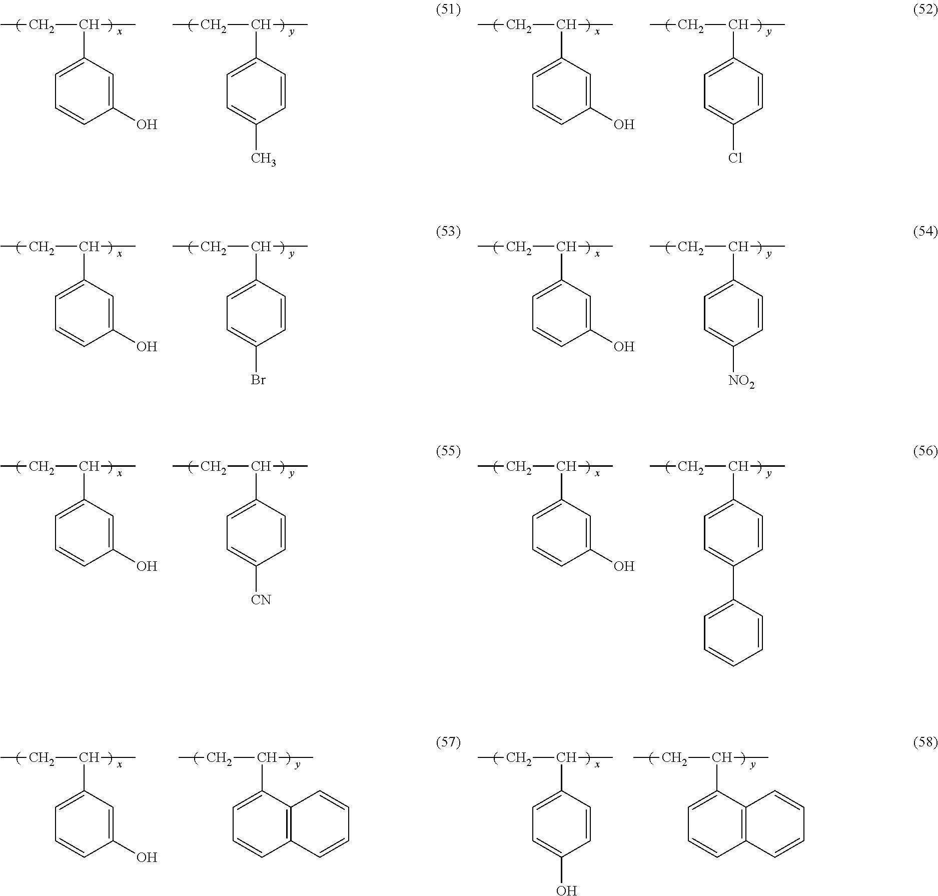

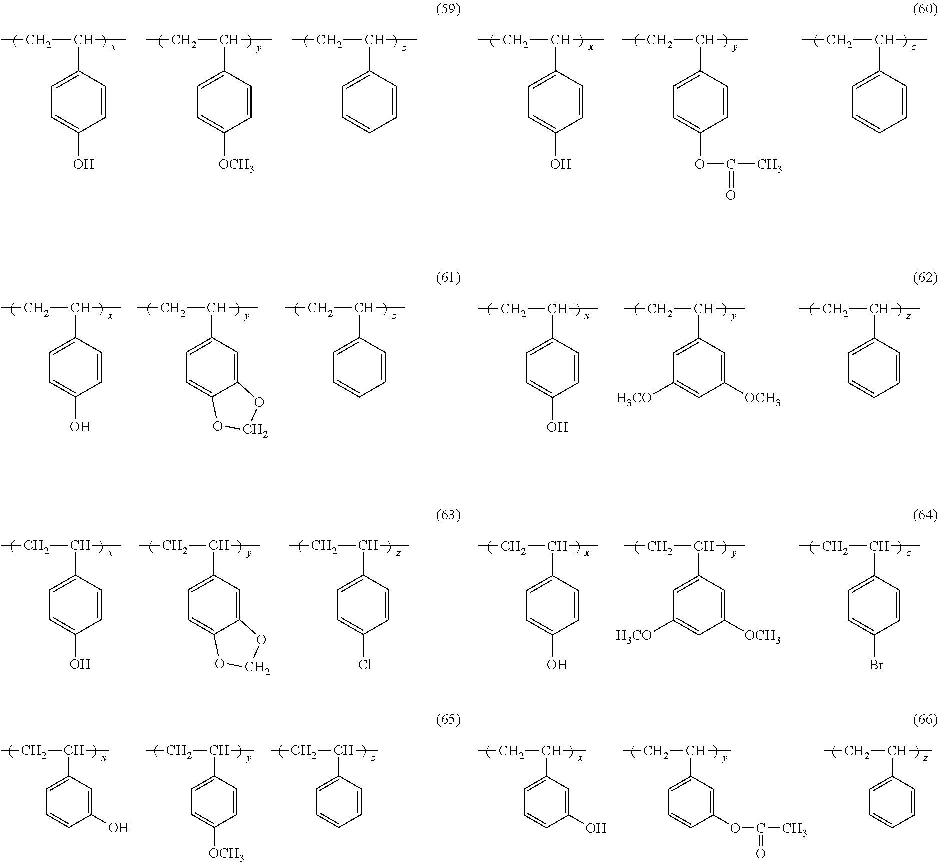

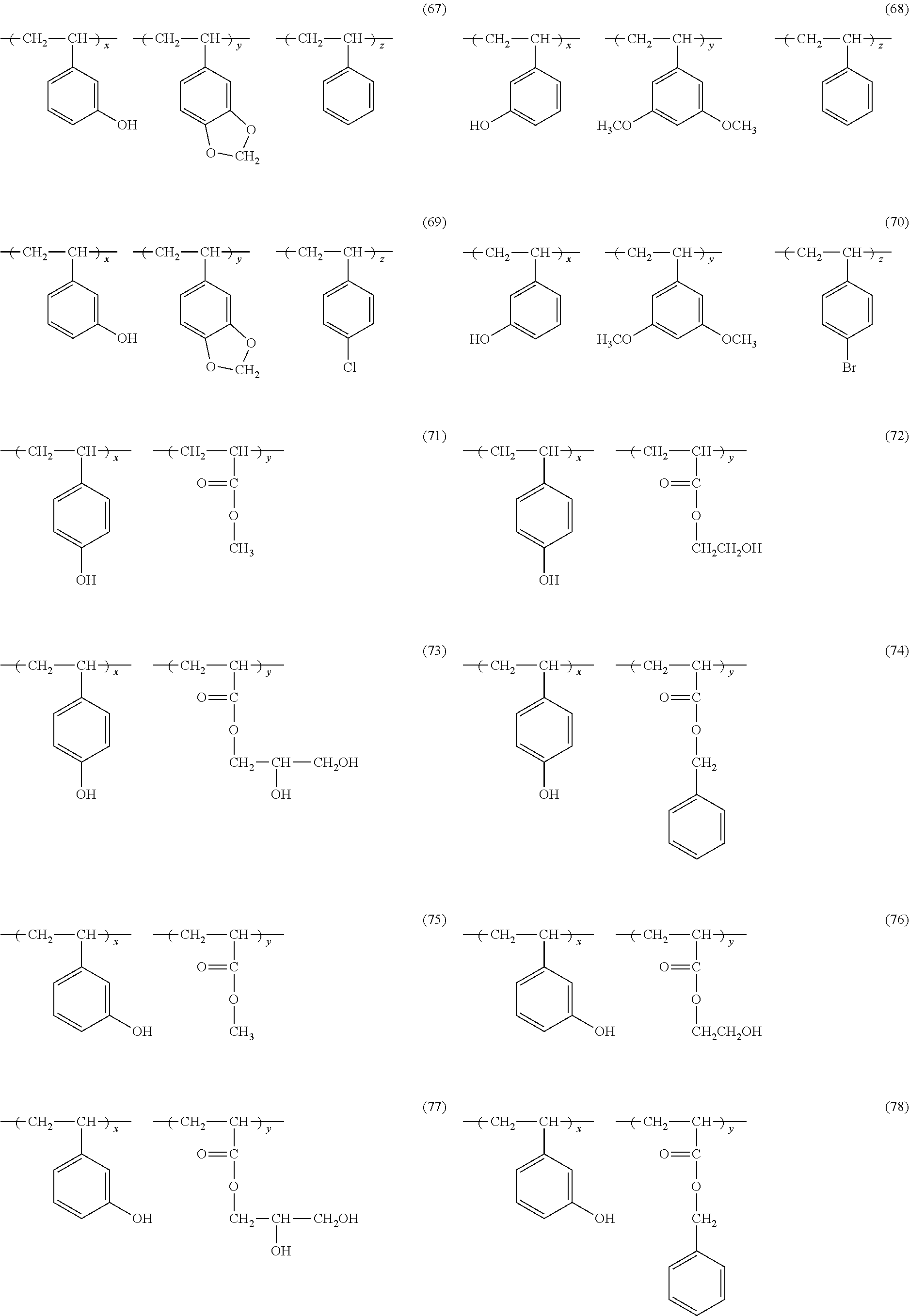

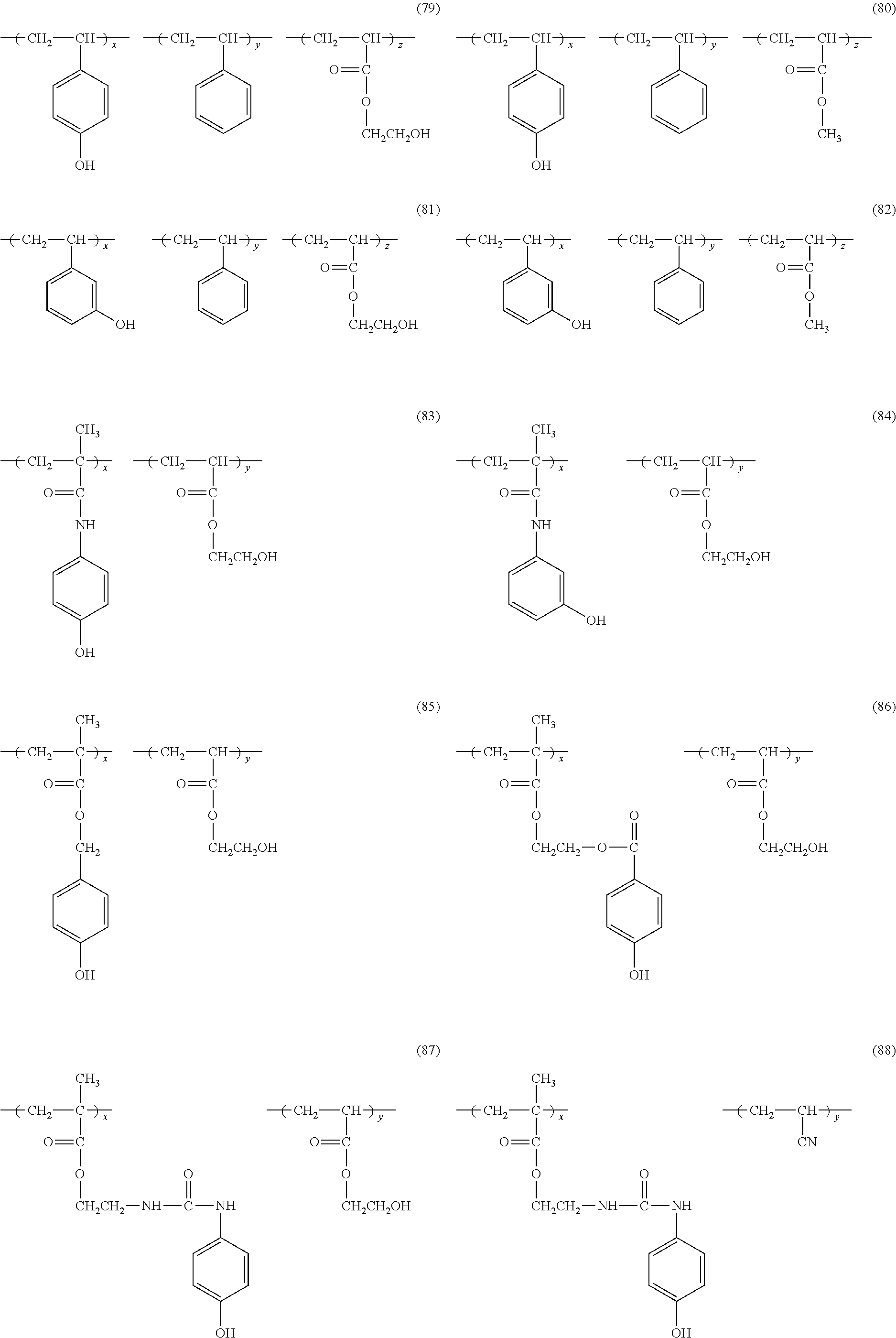

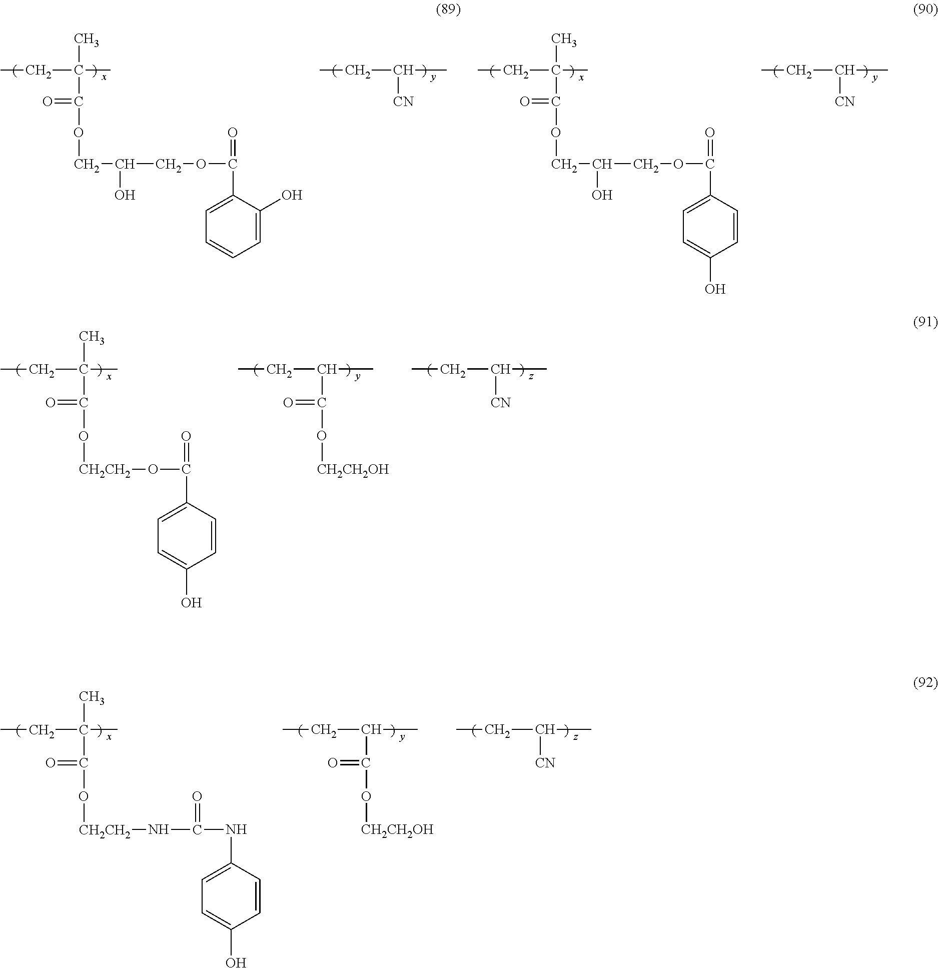

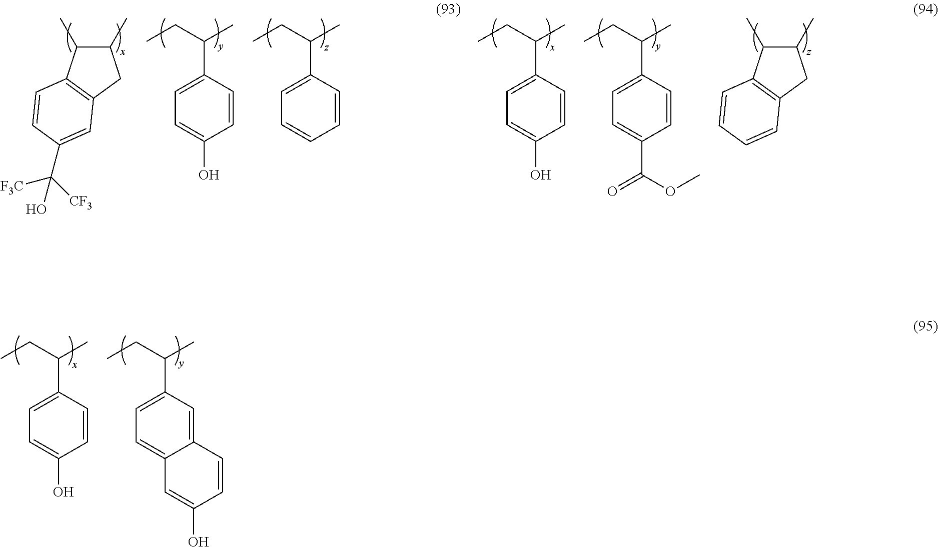

[3] (A) Compound that Generates Acid by Irradiation with Active Light or Radiation

The active light sensitive or radiation sensitive composition of the present invention contains a compound (A) that generates an acid by irradiation with active light or radiation (hereinafter, also referred to as an “acid generator (A)”).

The acid generator (A) may be the same component as the compound [P-B], or may be a different component from the compound [P-B]. In addition, the acid generator (A) may be the same component as the compound [N-B], or may be a different component from the compound [N-B].

In a case where the acid generator (A) is a different component from the compound [P-B] and the compound [N-B], regarding the preferable examples and the specific examples of the acid generator (A), the description for the compound [P-B] or the description for the compound [N-B] is applied, respectively, except for excluding the requirement of “having an acid-decomposable group” and the requirement of “having a polymerizable group”.

The acid generator (A) may have a form of a low molecular weight compound, or may have a form in which the acid generator (A) is incorporated into a part of a polymer. In addition, a form of a low molecular weight compound and a form in which the acid generator (A) is incorporated into a part of a polymer may be used in combination.

In a case where the acid generator (A) has a form of a low molecular weight compound, the molecular weight is preferably 3000 or less, more preferably 2000 or less, and still more preferably 1000 or less.

In the case of a form in which the acid generator (A) is incorporated into a part of a polymer, the acid generator (A) may be incorporated into the resin [P-A], the resin [N-A], or a part of the resin (A), or may be incorporated into a resin different from the resin [P-A], the resin [N-A], and the resin (A). In this case, the acid generator (A) is preferably a resin containing a repeating unit having a portion that generates an acid by irradiation with active light or radiation.

Particularly preferable examples of the acid generator (A) are exemplified below.

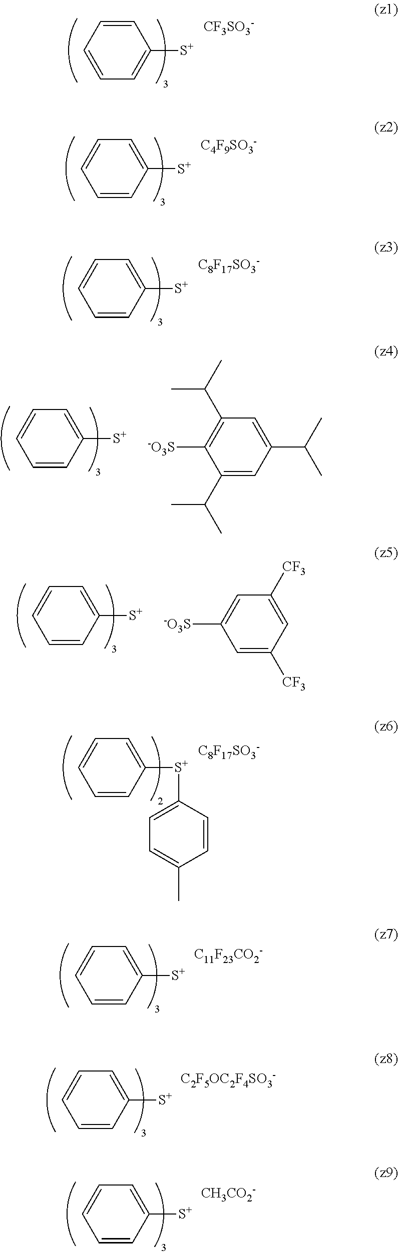

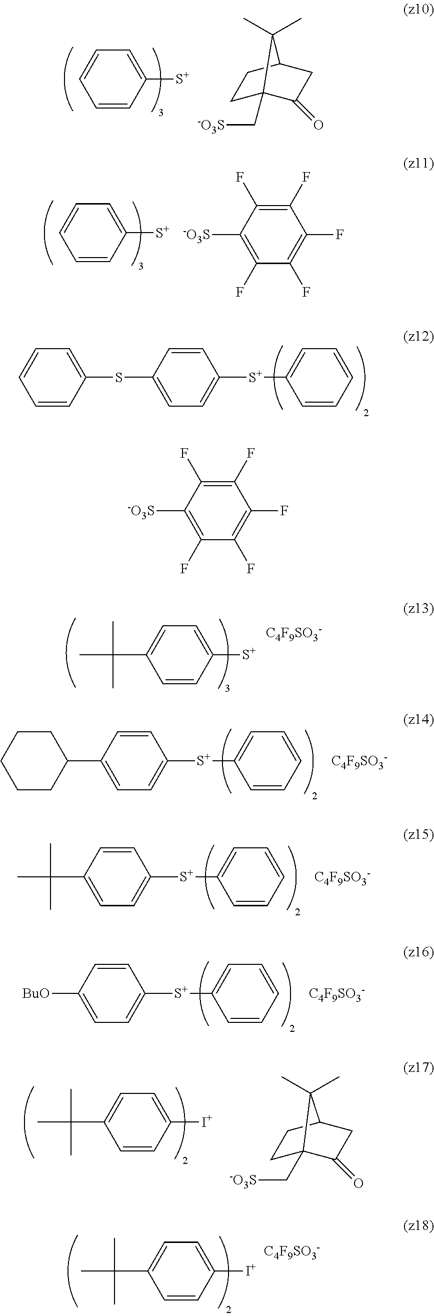

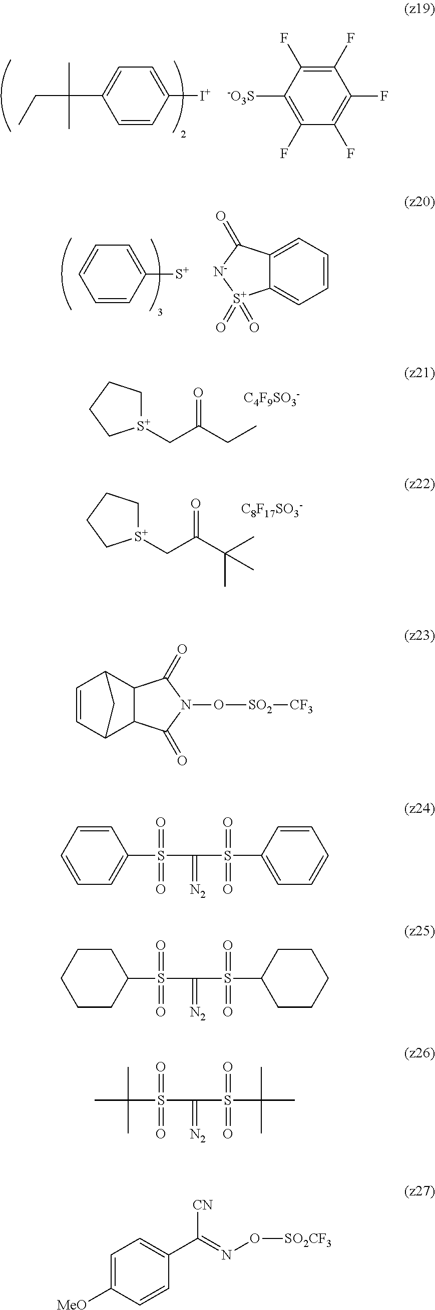

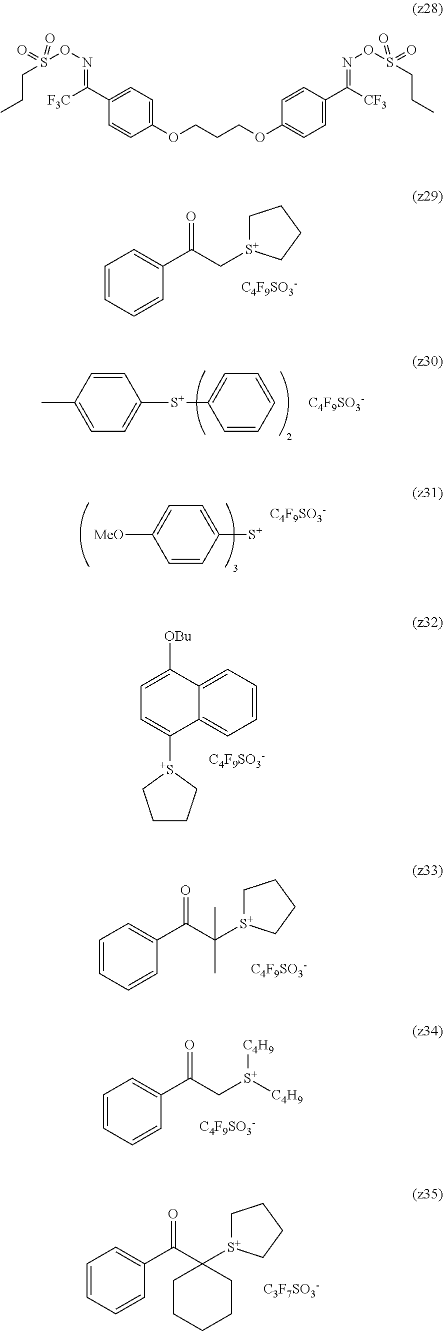

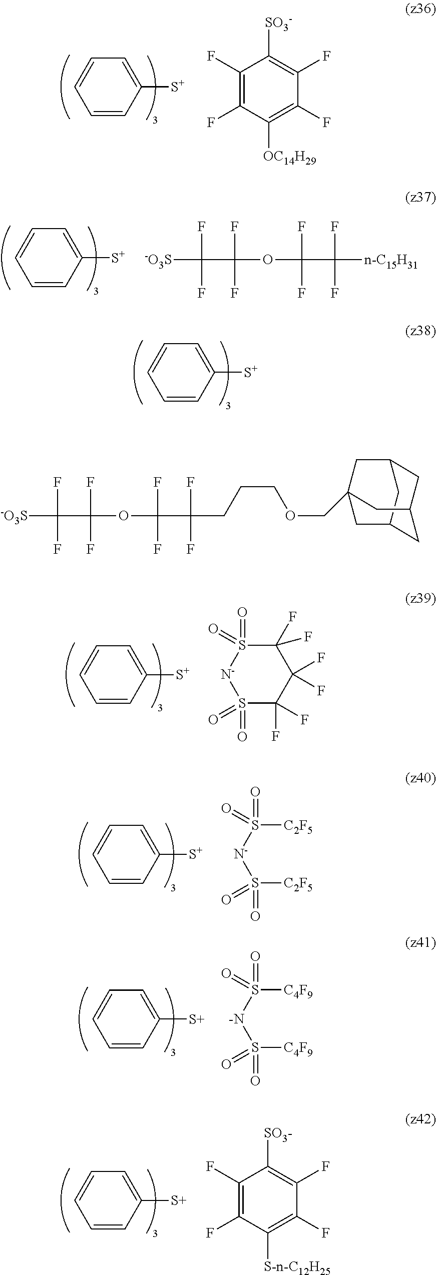

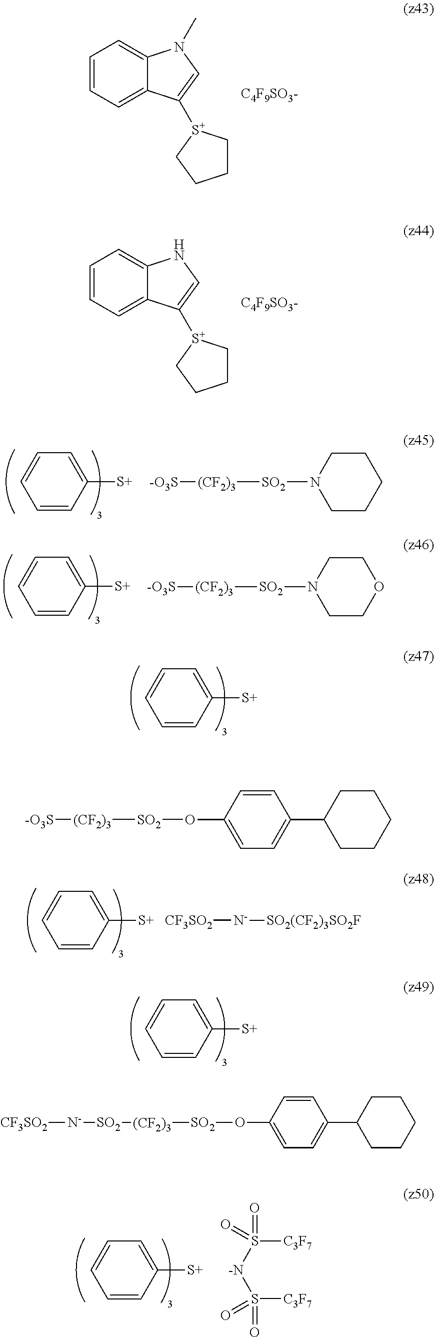

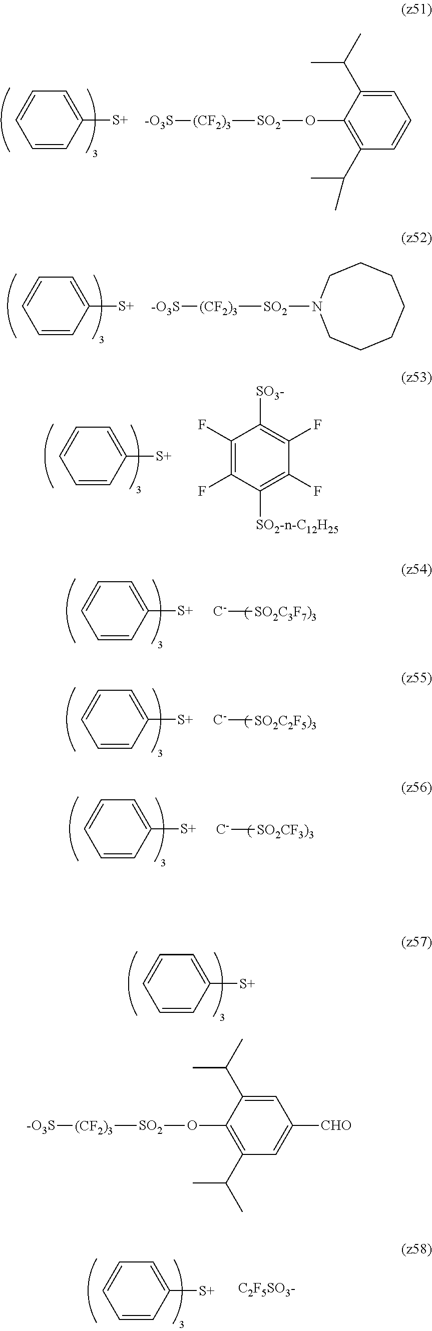

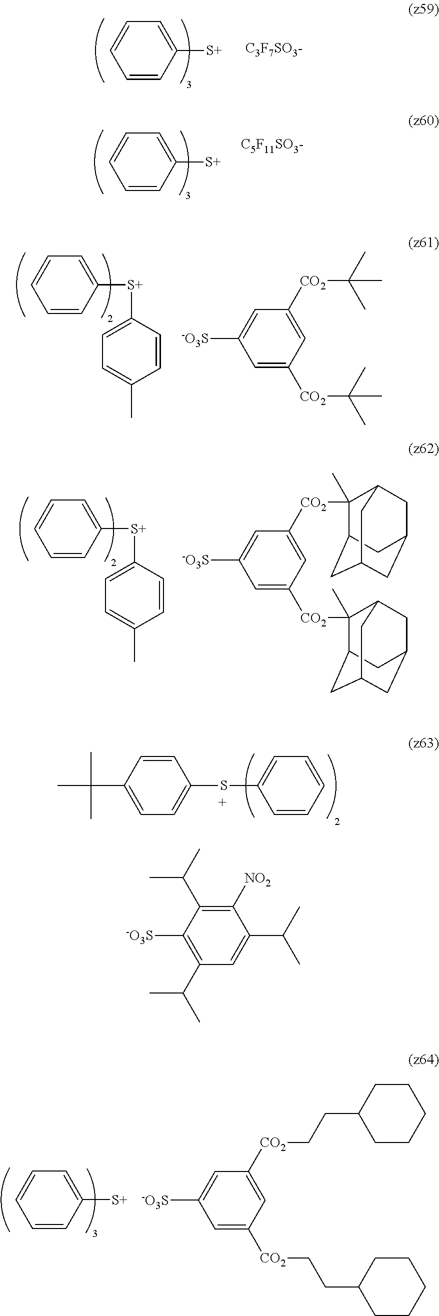

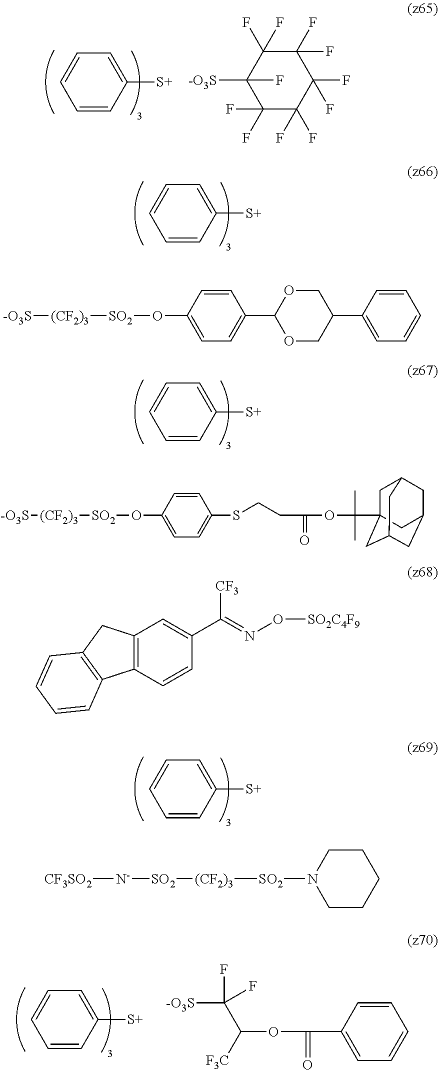

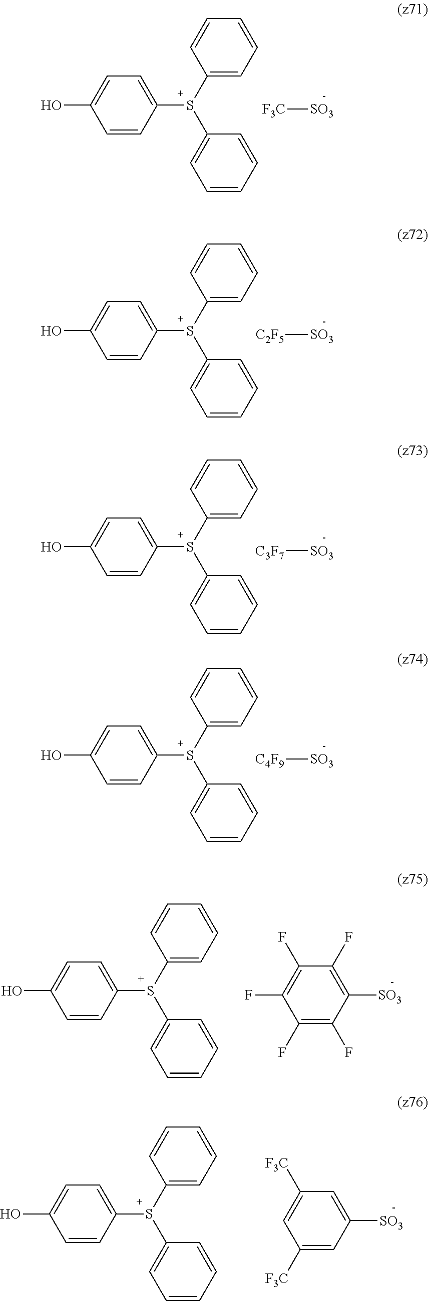

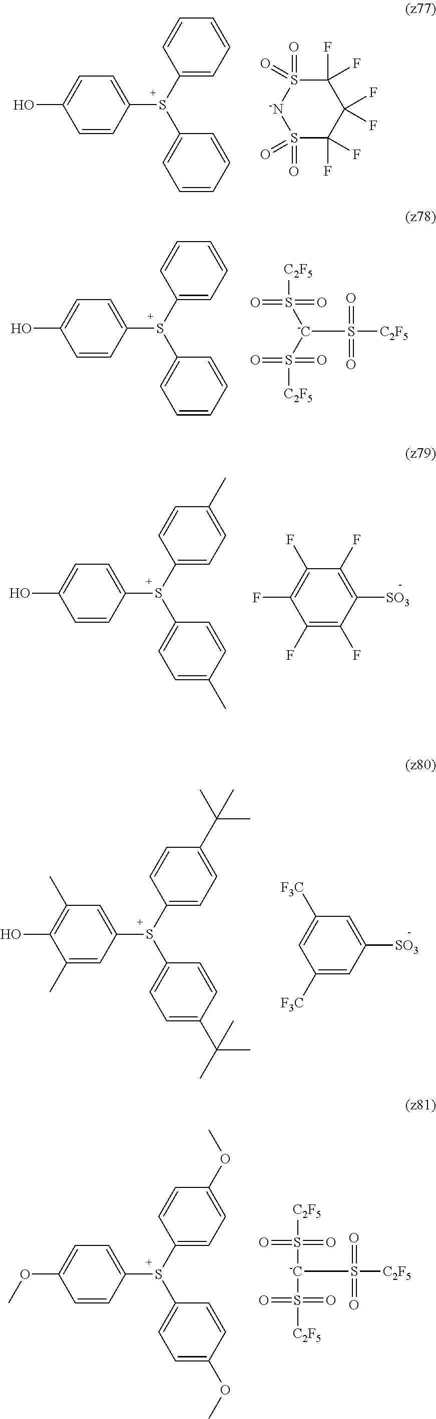

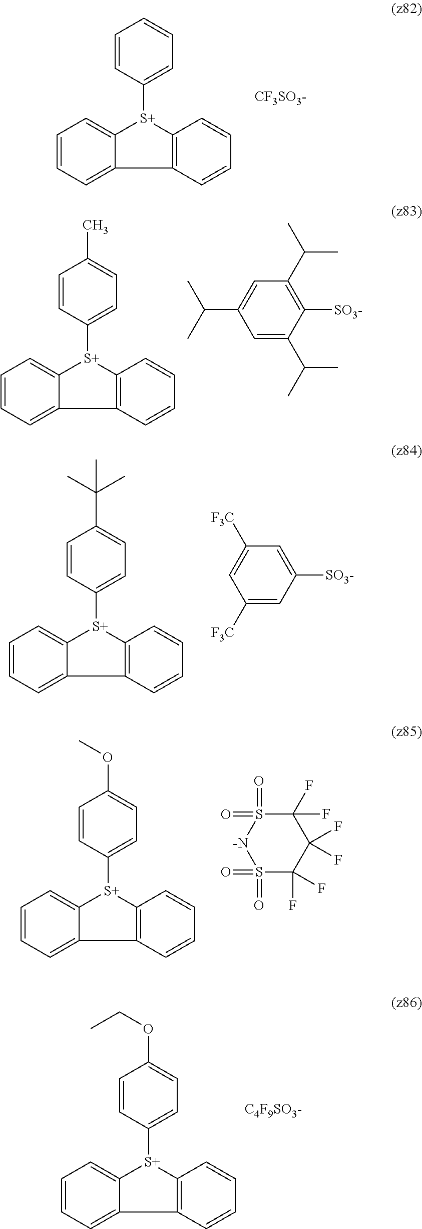

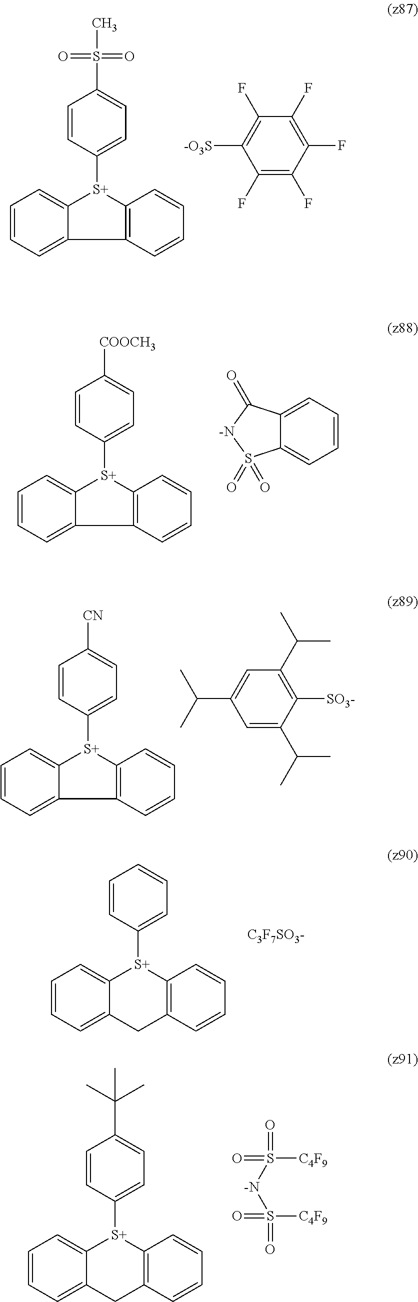

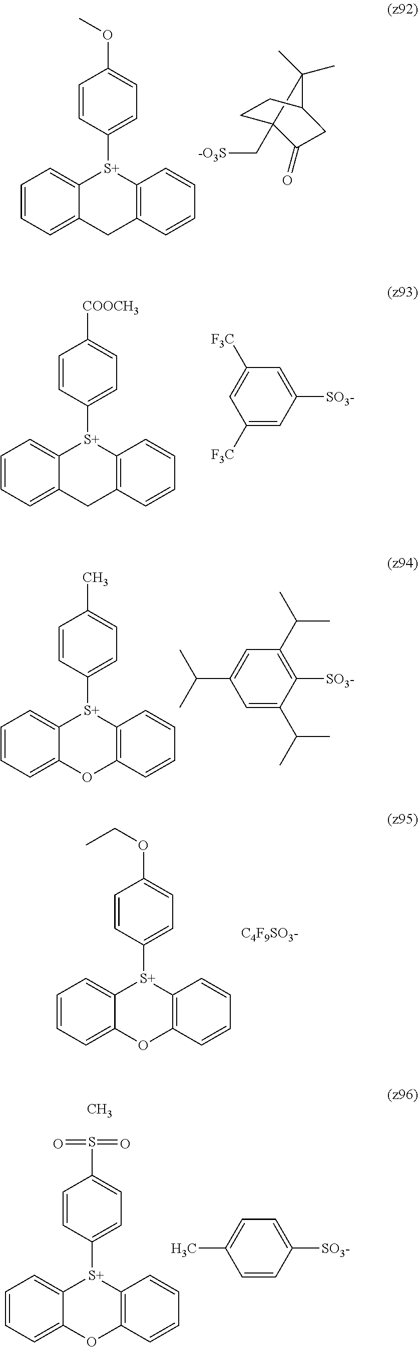

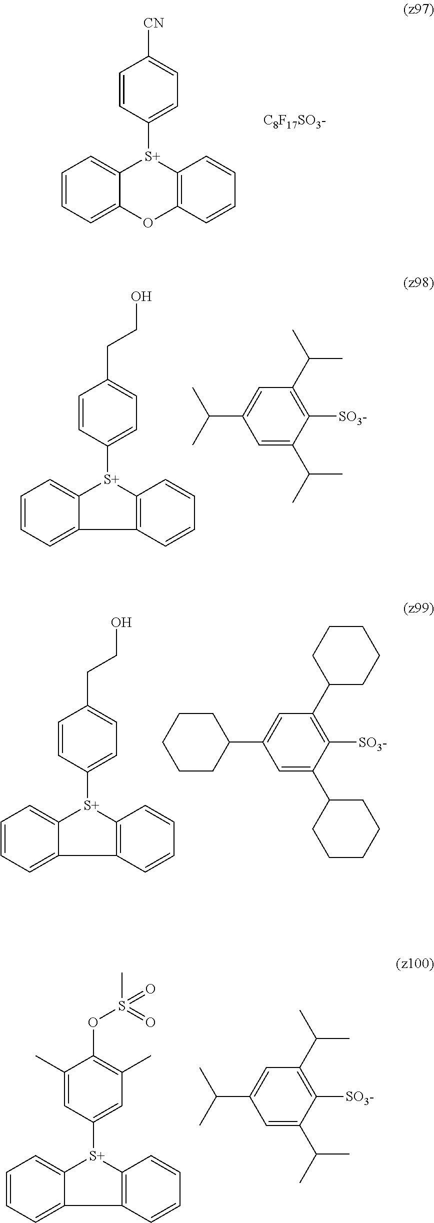

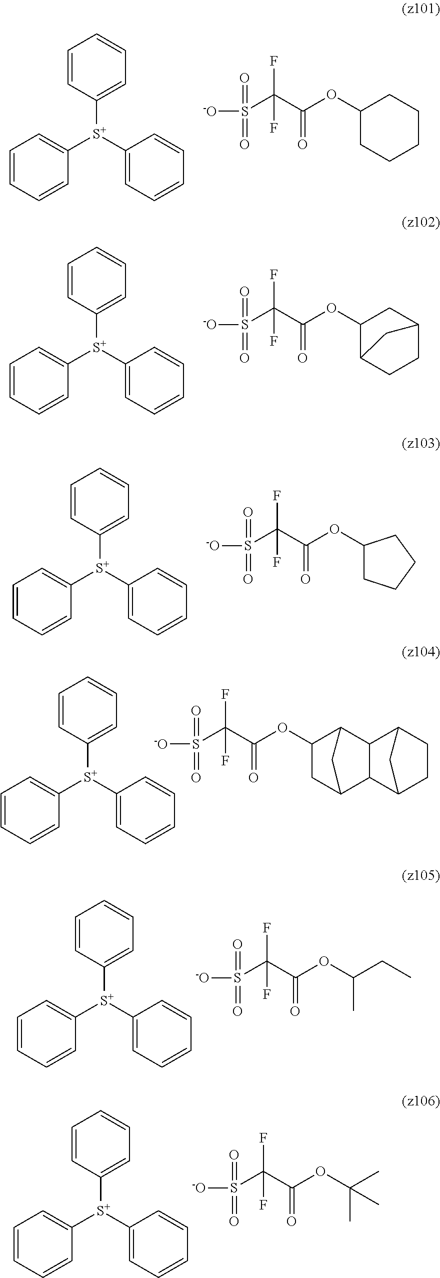

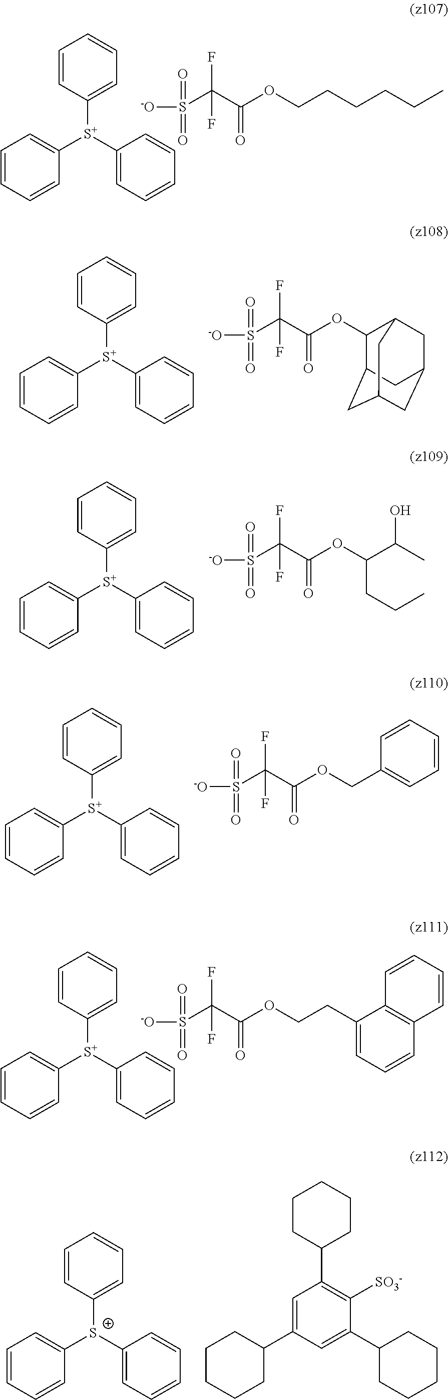

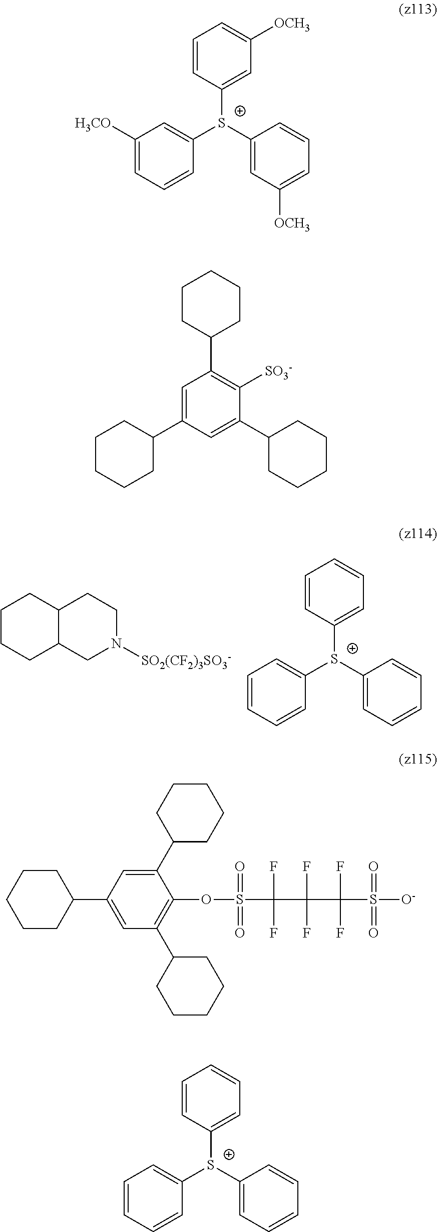

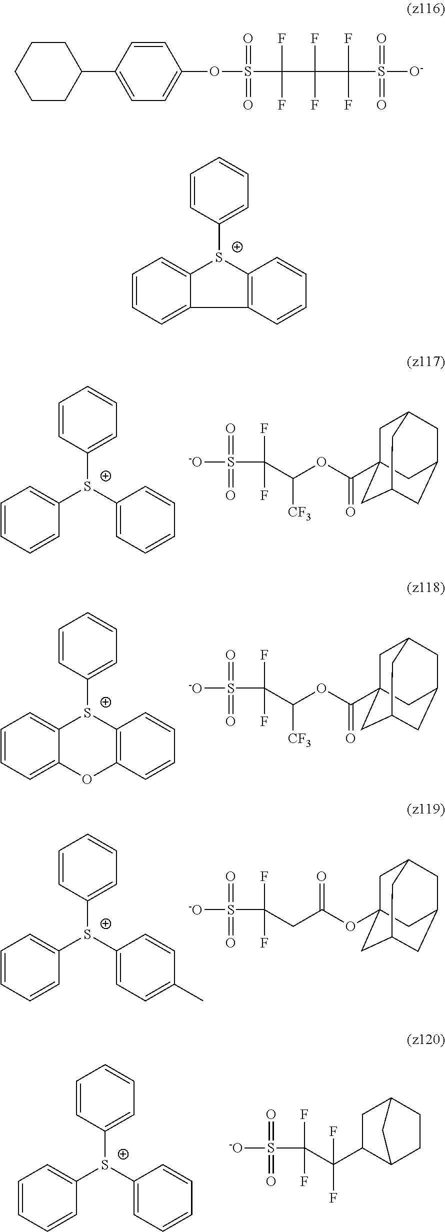

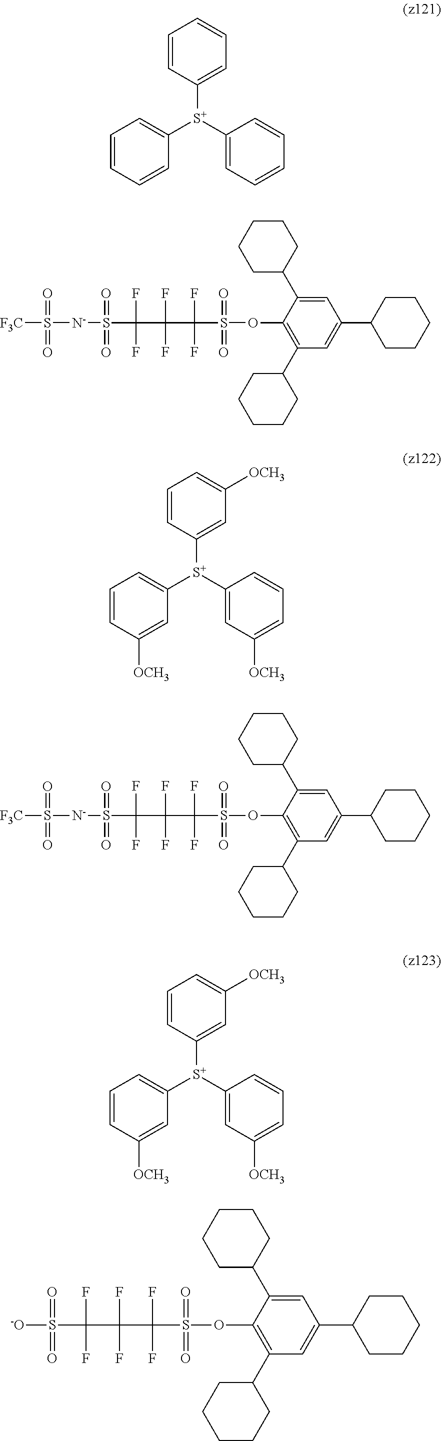

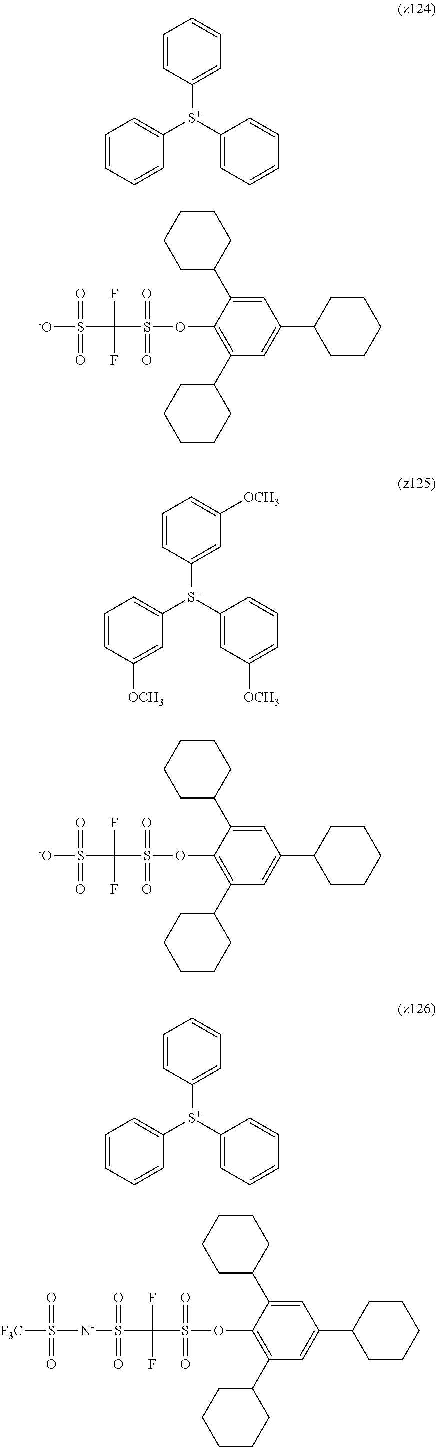

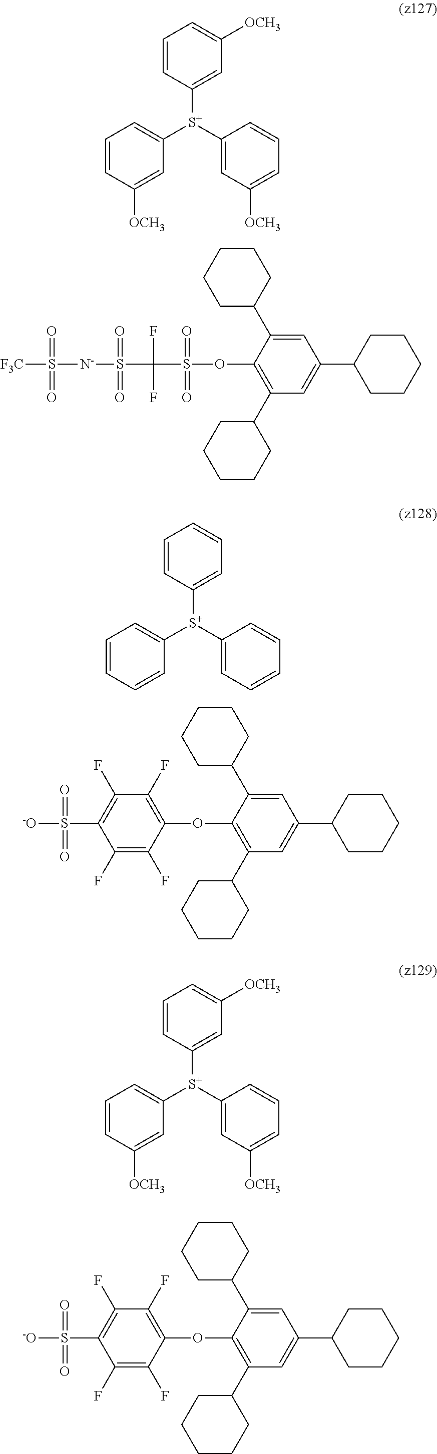

The acid generator (A) is preferably a compound that generates an acid having a volume of 240 Angstrom³ or greater, more preferably a compound that generates an acid having a volume of 300 Angstrom³ or greater, still more preferably a compound that generates an acid having a volume of 350 Angstrom³ or greater, and particularly preferably a compound that generates an acid having a volume of 400 Angstrom³ or greater, by irradiation with active light or radiation, from the viewpoint of suppressing diffusion of the acid generated by exposure to the unexposed portion and improving resolution. Here, from the viewpoint of sensitivity and coating solvent solubility, the volume is preferably 2000 Angstrom³ or less, and more preferably 1500 Angstrom³ or less. The volume value is determined by using “WinMOPAC” manufactured by FUJITSU. That is, first, the chemical structure of the acid according to each example is input, then, using this structure as an initial structure, the most stable conformation of each acid is determined by molecular force field calculation using an MM3 method, and then, by performing molecular orbital calculation using a PM3 method on these most stable conformations, the “accessible volume” of each acid can be calculated.

In the present invention, particularly preferable acid generators are exemplified below. Calculated volume values are given to some examples (unit Angstrom³). Moreover, the calculated value determined here is a volume value of an acid in which a proton is bonded to the anionic portion.

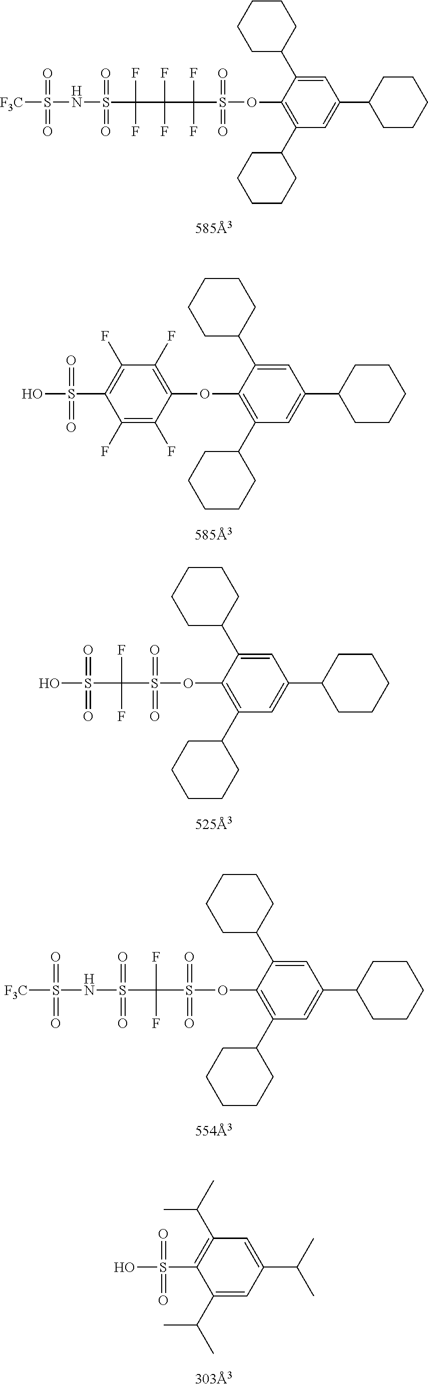 [SMILES: O=S(=O)(NS(=O)(=O)C(F)(F)C(F)(F)C(F)(F)S(=O)(=O)Oc1c(C2CCCCC2)cc(C2CCCCC2)cc1C1CCCCC1)C(F)(F)F ; O=S(=O)(O)c1c(F)c(F)c(Oc2c(C3CCCCC3)cc(C3CCCCC3)cc2C2CCCCC2)c(F)c1F ; O=S(=O)(O)C(F)(F)S(=O)(=O)Oc1c(C2CCCCC2)cc(C2CCCCC2)cc1C1CCCCC1 ; O=S(=O)(NS(=O)(=O)C(F)(F)S(=O)(=O)Oc1c(C2CCCCC2)cc(C2CCCCC2)cc1C1CCCCC1)C(F)(F)F ; CC(C)c1cc(C(C)C)c(S(=O)(=O)O)c(C(C)C)c1]

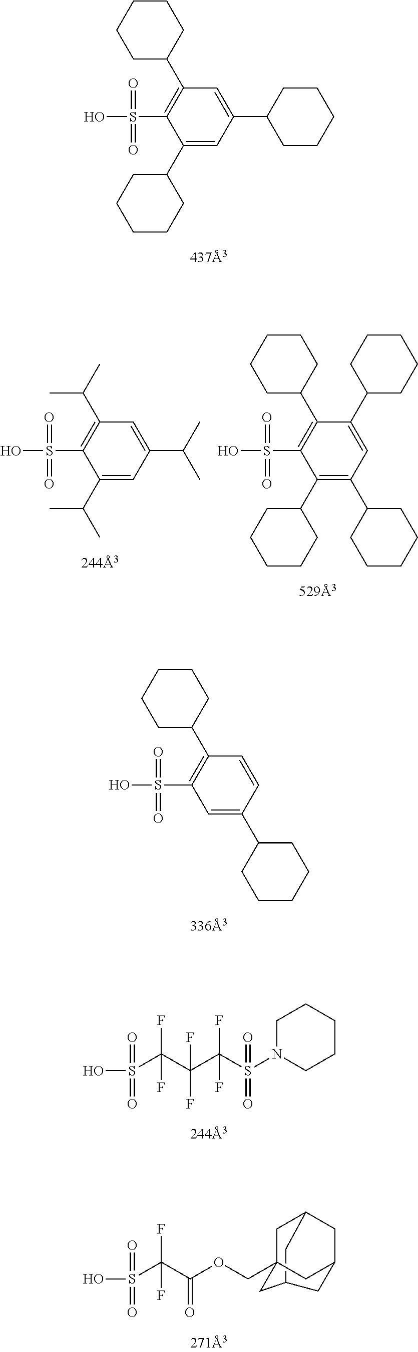

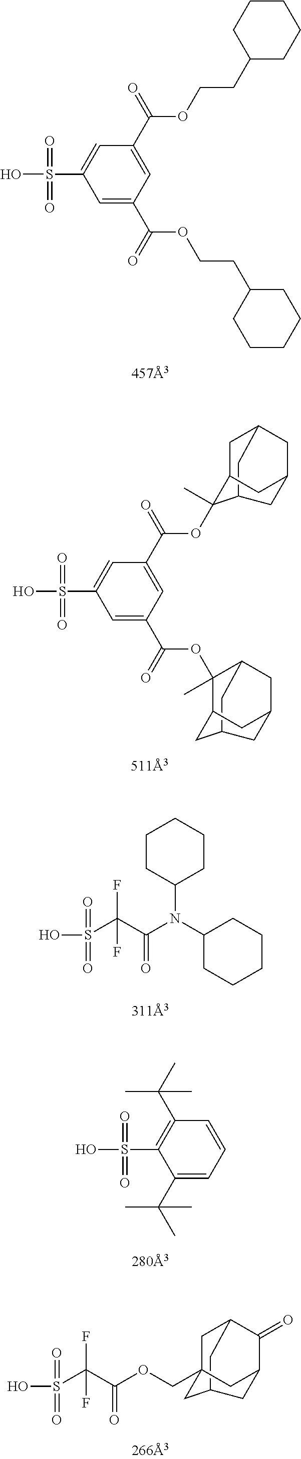

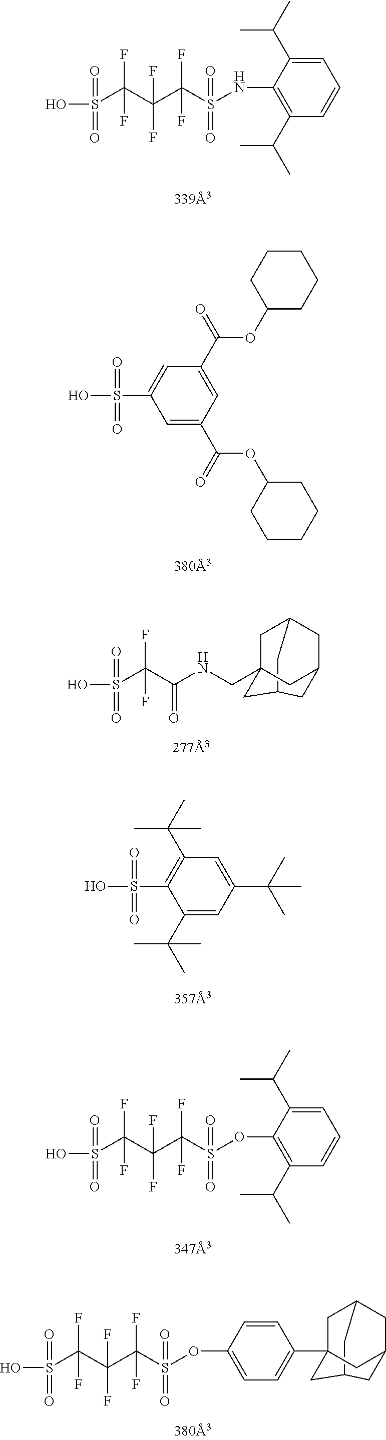 [SMILES: CC(C)c1cccc(C(C)C)c1NS(=O)(=O)C(F)(F)C(F)(F)C(F)(F)S(=O)(=O)O ; O=C(OC1CCCCC1)c1cc(C(=O)OC2CCCCC2)cc(S(=O)(=O)O)c1 ; O=C(NCC12CC3CC(CC(C3)C1)C2)C(F)(F)S(=O)(=O)O ; CC(C)(C)c1cc(C(C)(C)C)c(S(=O)(=O)O)c(C(C)(C)C)c1 ; CC(C)c1cccc(C(C)C)c1OS(=O)(=O)C(F)(F)C(F)(F)C(F)(F)S(=O)(=O)O ; O=S(=O)(O)C(F)(F)C(F)(F)C(F)(F)S(=O)(=O)Oc1ccc(C23CC4CC(CC(C4)C2)C3)cc1]

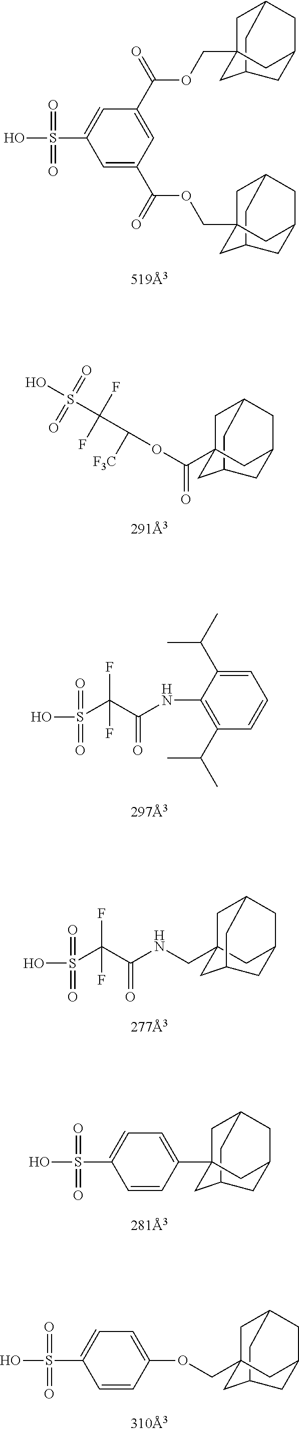 [SMILES: O=C(OCC12CC3CC(CC(C3)C1)C2)c1cc(C(=O)OCC23CC4CC(CC(C4)C2)C3)cc(S(=O)(=O)O)c1 ; O=C(OC(C(F)(F)F)C(F)(F)S(=O)(=O)O)C12CC3CC(CC(C3)C1)C2 ; CC(C)c1cccc(C(C)C)c1NC(=O)C(F)(F)S(=O)(=O)O ; O=C(NCC12CC3CC(CC(C3)C1)C2)C(F)(F)S(=O)(=O)O ; O=S(=O)(O)c1ccc(C23CC4CC(CC(C4)C2)C3)cc1 ; O=S(=O)(O)c1ccc(OCC23CC4CC(CC(C4)C2)C3)cc1]

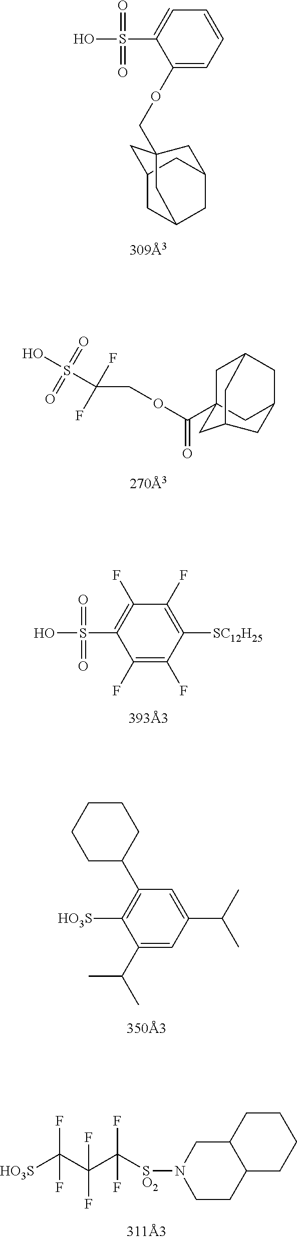

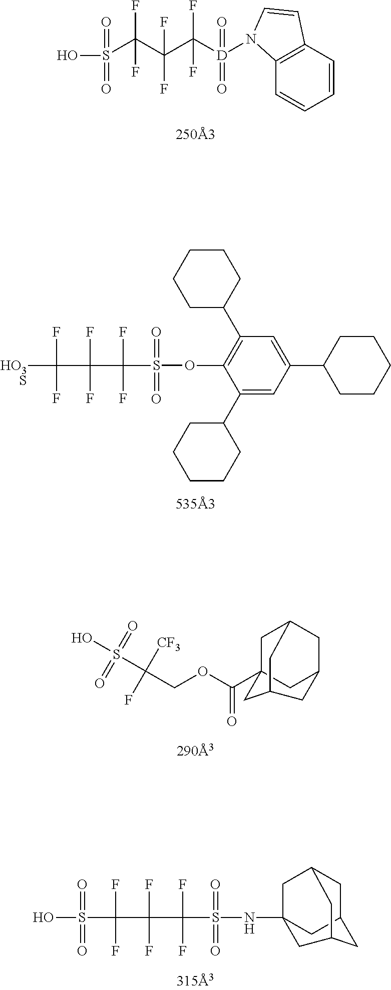

The acid generator (A) can be used alone, or two or more types thereof can be used in combination.

In the case of forming a negative image (that is, in a case where the active light sensitive or radiation sensitive composition is a negative type active light sensitive or radiation sensitive composition), the content of the acid generator (A) in the composition is preferably 0.1% by mass to 25% by mass, more preferably 0.5% by mass to 20% by mass, and still more preferably 1% by mass to 18% by mass based on the total solid content of the composition. In the case of forming a positive image (that is, in a case where the active light sensitive or radiation sensitive composition is a positive type active light sensitive or radiation sensitive composition), the content of the acid generator (A) in the composition is preferably 0.1% by mass to 20% by mass, more preferably 0.5% by mass to 15% by mass, and still more preferably 1% by mass to 10% by mass based on the total solid content of the composition.

In the case of a form in which the acid generator (A) is incorporated into a part of a polymer, the polymer preferably contains a repeating unit having a portion that generates an acid by irradiation with active light or radiation. Specific examples of the repeating unit having a portion that generates an acid by irradiation with active light or radiation are exemplified below.

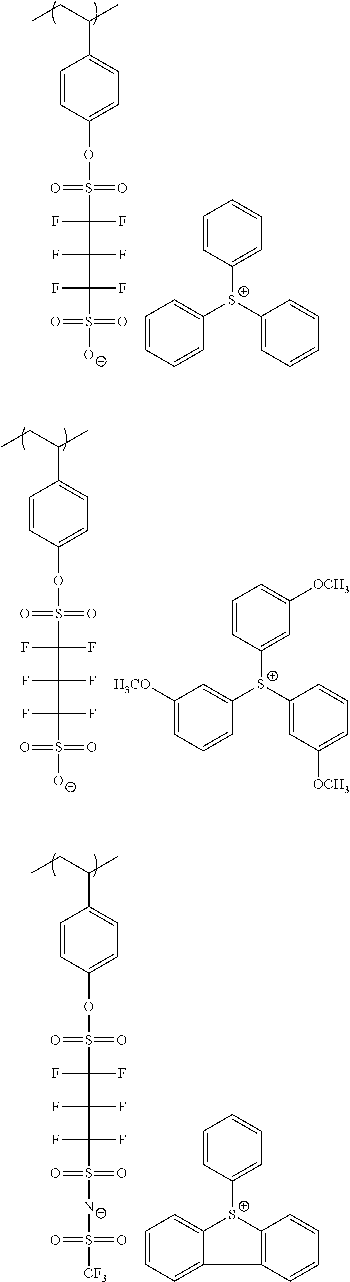

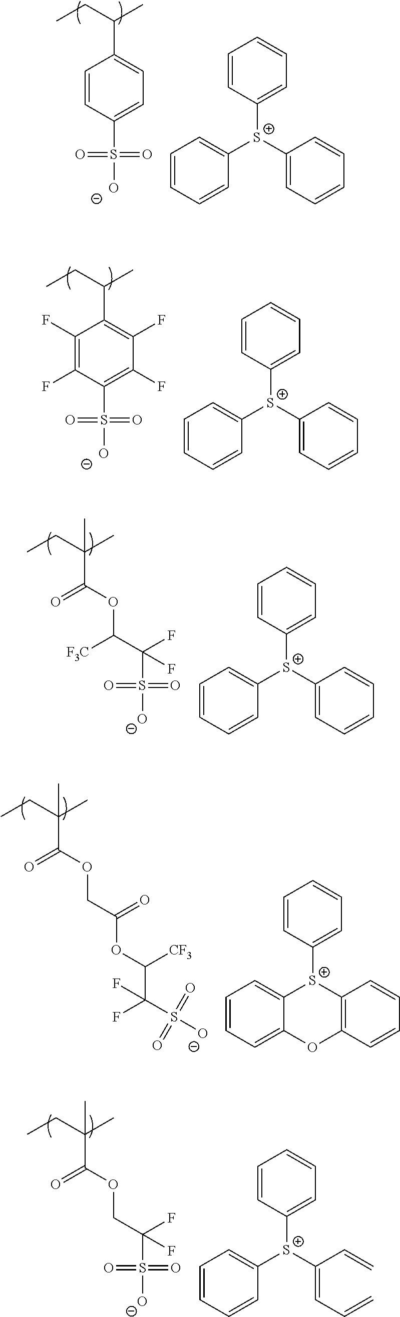

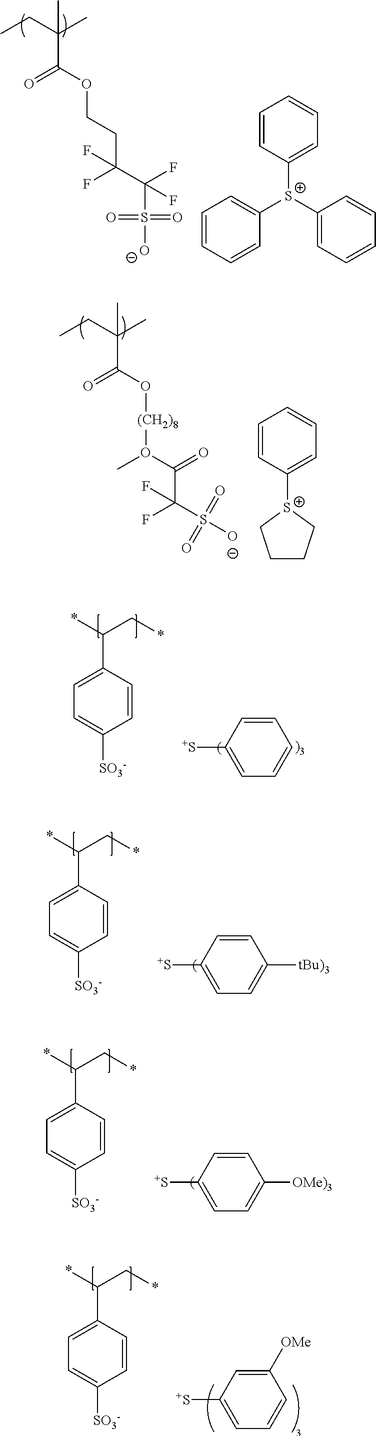

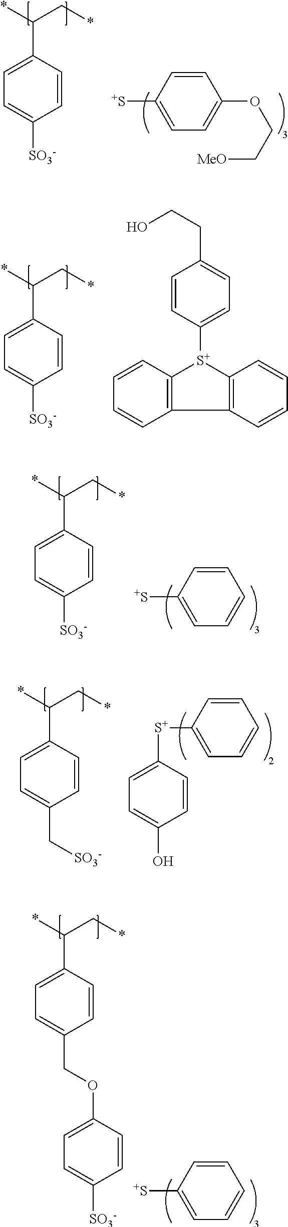

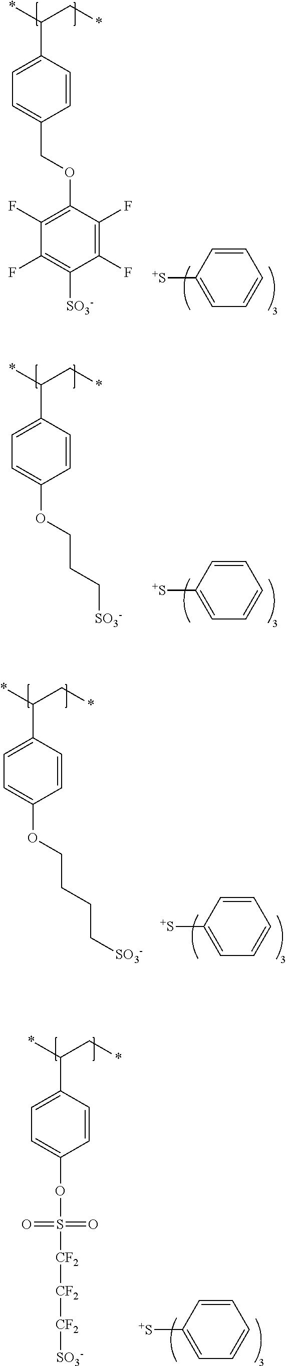

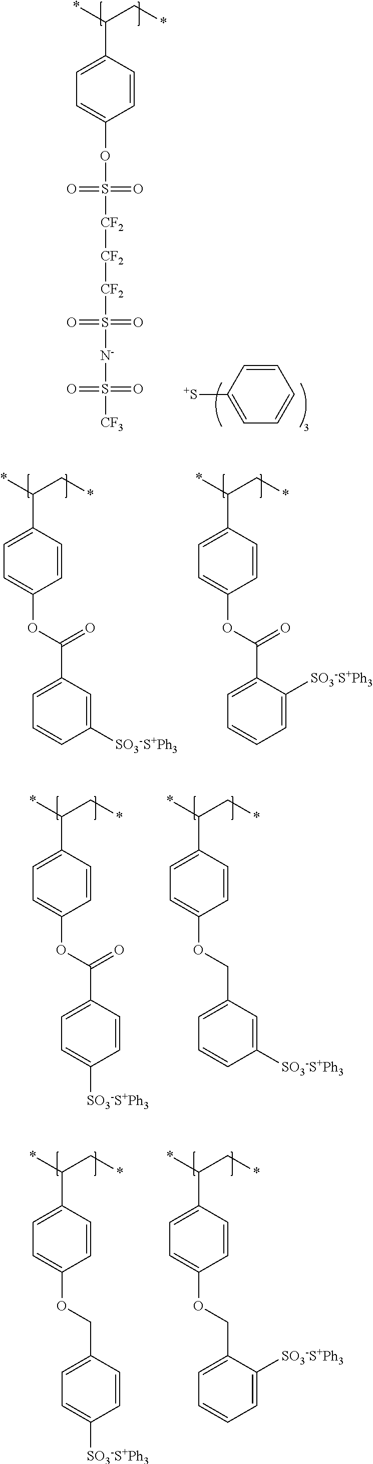

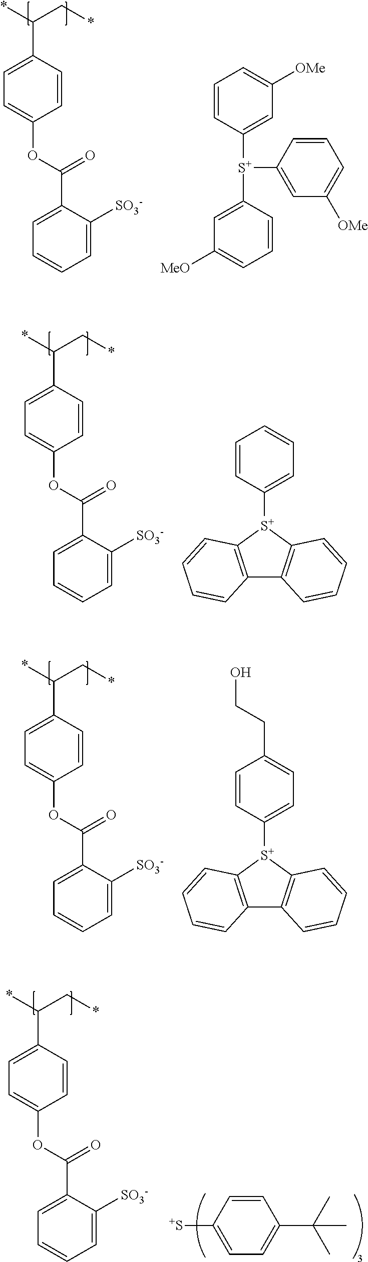

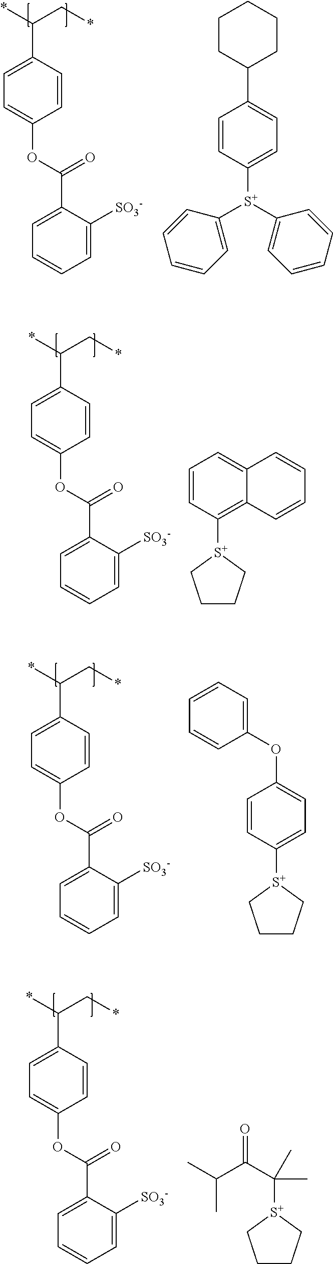

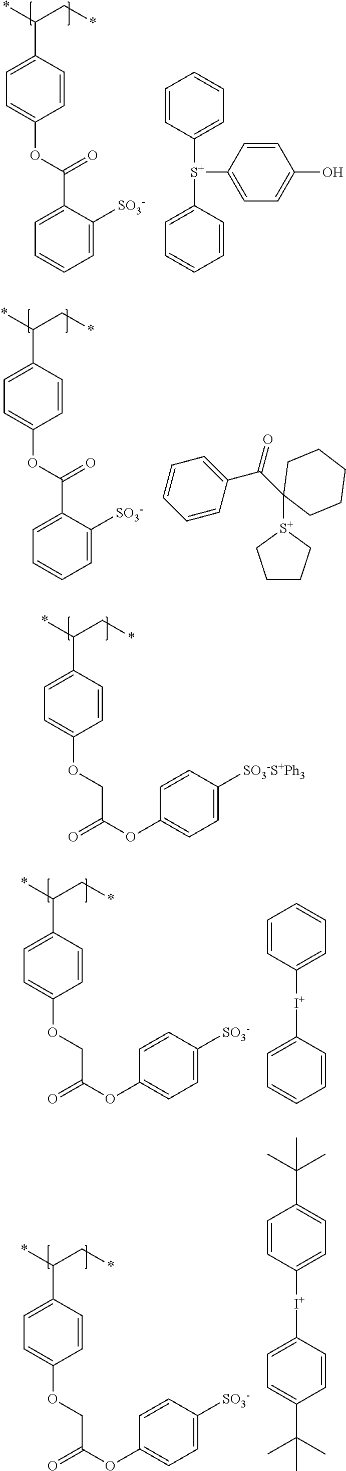

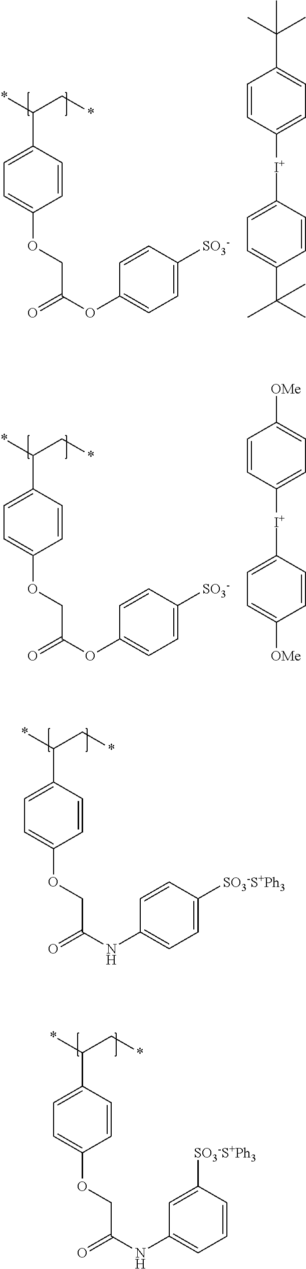

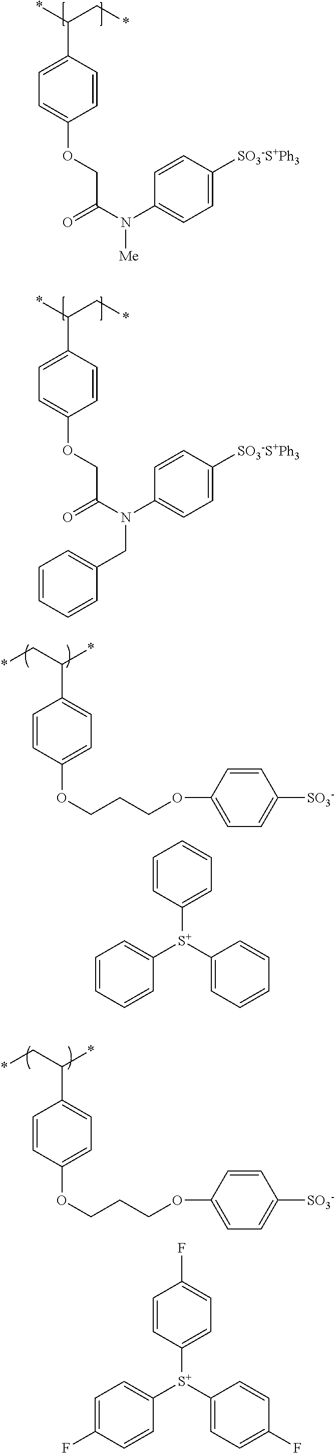

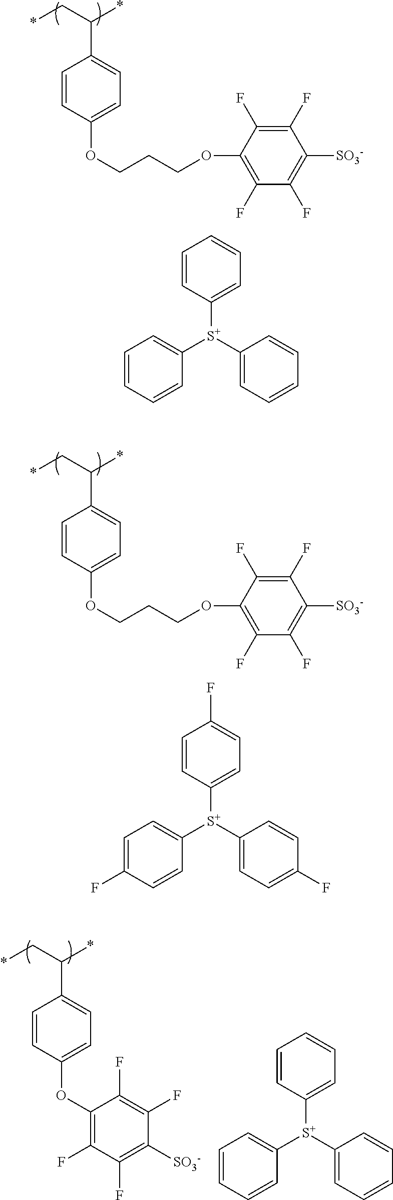

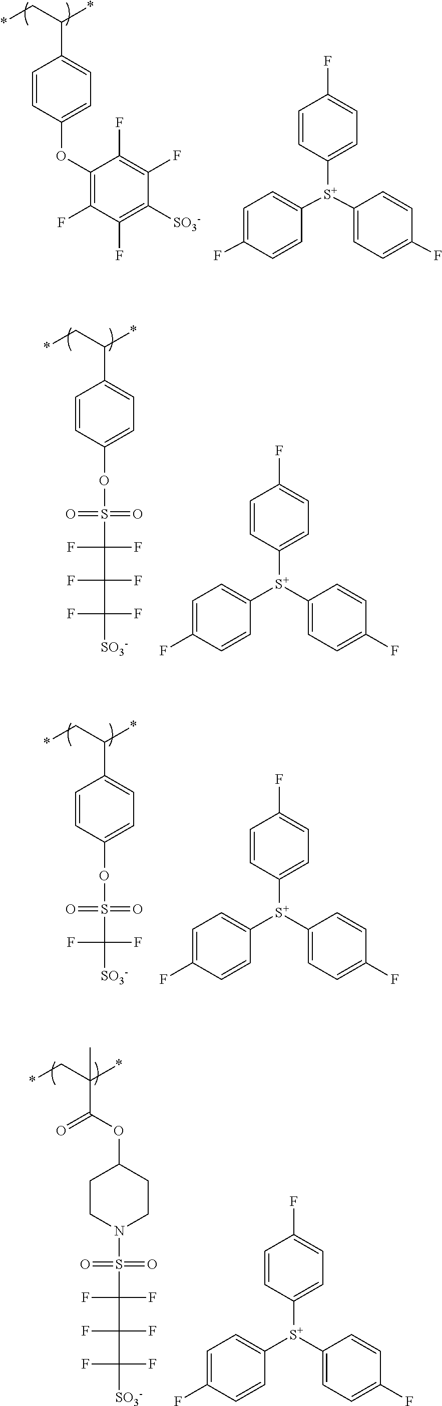

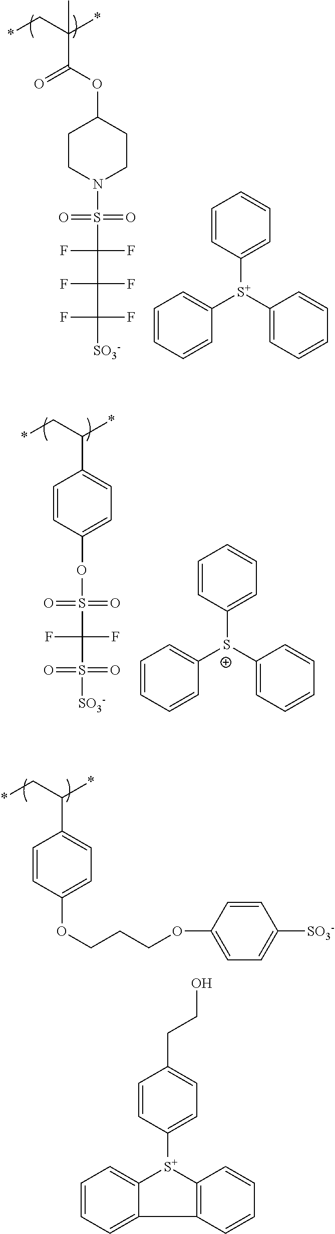

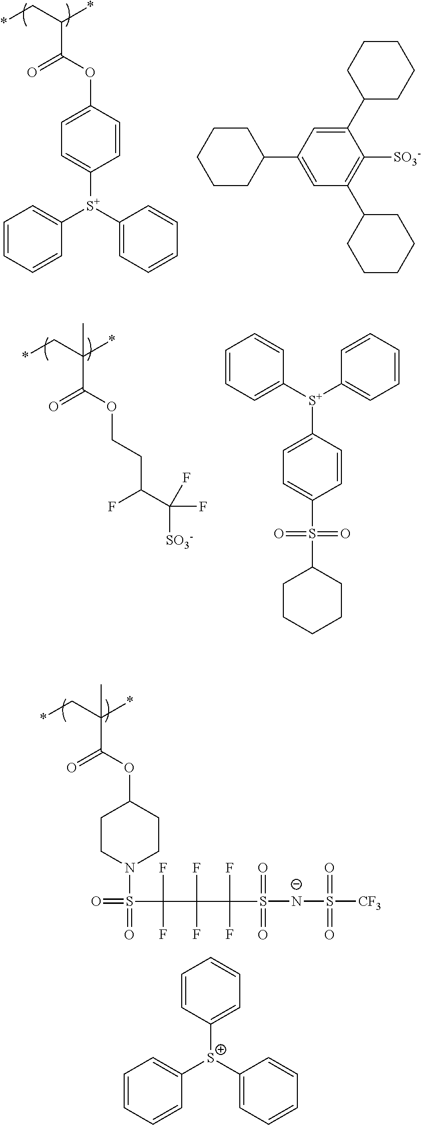

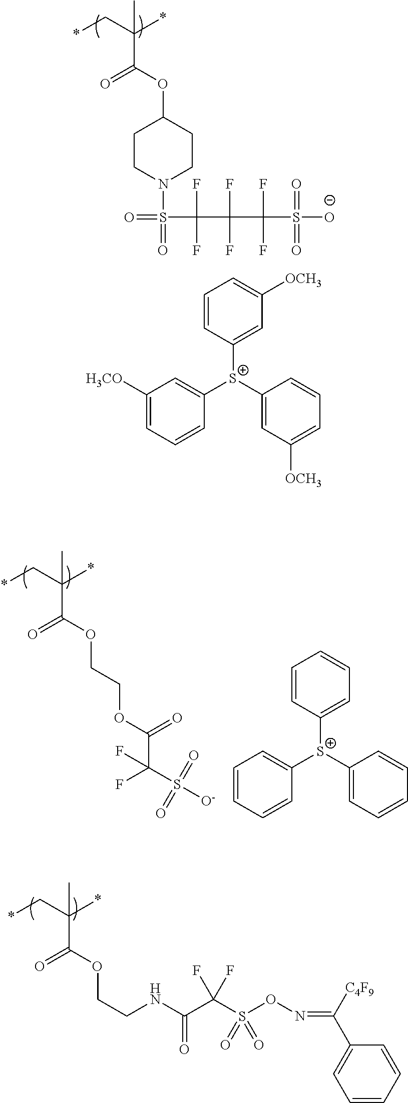

As described above, the active light sensitive or radiation sensitive composition of the present invention contains the compound (A) that generates an acid by irradiation with active light or radiation, the compound (P) of which the solubility in alkali developers is increased due to the action of an acid, and at least one compound (N) selected from the group consisting of (N-1) to (N-3) described above, and can contain other components. Other components will be described below.

The active light sensitive or radiation sensitive composition of the present invention may contain the resin (A) even in the case of not containing a cross-linking agent as the low molecular weight compound [N-C]. The details and the content of the resin (A) are as described above.

[4] Resist Solvent (Coating Solvent)

The solvent which can be used when preparing the composition is not particularly limited as long as each component is dissolved therein, and examples thereof include an alkylene glycol monoalkyl ether carboxylate (propylene glycol monomethyl ether acetate (PGMEA; also referred to as 1-methoxy-2-acetoxypropane) and the like), an alkylene glycol monoalkyl ether (propylene glycol monomethyl ether (PGME; also referred to as 1-methoxy-2-propanol) or the like), an alkyl lactate (ethyl lactate, methyl lactate, or the like), a cyclic lactone (γ-butyrolactone or the like, which preferably has 4 to 10 carbon atoms), a chain-like or a cyclic ketone (2-heptanone, cyclohexanone, or the like, which preferably has 4 to 10 carbon atoms), an alkylene carbonate (ethylene carbonate, propylene carbonate, or the like), an alkyl carboxylate (an alkyl acetate such as butyl acetate is preferable), and an alkyl alkoxyacetate (ethyl ethoxypropionate). Other examples of the solvent which can be used include the solvents described in paragraphs [0244] and later of US2008/0248425A1.

Among these, an alkylene glycol monoalkyl ether carboxylate, or an alkylene glycol monoalkyl ether is preferable.

These solvents may be used alone or in a mixture of two or more types thereof. In a case where two or more types are mixed, it is preferable to mix a solvent having a hydroxyl group and a solvent not having a hydroxyl group. The mass ratio of the solvent having a hydroxyl group and the solvent not having a hydroxyl group is 1/99 to 99/1, preferably 10/90 to 90/10, and more preferably 20/80 to 60/40.

The solvent having a hydroxyl group is preferably alkylene glycol monoalkyl ether, and the solvent not having a hydroxyl group is preferably alkylene glycol mono alkyl ether carboxylate.

[5] Basic Compound

The active light sensitive or radiation sensitive composition in the present invention preferably contains a basic compound.

The active light sensitive or radiation sensitive composition preferably contains a basic compound or an ammonium salt compound (C) (hereinafter, also referred to as a “compound (C)”), of which the basicity is decreased by irradiation with active light or radiation.

The compound (C) is preferably a compound (C-1) having a basic functional group or an ammonium group and a group that generates an acidic functional group by irradiation with active light or radiation. That is, the compound (C) is preferably a basic compound having a basic functional group and a group that generates an acidic functional group by irradiation with active light or radiation, or an ammonium salt compound having an ammonium group and a group that generates an acidic functional group by irradiation with active light or radiation. The compound (C) is more preferably a sulfonium salt having a nitrogen atom on the cation thereof.

Particularly preferable examples of the compound (C) are exemplified below. In addition, compounds exemplified as (A-1) to (A-23) on page 5 and later in the specification of US2012/0156617A and compounds exemplified as (A-1) to (A-44) on page 9 and later in the specification of US2006/0264528A are also preferably exemplified.

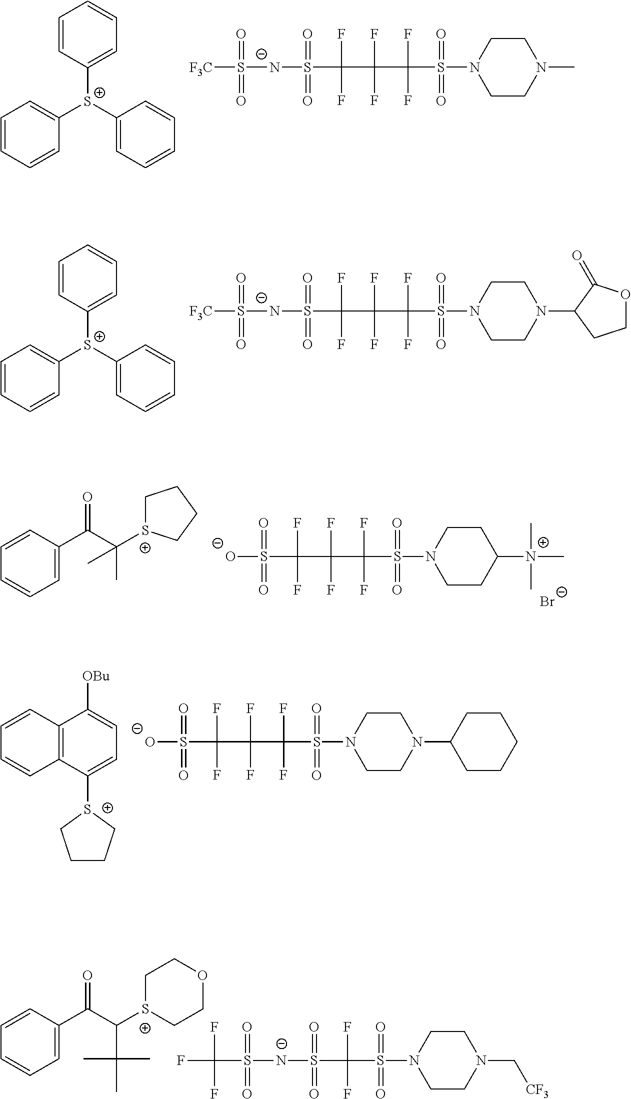

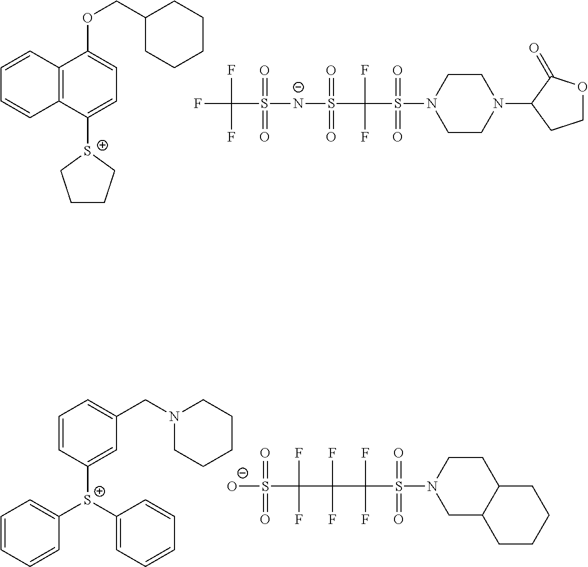 [SMILES: c1ccc2c([S+]3CCCC3)ccc(OCC3CCCCC3)c2c1 ; O=C1OCCC1N1CCN(S(=O)(=O)C(F)(F)S(=O)(=O)[N-]S(=O)(=O)C(F)(F)F)CC1 ; c1ccc([S+](c2ccccc2)c2cccc(CN3CCCCC3)c2)cc1 ; O=S(=O)([O-])C(F)(F)C(F)(F)C(F)(F)S(=O)(=O)N1CCC2CCCCC2C1]

These compounds can be synthesized according to the synthesis examples in JP2006-330098A.

The molecular weight of the compound (C) is preferably 500 to 1000.

Although the active light sensitive or radiation sensitive composition in the present invention may not contain the compound (C), in the case of containing, the content of the compound (C) is preferably 0.1% by mass to 20% by mass and more preferably 0.1% by mass to 10% by mass, based on the total solid content of the active light sensitive or radiation sensitive composition.

The active light sensitive or radiation sensitive composition in the present invention may contain a basic compound (N′) different from the compound (C) as a basic compound, to reduce changes in performance over time from exposure to heating.

As the compound (N′), compounds having structures represented by the following General Formulas (A′) to (E′) can be preferably exemplified.

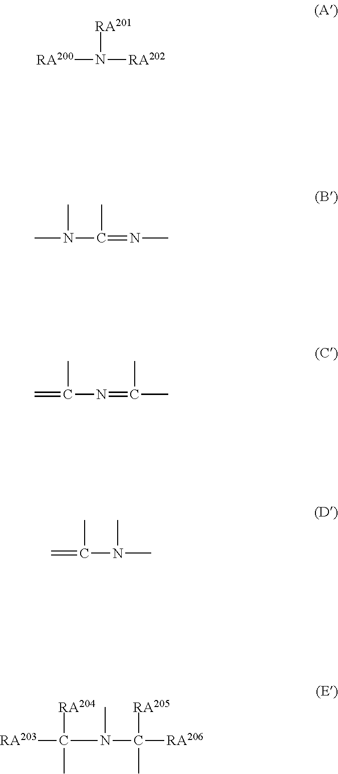

In General Formulas (A′) to (E′), RA²⁰⁰ and RA²⁰² may be the same as or different from each other, and each of RA²⁰⁰, RA²⁰¹, and RA²⁰² represents a hydrogen atom, an alkyl group (preferably having 1 to 20 carbon atoms), a cycloalkyl group (preferably having 3 to 20 carbon atoms), or an aryl group (having 6 to 20 carbon atoms), and RA²⁰¹ and RA²⁰² may be bonded to each other to form a ring. RA²⁰³, RA²⁰⁴, RA²⁰⁵, and RA²⁰⁶ may be the same as or different from each other, and each of RA²⁰³, RA²⁰⁴, RA²⁰⁵, and RA²⁰⁶ represents an alkyl group (preferably having 1 to 20 carbon atoms).

The alkyl group may have a substituent, and preferable examples of the alkyl group having a substituent include an aminoalkyl group having 1 to 20 carbon atoms, a hydroxyalkyl group having 1 to 20 carbon atoms, and a cyanoalkyl group having 1 to 20 carbon atoms.

These alkyl groups in General Formulas (A′) and (E′) are more preferably unsubstituted.

Preferable specific examples of the basic compound (N′) include guanidine, aminopyrrolidine, pyrazole, pyrazoline, piperazine, aminomorpholine, aminoalkyl morpholine, and piperidine, and more preferable specific examples thereof include a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, and an aniline derivative having a hydroxyl group and/or an ether bond.

Examples of the compound having an imidazole structure include imidazole, 2,4,5-triphenyl imidazole, and benzimidazole. Examples of the compound having a diazabicyclo structure include 1,4-diazabicyclo[2,2,2]octane, 1,5-diazabicyclo[4,3,0]non-5-ene, and 1,8-diazabicyclo[5,4,0]undec-7-ene. Examples of the compound having an onium hydroxide structure include triarylsulfonium hydroxide, phenacylsulfonium hydroxide, and sulfonium hydroxide having a 2-oxoalkyl group, specifically, triphenylsulfonium hydroxide, tris(t-butylphenyl) sulfonium hydroxide, bis(t-butylphenyl)iodonium hydroxide, phenacylthiophenium hydroxide, and 2-oxopropylthiophenium hydroxide. The compound having an onium carboxylate structure is a compound obtained by the anion portion of a compound having an onium carboxylate structure becoming carboxylate, and examples thereof include acetate, adamantane-1-carboxylate, and perfluoroalkyl carboxylate. Examples of the compound having a trialkylamine structure include tri(n-butyl)amine and tri(n-octyl)amine. Examples of the compound having an aniline structure include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, and tris(methoxyethoxyethyl)amine. Examples of the aniline derivative having a hydroxyl group and/or an ether bond include N,N-bis(hydroxyethyl)aniline.

Examples of a preferable basic compound include an amine compound having a phenoxy group, an ammonium salt compound having a phenoxy group, an amine compounds having a sulfonic acid ester group, and an ammonium salt compound having a sulfonic acid ester group. Specific examples thereof include the compounds (C1-1) to (C3-3) exemplified in paragraph [0066] of US2007/0224539A, but the present invention is not limited thereto.

In addition, as one type of the basic compounds, a nitrogen-containing organic compound having a group leaving due to the action of an acid. Specific examples of the compound are shown below.

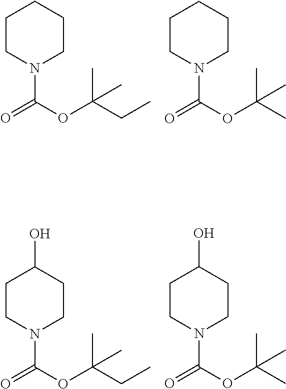

The compounds can be synthesized according to, for example, the method described in JP2009-199021A.

In addition, as the basic compound (N′), a compound having an amine oxide structure can also be used. Specific examples of the compound include triethylamine pyridine N-oxide, tributylamine N-oxide, triethanolamine N-oxide, tris(methoxyethyl)amine N-oxide, tris(2-(methoxymethoxy)ethyl)amine=oxide, 2,2′,2″-nitrilotriethyl propionate N-oxide, N-2-(2-methoxyethoxy)methoxyethyl morpholine N-oxide, and amine oxide compounds exemplified in JP2008-102383A.

The molecular weight of the basic compound (N′) is preferably 250 to 2000, and more preferably 400 to 1000. From the viewpoint of further reduction of LWR and evenness of a local pattern dimension, the molecular weight of the basic compound is preferably 400 or greater, more preferably 500 or greater, and still more preferably 600 or greater.

These basic compounds (N′) may be used in combination with the compound (C), or may be used alone or in combination of two or more types thereof.

Although the active light sensitive or radiation sensitive composition in the present invention may not contain the basic compound (N′), in the case of containing, the amount of the basic compound (N′) used is typically 0.001% by mass to 10% by mass and preferably 0.01% by mass to 5% by mass, based on the total solid content of the active light sensitive or radiation sensitive composition.

In addition, as the active light sensitive or radiation sensitive composition in the present invention, a compound having both an onium salt structure and an acid anion structure in one molecule (hereinafter, also referred to as a betaine compound), such as the compound included in Formula (I) in JP2012-189977A, the compound represented by Formula (I) in JP2013-6827A, the compound represented by Formula (I) in JP2013-8020A, or the compound represented by Formula (I) in JP2012-252124A, can also be preferably used. Examples of the onium salt structure include a sulfonium structure, an iodonium structure, and an ammonium structure, and a sulfonium structure, an iodonium salt structure is preferable. In addition, as the acid anion structure, a sulfonate anion or a carboxylate anion is preferable. Examples of the compound include the following.

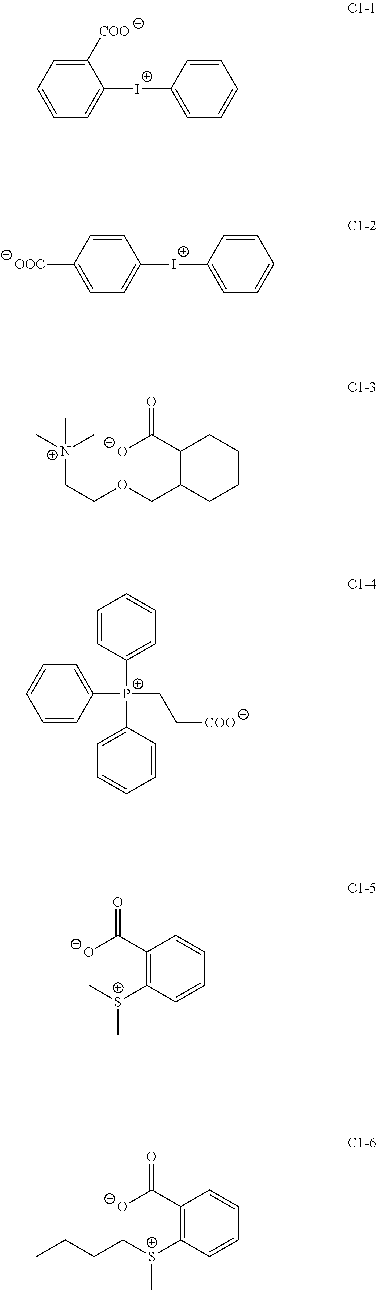

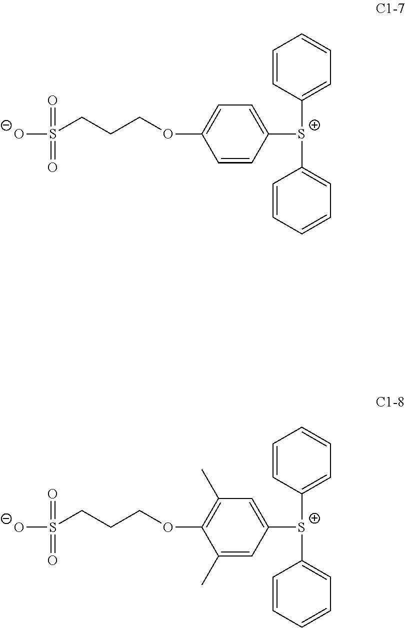 [SMILES: O=S(=O)([O-])CCCOc1ccc([S+](c2ccccc2)c2ccccc2)cc1 ; Cc1cc([S+](c2ccccc2)c2ccccc2)cc(C)c1OCCCS(=O)(=O)[O-]]

[6] Compound that Generates Acid by being Decomposed due to Action of Acid.

The active light sensitive or radiation sensitive composition of the present invention may further include one or two or more types of compound that generates an acid by being decomposed due to the action of an acid. The acid generated by the compound that generates an acid by being decomposed due to the action of an acid is preferably sulfonic acid, methide acid, or imidic acid.

Examples of the compound that generates an acid by being decomposed due to the action of an acid which can be used in the present invention will be shown below, but the present invention is not limited thereto.

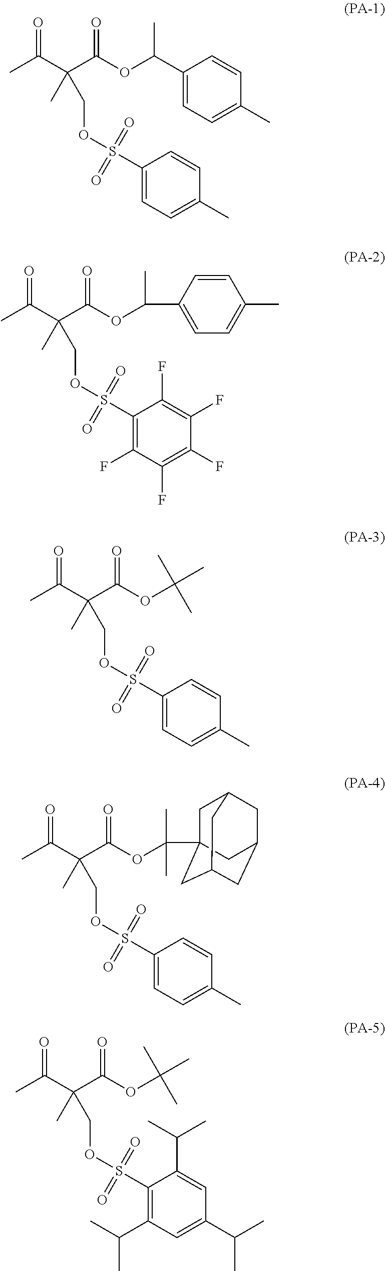

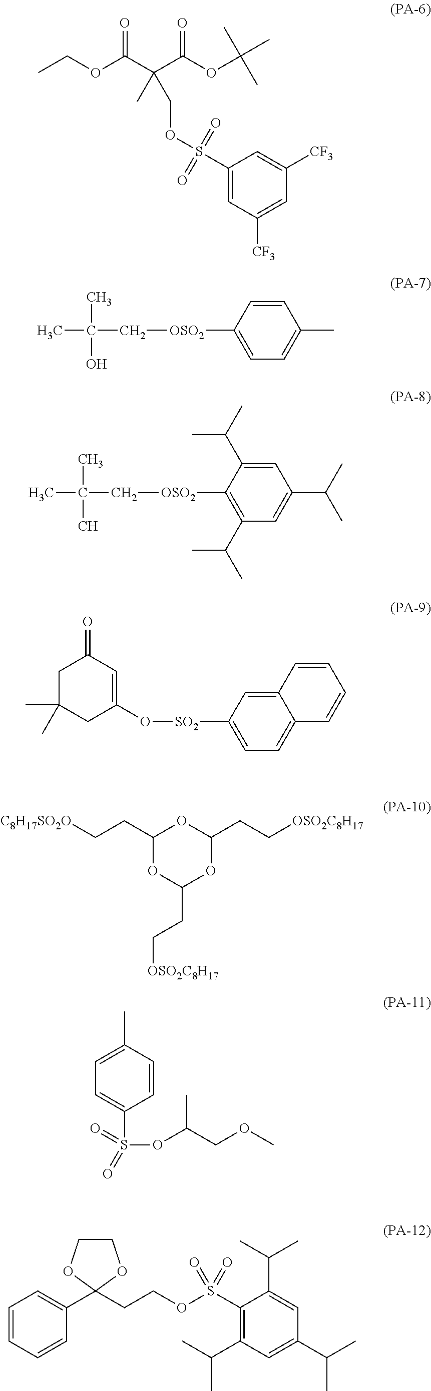

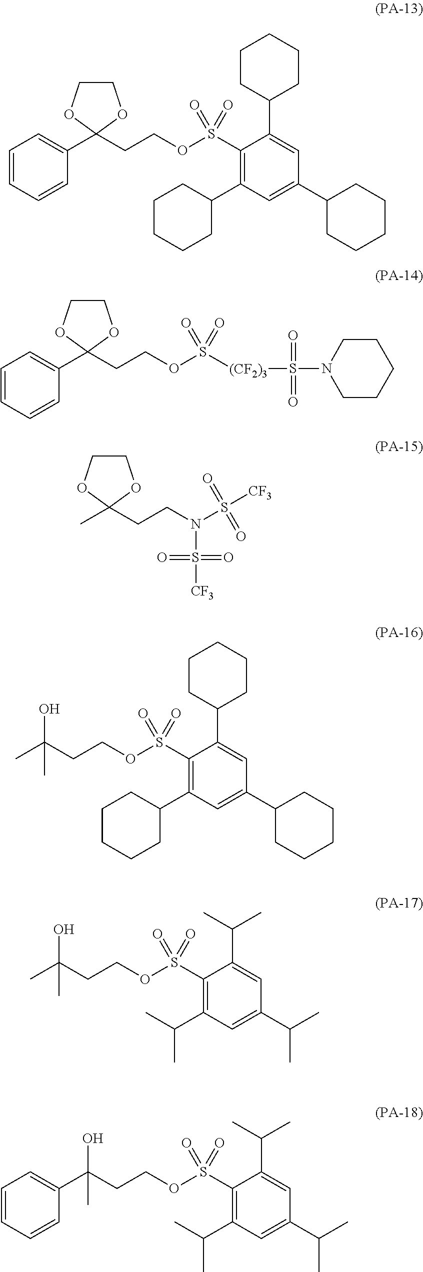

The compound that generates an acid by being decomposed due to the action of an acid may be used alone or two or more types thereof can be used in combination.

The content of the compound that generates an acid by being decomposed due to the action of an acid is preferably 0.1% by mass to 40% by mass, more preferably 0.5% by mass to 30% by mass, and still more preferably 1.0% by mass to 20% by mass, based on the total solid content of the active light sensitive or radiation sensitive composition.

[7] Hydrophobic Resin (HR)

The active light sensitive or radiation sensitive composition of the present invention may have a hydrophobic resin (HR) separately from the resin [P-A], the resin [N-A], and the resin (A).

The hydrophobic resin (HR) preferably contains a group having a fluorine atom, a group having a silicon atom, or a hydrocarbon group having 5 or more carbon atoms, in order to be unevenly distributed on a film surface. These groups may be contained in the main chain of the resin or may be substituted on the side chain. By uneven distribution of a hydrophobic resin on the resist film surface, control of a surface contact angle, suppression of permeation of an immersion liquid into the resist film, and suppression of outgassing become possible. Specific examples of the hydrophobic resin (HR) will be shown below.

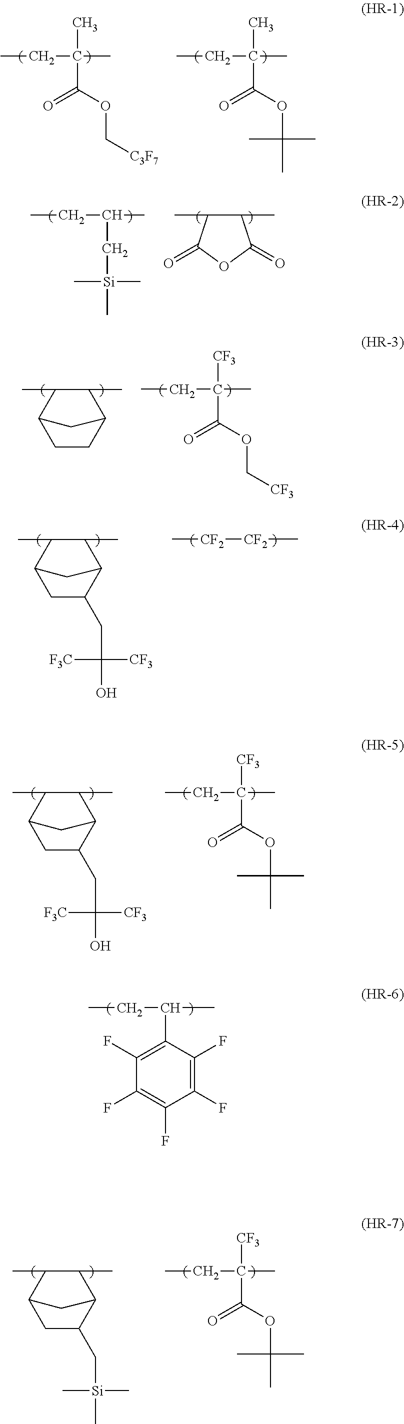

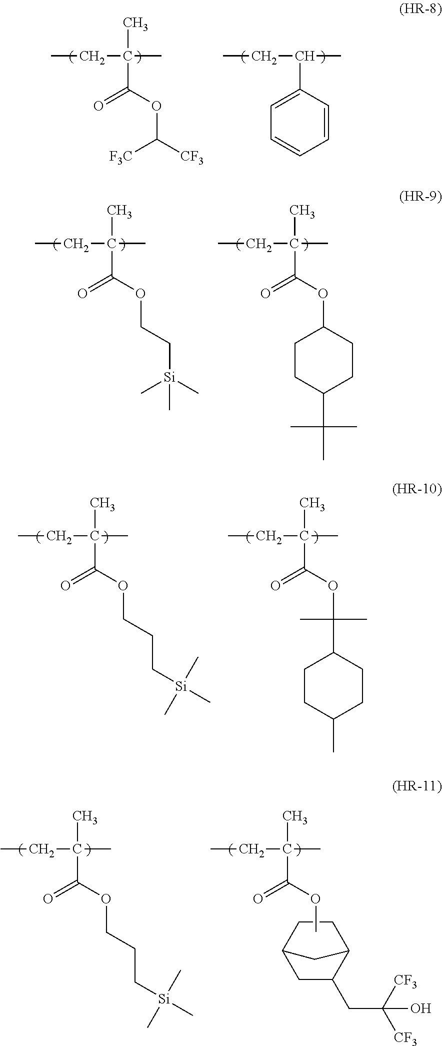

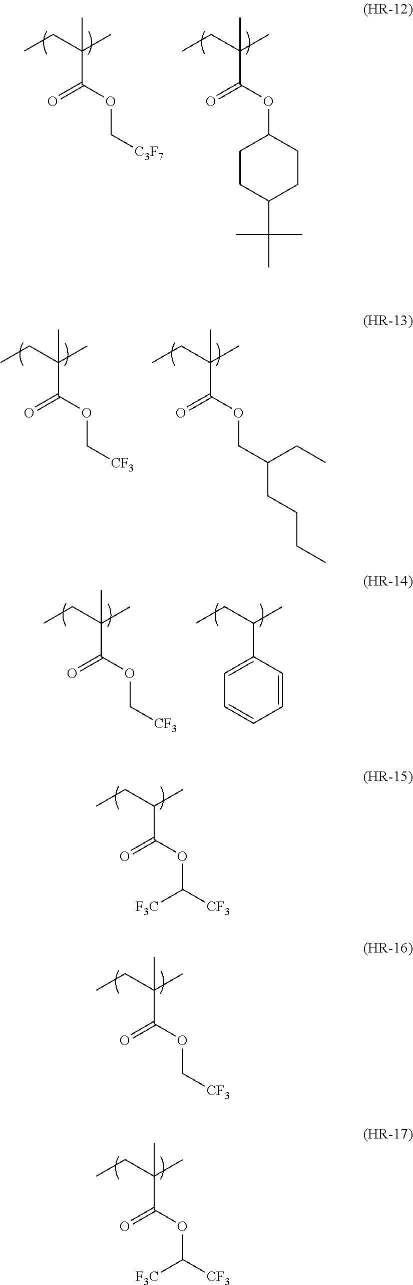

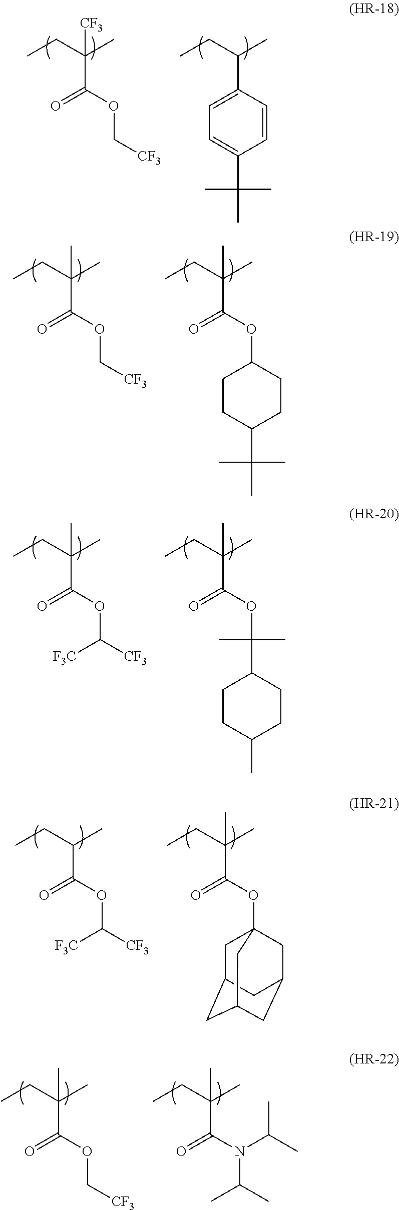

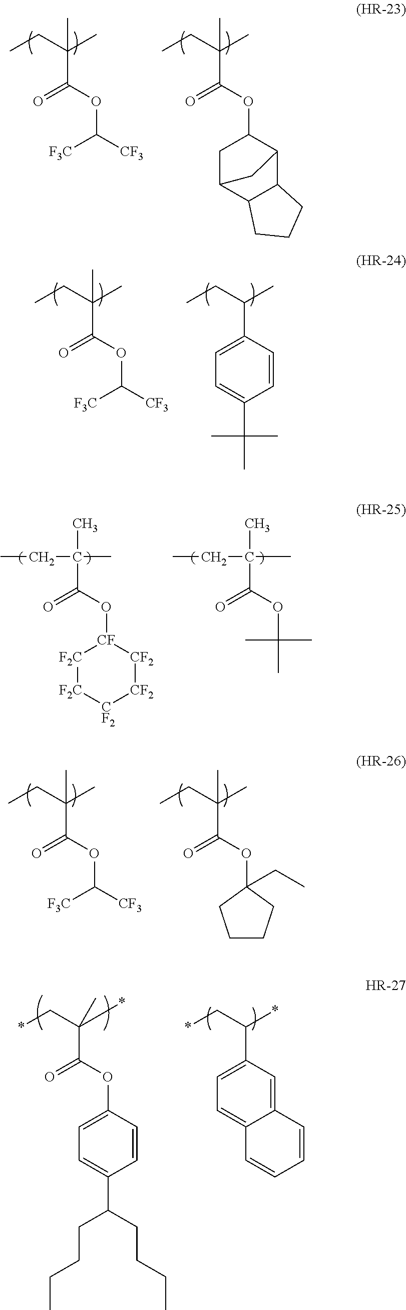

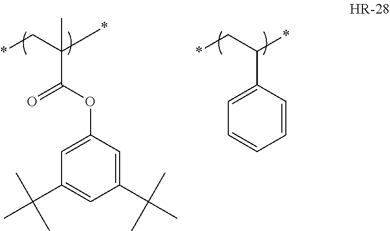

In addition to the hydrophobic resins, the hydrophobic resins described in JP2011-248019A, JP2010-175859A, or JP 2012-032544A can also be preferably used.

[8] Surfactant

The composition according to the present invention may further include a surfactant. By containing a surfactant, in a case where an exposure light source having a wavelength of 250 nm or less is used, in particular, 220 nm or less, a pattern having smaller adhesion and development defect can be formed with a favorable sensitivity and resolution.

As the surfactant, a fluorine-based surfactant and/or a silicon-based surfactant is particularly preferable.

Examples of the fluorine-based surfactant and/or the silicon-based surfactant include surfactants described in paragraph [0276] of US2008/0248425A. In addition, F Top EF301 or EF303 (manufactured by Shin-Akita Kasei Co., Ltd.); Fluorad FC430, 431, or 4430 manufactured by Sumitomo 3M Ltd.); Megafac F171, F173, F176, F189, F113, F110, F177, F120, or R08 (manufactured by DIC Corporation); Surflon S-382, SC101, 102, 103, 104, 105, or 106 manufactured by Asahi Glass Co., Ltd.); Troysol S-366 (manufactured by Troy Chemical Corp.); GF-300 or GF-150 (manufactured by Toagosei Chemical Industry Co., Ltd.), Surflon S-393 (manufactured by AGC Seimi Chemical Co., Ltd.); Eftop EF121, EF122A, EF122B, RF122C, EF125M, EF135M, EF351, EF352, EF801, EF802, or EF601 ((manufactured by Jemco Co., Ltd); PF636, PF656, PF6320, or PF6520 (manufactured by OMNOVA Solutions Inc.); or FTX-204G, 208G, 218G, 230G, 204D, 208D, 212D, 218D, or 222D (manufactured by Neos Company Limited) may be used. Moreover, a polysiloxane polymer KP-341 (manufactured by Shin-Etsu Chemical Co., Ltd.) can also be used as a silicon-based surfactant.

In addition, in addition to the known surfactants as described above, the surfactant may be synthesized using a fluoroaliphatic compound prepared by a telomerization method (also referred to as a telomer method) or an oligomerization method (also referred to as an oligomer method). Specifically, a polymer having a fluoroaliphatic group derived from the fluoroaliphatic compound may be used as a surfactant. The fluoroaliphatic compound can be synthesized by the method described in JP2002-90991A.

As the polymer having a fluoroaliphatic group, a copolymer of a monomer having a fluoroaliphatic group and (poly(oxyalkylene))acrylate or methacrylate and/or (poly(oxyalkylene))methacrylate is preferable, and the polymer may be irregularly distributed, or may be a block copolymer.

Examples of the poly(oxyalkylene) group include a poly(oxyethylene) group, a poly(oxypropylene) group, and a poly(oxybutylene) group. In addition, the poly(oxyalkylene) group may be a unit having alkylenes having different chain lengths in the same chain, such as poly(block connector of oxyethylene oxypropylene and oxyethylene) and poly(block connector of oxyethylene and oxypropylene).

Furthermore, a copolymer of a monomer having a fluoroaliphatic group and (poly(oxyalkylene))acrylate or methacrylate may be a ternary or higher compound system copolymer formed by copolymerizing a monomer having two or more types of fluoroaliphatic group and two or more types of (poly(oxyalkylene))acrylate or methacrylate at the same time.

For example, examples of a commercially available surfactant include Megafac F178, F-470, F-473, F-475, F-476, and F-472 (manufactured by DIC Corporation). Examples of a commercially available surfactant include a copolymer of acrylate or methacrylate having a C₆F₁₃ group and (poly(oxyalkylene))acrylate or methacrylate, a copolymer of acrylate or methacrylate having a C₆F₁₃ group, (poly(oxyethylene))acrylate or methacrylate, and (poly(oxypropylene))acrylate or methacrylate, a copolymer of acrylate or methacrylate having a C₈F₁₇ group and (poly(oxyalkylene))acrylate or methacrylate, and a copolymer of acrylate or methacrylate having a C₈F₁₇ group, (poly(oxyethylene))acrylate or methacrylate, and (poly(oxypropylene))acrylate or methacrylate.

In addition, surfactants other than the fluorine-based surfactant and/or the silicon-based surfactant described in paragraph [0280] of US2008/0248425A may be used.

These surfactants may be used alone or in combination of two or more types thereof.

In a case where the composition according to the present invention includes a surfactant, the content thereof is preferably 0% by mass to 2% by mass, more preferably 0.0001% by mass to 2% by mass, and still more preferably 0.0005% by mass to 1% by mass, based on the total solid content of the composition.

[9] Other Additives

The composition of the present invention can suitably contain carboxylic acid, an onium carboxylate salt, a dissolution inhibiting compound having a molecular weight of 3000 or less described in Proceeding of SPIE, 2724, 355 (1996) or the like, a dye, a plasticizer, a photosensitizer, a light absorber, or an antioxidant, in addition to the components described above.

In particular, carboxylic acid is suitably used to improve performance. As the carboxylic acid, aromatic dicarboxylic acid such as benzoic acid or naphthoic acid is preferable.

The content of the carboxylic acid is preferably 0.01% by mass to 10% by mass, more preferably 0.01% by mass to 5% by mass, and still more preferably 0.01% by mass to 3% by mass, with respect to the total solid content concentration in the composition.

The active light sensitive or radiation sensitive composition in the present invention is preferably used in a film thickness of 10 nm to 250 nm, more preferably used in a film thickness of 20 nm to 200 nm, and still more preferably used in a film thickness of 30 nm to 100 nm, for the viewpoint of resolution improvement. By setting the solid content concentration in the composition within a suitable range to obtain suitable viscosity, coating properties and film-forming properties are improved, and as a result, such film thicknesses can be obtained.

The solid content concentration of the active light sensitive or radiation sensitive composition in the present invention is typically 1.0% by mass to 10% by mass, preferably 2.0% by mass to 5.7% by mass, and still more preferably 2.0% by mass to 5.3% by mass. When the solid content concentration is within the above range, it is possible to evenly apply a resist solution to a substrate, and it is possible to form a resist pattern having excellent line width roughness. The reason for this is not clear, but, it is thought that, when the solid content concentration is 10% by mass or less, preferably 5.7% by mass or less, aggregation of the material, in particular, the photoacid generator in the resist solution is suppressed, and as a result, an even resist film can be formed.

The solid content concentration is a weight percentage in terms of the weight of the resist components excluding the solvent with respect to the total weight of the active light sensitive or radiation sensitive composition.

As the active light sensitive or radiation sensitive composition in the present invention, the components described above are dissolved in a predetermined organic solvent, preferably, dissolved in the mixed solvent described above, then, the resultant product is filtered using a filter, and is applied to a predetermined support (substrate), and used. As the filter used in filtration, a filter made of polytetrafluoroethylene, made of polyethylene, or made of nylon, preferably having a pore size of 0.1 μm or less, more preferably having a pore size of 0.05 μm or less, and still more preferably having a pore size of 0.03 μm or less is preferable. In the filtration using a filter, for example, as in JP2002-62667A, circulation filtration may be performed, or filtration may be performed in a state of connecting a plurality of filters in series or in parallel. The composition may be filtered multiple times. Furthermore, before and after the filtration using a filter, the composition may be subjected to a deaeration treatment.

[10] Pattern Forming Method

The present invention also relates to the resist film formed by using the composition of the present invention.

In addition, the pattern forming method of the present invention has at least (a) a step of forming a resist film using the active light sensitive or radiation sensitive composition, (b) a step of exposing the film, and (c) a step of developing the exposed film using an alkali developer.

Exposure in the step (b) is preferably a step of exposing to an electron beam or EUV light (extreme ultraviolet rays).

In addition, exposure in the step (b) may be liquid immersion exposure.

The pattern forming method of the present invention preferably has (d) a step of heating after (b) the step of exposing.

The pattern forming method of the present invention may further have (e) a step of developing using a developer including an organic solvent.

In the pattern forming method of the present invention, (b) the step of exposing can be performed multiple times.

In the pattern forming method of the present invention, (e) the step of heating can be performed multiple times.

The pattern forming method of the present invention may have a step of forming a topcoat layer on a resist film. As the composition for forming a topcoat layer, a known composition can be used.

The resist film is formed of the active light sensitive or radiation sensitive composition of the present invention, and more specifically, is preferably formed on a substrate. In the pattern forming method of the present invention, a step of forming a film formed of the active light sensitive or radiation sensitive composition on a substrate, a step of exposing the film, and a step of developing can be performed by methods generally known in the related art.

For example, the composition is applied on a substrate (example: silicon/silicon dioxide coating, quartz substrate deposited with silicon nitride or chromium, or the like) which is used in manufacture of precision integrated circuit elements or a mold for imprint, using a spinner or a coater. Thereafter, by drying the resultant product, an active light sensitive or radiation sensitive film can be formed.

Before forming the resist film, an antireflection film may be applied on the substrate in advance. As the antireflection film, any type of an inorganic film type such as titanium, titanium dioxide, titanium nitride, chromium oxide, carbon, or amorphous silicon, and an organic film type formed of a light absorber and a polymer material can be used. In addition, as the organic antireflection film, a commercially available organic antireflection film such as DUV30 series or DUV-40 series manufactured by Brewer Science, Inc., or AR-2, AR-3, or AR-5 manufactured by Shipley Company, L.L.C. can also be used.

After film formation, before an exposure step, a prebake step (PB) is also preferably included. In addition, after an exposure step and before a developing step, a post exposure bake step (PEB) is also preferably included.

Each of PB and PEB is preferably performed at 70° C. to 120° C., and more preferably performed at 80° C. to 110° C.

The heating time is preferably 30 seconds to 300 seconds, more preferably 30 seconds to 180 seconds, and still more preferably 30 seconds to 90 seconds.

The heating can be typically performed by means provided in an exposure developing device, or may be performed using a hot plate or the like.

The reaction of an exposed portion is promoted by baking, and the sensitivity or the pattern profile is improved.

In addition, a heating step (post bake) is also preferably included after a rinsing step. By baking, the developer and the rinsing liquid remaining between the patterns and in the patterns are removed.

Examples of the active light or the radiation include infrared light, visible light, ultraviolet light, far-ultraviolet light, X-rays, and an electron beam.

The substrate on which a film is formed in the present invention is not particularly limited, and an inorganic substrate such as silicon, SiN, SiO₂, or SiN, and a coated inorganic substrate such as SOG, and a substrate which is generally used in a step of manufacturing a semiconductor such as IC, a step of manufacturing a circuit board for liquid crystal or a thermal head, or a lithography step of photofabrication can be used. As necessary, an organic antireflection film may be formed between a film and a substrate.

As the alkali developer, for example, alkali aqueous solutions such as inorganic alkalies including sodium hydroxide, potassium hydroxide, sodium carbonate, sodium silicate, sodium metasilicate, and ammonia water, primary amines including ethylamine and n-propylamine, secondary amines including diethylamine and di-n-butylamine, tertiary amines including triethylamine and methyldiethylamine, alcohol amines including dimethyl ethanolamine and triethanolamine, tetraalkylammonium hydroxide including tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide, quaternary ammonium salts including trimethylphenylammonium hydroxide, trimethylbenzylammonium hydroxide, and triethylbenzylammonium hydroxide, and cyclic amines including pyrrole and piperidine can be used.

A suitable amount of alcohol or a surfactant can also be added to the alkali aqueous solution and used.

The alkali concentration of the alkali developer is typically 0.1% by mass to 20% by mass.

The pH of the alkali developer is typically 10.0 to 15.0.

As the alkali developer, a 2.38% by mass tetramethylammonium hydroxide aqueous solution is particularly preferably used.

As the rinse liquid in the rinse treatment performed after the alkali development, pure water is used, and a suitable amount of surfactant can also be added thereto and used.

After the development treatment or the rinse treatment, a treatment of removing the developer or rinse liquid adhered to the pattern by a supercritical fluid can be performed.

As the developer including an organic solvent (hereinafter, also referred to as “organic-based developer”) in the step (e), a polar solvent such as an ester solvent (butyl acetate, ethyl acetate, or the like), a ketone solvent (2-heptanone, cyclohexanone, or the like), an alcohol-based solvent, an amide-based solvent, or an ether-based solvent, or a hydrocarbon-based solvent can be used. The water content of the entirety of the organic-based developer is preferably less than 10% by mass, and the developer more preferably does not contains water substantially.

In addition, the organic-based developer may contain a suitable amount of basic compound, as necessary. Examples of the basic compound include the basic compounds described above.

As the developing method, a method in which a substrate is dipped in a bath filled with a developer for a predetermined period of time (dipping method), a method in which developing is performed by placing a developer on the substrate surface using surface tension and this being held stationary for a predetermined period of time (puddle method), a method in which a developer is sprayed onto a substrate surface (spray method), or a method in which a substrate is spun at a constant rate, and a developer discharge nozzle is then scanned across the substrate at a constant rate while a developer is discharged continuously on the substrate from the nozzle (dynamic dispensing method) can be applied.

In the rinsing step, the wafer developed by using a developer including an organic solvent is subjected to a washing treatment using the rinse liquid including an organic solvent described above. The method of washing treatment is not particularly limited, and, for example, a method in which a rinse liquid is discharged continuously onto a substrate while the substrate is spun at a constant rate (spin coating method), a method in which a substrate is dipped in a bath filled with a rinse liquid for a predetermined period of time (dipping method), or a method in which a rinse liquid is sprayed onto a substrate surface (spray method) can be suitably used, and among these, it is preferable that a washing treatment is performed by the spin coating method, and, after washing, a rinse liquid is removed from the substrate by rotating the substrate at a rotation speed of 2000 rpm to 4000 rpm. In addition, a heating step (post bake) is also preferably included after the rinsing step. By baking, the developer and the rinsing liquid remaining between the patterns and in the patterns are removed. The heating step after the rinsing step is performed typically 40° C. to 160° C., and preferably 70° C. to 95° C., and typically for 10 seconds to 3 minutes, and preferably 30 seconds to 90 seconds.

In addition, the present invention also relates to a resist-coated mask blank coated with the active light sensitive or radiation sensitive composition of the present invention, that is, coated with a resist film obtained in the above manner. To obtained such a resist-coated mask blank, in the case of forming a resist pattern on a photomask blank for photomask production, as a transparent substrate to be used, transparent substrates such as quartz and calcium fluoride are exemplified. In general, necessary functional films such as a shielding film, an antireflection film, and a phase shift film, and additionally, an etching stopper film, and an etching mask film are laminated on the substrate. As the material of the functional film, a film containing silicon or a transition metal such as chromium, molybdenum, zirconium, tantalum, tungsten, titanium, or niobium is laminated. In addition, the material used for the outermost layer include a material having silicon or a material containing oxygen and/or nitrogen in silicon as the main constituent material, a silicon compound material having a material containing a transition metal to therein as the main constituent material, and a transition metal compound material having a transition metal, in particular, one or more types of transition metal selected from chromium, molybdenum, zirconium, tantalum, tungsten, titanium, and niobium, or a material including one or more elements selected from oxygen, nitrogen, and carbon therein as a main constituent material.

The light shielding film may be a single layer but is preferably a multi-layer structure where a plurality of material are coated and overlapped. In a case of a multi-layer structure, the thickness of the film for each single layer is not particularly limited, but is preferably 5 nm to 100 nm and is more preferably 10 nm to 80 nm. The thickness of the entire light shielding film is not particularly limited, but is preferably 5 nm to 200 nm and more preferably 10 nm to 150 nm.

In the case of forming a pattern on a photomask blank having a material containing oxygen or nitrogen in chromium in the outermost surface layer by using a negative chemical amplification resist composition, a so-called undercut shape which is a constriction shape formed in the vicinity of the substrate is likely to occur, but in the case of using the active light sensitive or radiation sensitive composition of the present invention, it is possible to improve the undercut problem compared to that in the related art.

Next, this resist-coated mask blank is exposed to an electron beam or EUV light, and preferably baked (typically at 80° C. to 150° C., and more preferably at 90° C. to 130° C., and typically for 1 minute to 20 minutes, and preferably for 1 minute to 10 minutes), and developed using an alkali developer. Thus, an excellent pattern can be obtained. Using the pattern as a mask, by performing an appropriate etching process, ion implantation, or the like a fine semiconductor circuit, a mold structure for imprint, a photomask, or the like is produced.

Moreover, a mold for imprint may be produced by using the composition according to the present invention, and regarding the details thereof, for example, JP4109085B, JP2008-162101A, and “Fundamentals of Nanoimprint and Technical Development/Application Deployment-Substrate Technique of Nanoimprint and Latest Application Deployment”, edited by Yoshihiko Hirai (Frontier Publishing) may be referenced.

The present invention also relates to a photomask obtained by exposing and developing a resist-coated mask blank. As exposure and development, the step described above is applied. The photomask is suitably used in production of a semiconductor.

The photomask in the present invention may be a light transmittance type mask used in an ArF excimer laser, or may be a light reflective type mask used in reflection system lithography in which EUV light is used as a light source.

[Applications]

The pattern forming method of the present invention is suitably used in production of a fine semiconductor circuit such as manufacture of an ultra LSI or a high-capacity microchip. Moreover, when producing a fine semiconductor circuit, after a resist film on which a pattern has been formed is subjected to circuit formation or etching, the remaining resist film portion is ultimately removed by a solvent or the like, and thus, unlike a so-called permanent resist used for a printed circuit board or the like, in a final product such as a microchip, a resist film derived from the active light sensitive or radiation sensitive composition described in the present invention does not remain.

In addition, the present invention also relates to a method for manufacturing an electronic device including the pattern forming method of the present invention described above and an electronic device manufactured by the manufacturing method.

The electronic device of the present invention is suitably mounted on electrical and electronic equipment (home electrical appliances, OA and media-related equipment, optical equipment, communication equipment, or the like).

### EXAMPLES

Hereinafter, the present invention will be specifically described by examples, but the present invention is not limited to the following examples.

### Synthesis Example 1

### Synthesis of Resin (PA-1)

23.5 g of acetyl chloride was added to 41.4 g of phenylacetaldehyde dimethyl acetal, followed by stirring in a water bath at 45° C. for 6 hours. After the temperature was returned to room temperature, the unreacted acetyl chloride was removed under reduced pressure, whereby a compound CI-1 shown below was obtained as a chloroether compound.

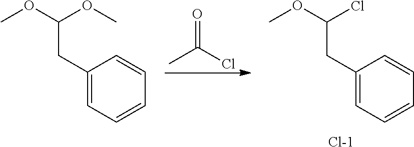

10.0 g of poly(p-hydroxystyrene) (VP-2500, manufactured by NIPPON SODA CO., LTD.) as a polyhydroxystyrene compound was dissolved in 50 g of tetrahydrofuran (THF), and 8.85 g of triethylamine was added thereto, followed by stirring in an ice water bath. A mixture (0.71 g) including the compound CI-1 obtained above was added dropwise to the reaction liquid, followed by stirring for 4 hours. A small amount of the reaction liquid was collected, and ¹H-NMR measurement was performed on the collected reaction liquid, and as a result, a protection ratio of 4.1% was obtained. Thereafter, a mixture including a small amount of compound CI-1 was additionally added thereto, followed by stirring for 1 hour, then, ¹H-NMR measurement was repeatedly performed, and when the protection ratio exceeds 5% which is the target value, the reaction was stopped by adding distilled water. THF therein was distilled off under reduced pressure, and the reaction product was dissolved in ethyl acetate. After the obtained organic layer was washed with distilled water 5 times, the organic layer was added dropwise to 1.5 L of hexane. After the obtained precipitate was filtered off and washed with a small amount of hexane, the resultant product was dissolved in 35 g of propylene glycol monomethyl ether acetate (PGMEA). A low-boiling point solvent was removed from the obtained solution by using an evaporator, whereby 41.3 g of a PGMEA solution (25.4% by mass) of a resin (P-1) was obtained.

¹H-NMR measurement was performed on the obtained resin (P-1), and the compositional ratio (molar ratio) of the resin (P-1) was calculated. In addition, a weight average molecular weight (Mw: in terms of polystyrene), a number average molecular weight (Mn: in terms of polystyrene), and dispersity (Mw/Mn, hereinafter, also referred to as “Pd”) of the resin (P-1) were calculated by GPC (solvent: THF) measurement. Mw and Pd are shown in the following chemical formula.

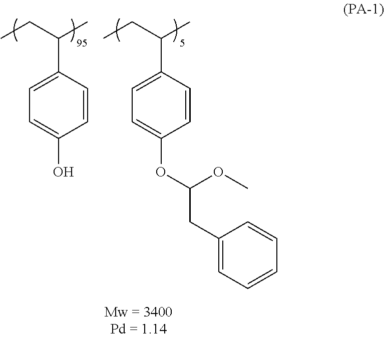

### Synthesis Examples 2 to 14

### Synthesis of Resin (PA-2) to (PA-8) and (NA-1) to (NA-6)

Resins (PA-2) to (PA-8) and (NA-1) to (NA-6) were synthesized in the same manner as in Synthesis Example 1 except that the polyhydroxystyrene compound and the chloroether compound used were appropriately changed. Moreover, the used chloroether compound was synthesized from the corresponding acetal compound in the same manner as in Synthesis Example 1.

The polymer structure, the weight average molecular weight (Mw), and the dispersity (Pd) of the synthesized polymer are described below. In addition, the compositional ratio of each repeating unit of the following polymer structures is shown in a molar ratio.

<Resin [P-A]>

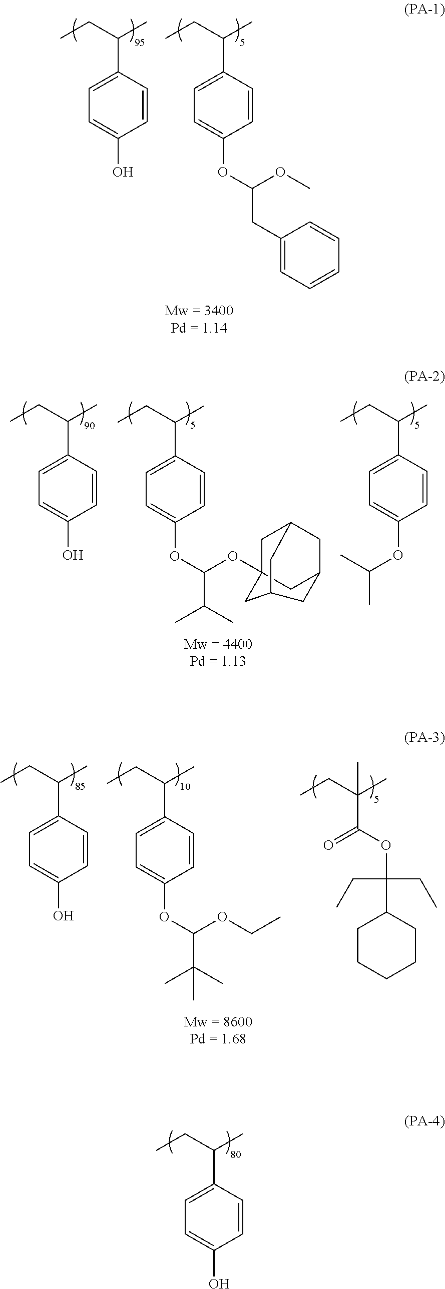

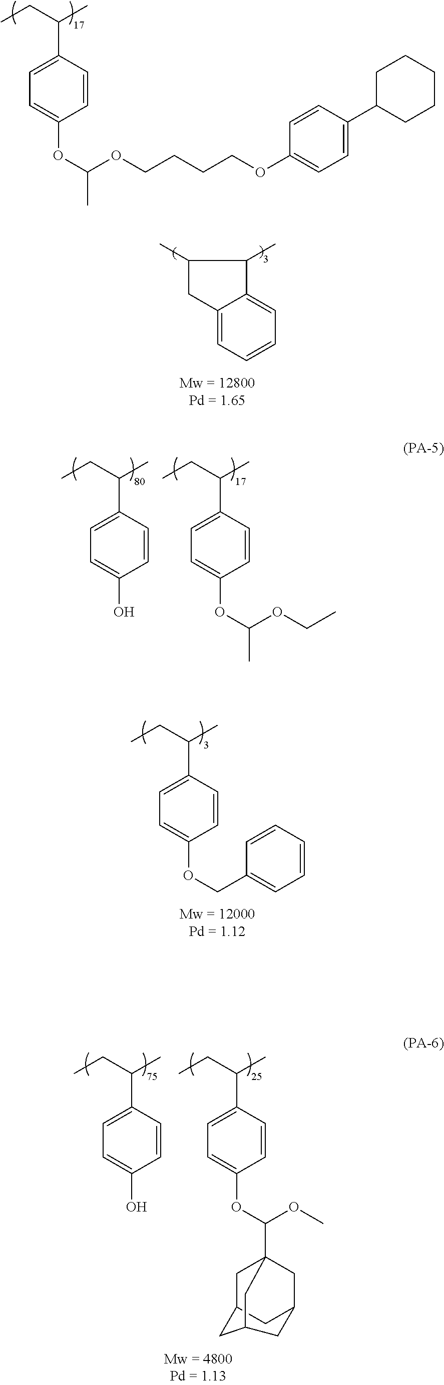

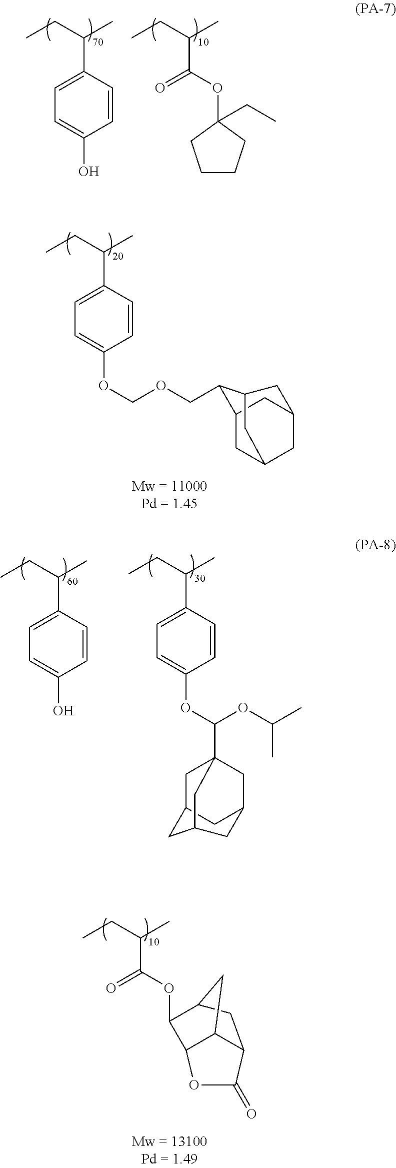

<Resin [N-A]>

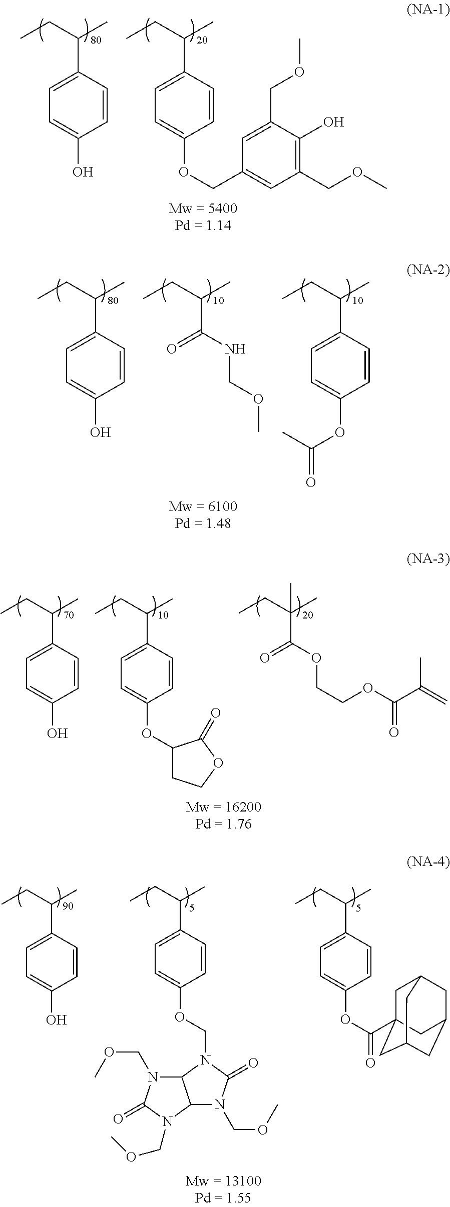

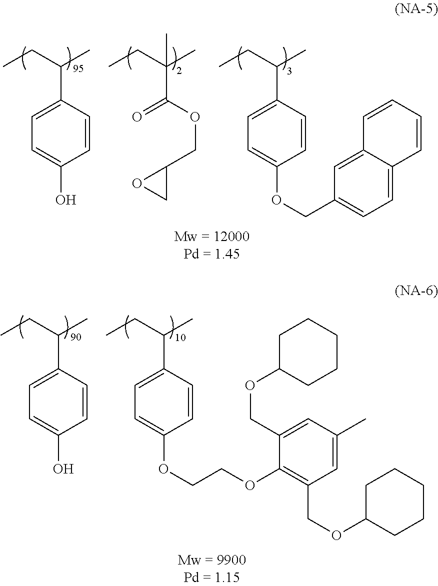

<Acid Generator [P-13]>

As the acid generator [P-B], the following compounds were prepared.

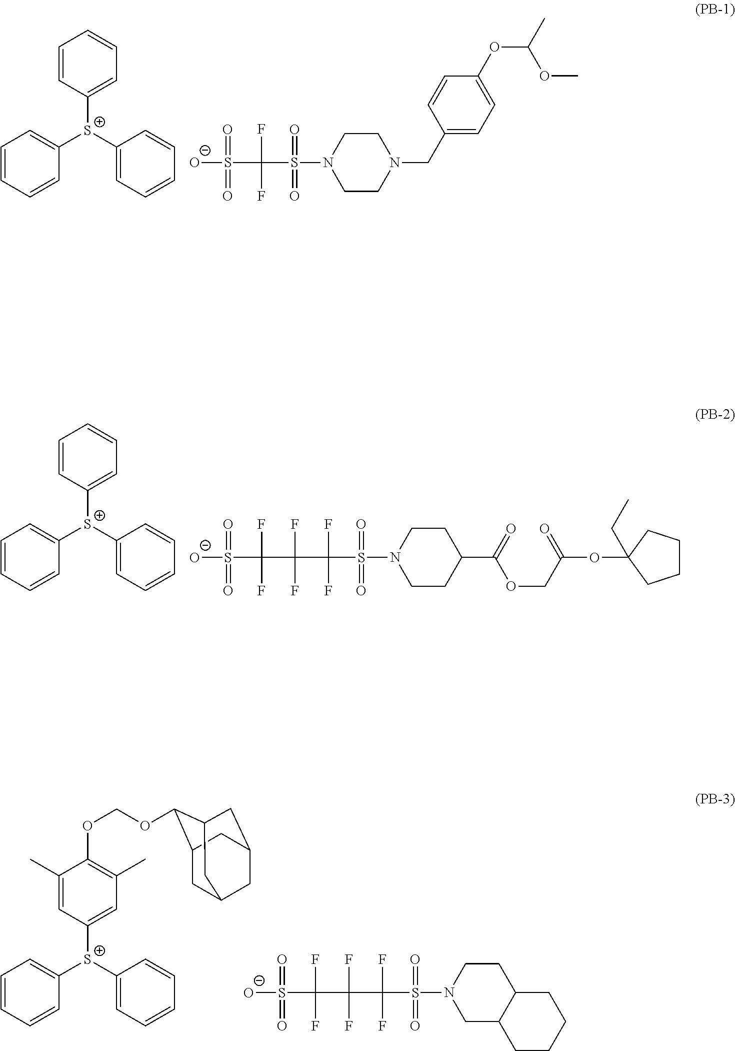 [SMILES: c1ccc([S+](c2ccccc2)c2ccccc2)cc1 ; COC(C)Oc1ccc(CN2CCN(S(=O)(=O)C(F)(F)S(=O)(=O)[O-])CC2)cc1 ; c1ccc([S+](c2ccccc2)c2ccccc2)cc1 ; CCC1(OC(=O)COC(=O)C2CCN(S(=O)(=O)C(F)(F)C(F)(F)C(F)(F)S(=O)(=O)[O-])CC2)CCCC1 ; Cc1cc([S+](c2ccccc2)c2ccccc2)cc(C)c1OCOC1C2CC3CC(C2)CC1C3 ; O=S(=O)([O-])C(F)(F)C(F)(F)C(F)(F)S(=O)(=O)N1CCC2CCCCC2C1]

<Low Molecular Weight Compound [P-C]>

As the low molecular weight compound [P-C], the following compounds were prepared.

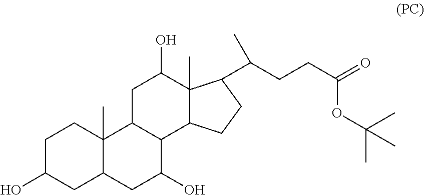 [SMILES: CC(CCC(=O)OC(C)(C)C)C1CCC2C3C(O)CC4CC(O)CCC4(C)C3CC(O)C12C]

<Acid Generator [N-B]>

As the acid generator [N-B], the following compounds were prepared.

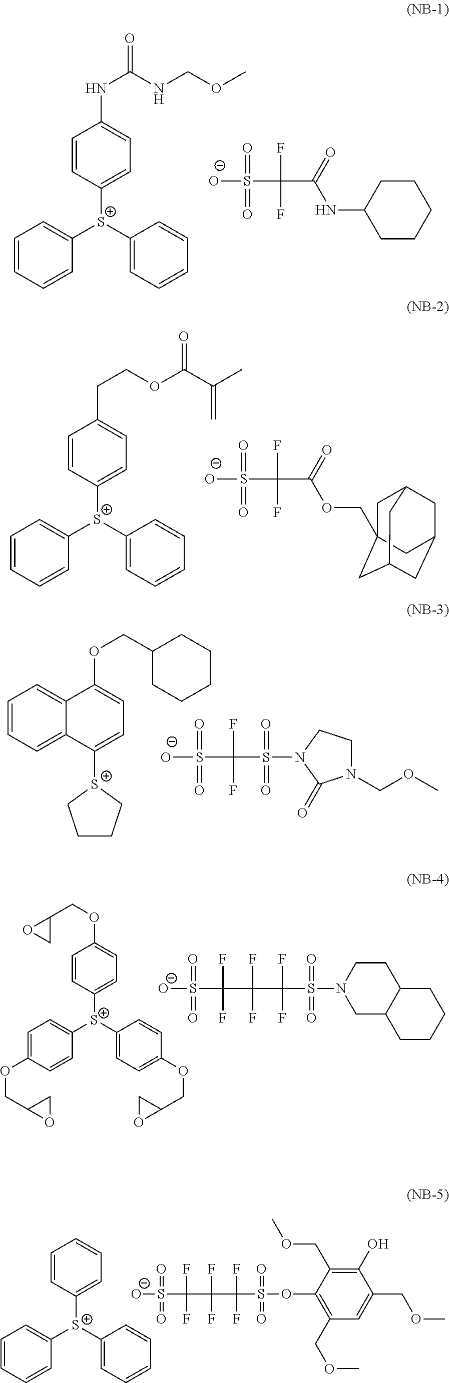

<Resin in a case where Components of Resin [P-A] and Resin [N-A] are the Same>

The polymer structure and the compositional ratio (molar ratio) of each repeating unit of a resin in a case where the components of the resin [P-A] and the resin [N-A] are the same are shown below.

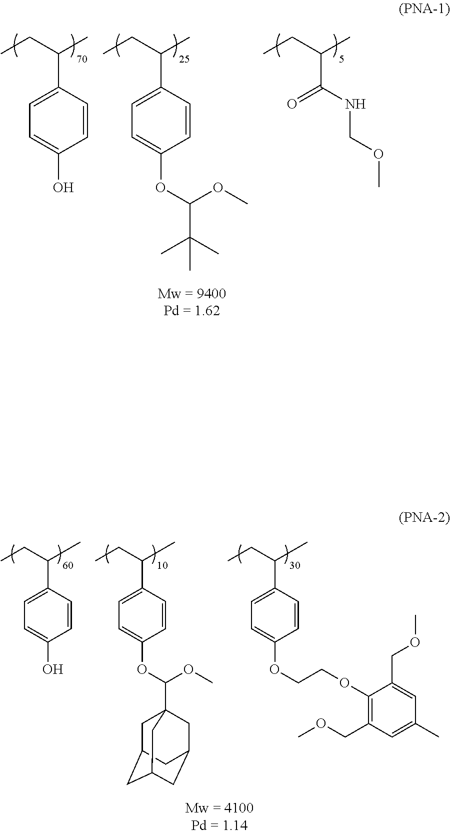

<Low Molecular Weight Compound [N-C]>

As the low molecular weight compound [N-C], the following compounds were prepared.

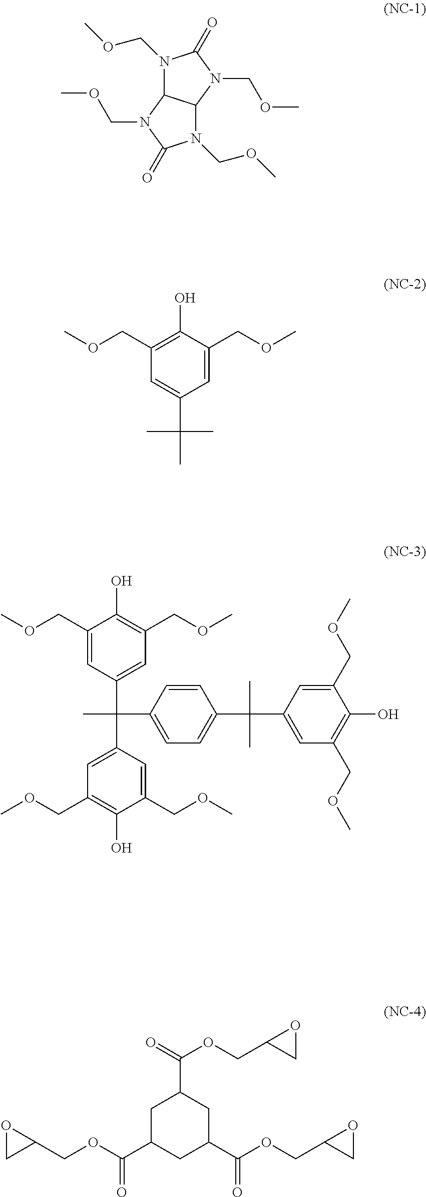

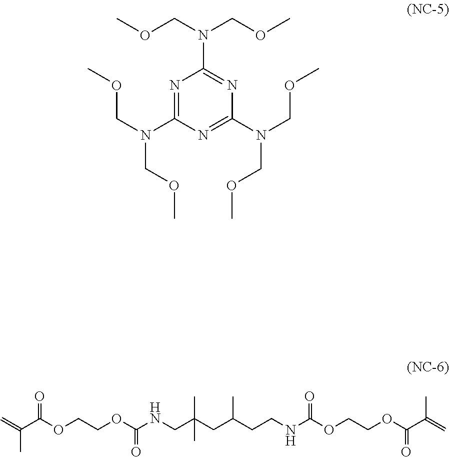

<Acid Generator [A]>

As the acid generator [A], the following compounds were prepared. The weight average molecular weight (Mw) and the dispersity (Pd) of each of the compounds (PAG-6) and (PAG-7) are described below. In addition, the compositional ratio of each repeating unit of the polymer structures of the compounds (PAG-6) and (PAG-7) is shown in a molar ratio. Moreover, the compound (PAG-7) also corresponds to the resin [P-A].

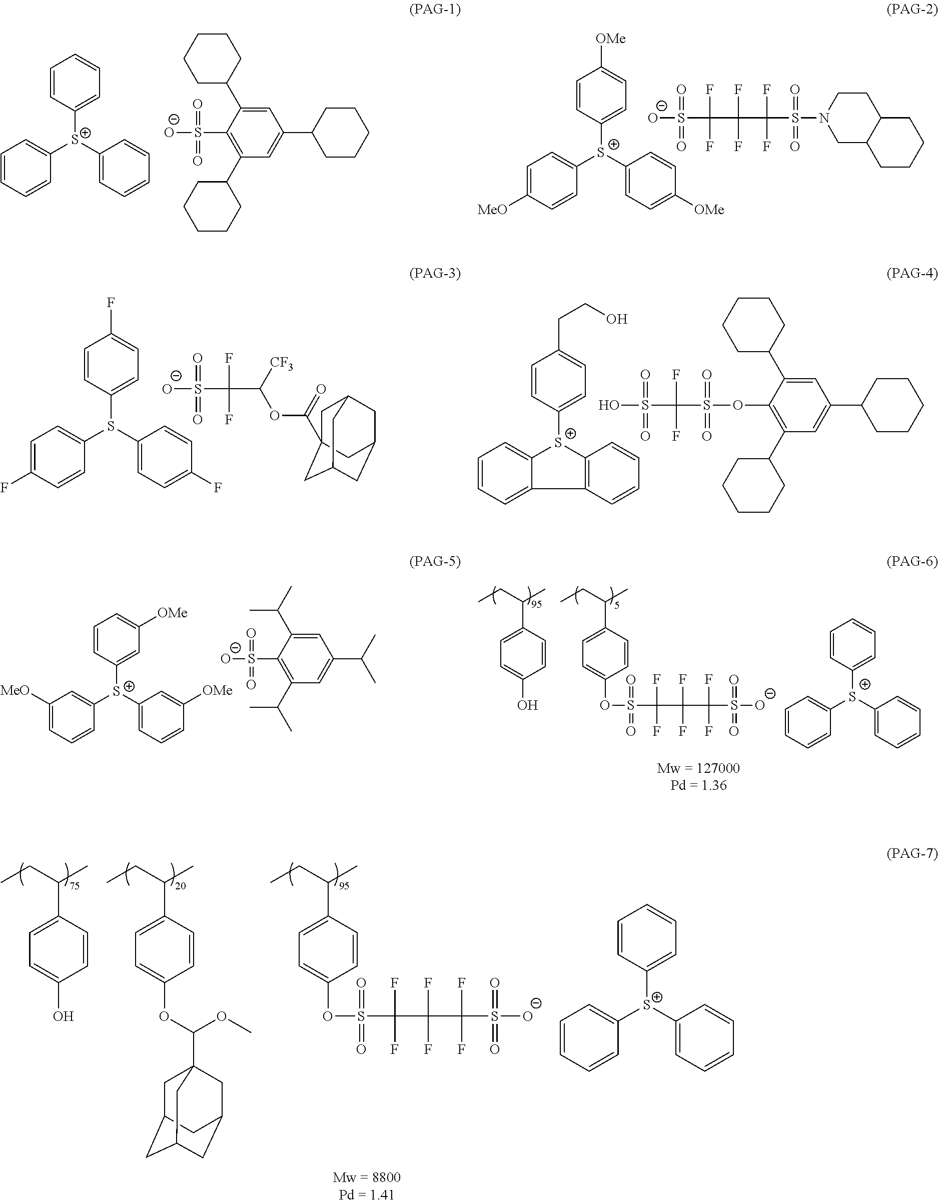

<Resin [A]>

As the resin [A], the following resins were prepared. The compositional ratio of each repeating unit of the following polymer structures is shown in a molar ratio.

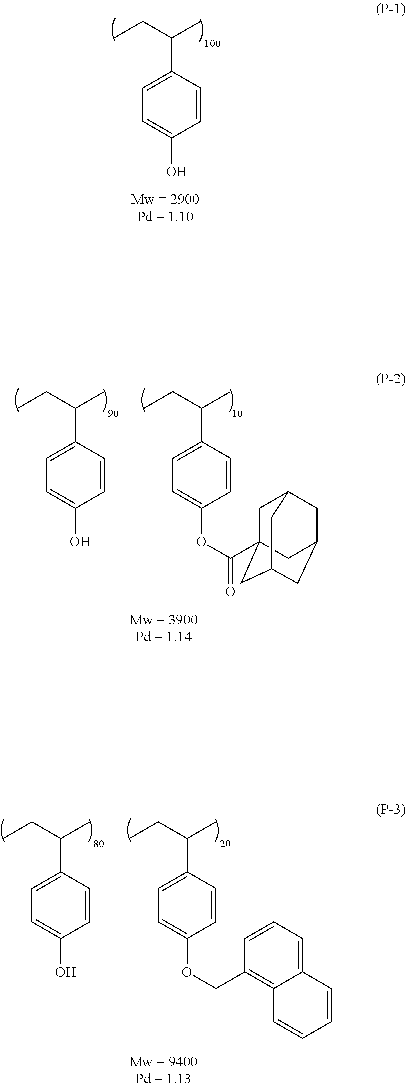

<Basic Compound>

As a basic compound, the following compounds were prepared.

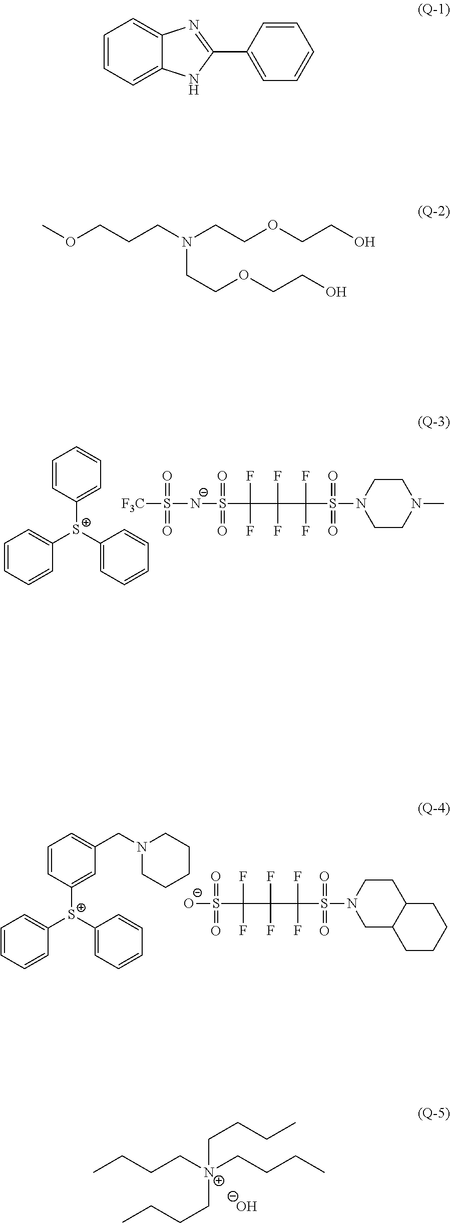

<Solvent>

As a solvent, the following solvents were prepared.

SL-1: propylene glycol monomethyl ether acetate (PGMEA; also referred to as 1-methoxy-2-acetoxypropane)

SL-2: propylene glycol monomethyl ether (PGME; 1-methoxy-2-propanol)

SL-3: 2-heptanone

SL-4: ethyl lactate

SL-5: cyclohexanone

SL-6: γ-butyrolactone

SL-7: propylene carbonate

<Surfactant>

As a surfactant, the following compounds were prepared.

W-1: PF6320 (manufactured by OMNOVA Solutions Inc.)

W-2: Megafac F176 (manufactured by DIC Corporation; fluorine-based surfactant)

W-3: polysiloxane polymer KP-341 (manufactured by Shin-Etsu Chemical Co., Ltd.; silicon-based surfactant)

### EB Exposure (Positive Alkali Development)

### Examples EB-P1 to EB-P14 and Comparative Example C-EB-P1

(1) Coating Liquid Preparation and Application of Active Light Sensitive or Radiation Sensitive Composition

A coating liquid composition having the compositional ratio shown in the following Table 1 was microfiltered using a membrane filter having a pore size of 0.1 μm, whereby an active light sensitive or radiation sensitive composition (positive resist composition) solution was obtained.

This active light sensitive or radiation sensitive composition solution was applied to a 8-inch Si wafer subjected to a hexamethyldisilazane (HMDS) treatment using a spin coater Mark 8 manufactured by Tokyo Electron Limited, and dried on a hot plate at 110° C. for 90 seconds, whereby a resist film having a thickness of 50 nm was obtained.

TABLE 1
Positive type composition

| Resist | | | Acid | | Basic | | Cross- | | | | | | Solid content |
|---|---|---|---|---|---|---|---|---|---|---|---|---|---|
| compo- | | | gener- | | com- | | linking | | Surfac- | | | (mass | concentration |
| sition | Resin | (g) | ator | (g) | pound | (g) | agent | (g) | tant | (g) | Solvent | ratio) | (% by weight) |
| R-1 | PA-5 | 10 | PAG-1 | 0.9 | Q-1 | 0.15 | NC-1 | 0.1 | W-3 | 0.05 | SL-3/SL-4 | 80/20 | 1.5 |
| R-2 | PA-6 | 10 | PAG-2 | 1.0 | Q-2 | 0.15 | NC-3 | 0.12 | W-1 | 0.05 | SL-1/SL-5 | 70/30 | 1.5 |
| R-3 | PA-7 | 10 | PAG-3 | 0.9 | Q-3 | 0.19 | NC-6 | 0.14 | W-1 | 0.05 | SL-1/SL-7 | 90/10 | 1.5 |
| R-4 | PA-8 | 10 | PAG-4 | 0.8 | Q-5 | 0.15 | NC-5 | 0.2 | W-2 | 0.05 | SL-3/SL-6 | 70/30 | 1.5 |
| R-5 | PNA-1 | 10 | PAG-5 | 0.9 | Q-4 | 0.19 | | | W-1 | 0.05 | SL-1/SL-5/ | 70/20/10 | 1.5 |
| | | | | | | | | | | | SL-7 | | |
| R-6 | PA-5/ | 5/5 | NB-1 | 1.0 | Q-2 | 0.15 | | | W-3 | 0.05 | SL-1/SL-6 | 80/20 | 1.5 |
| | NA-1 | | | | | | | | | | | | |
| R-7 | PNA-1 | 10 | NB-2 | 0.9 | Q-3 | 0.19 | | | | | SL-2/SL-7 | 90/10 | 1.5 |
| R-8 | PA-6 | 10 | NB-3 | 1.1 | Q-4 | 0.19 | | | W-3 | 0.05 | SL-1/SL-5 | 80/20 | 1.5 |
| R-9 | PA-7 | 10 | NB-4 | 1.0 | Q-5 | 0.15 | | | W-2 | 0.05 | SL-1/SL-5 | 60/40 | 1.5 |
| R-10 | PA-8 | 10 | PAG-1/ | 0.6/0.6 | Q-4 | 0.15 | NC-4 | 0.2 | W-1 | 0.05 | SL-1/SL-5 | 60/40 | 1.5 |
| | | | PAG-5 | | | | | | | | | | |
| R-11 | PA-5/ | 7/3 | PAG-3 | 0.9 | Q-1 | 0.15 | | | W-2 | 0.05 | SL-3/SL-6 | 90/10 | 1.5 |
| | NA-4 | | | | | | | | | | | | |
| R-12 | PA-6/ | 8.5/1.5 | PAG-4 | 1.1 | Q-2 | 0.15 | | | W-3 | 0.05 | SL-1/SL-5 | 80/20 | 1.5 |
| | NA-5 | | | | | | | | | | | | |
| R-13 | PA-7/ | 9/1 | PAG-5 | 0.9 | Q-3 | 0.19 | | | W-1 | 0.05 | SL-1/SL-5 | 60/40 | 1.5 |
| | NA-6 | | | | | | | | | | | | |
| R-14 | PA-6 | 5 | PAG-6 | 5 | | | NC-3 | 0.12 | W-2 | 0.05 | SL-3/SL-6 | 90/10 | 1.5 |
| R-15 | PA-5 | 10 | PAG-1 | 0.9 | Q-1 | 0.15 | | | W-3 | 0.05 | SL-3/SL-4 | 80/20 | 1.5 |

(2) EB Exposure and Development (Positive Alkali Development)

By using an electron beam irradiation instrument (JBX 6000 manufactured by JEOL, Ltd.; accelerating voltage of 50 keV), the resist film obtained in (1) was exposed for every 2.5 nm to form a line pattern (a longitudinal direction of 0.2 mm, the number of drawing lines of 40) with a line width of 30 nm while changing the irradiation amount (referred to as EB exposure (1)). After irradiation, the resultant product was heated on a hot plate at 100° C. for 90 seconds.

Subsequently, the resultant product was developed for 30 seconds using a 2.38% by mass tetramethylammonium hydroxide (TMAH) solution, then, washed with pure water, and finally, dried by being rotated at a high speed of 2000 rpm for 20 seconds.

Evaluations of the resolving power, the line width roughness (LWR), the pattern shape were performed on the obtained pattern by the following method. The evaluation results are shown in the following Table 2.

(2-1) Resolving Power (LS Resolving Power)

The cross-sectional shape of the obtained pattern was observed by using a scanning electron microscope (S-4300 manufactured by Hitachi, Ltd.). The marginal resolving power (a minimum line width at which a line and a space (line:space=1:1) are separately resolved) at the irradiation amount (sensitivity) when resolving a resist pattern of a line and space in a ratio of 1:1 having a line width of 30 nm was taken as a resolving power (nm). A smaller value indicates a better performance.

(2-2) Line Width Roughness (LWR)

For arbitrary 30 points in a longitudinal direction of 5 μm of the line pattern with a line width of 30 nm at the irradiation amount at which the above sensitivity was exhibited, the line widths were measured, and the deviation was evaluated based on the obtained 3σ. A smaller value indicates a better performance.

(2-3) Pattern Shape

In the sectional shape of the line pattern obtained by observing a sectional shape of the line and space pattern in a ratio of 1:1 having a line width of 30 nm at the irradiation amount at which the above sensitivity was exhibited using a scanning electron microscope (S-4800 manufactured by Hitachi, Ltd.), a case where the ratio represented by [line width at the top portion (surface portion) of a line pattern/line width at the center portion (height position at half the height of a line pattern) of a line pattern] was 1.2 or greater was evaluated as “reverse taper”, a case where the ratio was 1.05 or greater and less than 1.2 was evaluated as “slight reverse tape”, and a case where the ratio was less than 1.05 was evaluated as “rectangle”.

TABLE 2
EB-positive alkali development

| | | | LS resolving | | |
|---|---|---|---|---|---|
| | Exposure | Resist | power | Pattern | LWR |
| | conditions | composition | [nm] | shape | [nm] |
| Examples | | | | | |
| Example EB-P1 | EB exposure (1) | R-1 | 30 | Rectangular | 6.0 |
| Example EB-P2 | EB exposure (1) | R-2 | 27.5 | Rectangular | 5.8 |
| Example EB-P3 | EB exposure (1) | R-3 | 29.5 | Rectangular | 5.9 |
| Example EB-P4 | EB exposure (1) | R-4 | 27.5 | Rectangular | 5.7 |
| Example EB-P5 | EB exposure (1) | R-5 | 25 | Rectangular | 5.1 |
| Example EB-P6 | EB exposure (1) | R-6 | 27.5 | Rectangular | 5.3 |
| Example EB-P7 | EB exposure (1) | R-7 | 27.5 | Rectangular | 5.7 |
| Example EB-P8 | EB exposure (1) | R-8 | 25 | Rectangular | 5.6 |
| Example EB-P9 | EB exposure (1) | R-9 | 29 | Rectangular | 5.9 |
| Example EB-P10 | EB exposure (1) | R-10 | 28.5 | Rectangular | 5.7 |
| Example EB-P11 | EB exposure (1) | R-11 | 27.5 | Rectangular | 5.4 |
| Example EB-P12 | EB exposure (1) | R-12 | 27.5 | Rectangular | 5.3 |
| Example EB-P13 | EB exposure (1) | R-13 | 27.5 | Rectangular | 5.3 |
| Example EB-P14 | EB exposure (1) | R-14 | 27.5 | Rectangular | 5.6 |
| Comparative | | | | | |
| Example | | | | | |
| Comparative | EB exposure A | R-15 | 40 | Reverse | 10.9 |
| Example C-EB-P1 | | | | taper | |

As apparent from the results shown in Table 2, it was found that Examples EB-P1 to EB-P14 can satisfy high resolving power, an excellent pattern shape, and low line width roughness (LWR) at the same time to a high level in formation of a very fine pattern (for example, a line width of 50 nm or less), compared to Comparative Example C-EB-P1.

### EB Exposure (Negative Alkali Development)

### Examples EB-N1 to EB-N14 and Comparative Example C-EB-N1

(1) Coating Liquid Preparation and Application of Active Light Sensitive or Radiation Sensitive Composition

A coating liquid composition having the compositional ratio shown in the following Table 3 was microfiltered using a membrane filter having a pore size of 0.1 μm, whereby an active light sensitive or radiation sensitive composition (negative resist composition) solution was obtained.

This active light sensitive or radiation sensitive composition solution was applied to a 8-inch Si wafer subjected to a hexamethyldisilazane (HMDS) treatment using a spin coater Mark 8 manufactured by Tokyo Electron Limited, and dried on a hot plate at 110° C. for 90 seconds, whereby a resist film having a thickness of 50 nm was obtained.

TABLE 3
Negative type composition

| Resist | | | Acid | | Basic | | Cross | | | | | | | | Solid content |
|---|---|---|---|---|---|---|---|---|---|---|---|---|---|---|---|
| compo- | | | gener- | | com- | | -linking | | Addi- | | Surfac- | | | (mass | concentration |
| sition | Resin | (g) | ator | (g) | pound | (g) | agent | (g) | tive | (g) | tant | (g) | Solvent | ratio) | (% by weight) |
| R-16 | P-1 | 10 | PB-1 | 2.7 | Q-1 | 0.45 | NC-1 | 4 | | | W-2 | 0.05 | SL-2/SL-7 | 90/10 | 1.5 |
| R-17 | P-2 | 10 | PB-2 | 3.0 | Q-4 | 0.57 | NC-3 | 2 | | | W-3 | 0.05 | SL-3/SL-6 | 90/10 | 1.5 |
| R-18 | P-3 | 10 | PB-3 | 2.7 | Q-3 | 0.57 | NC-6 | 2.4 | | | W-2 | 0.05 | SL-1/SL-5 | 80/20 | 1.5 |
| R-19 | NA-1 | 10 | PB-1/ | 1.2/1.2 | Q-2 | 0.45 | | | | | W-1 | 0.05 | SL-1/SL-5 | 70/30 | 1.5 |
| | | | PB-2 | | | | | | | | | | | | |
| R-20 | NA-2 | 10 | PB-2 | 3.0 | Q-2 | 0.45 | | | | | W-3 | 0.05 | SL-1/SL-5 | 80/20 | 1.5 |
| R-21 | NA-3 | 10 | PB-3 | 2.7 | Q-3 | 0.57 | | | | | W-1 | 0.05 | SL-1/SL-5 | 60/40 | 1.5 |
| R-22 | PA-1 | 10 | PAG-1 | 2.7 | Q-4 | 0.57 | NC-5 | 3.2 | | | W-2 | 0.05 | SL-1/SL-5 | 60/40 | 1.5 |
| R-23 | PA-2 | 10 | PAG-2 | 3.3 | Q-4 | 0.45 | NC-1 | 3.6 | | | W-3 | 0.05 | SL-3/SL-4 | 80/20 | 1.5 |
| R-24 | PA-3 | 10 | NB-5 | 3.0 | Q-2 | 0.45 | NC-2/ | 3.6/1.2 | | | W-1 | 0.05 | SL-1/SL-5/ | 70/20/10 | 1.5 |
| | | | | | | | NC-3 | | | | | | SL-7 | | |
| R-25 | PA-4 | 10 | PAG-3 | 3.6 | Q-1 | 0.45 | NC-4 | 4 | | | W-1 | 0.05 | SL-1/SL-6 | 80/20 | 1.5 |
| R-26 | P-1 | 10 | PAG-1 | 2.7 | Q-5 | 0.45 | NC-1 | 4.4 | PC | 0.2 | W-3 | 0.05 | SL-1/SL-7 | 90/10 | 1.5 |
| R-27 | PNA-2 | 10 | PAG-4 | 3.3 | Q-3 | 0.57 | | | | | W-1 | 0.05 | SL-3/SL-6 | 70/30 | 1.5 |
| R-28 | P-1/ | 2/8 | PAG-5 | 2.7 | Q-5 | 0.45 | NC-3 | 4 | | | W-3 | 0.05 | SL-1/SL-5 | 60/40 | 1.5 |
| | PA-5 | | | | | | | | | | | | | | |
| R-29 | | | PAG-7 | 10 | Q-2 | 0.45 | NC-1 | 4.4 | | | W-3 | 0.05 | SL-1/SL-5 | 60/40 | 1.5 |
| R-30 | P-1 | 10 | PAG-1 | 0.9 | Q-1 | 0.15 | NC-1 | 1 | | | W-3 | 0.05 | SL-3/SL-4 | 80/20 | 1.5 |

(2) EB Exposure and Development (Negative Alkali Development)

By using an electron beam irradiation instrument (JBX 6000 manufactured by JEOL, Ltd.; accelerating voltage of 50 keV), the resist film obtained above was exposed for every 2.5 nm to form a line pattern (a longitudinal direction of 0.2 mm, the number of drawing lines of 40) with a line width of 25 nm to 40 nm while changing the irradiation amount (referred to as EB exposure (2)). After irradiation, the resultant product was heated on a hot plate at 100° C. for 90 seconds.

Subsequently, the resultant product was developed for 30 seconds using a 2.38% by mass tetramethylammonium hydroxide (TMAH) solution, then, washed with pure water, and finally, dried by being rotated at a high speed of 2000 rpm for 20 seconds.

Evaluations of the resolving power, the line width roughness, and the pattern shape were performed on the obtained pattern in the same manner as in the method described in [EB Exposure (positive alkali development)]. The evaluation results are shown in the following Table 4.

TABLE 4
EB-negative alkali development

| | | | LS resolving | | |
|---|---|---|---|---|---|
| | Exposure | Resist | power | Pattern | LWR |
| | conditions | composition | [nm] | shape | [nm] |
| Examples | | | | | |
| Example EB-N1 | EB exposure (2) | R-16 | 30 | Rectangular | 6.1 |
| Example EB-N2 | EB exposure (2) | R-17 | 27.5 | Rectangular | 5.2 |
| Example EB-N3 | EB exposure (2) | R-18 | 27.5 | Rectangular | 5.3 |
| Example EB-N4 | EB exposure (2) | R-19 | 29 | Rectangular | 5.6 |
| Example EB-N5 | EB exposure (2) | R-20 | 27.5 | Rectangular | 5.7 |
| Example EB-N6 | EB exposure (2) | R-21 | 27.5 | Rectangular | 5.7 |
| Example EB-N7 | EB exposure (2) | R-22 | 22.5 | Rectangular | 4.9 |
| Example EB-N8 | EB exposure (2) | R-23 | 27.5 | Rectangular | 5.4 |
| Example EB-N9 | EB exposure (2) | R-24 | 27.5 | Rectangular | 5.3 |
| Example EB-N10 | EB exposure (2) | R-25 | 27.5 | Rectangular | 5.8 |
| Example EB-N11 | EB exposure (2) | R-26 | 29 | Rectangular | 5.9 |
| Example EB-N12 | EB exposure (2) | R-27 | 25 | Rectangular | 5.2 |
| Example EB-N13 | EB exposure (2) | R-28 | 27.5 | Rectangular | 5.7 |
| Example EB-N14 | EB exposure (2) | R-29 | 27.5 | Rectangular | 5.4 |
| Comparative | | | | | |
| Example | | | | | |
| Comparative | EB exposure (2) | R-30 | 37.5 | Reverse | 8.7 |
| Example C-EB-N1 | | | | taper | |

As apparent from the results shown in Table 4, it was found that Examples EB-N1 to EB-N14 can satisfy high resolving power, an excellent pattern shape, low line width roughness (LWR) at the same time to a high level in formation of a very fine pattern (for example, a line width of 50 nm or less), compared to Comparative Example C-EB-N1.

### EUV Exposure (Positive Alkali Development)

### Examples EUV-P1 to EUV-P14 and Comparative Example C-EUV-P1

(1) Coating Liquid Preparation and Application of Active Light Sensitive or Radiation Sensitive Composition

The positive resist composition shown in Table 1 was microfiltered using a polytetrafluoroethylene filter having a pore size of 0.04 μm, whereby an active light sensitive or radiation sensitive composition (positive resist composition) solution was obtained.

This active light sensitive or radiation sensitive composition solution was applied to a 6-inch Si wafer using a spin coater Mark 8 manufactured by Tokyo Electron Limited, and dried on a hot plate at 110° C. for 90 seconds, whereby a resist film having a thickness of 50 nm was obtained. That is, a resist-coated mask blank was obtained.

(2) EUV Exposure and Development (Positive Alkali Development)

Using EUV light (wavelength of 13 nm), exposure was performed on the resist film of the resist-coated mask blank obtained in (1) above through a reflective mask of a line and space pattern in a ratio of 1:1 having a line width of 50 nm (referred to as EUV exposure (1)), and followed by baking at 110° C. for 90 seconds. Thereafter, development was performed using a 2.38% by mass tetramethylammonium hydroxide (TMAH) solution.

Evaluations of the resolving power, the line width roughness (LWR), the pattern shape were performed on the obtained pattern by the following method.

(2-1) Resolving Power (LS Resolving Power)

The cross-sectional shape of the obtained pattern was observed by using a scanning electron microscope (S-4300 manufactured by Hitachi, Ltd.). The marginal resolving power (a minimum line width at which a line and a space (line:space=1:1) are separately resolved) at the exposure amount (sensitivity) when resolving a resist pattern of a line and space in a ratio of 1:1 having a line width of 50 nm was taken as a resolving power (nm).

(2-2) Line Edge Roughness (LWR)

For arbitrary 30 points in a longitudinal direction of 50 μm of the line pattern with a line width of 50 nm in the exposure amount at which the above sensitivity was exhibited, the line widths were measured, and the deviation was evaluated based on the obtained 36. A smaller value indicates a better performance.

(2-3) Pattern Shape

A sectional shape of the line and space pattern in a ratio of 1:1 having a line width of 50 nm at the exposure amount at which the above sensitivity was exhibited was observed using a scanning electron microscope (S-4300 manufactured by Hitachi, Ltd.). In the sectional shape of the line pattern, a case where the ratio represented by [line width at the top portion (surface portion) of a line pattern/line width at the center portion (height position at half the height of a line pattern) of a line pattern] was 1.2 or greater was evaluated as “reverse tape”, a case where the ratio was 1.05 or greater and less than 1.2 was evaluated as “slight reverse taper”, a case where the ratio was 0.95 or greater and less than 1.05 was evaluated as “rectangle”, and a case where the ratio was less than 0.95 was evaluated as “taper”. The pattern shape is preferably “rectangle”.

TABLE 5
EUV-positive alkali development

| | | | LS resolving | | |
|---|---|---|---|---|---|
| | Exposure | Resist | power | Pattern | LWR |
| | conditions | composition | [nm] | shape | [nm] |
| Examples | | | | | |
| Example EUV-P1 | EUV exposure (1) | R-1 | 22 | Rectangular | 4.5 |
| Example EUV-P2 | EUV exposure (1) | R-2 | 20 | Rectangular | 4.4 |
| Example EUV-P3 | EUV exposure (1) | R-3 | 21 | Rectangular | 4.3 |
| Example EUV-P4 | EUV exposure (1) | R-4 | 21 | Rectangular | 4.3 |
| Example EUV-P5 | EUV exposure (1) | R-5 | 18 | Rectangular | 3.9 |
| Example EUV-P6 | EUV exposure (1) | R-6 | 20 | Rectangular | 4.2 |
| Example EUV-P7 | EUV exposure (1) | R-7 | 20 | Rectangular | 4.3 |
| Example EUV-P8 | EUV exposure (1) | R-8 | 21 | Rectangular | 4.2 |
| Example EUV-P9 | EUV exposure (1) | R-9 | 21 | Rectangular | 4.4 |
| Example EUV-P10 | EUV exposure (1) | R-10 | 20 | Rectangular | 4.3 |
| Example EUV-P11 | EUV exposure (1) | R-11 | 21 | Rectangular | 4.1 |
| Example EUV-P12 | EUV exposure (1) | R-12 | 19 | Rectangular | 4.0 |
| Example EUV-P13 | EUV exposure (1) | R-13 | 20 | Rectangular | 4.1 |
| Example EUV-P14 | EUV exposure (1) | R-14 | 20 | Rectangular | 4.3 |
| Comparative | | | | | |
| Example | | | | | |
| Comparative | EUV exposure (1) | R-15 | 31.5 | Taper | 8.4 |
| Example C-EUV-P1 | | | | | |

As apparent from the results shown in Table 5, it was found that Examples EUV-P1 to EUV-P14 can satisfy high resolving power, an excellent pattern shape, low line width roughness (LWR) at the same time to a high level in formation of a very fine pattern (for example, a line width of 50 nm or less), compared to Comparative Example C-EUV-P1.

### EUV Exposure (Negative Alkali Development)

### Examples EUV-N1 to EUV-N14 and Comparative Example C-EUV-N1

(1) Coating Liquid Preparation and Application of Active Light Sensitive or Radiation Sensitive Composition

The negative resist composition shown in Table 3 was microfiltered using a polytetrafluoroethylene filter having a pore size of 0.04 μm, whereby an active light sensitive or radiation sensitive composition (negative resist composition) solution was obtained.

This active light sensitive or radiation sensitive composition solution was applied to a 6-inch Si wafer using a spin coater Mark 8 manufactured by Tokyo Electron Limited, and dried on a hot plate at 110° C. for 90 seconds, whereby a resist film having a thickness of 50 nm was obtained. That is, a resist-coated mask blank was obtained.

(2) EUV Exposure and Development (Negative Alkali Development)

Using EUV light (wavelength of 13 nm), exposure was performed on the resist film obtained above through a reflective mask of a line and space pattern in a ratio of 1:1 having a line width of 50 nm (referred to as EUV exposure (2)), and followed by baking at 110° C. for 90 seconds. Thereafter, development was performed using a 2.38% by mass tetramethylammonium hydroxide (TMAH) solution.

Evaluations of the resolving power, the line width roughness (LWR), and the pattern shape were performed on the obtained pattern by the method described in [EUV Exposure (positive alkali development)].

TABLE 6
EUV-negative alkali development

| | | | LS resolving | | |
|---|---|---|---|---|---|
| | Exposure | Resist | power | Pattern | LWR |
| | conditions | composition | [nm] | shape | [nm] |
| Examples | | | | | |
| Example EUV-N1 | EUV exposure (2) | R-16 | 22 | Rectangular | 4.7 |
| Example EUV-N2 | EUV exposure (2) | R-17 | 20 | Rectangular | 4.2 |
| Example EUV-N3 | EUV exposure (2) | R-18 | 20 | Rectangular | 4.4 |
| Example EUV-N4 | EUV exposure (2) | R-19 | 21 | Rectangular | 4.1 |
| Example EUV-N5 | EUV exposure (2) | R-20 | 21 | Rectangular | 4.1 |
| Example EUV-N6 | EUV exposure (2) | R-21 | 20 | Rectangular | 4.4 |
| Example EUV-N7 | EUV exposure (2) | R-22 | 18 | Rectangular | 4.5 |
| Example EUV-N8 | EUV exposure (2) | R-23 | 19 | Rectangular | 4.3 |
| Example EUV-N9 | EUV exposure (2) | R-24 | 20 | Rectangular | 4.2 |
| Example EUV-N10 | EUV exposure (2) | R-25 | 21 | Rectangular | 4.1 |
| Example EUV-N11 | EUV exposure (2) | R-26 | 20 | Rectangular | 4.5 |
| Example EUV-N12 | EUV exposure (2) | R-27 | 21 | Rectangular | 4.1 |
| Example EUV-N13 | EUV exposure (2) | R-28 | 20 | Rectangular | 4.3 |
| Example EUV-N14 | EUV exposure (2) | R-29 | 20 | Rectangular | 4.4 |
| Comparative | | | | | |
| Example | | | | | |
| Comparative | EUV exposure (2) | R-30 | 30 | Reverse | 8.8 |
| Example C-EUV-N1 | | | | taper | |

As apparent from the results shown in Table 6, it was found that Examples EUV-N1 to EUV-N14 can satisfy high resolving power, an excellent pattern shape, low line width roughness (LWR) at the same time to a high level in formation of a very fine pattern (for example, a line width of 50 nm or less), compared to Comparative Example C-EUV-N1.

According to the present invention, it is possible to provide an active light sensitive or radiation sensitive composition which can satisfy high resolving power, an excellent pattern shape, and low line width roughness (LWR) at the same time to a high level in formation of a very fine pattern (for example, a line width of 50 nm or less).

In addition, according to the present invention, it is possible to provide a resist film, a pattern forming method, a resist-coated mask blank, a method for producing a photomask, a photomask, a method for manufacturing an electronic device, and an electronic device, each of which uses the active light sensitive or radiation sensitive composition.

The present invention has been described in detail and with reference to specific embodiments, and it is apparent to those skilled in the art that various modifications and changes are possible without departing from the spirit and the scope of the present invention.

This application is based on Japanese Patent Application (Japanese Patent Application No. 2013-200599) filed on Sep. 26, 2013, and the contents thereof are incorporated herein by reference.

What is claimed is:

1. An active light sensitive or radiation sensitive composition, comprising:
(A) a compound that generates an acid by irradiation with active light or radiation;
(P) a compound of which the solubility in alkali developers is increased due to the action of an acid; and
(N) at least one compound selected from the group consisting of the following [N-A], [N-B], and [N-C],
wherein [N-A] is a resin of which the solubility in alkali developers is decreased due to the action of an acid, active light or radiation, or an activated species,
[N-B] is a compound that generates an acid by irradiation with active light or radiation, and of which the solubility in alkali developers is decreased due to the action of an acid, active light or radiation, or an activated species, and
[N-C] is a low molecular compound of which the solubility in alkali developers is decreased due to the action of an acid, active light or radiation, or an activated species.

2. The active light sensitive or radiation sensitive composition according to claim 1, which is an active light sensitive or radiation sensitive composition for alkali developing type electron beam exposure or for EUV exposure.

3. The active light sensitive or radiation sensitive composition according to claim 1, which is a negative type active light sensitive or radiation sensitive composition,
wherein the content of the compound (N) is 10% by mass or greater with respect to the total solid content of the active light sensitive or radiation sensitive composition.

4. The active light sensitive or radiation sensitive composition according to claim 3,
wherein the compound (P) is a resin of which the solubility in alkali developers is increased due to the action of an acid.

5. The active light sensitive or radiation sensitive composition according to claim 4,
wherein the compound (P) is a resin having a repeating unit represented by the following General Formula (1), and 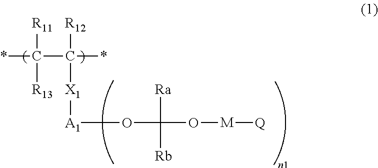
wherein, in General Formula (1),
X₁ represents a single bond or a divalent connecting group;
A₁ represents a keto group or an (n1+1) valent aromatic ring group, and each of R₁₁, R₁₂, and R₁₃ independently represents a hydrogen atom, an alkyl group, a cycloalkyl group, a halogen atom, a cyano group, or an alkoxycarbonyl group;
R₁₃ may be bonded to A₁ to form a ring, and R₁₃ in this case represents an alkylene group;
Ra represents a hydrogen atom, an alkyl group, a cycloalkyl group, an aryl group, an aralkyl group, or a heterocyclic group, and Rb represents a hydrogen atom, an alkyl group, a cycloalkyl group, an aryl group, an aralkyl group, or a heterocyclic group;
M represents a single bond or a divalent connecting group; Q represents an alkyl group, a cycloalkyl group, an aryl group, an aralkyl group, or a heterocyclic group; Ra and Rb may be bonded to each other to form a ring; at least two of Ra, M, and Q may be bonded to each other to form a ring; and
when A₁ is a keto group, n1 represents 1, and when A₁ is an (n+1) valent aromatic group, n1 represents an integer of 1 to 4; and when n1 is 2 or greater, a plurality of Ra's, a plurality of Rb's, a plurality of M's, and a plurality of Q's may be the same as or different from each other, respectively.

6. The active light sensitive or radiation sensitive composition according to claim 3, further comprising, as the compound (N):
a compound having a molecular weight of 500 or greater.

7. The active light sensitive or radiation sensitive composition according to claim 3, still further comprising, as the compound (N):
a compound (N-1) of which the solubility in alkali developers is decreased due to the action of an acid.

8. The active light sensitive or radiation sensitive composition according to claim 3,
wherein the compound (A) is a resin containing a repeating unit having a portion that generates an acid by irradiation with active light or radiation.

9. The active light sensitive or radiation sensitive composition according to claim 3, still further comprising:
(C) a basic compound or an ammonium salt compound, of which the basicity is decreased by irradiation with active light or radiation.

10. The active light sensitive or radiation sensitive composition according to claim 9,
wherein the compound (C) is a sulfonium salt having a nitrogen atom on the cation thereof.

11. The active light sensitive or radiation sensitive composition according to claim 1, which is a positive type active light sensitive or radiation sensitive composition,
wherein the content of the compound (N) is 1% by mass or greater with respect to the total solid content of the active light sensitive or radiation sensitive composition.

12. The active light sensitive or radiation sensitive composition according to claim 11,
wherein the compound (P) is a resin of which the solubility in alkali developers is increased due to the action of an acid.

13. The active light sensitive or radiation sensitive composition according to claim 12,
wherein the compound (P) is a resin having a repeating unit represented by the following General Formula (1), and 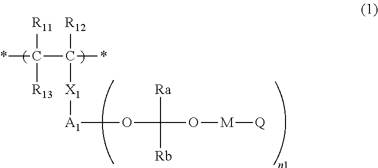
wherein, in General Formula (1),
X₁ represents a single bond or a divalent connecting group;
A₁ represents a keto group or an (n1+1) valent aromatic ring group, and each of R₁₁, R₁₂, and R₁₃ independently represents a hydrogen atom, an alkyl group, a cycloalkyl group, a halogen atom, a cyano group, or an alkoxycarbonyl group;
R₁₃ may be bonded to A₁ to form a ring, and R₁₃ in this case represents an alkylene group;
Ra represents a hydrogen atom, an alkyl group, a cycloalkyl group, an aryl group, an aralkyl group, or a heterocyclic group, and Rb represents a hydrogen atom, an alkyl group, a cycloalkyl group, an aryl group, an aralkyl group, or a heterocyclic group;
M represents a single bond or a divalent connecting group; Q represents an alkyl group, a cycloalkyl group, an aryl group, an aralkyl group, or a heterocyclic group; Ra and Rb may be bonded to each other to form a ring; at least two of Ra, M, and Q may be bonded to each other to form a ring; and
when A₁ is a keto group, n1 represents 1, and when A₁ is an (n+1) valent aromatic group, n1 represents an integer of 1 to 4; and when n1 is 2 or greater, a plurality of Ra's, a plurality of Rb's, a plurality of M's, and a plurality of Q's may be the same as or different from each other, respectively.

14. The active light sensitive or radiation sensitive composition according to claim 11, still further comprising, as the compound (N):
a compound having a molecular weight of 500 or greater.

15. The active light sensitive or radiation sensitive composition according to claim 11, still further comprising, as the compound (N):
a compound (N-1) of which the solubility in alkali developers is decreased due to the action of an acid.

16. The active light sensitive or radiation sensitive composition according to claim 11,
wherein the compound (A) is a resin containing a repeating unit having a portion that generates an acid by irradiation with active light or radiation.

17. The active light sensitive or radiation sensitive composition according to claim 11, still further containing (C) the basic compound or an ammonium salt compound, of which the basicity is decreased by irradiation with active light or radiation.

18. The active light sensitive or radiation sensitive composition according to claim 17,
wherein the compound (C) is a sulfonium salt having a nitrogen atom on the cation thereof.

19. A resist film which is formed using the active light sensitive or radiation sensitive composition according to claim 1.

20. A pattern forming method, comprising:
(a) forming a film using an active light sensitive or radiation sensitive composition according to claim 1;
(b) exposing the film; and
(c) developing the exposed film using an alkali developer.

21. A resist-coated mask blank coated with the active light sensitive or radiation sensitive composition according to claim 1.

22. A method for producing a photomask, comprising:
exposing the resist-coated mask blank according to claim 21 to an electron beam or EUV light; and
developing the exposed mask blank using an alkali developer.

23. A photomask obtained by the method for producing a photomask according to claim 22.

24. A method for manufacturing an electronic device, comprising:
the pattern forming method according to claim 20.

25. An electronic device manufactured by the method for manufacturing an electronic device according to claim 24.
